(19) United States
(12) Patent Application Publication
(10) Pub. No.: US 2026/0058674 A1
(43) Pub. Date: Feb. 26, 2026

(54) POLAR CODE ENCODING METHOD AND APPARATUS, AND DECODING METHOD AND APPARATUS

(71) Applicant: HUAWEI TECHNOLOGIES CO., LTD., Shenzhen (CN)

(72) Inventors: Jun Wang, Hangzhou (CN); Wen Tong, Ottawa (CA); Xianbin Wang, Hangzhou (CN); Rong Li, Boulogne Billancourt (FR); Yourui HuangFu, Hangzhou (CN); Shengchen Dai, Hangzhou (CN); Huazi Zhang, Hangzhou (CN); Jian Wang, Beijing (CN)

(21) Appl. No.: 19/372,704

(22) Filed: Oct. 29, 2025

Related U.S. Application Data
(63) Continuation of application No. 18/151,976, filed on Jan. 9, 2023, now Pat. No. 12,483,274.
Application No. 18/151,976 is a continuation of application No. PCT/CN2021/101177, filed on Jun. 21, 2021.

(30) Foreign Application Priority Data
Jul. 10, 2020 (CN) 202010663589.9

(51) Int. Cl. H03M 13/09; H03M 13/00

(52) U.S. Cl. CPC H03M 13/09; H03M 13/611

(57) ABSTRACT

This application discloses a polar decoding method, apparatus, and a medium used in wireless communication. An example method includes: obtaining, a to-be-decoded information sequence, wherein the to-be-decoded information sequence comprises K to-be-decoded bits; determining a mother code length N and a first sequence, wherein the first sequence comprises sequence numbers of N polarized subchannels, the sequence numbers of the N polarized subchannels are arranged in the first sequence based on reliability of the N polarized subchannels, N=2ⁿ, K≤N, N is greater than or equal to 32, and K, n, and N are positive integers; determining, based on the first sequence, K polarized subchannels used to contain the K to-be-decoded bits, and decoding the to-be-decoded information sequence to obtain a decoding result.

### CROSS-REFERENCE TO RELATED APPLICATIONS

This application is a continuation of U.S. patent application Ser. No. 18/151,976, filed on Jan. 9, 2023, which is a continuation of International Patent Application No. PCT/CN2021/101177, filed on Jun. 21, 2021, which claims priority to Chinese Patent Application No. 202010663589.9, filed on Jul. 10, 2020. All of the afore-mentioned patent applications are hereby incorporated by reference in their entireties.

### TECHNICAL FIELD

Embodiments of this application relate to the field of communications technologies, and in particular, to a polar code encoding method and apparatus.

### BACKGROUND

Channel encoding, as a most fundamental radio access technology, is crucial in ensuring reliable data transmission. In an existing wireless communications system, turbo code, low density parity check (LDPC) code, and polar code are usually used to perform channel encoding. The turbo code cannot support information transmission at an excessively low or high code rate. Due to encoding/decoding features of the turbo code and the LDPC code, for medium and short packet transmission, it is difficult for the turbo code and the LDPC code to achieve ideal performance in a case of a limited code length. During implementation, the turbo code and the LDPC code have high computation complexity in an encoding/decoding implementation process. The polar code is high-performance code that has been theoretically proved to be capable of achieving Shannon capacity and that has low encoding/decoding complexity, and therefore is applied increasingly widely.

In a 5th generation (5G) communications system, the polar code is determined as an encoding scheme of a control channel. Because a data amount included in the control channel is usually not large, a code block is not large. In the 3GPP standard, only a reliability ranking sequence whose mother code length is Nₘₐₓ=1024 is specified, and is used to sort reliability of 1024 subchannels to select a location of an information bit. For another case in which the mother code length N is less than 1024, a subsequence of the reliability ranking sequence in which Nₘₐₓ=1024 may be used as a corresponding reliability ranking sequence. A system design can be simplified by using this sequence nesting feature.

However, during data channel encoding, a long code block needs to be used for encoding in a plurality of cases. In this case, it is not enough to still use the reliability ranking sequence in which Nₘₐₓ=1024. Therefore, how to design a long reliability ranking sequence to meet a requirement of a data channel becomes a problem that needs to be resolved.

### SUMMARY

Embodiments of this application provide a polar code encoding method and apparatus applied to wireless communication, to support polar code encoding of a large data block, and to allow backward compatibility with a reliability ranking sequence supported by an existing NR system. This reuses the conventional technology to a maximum extent.

Specific technical solutions provided in embodiments of this application are as follows.

According to a first aspect, a polar code encoding method is provided, including:

An encoding apparatus obtains K to-be-encoded bits, a mother code length N, and a first sequence, where the first sequence includes sequence numbers of N polarized subchannels, the sequence numbers of the N polarized subchannels are arranged in the first sequence based on reliability of the N polarized subchannels, N=2ⁿ, and K≤N, N is greater than or equal to 32, and K, n, and N are positive integers;
determines, based on the first sequence, K polarized subchannels used to contain the K to-be-encoded bits, and performs polarization encoding on the K to-be-encoded bits to obtain an encoded bit sequence;
performs rate matching on the encoded sequence to obtain a rate-matched sequence; and
outputs the rate-matched sequence, where
the first sequence is any Q sequence whose length is N in the appendix.

This design fits a feature of a large data block, and can be backward compatible with a reliability ranking sequence supported by an existing NR system. This reduces implementation difficulty.

In a possible design, the first sequence is a subsequence of a second sequence, the second sequence includes sequence numbers of Nₘₐₓ polarized subchannels, the sequence numbers of the Nₘₐₓ polarized subchannels are arranged in the second sequence based on reliability of the Nₘₐₓ polarized subchannels, N is less than or equal to Nₘₐₓ, and Nₘₐₓ=2ⁿ^{ₘₐₓ}, where nₘₐₓ is a positive integer, n is less than or equal to nₘₐₓ, and the second sequence is any Q sequence whose length is Nₘₐₓ in the appendix.

In a possible design, the K to-be-encoded bits include a cyclic redundancy check bit.

In a possible design, the K to-be-encoded bits include a parity check bit.

In a possible design, the polar encoding method is performed by a network device or a terminal.

In a possible design, the determining, based on the first sequence, K polarized subchannels used to contain the K to-be-encoded bits is: when M is less than or equal to N, mapping the K to-be-encoded bits to the K polarized subchannels with high reliability in M-P non-punctured polarized subchannels to enable reliability of the polarized subchannels containing the K to-be-encoded bits to be higher than reliability of remaining M−P−K polarized subchannels, where M is a target code length, P is a quantity of pre-frozen polarized subchannels, and P is greater than or equal to 0.

In a possible design, the first sequence is prestored.

In a possible design, the sequence numbers of the N polarized subchannels are 0 to (N−1) or 1 to N.

According to a second aspect, a polar code decoding method is provided, including:
A decoding apparatus obtains a to-be-decoded information sequence, where the to-be-decoded information sequence includes K to-be-decoded bits;
determines a mother code length N and a first sequence, where the first sequence includes sequence numbers of N polarized subchannels, the sequence numbers of the N polarized subchannels are arranged in the first sequence based on reliability of the N polarized subchannels, N=2ⁿ, K≤N, N is greater than or equal to 32, and K, n, and N are positive integers;
determines, based on the first sequence, K polarized subchannels used to contain the K to-be-decoded bits, and decodes the to-be-decoded information sequence to obtain a decoding result; and
outputs the decoding result, where
the first sequence is any Q sequence whose length is N in the appendix or a subsequence of any Q sequence whose length is greater than N in the appendix.

This design completely corresponds to the encoding method according to the first aspect, fits a feature of a large data block, and can be backward compatible with a reliability ranking sequence supported by an existing NR system. This reduces implementation difficulty.

In a possible design, the first sequence is a subsequence of a second sequence, the second sequence includes sequence numbers of Nₘₐₓ polarized subchannels, the sequence numbers of the Nₘₐₓ polarized subchannels are arranged in the second sequence based on reliability of the Nₘₐₓ polarized subchannels, N is less than or equal to Nₘₐₓ and Nₘₐₓ=2ⁿ^{ₘₐₓ}, where nₘₐₓ is a positive integer, n is less than or equal to nₘₐₓ, and the second sequence is any Q sequence whose length is Nₘₐₓ in the appendix.

In a possible design, the K to-be-decoded bits include a cyclic redundancy check bit.

In a possible design, the K to-be-decoded bits include a parity check bit.

In a possible design, the polar encoding method is performed by a network device or a terminal.

In a possible design, the determining, based on the first sequence, K polarized subchannels used to contain the K to-be-decoded bits is: when M is less than or equal to N, mapping the K to-be-decoded bits to the K polarized subchannels with high reliability in M−P non-punctured polarized subchannels to enable reliability of the polarized subchannels containing the K to-be-decoded bits to be higher than reliability of remaining M−P−K polarized subchannels, where M is a target code length, P is a quantity of pre-frozen polarized subchannels, and P is greater than or equal to 0.

In a possible design, the first sequence is prestored.

In a possible design, the sequence numbers of the N polarized subchannels are 0 to (N−1) or 1 to N.

According to a third aspect, a polar code encoding apparatus is provided. The apparatus has functions of implementing the method according to any one of the first aspect and the possible designs of the first aspect. The function may be implemented by hardware, or may be implemented by hardware executing corresponding software. The hardware or the software includes one or more modules corresponding to the foregoing function.

In a possible design, when some or all of the functions are implemented by using hardware, the polar code encoding apparatus includes: an input interface circuit, configured to obtain a to-be-encoded bit; a logical circuit, configured to perform the operation according to any one of the first aspect and the possible designs of the first aspect; and an output interface circuit, configured to output a rate-matched sequence.

Optionally, the polar code encoding apparatus may be a chip or an integrated circuit.

In a possible design, when some or all of the functions are implemented by using software, the polar code encoding apparatus includes: a memory, configured to store a program; and a processor, configured to execute the program stored in the memory. When the program is executed, the polar code encoding apparatus may implement the method according to any one of the first aspect and the possible designs of the first aspect.

Optionally, the memory may be a physically independent unit, or may be integrated with the processor.

In a possible design, when some or all of the functions are implemented by using software, the polar code encoding apparatus includes a processor. A memory configured to store a program is located outside of the polar code encoding apparatus, and the processor is connected to the memory through a circuit/cable, and is configured to read and execute the program stored in the memory.

In a possible design, the apparatus is a network device or a terminal.

According to a fourth aspect, a polar code decoding apparatus is provided. The apparatus has functions of implementing the method according to any one of the second aspect and the possible designs of the second aspect. The function may be implemented by hardware, or may be implemented by hardware executing corresponding software. The hardware or the software includes one or more modules corresponding to the foregoing function.

In a possible design, when some or all of the functions are implemented by using hardware, the polar code decoding apparatus includes: an input interface circuit, configured to obtain a to-be-decoded information sequence; a logical circuit, configured to perform the operation according to any one of the second aspect and the possible designs of the second aspect; and an output interface circuit, configured to output a decoding result.

Optionally, the polar code decoding apparatus may be a chip or an integrated circuit.

In a possible design, when some or all of the functions are implemented by using software, the polar code decoding apparatus includes: a memory, configured to store a program; and a processor, configured to execute the program stored in the memory. When the program is executed, the polar code decoding apparatus may implement the method according to any one of the second aspect and the possible designs of the second aspect.

Optionally, the memory may be a physically independent unit, or may be integrated with the processor.

In a possible design, when some or all of the functions are implemented by using software, the polar code decoding apparatus includes a processor. A memory configured to store a program is located outside of the polar code decoding apparatus, and the processor is connected to the memory through a circuit/cable, and is configured to read and execute the program stored in the memory.

In a possible design, the apparatus is a network device or a terminal.

According to a fifth aspect, a communications system is provided. The communications system includes a network device and a terminal. The network device performs the method according to the first aspect and the possible designs of the first aspect, and the terminal performs the method according to the second aspect and the possible designs of the second aspect. Alternatively, the terminal performs the method according to the first aspect and the possible designs of the first aspect, and the network device performs the method according to the second aspect and the possible designs of the second aspect.

According to a sixth aspect, a computer storage medium is provided, where the computer storage medium stores a computer program. The computer program includes instructions used to perform the method according to any one of the first aspect and the possible designs of the first aspect.

According to a seventh aspect, a computer storage medium is provided, where the computer storage medium stores a computer program. The computer program includes instructions used to perform the method according to any one of the second aspect and the possible designs of the second aspect.

According to an eighth aspect, an embodiment of this application provides a computer program product including instructions. When the instructions are run on a computer, the computer is enabled to perform the method in the foregoing aspects.

According to a ninth aspect, a wireless device is provided, including an encoding apparatus and a transceiver that are configured to implement any one of the first aspect and the possible designs of the first aspect.

The transceiver is configured to receive or send a signal.

In a possible design, the wireless device is a terminal or a network device.

According to a tenth aspect, a wireless device is provided, including a decoding apparatus and a transceiver that are configured to implement any one of the second aspect and the possible designs of the second aspect.

The transceiver is configured to receive or send a signal.

In a possible design, the wireless device is a terminal or a network device.

### BRIEF DESCRIPTION OF DRAWINGS

FIG. 1 is a schematic diagram of an architecture of a communications system to which an embodiment of this application is applied;

FIG. 2 is a schematic flowchart of a polar code encoding method according to an embodiment of this application;

FIG. 3 is a first schematic diagram of a structure of a polar code encoding apparatus according to an embodiment of this application;

FIG. 4 is a second schematic diagram of a structure of a polar code encoding apparatus according to an embodiment of this application;

FIG. 5 is a third schematic diagram of a structure of a polar code encoding apparatus according to an embodiment of this application;

FIG. 6 is a fourth schematic diagram of a structure of a polar code encoding apparatus according to an embodiment of this application;

FIG. 7 is a first schematic diagram of a structure of a polar code decoding apparatus according to an embodiment of this application;

FIG. 8 is a second schematic diagram of a structure of a polar code decoding apparatus according to an embodiment of this application;

FIG. 9 is a third schematic diagram of a structure of a polar code decoding apparatus according to an embodiment of this application; and

FIG. 10 is a fourth schematic diagram of a structure of a polar code decoding apparatus according to an embodiment of this application.

### DESCRIPTION OF EMBODIMENTS

The following describes in detail embodiments of this application with reference to accompanying drawings.

If a polar code encoding scheme used for a control channel in an existing 5G NR standard is directly applied to data without considering a feature of a data channel, because in the current 5G NR standard, a maximum mother code length of a polar code is 1024, a data packet length that can be supported is limited. Therefore, it is necessary to redesign the polar code encoding scheme, to be more suitable for the data channel. In addition, it is optimal that the polar code encoding scheme is applicable to the control channel.

Embodiments of this application provide a polar code encoding method and apparatus. A sequence number of a polarized subchannel used to send an information bit is selected based on a prestored reliability ranking sequence or a subsequence of the reliability ranking sequence, and polar code encoding is performed based on the selected sequence number of the information polarized subchannel. Then, a rate matching operation is performed on an encoded sequence, and a rate-matched sequence is output, where the rate matching operation includes repetition, puncturing, or shortening. Embodiments of this application are more applicable to the data channel. The following describes in detail the polar code encoding method and apparatus provided in embodiments of the present application with reference to the accompanying drawings.

For convenience of understanding embodiments of this application, polar code is briefly described below.

According to an encoding policy of the polar code, a noiseless channel is used to transmit information useful to a user, while a pure noisy channel is used to transmit agreed information or is not used to transmit information. The polar code is also linear block code. An encoding matrix of the polar code is G_{N}, and an encoding process is

$${x}_{1}^{N} = {u}_{1}^{N} {G}_{N} \cdot {u}_{1}^{N} = ( {u}_{1} , {u}_{2} , … , {u}_{N} )$$

is a binary row vector whose length is N (that is, a code length. It can be learned that lengths of the sequences x and u before and after encoding are both N, where N is also referred to as a mother code length). G_{N} is an N×N matrix, and

$${G}_{N} = {F}_{2}^{⊗ ( {log}_{2} ( N ) )} \cdot {F}_{2}^{⊗ ( {log}_{2} ( N ) )}$$

is defined as a Kronecker product of log₂ N matrices F₂. The matrix

$${F}_{2} = [ \begin{matrix}1 & 0 \\ 1 & 1\end{matrix} ] .$$

In some implementations, there may be a transpose matrix in

$${u}_{1}^{N}$$

and G_{N}. Because polar code performance is not affected essentially, details are not described in this application.

In a polar code encoding process, one part of bits in

$${u}_{1}^{N}$$

are used to carry information, and are referred to as a set of information bits, where a set of indexes of the bits is denoted as A; and another part of bits are set to a fixed value pre-agreed upon between a receiving end and a transmitting end, and are referred to as a set of fixed bits or a set of frozen bits, where a set of indexes of the bits is indicated by a complementary set A^{c} of A. The polar code encoding process is equivalent to:

$${x}_{1}^{N} = {u}_{A} {G}_{N .} ( A ) ⊕ {u}_{{A}^{C}} {G}_{N .} ( {A}^{C} ) .$$

Herein, G_{N}(A) is a submatrix obtained by using rows corresponding to the indexes in the set A in G_{N}, and G_{N}(A^{C}) is a submatrix obtained by using rows corresponding to the indexes in the set A^{c} in G_{N}. u_{A} is an information bit set in

$${u}_{1}^{N} ,$$

and a quantity of information bits is K. Usually, various types of check bits including but not limited to a cyclic redundancy check (CRC) bit and a parity check (PC) bit may also be included in the information bit set. u_{A}_{^{c}} is a frozen bit set in

$${u}_{1}^{N} ,$$

a quantity of frozen bits is (N−K), and the frozen bits are known bits. These frozen bits are usually set to 0. However, values of the frozen bits may be set to any value provided that the value is pre-agreed on by the receiving end and the transmitting end. Therefore, an encoding output of the polar code may be simplified as

$${x}_{1}^{N} = {u}_{A} {G}_{N} ( A ) .$$

Herein, u_{A} is the information bit set in

$${u}_{1}^{N} ,$$

and u_{A} is a row vector of a length K, that is, |A|=K. |·| indicates a quantity of elements in the set, K is an information block size, G_{N}(A) is the submatrix obtained by using the rows corresponding to the indexes in the set A in the matrix G_{N}, and G_{N}(A) is a K×N matrix.

After the mother code length N is determined, a polar code construction process is a selection process of the set A, and polar code performance is determined. The polar code construction process is usually as follows: It is determined, based on the mother code length N that N polarized channels co-exist, where the N polarized channels respectively correspond to N rows in an encoding matrix.

When rate matching is not performed, indexes of first K polarized subchannels with high reliability are used as elements of the set A, and indexes corresponding to remaining (N−K) polarized subchannels are used as elements of the index set A^{c} of the frozen bits. The set A determines a location of the information bit, and the set A^{c} determines a location of the frozen bit. A sequence number of a polarized channel is a location index of an information bit or a frozen bit, that is, a location index in

$${u}_{1}^{N} .$$

When rate matching is performed, particularly when puncturing or shortening is performed, N−M polarized subchannels that need to be punctured or shortened (that is, deleted) usually are first determined. Herein, M is a target code length, that is, a length of a rate-matched bit sequence, and the N−M polarized subchannels selected herein are used to contain frozen bits. In the 5G NR standard, when puncturing is performed, some pre-frozen polarized subchannels are further additionally determined, and are also used to contain frozen bits. Herein, a quantity of the pre-frozen polarized subchannels are defined as P, and P is greater than or equal to 0 (in 5G NR, when shortening is performed, P is 0, and in this case, P may not need to be considered. This is not limited in this application). Then, the K polarized subchannels with high reliability are selected from remaining M−P polarized subchannels based on reliability to contain K information bits. Certainly, M−P−K subchannels with low reliability may alternatively be first selected to contain frozen bits, and remaining K subchannels are used to contain information bits. Reliability of any one of the K polarized subchannels containing the K information bits is higher than reliability of any one of the M−P−K subchannels containing the frozen bits. In this application, a value of P is not limited. Even when puncturing is performed, P may be 0. Even when shortening is performed, P may be greater than 0. This does not affect implementation of the technical solutions in this application. Regardless of an encoder or a decoder, principles and methods for determining that the K subchannels are used to contain the K information bits are consistent. In the 5G NR standard, for selection of N−M polarized subchannels, a solution is to contain a sequence obtained after subblock interleaving (divided into 32 subblocks) in a circular buffer (equivalent to a rate-matched sequence). If puncturing is performed, reading starts from an (N−M)^{th} location in the circular buffer, and bits from a 0^{th} location to an (N−M−1)^{th} location are discarded. If shortening is performed, reading starts from a 0^{th} location to an (M−1)^{th} location in the circular buffer, and bits from an M^{th} location to an (N−1)^{th} location are discarded. Generally, a reliability ranking sequence whose length is the mother code length N is used to represent a relative reliability relationship between different polarized subchannels. The reliability ranking sequence includes sequence numbers (starting from 0 to N −1) of N polarized subchannels, and the sequence numbers may be arranged in descending order or ascending order of reliability. Without loss of generality, this application uses an example in which the sequence numbers are arranged in ascending order of the reliability.

It should be noted that the relative reliability relationship described herein is based on a specific reliability calculation manner. Different reliability calculation manners may cause a change in the relative reliability relationship between the polarized subchannels. However, methods for selecting polarized subchannels used to contain information bits are the same. In addition to the 5G NR standard, it may also be considered that an information bit is contained by a last punctured or shortened polarized subchannel. In this application, it is not limited that the polarized subchannel containing the information bit needs to be selected according to the 5G NR standard.

In the 5G NR standard, when reliability ranking sequences corresponding to different mother code lengths meet a nesting feature, that is, the mother code length N is less than or equal to a mother code length N′, a relative relationship between reliability of polarized subchannels (polarized subchannels 0, . . . , and N −1) in the reliability ranking sequence corresponding to N is consistent with a relative relationship between the reliability of the polarized subchannels (the polarized subchannels 0, . . . , and N −1) in a reliability ranking sequence corresponding to N′. In other words, in the reliability ranking sequence corresponding to N′, only numbers of polarized subchannels less than N are retained, and a relative ranking relationship between locations of the numbers of the N polarized subchannels is not changed. In this way, the reliability ranking sequence corresponding to N can be obtained. Therefore, the reliability ranking sequence whose length is N may be referred to as a subsequence of the reliability ranking sequence whose length is N′, where N is less than or equal to N′. For example, N′=8, and a reliability ranking sequence 1 is [0, 4, 6, 2, 3, 1, 7, 5]. Correspondingly, if N=4, and a reliability ranking sequence 2 is [0, 2, 3, 1], the sequence 2 is a subsequence of the sequence 1. Therefore, in a specific implementation, reliability ranking sequences of different mother code lengths may be prestored. Alternatively, only a reliability ranking sequence whose length is equal to a maximum mother code length Nₘₐₓ may be prestored, and another reliability ranking sequence corresponding to the mother code length N is obtained by retaining only sequence numbers of polarized subchannels less than N in the reliability ranking sequence corresponding to the maximum mother code length. In this way, storage overheads can be reduced. Particularly, a sequence may also be a subsequence of the sequence. Therefore, a largest value of N may be equal to Nₘₐₓ.

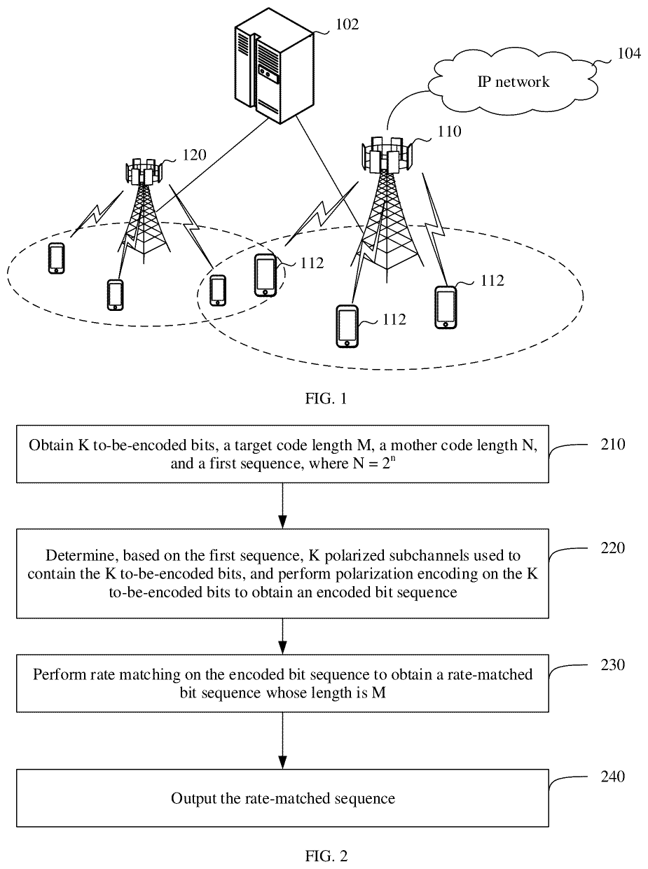

FIG. 1 is a schematic diagram of a structure of a wireless communications network according to an embodiment of the present invention. FIG. 1 is merely an example, and other wireless networks to which the encoding method or apparatus in embodiments of the present application can be applied shall fall within the protection scope of the present invention.

As shown in FIG. 1, the wireless communications network 100 includes a network device 110 and a terminal 112. When the wireless communications network 100 includes a core network 102, the network device 110 may further be connected to the core network 102. The network device 110 may further communicate with an IP network 104 such as the Internet, a private IP network, or another data network. The network device provides services for a terminal within coverage. For example, refer to FIG. 1. The network device 110 provides wireless access for one or more terminals 112 within the coverage of the network device 110. In addition, coverage of network devices, for example, the network device 110 and a network device 120, may have an overlapping area. The network devices may further communicate with each other. For example, the network device 110 may communicate with the network device 120.

The network device may be a device configured to communicate with a terminal device. For example, the network device may be an evolved NodeB (eNB, or eNodeB) in an LTE system, may be a gNB in a 5G network, may be a satellite in satellite communication, a network side device in a future communications system, or the like. Alternatively, the network device may be a relay station, an access point, a vehicle-mounted device, or the like. In a device to device (D2D) communications system, a machine to machine (M2M) communications system, and an Internet of vehicles system, the network device may alternatively be a terminal that functions as a base station.

The terminal may be user equipment (UE), an access terminal, a subscriber unit, a mobile station, a remote station, a remote terminal, a mobile device, a user terminal, a wireless communications device, a user agent, or a user apparatus. The access terminal may be a cellular phone, a cordless phone, a session initiation protocol (SIP) phone, a wireless local loop (WLL) station, a personal digital assistant (PDA), a handheld device having a wireless communications function, a computing device, another processing device connected to a wireless modem, a vehicle-mounted device, a wearable device, or a terminal device in a future communications network.

Based on the architecture of the communications system shown in FIG. 1, in embodiments of this application, the polar code encoding method may be performed by the foregoing network device or terminal. When the network device or the terminal is used as a transmitting end to send data or information, the polar code encoding method may be used. Correspondingly, when the network device or the terminal serves as a receiving end to receive data or information, the network device or the terminal also needs to determine a reliability ranking sequence according to the method described in the present application and then perform decoding. The following describes in detail the polar code encoding method provided in embodiments of this application.

Based on the architecture of the communications system shown in FIG. 1, as shown in FIG. 2, a specific process of a polar code encoding method provided in an embodiment of this application is as follows.

Operation 210: Obtain K to-be-encoded bits, a target code length M, a mother code length N, and a first sequence, where the first sequence is a reliability ranking sequence and includes sequence numbers of N polarized subchannels, the sequence numbers of the N polarized subchannels are arranged in the first sequence based on reliability of the N polarized subchannels, N=2ⁿ, and K≤N. In an application scenario of polar code, N may be a value greater than or equal to 32, and M, K, n, and N are positive integers.

The K to-be-encoded bits herein may include only a payload bit, or may include one or more types of other types of non-frozen bits such as a CRC bit and a PC bit in addition to the payload bit.

How to obtain the mother code length N based on factors such as the target code length M and a code rate is specified in the 5G NR system. Because this is not a technical problem to be resolved in this application, the manner of obtaining the mother code length N is directly used, but it is not indicated that only the 5G NR manner can be used to obtain the mother code length N in the solution of this application.

After N is determined, the first sequence whose length is N may be determined. As described above, the first sequence may be prestored, or may be a subsequence whose length is N and that is extracted from a second sequence. The second sequence is a reliability ranking sequence whose length is a maximum mother code length Nₘₐₓ. The first sequence may be any Q sequence whose length is N in the appendix or a subsequence of any Q sequence whose length is greater than N in the appendix, the second sequence may be any Q sequence whose length is Nₘₐₓ in the appendix, and the first sequence is a subsequence of the second sequence, where N is less than or equal to Nₘₐₓ. Nₘₐₓ may be any one of 2048, 4096, 8192, and 16384.

In this application, the appendix provides, based on decoding implementation, rate matching, and code block retransmission, eight groups of polar code reliability ranking sequences applicable to long code block encoding. In terms of reliability, each group of sequences includes reliability ranking sequences (Qx_y sequences, which are generally referred to as Q sequences for ease of understanding, where x is any integer from 1 to 8, and y is any value in 2048, 4096, 8192, and 16384. This also applies to the following statements) that are of lengths of 2048, 4096, 8192, and 16384 and that are arranged in ascending order of the reliability, and corresponding reliability location sequences (Zx_y sequences, which are generally referred to as Z sequences for ease of understanding, where x is any integer from 1 to 8, and y is any value in 2048, 4096, 8192, and 16384. This also applies to the following statements). For the Q sequence, each value in the sequence is a sequence number of a polarized subchannel, and a location of the value in the sequence is a reliability order. A higher location indicates lower reliability. For the Z sequence, each value in the sequence is a reliability order of a location of the value (that is, a polarized subchannel containing the value) in reliability of all polarized subchannels. The Q sequence is in a one-to-one correspondence with the Z sequence. In a simple example, if a Q sequence is [0, 4, 6, 2, 3, 1, 7, 5], a corresponding Z sequence is [0, 5, 3, 4, 1, 7, 2, 6], and both the Q sequence and the Z sequence indicate that a polarized subchannel 5 has highest reliability, a polarized subchannel 7 has second highest reliability, and a polarized subchannel 1 has third highest reliability. The rest may be deduced by analogy. A polarized subchannel 0 has lowest reliability. It should be noted that only reliability ranking sequences whose lengths are greater than 1024 is provided in the appendix. This is because the sequences are backward compatible. To be specific, a reliability ranking sequence whose length is Nₘ=1024 and that is specified in the 5G NR protocol is a subsequence of any Qx_y sequence in the appendix. In other words, reliability ranking sequences whose lengths are separately 32, 64, 128, 256, 512, or 1024 and that are used in the 5G NR protocol are subsequences of any Qx_y sequence in the appendix. In an actual implementation, K polarized subchannels are usually selected by using the Q sequence, but may also be selected by using the Z sequence.

Sequence group 1 (Q1_y and Z1_y): A criterion for designing the sequence is to ensure decoding performance and provide a high degree of parallelism for polar decoding, to further reduce a decoding delay. Q1_2048, Q1_4096 are subsequences of Q1_8192 in the appendix. Q1_2048 can be obtained by retaining numbers less than 2048 and keeping a relative ranking relationship between locations of the numbers of the 2048 polarized subchannels in Q1_8192 unchanged; Q1_4096 can be obtained by retaining numbers less than 4096 and keeping the a relative ranking relationship between locations of the numbers of the 4096 polarized subchannels in Q1_8192 unchanged.

Sequence group 2 (Q2_y and Z2_y): Currently, in NR, in addition to a repetition rate matching scheme, there are two rate matching schemes based on a code rate: puncturing and shortening. A criterion for designing the sequence is to preferentially optimize performance in the rate matching scheme in which puncturing is performed. Q2_2048, Q2_4096 are subsequences of Q2_8192 in the appendix. Q2_2048 can be obtained by retaining numbers less than 2048 Q2_8192 and keeping a relative ranking relationship between locations of the numbers of the 2048 polarized subchannels in Q2_8192 unchanged; Q2_4096 can be obtained by retaining numbers less than 4096 and keeping a relative ranking relationship between locations of the numbers of the 4096 polarized subchannels in Q2_8192 unchanged.

Sequence group 3 (Q3_y and Z3_y): Currently, in NR, in addition to a repetition rate matching scheme, there are two rate matching schemes based on a code rate: puncturing and shortening. A criterion for designing the sequence is to preferentially optimize performance in the rate matching scheme in which shortening is performed. Q3_2048, Q3_4096 are subsequences of Q3_8192 in the appendix. Q3_2048 can be obtained by retaining numbers less than 2048 Q3_8192 and keeping a relative ranking relationship between locations of the numbers of the 2048 polarized subchannels in Q3_8192 unchanged; Q3_4096 can be obtained by retaining numbers less than 4096 in Q3_8192 and keeping a relative ranking relationship between locations of the numbers of the 4096 polarized subchannels in Q3_8192 unchanged.

Sequence group 4 (Q4_y and Z4_y): HARQ needs to be supported in a data channel. Currently, a polar code HARQ solution commonly used in the industry mainly includes IR and IF. A criterion for designing the sequence is to consider both IR (incremental redundancy) HARQ performance and IF (incremental frozen) HARQ performance. Q4_2048, Q4_4096 are subsequences of Q4_8192 in the appendix. Q4_2048 can be obtained by retaining numbers less than 2048 in Q4_8192 and keeping a relative ranking relationship between locations of the numbers of the 2048 polarized subchannels in Q4_8192 unchanged; Q4_4096 can be obtained by retaining numbers less than 4096 in Q4_8192 and keeping a relative ranking relationship between locations of the numbers of the 4096 polarized subchannels in Q4_8192 unchanged.

In a high-throughput communications scenario of a data channel, a system defines several fixed MCS formats, and corresponding required mother code lengths are expected to include 2048/4096/8192/16384 and the like. The mother code lengths vary with different subdivided scenarios. Therefore, some reliability ranking sequences are designed for different mother code lengths and modulation schemes in the present invention.

Sequence group 5 (Q5_y and Z5_y): Performance in a 16-QAM modulation scheme is preferentially considered, but it can also be ensured that performance in another modulation scheme can meet a requirement. Q5_2048, Q5_4096 are subsequences of Q5_8192 or Q5_16384 in the appendix. Q5_2048 can be obtained by retaining numbers less than 2048 and keeping a relative ranking relationship between locations of the numbers of the 2048 polarized subchannels in Q5_8192 or Q5_16384 unchanged; Q5_4096 can be obtained by retaining numbers less than 4096 in Q5_8192 or Q5_16384 and keeping a relative ranking relationship between locations of the numbers of the 4096 polarized subchannels in Q5_8192 or Q5_16384 unchanged.

Sequence group 6 (Q6_y and Z6_y): Performance in a 64-QAM modulation scheme is preferentially considered, but it can also be ensured that performance in another modulation scheme can meet a requirement. Q6_2048 is a subsequence of Q6_4096 in the appendix. Q6_2048 can be obtained by retaining numbers less than 2048 in Q6_4096 and keeping a relative ranking relationship between locations of the numbers of the 2048 polarized subchannels in Q6_4096 unchanged.

Sequence group 7 (Q7_y and Z7_y): Performance of a mother code length 2048 is preferentially considered, but it can also be ensured that performance of another mother code length can meet a requirement. Q7_2048 is a subsequence of Q7_4096 in the appendix. Q7_2048 can be obtained by retaining numbers less than 2048 in Q7_4096 and keeping a relative ranking relationship between locations of the numbers of the 2048 polarized subchannels in Q7_4096 unchanged.

Sequence group 8 (Q8_y and Z8_y): Performance of a mother code length 4096 is preferentially considered, but it can also be ensured that performance of another mother code length can meet a requirement. Q8_2048 is a subsequence of Q8_4096 in the appendix. Q8_2048 can be obtained by retaining numbers less than 2048 in Q8_4096 and keeping a relative ranking relationship between locations of the numbers of the 2048 polarized subchannels in Q8_4096 unchanged.

Pay attention to the following points:

1. A reliability ranking sequence whose length is 1024 given in the 5G NR protocol is a subsequence of any Q sequence in the appendix. In this way, a data channel encoding requirement is met, and compatibility with an existing protocol is ensured. Correspondingly, reliability ranking sequences that are used in the 5G NR protocol and whose lengths are separately 32, 64, 128, 256, 512, or 1024 are subsequences of any Q sequence in the appendix.

2. Locations of fewer elements in the sequence are exchanged. For example, a sequence number location may be adjusted by a specified magnitude, for example, the specified magnitude is 5. A location of an element whose sequence number is 10 may be adjusted by left and right five locations.

3. Some elements in the sequence are adjusted, but channel sets that are used to transmit T-bit information and that are selected based on the sequence are consistent or similar.

4. The sequence includes N elements from 0 to N−1, and the N elements from 0 to N −1 represent sequence numbers of N polarized subchannels. Actually, the sequence numbers of the N polarized subchannels may alternatively start from 1 and end with N, that is, 1 is added to the sequence numbers in the foregoing sequence. This is also a sequence number form in the foregoing calculation manner. Certainly, a sequence number or an identifier of the polar subchannel may alternatively be represented in another manner. The specific representation manner does not affect a specific location of the polar subchannel in the sequence.

Operation 220: Determine, based on the first sequence, the K polarized subchannels used to contain the K to-be-encoded bits, and perform polarization encoding on the K to-be-encoded bits to obtain an encoded bit sequence.

For a specific encoding operation, refer to the foregoing description. A specific scheme of rate matching may be first determined. When puncturing or shortening is performed, polarized subchannels to be punctured or shortened (that is, deleted) and possible P pre-frozen polarized subchannels (P is greater than or equal to 0) are first determined, and the K polarized subchannels with high reliability are selected from remaining M−P polarized subchannels based on reliability to contain K information bits. When repetition is performed, the K polarized subchannels with high reliability are directly selected from the N polarized subchannels based on reliability to contain the K information bits. A decoder may also determine locations of the K information bits in the same manner.

Operation 230: Perform a rate matching operation on the encoded bit sequence to obtain a rate-matched bit sequence whose length is M.

For a specific rate matching operation, refer to a manner in which block interleaving is first performed and then bits are sequentially fetched in a circular buffer in 5G NR. Alternatively, a specific rate matching operation may be performed by using a preset rate matching sequence. This is not limited herein.

Operation 240: Output the rate-matched sequence.

It should be noted that if a modulation operation is used, the output herein should be a sequence obtained after modulation is performed on a rate-matched bit sequence. The sequence is a symbol sequence. In this case, a length of the sequence may not be M. If modulation is not used, the rate-matched sequence is a rate-matched bit sequence. For ease of understanding, terms “rate-matched sequence” and “rate-matched bit sequence” are not strictly distinguished in this application.

The embodiment shown in FIG. 2 is an operation of a transmitting end, and an operation of a receiving end is similar. After receiving a to-be-decoded information sequence, a receiver (or a receiving apparatus) also needs to use a similar method. A to-be-decoded information sequence including K to-be-decoded bits, a target code length M, and a mother code length N is obtained, a first sequence is determined, K polarized subchannels used to contain the K to-be-decoded bits are determined based on the first sequence, and a decoding operation is performed on the to-be-decoded information sequence to obtain and output a decoding result. A detailed decoding algorithm is not limited herein.

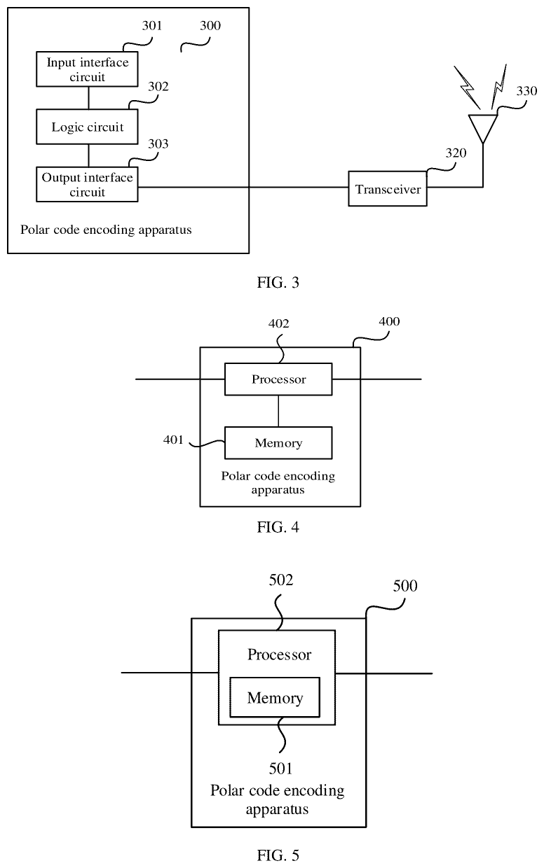

As shown in FIG. 3, an embodiment of this application further provides a polar code encoding apparatus 300. Some or all of the polar code encoding method shown in FIG. 3 may be implemented by hardware, or may be implemented by software.

For the polar code encoding apparatus 300, based on a same inventive concept as the polar code encoding method shown in FIG. 2, the polar code encoding apparatus 300 is configured to perform the polar code encoding method shown in FIG. 2. When some or all of the polar code encoding method is implemented by hardware, the polar code encoding apparatus 300 includes: an input interface circuit 301, configured to obtain to-be-encoded bits; a logic circuit 302, configured to perform the polar code encoding method shown in FIG. 2; and an output interface circuit 303, configured to output a rate-matched sequence. Further, the rate-matched sequence is still a modulated sequence, where for details, refer to description in the foregoing method embodiments, and details are not described herein again. The sequence is a modulated symbol sequence, and is output to a transceiver 320. The transceiver 320 performs corresponding processing (including but not limited to processing such as digital-to-analog conversion and/or frequency conversion) on the modulated sequence, and sends a processed modulated sequence through an antenna 330. Optionally, in a specific implementation, the polar code encoding apparatus 300 may be a chip or an integrated circuit.

Optionally, when some or all of the polar code encoding method in the foregoing embodiment is implemented by software, as shown in FIG. 4, a polar code encoding apparatus 400 includes: a memory 401, configured to store a program; and a processor 402, configured to execute the program stored in the memory 401. When the program is executed, the polar code encoding apparatus 400 can implement the polar code encoding method provided in the foregoing embodiment.

Optionally, the memory 401 may be a physically independent unit. Alternatively, as shown in FIG. 5, a memory 501 and a processor 502 may be integrated together.

Optionally, when some or all of the encoding method in the foregoing embodiment is implemented by software, the polar code encoding apparatus 400 may alternatively include only the processor 402. The memory 401 configured to store the program is located outside the polar code encoding apparatus 400. The processor 402 is connected to the memory 401 through a circuit/cable, and is configured to read and execute the program stored in the memory 401.

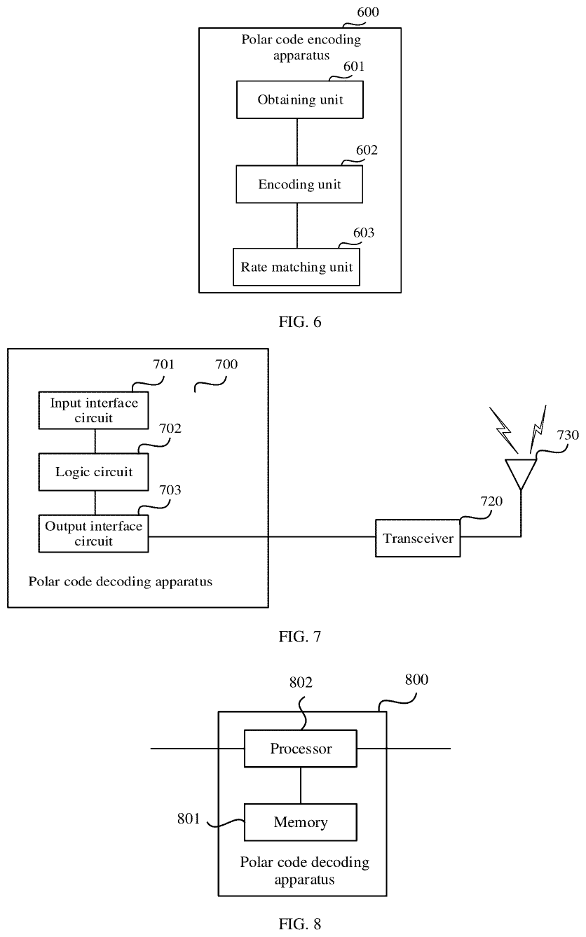

Based on the polar code encoding method shown in FIG. 2, as shown in FIG. 6, an embodiment of this application further provides a polar code encoding apparatus 600. The polar code encoding apparatus 600 is configured to perform the polar code encoding method shown in FIG. 2. The polar code encoding apparatus 600 includes:
an obtaining unit 601, configured to obtain K to-be-encoded bits;
an encoding unit 602, configured to: determine a mother code length N and a first sequence (a reliability ranking sequence whose length is N), and perform polar encoding on the K to-be-encoded bits based on the mother code length N to obtain an encoded bit sequence, where for a specific encoding process, refer to operation 220 in the foregoing embodiment; and
a rate matching unit 603, configured to perform a rate matching operation on the encoded bit sequence to obtain a rate-matched bit sequence whose length is M (or a sequence obtained through further modulation on the bit sequence, which is also referred to as a rate-matched sequence), where for a specific rate matching method, refer to operation 230 in the foregoing embodiment.

Corresponding to the transmitting end, an apparatus at the receiving end may also be designed similarly.

As shown in FIG. 7, a polar code decoding apparatus 700 includes: an input interface circuit 701, configured to obtain a to-be-decoded information sequence; a logic circuit 702, configured to perform the foregoing polar code decoding method to obtain a decoded information bit; and an output interface circuit 703, configured to output decoded information. The polar code decoding apparatus 700 may further include a transceiver 720 that obtains the to-be-decoded information sequence through an antenna 730. In a specific implementation, the polar code decoding apparatus 700 may be a chip or an integrated circuit.

Optionally, when some or all of the polar code decoding method in the foregoing embodiment is implemented by software, as shown in FIG. 8, a polar code decoding apparatus 800 includes: a memory 801, configured to store a program; and a processor 802, configured to execute the program stored in the memory 801. When the program is executed, the polar code decoding apparatus 800 can implement the polar code decoding method provided in the foregoing embodiment.

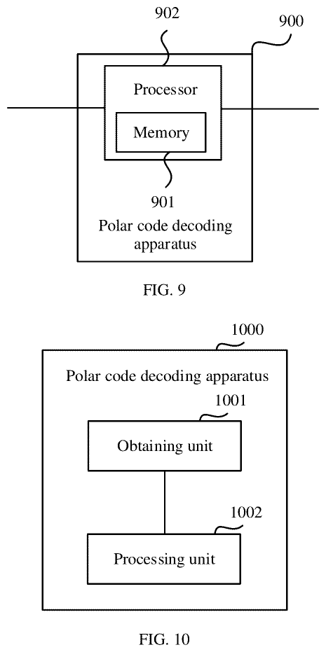

Optionally, the memory 801 may be a physically independent unit. Alternatively, as shown in FIG. 9, a memory 901 and a processor 902 may be integrated together.

Optionally, when some or all of the decoding method in the foregoing embodiment is implemented by software, the polar code decoding apparatus 800 may alternatively include only the processor 802. The memory 801 configured to store the program is located outside the polar code decoding apparatus 800. The processor 802 is connected to the memory 801 through a circuit/cable, and is configured to read and execute the program stored in the memory 801.

The processor 402 and/or the processor 802 may be a central processing unit (CPU), a network processor (NP), or a combination of the CPU and the NP.

The processor 402 and/or the processor 802 may further include a hardware chip. The hardware chip may be an application-specific integrated circuit (ASIC), a programmable logic device (PLD), or a combination thereof. The PLD may be a complex programmable logic device (CPLD), a field-programmable gate array (FPGA), generic array logic (GAL), or any combination thereof.

The memory in the foregoing embodiments may include a volatile memory, for example, a random-access memory (RAM). Alternatively, the memory may include a non-volatile memory, such as a flash memory, a hard disk drive (HDD), or a solid-state drive (SSD). Alternatively, the memory may include a combination of the foregoing types of memories.

Based on the foregoing polar code decoding method, as shown in FIG. 10, an embodiment of this application further provides a polar code decoding apparatus 1000. The polar code decoding apparatus 1000 is configured to perform the foregoing polar code decoding method. The polar code decoding apparatus 1000 includes:
an obtaining unit 1001, configured to obtain a to-be-decoded information sequence; and
a processing unit 1002, configured to: determine a first sequence of a mother code length N (a reliability ranking sequence whose length is N), and perform a decoding operation on the to-be-decoded information sequence to obtain and output a decoding result.

An embodiment of this application further provides a computer storage medium that stores computer program instructions. When the computer program instructions are executed by a computer, the foregoing polar code encoding method or polar code decoding method is performed.

An embodiment of this application further provides a computer program product including instructions. When the computer program product runs on a computer, the foregoing polar code encoding method or polar code decoding method is performed.

A person skilled in the art should understand that embodiments of this application may be provided as a method, a system, or a computer program product. Therefore, this application may use a form of hardware only embodiments, software only embodiments, or embodiments with a combination of software and hardware. In addition, this application may use a form of a computer program product that is implemented on one or more computer-usable storage media (including but not limited to a disk memory, a CD-ROM, an optical memory, and the like) that include computer-usable program code.

This application is described with reference to the flowcharts and/or block diagrams of the method, the device (system), and the computer program product according to embodiments of this application. It should be understood that computer program instructions may be used to implement each process and/or each block in the flowcharts and/or the block diagrams and a combination of a process and/or a block in the flowcharts and/or the block diagrams. The computer program instructions may be provided for a general-purpose computer, a dedicated computer, an embedded processor, or a processor of another programmable data processing device to generate a machine, so that the instructions executed by a computer or a processor of another programmable data processing device generate an apparatus for implementing a specific function in one or more processes in the flowcharts and/or in one or more blocks in the block diagrams.

The computer program instructions may be stored in a computer-readable memory that can instruct the computer or another programmable data processing device to work in a specific manner, so that the instructions stored in the computer-readable memory generate an artifact that includes an instruction apparatus. The instruction apparatus implements a specific function in one or more processes in the flowcharts and/or in one or more blocks in the block diagrams.

The computer program instructions may alternatively be loaded onto a computer or another programmable data processing device, so that a series of operations and steps are performed on the computer or the another programmable device. In this way, computer-implemented processing is generated. Therefore, the instructions executed on the computer or the another programmable device provide steps for implementing a specific function in one or more processes in the flowcharts and/or in one or more blocks in the block diagrams.

Although some example embodiments of this application have been described, a person skilled in the art can make changes and modifications to these embodiments once the person skilled in the art learns of the basic inventive concept. Therefore, the following claims are intended to be construed as to cover the embodiments and all changes and modifications falling within the scope of this application.

Clearly, a person skilled in the art can make various modifications and variations to embodiments of this application without departing from the scope of embodiments of this application. This application is intended to cover these modifications and variations provided that they fall within the scope of protection defined by the following claims and their equivalent technologies.

### APPENDIX

### Sequence Group 1: Q1_8192

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 1024, 1025, 67, 41, 144, 28, 69, 42, 516, 49, 74, 272, 160, 520, 288, 528, 192, 544, 70, 44, 131, 81, 50, 73, 15, 320, 133, 52, 23, 134, 384, 76, 1026, 1028, 137, 82, 56, 27, 97, 39, 259, 84, 138, 145, 261, 29, 43, 98, 515, 88, 1032, 1040, 140, 30, 2048, 2049, 2050, 2052, 146, 71, 262, 265, 161, 576, 45, 100, 640, 51, 148, 46, 1056, 1027, 75, 266, 273, 517, 104, 162, 53, 193, 1029, 1088, 152, 77, 1033, 1030, 164, 768, 1041, 1034, 268, 274, 518, 54, 83, 57, 521, 112, 135, 78, 289, 194, 85, 276, 522, 58, 168, 139, 99, 86, 60, 280, 89, 290, 529, 524, 196, 141, 2056, 2064, 2080, 2051, 101, 147, 176, 142, 530, 321, 31, 200, 90, 545, 292, 322, 532, 263, 149, 102, 105, 304, 296, 163, 92, 47, 267, 385, 546, 324, 208, 386, 1042, 1152, 150, 153, 2053, 2112, 2057, 2054, 165, 106, 55, 328, 4096, 4097, 4098, 4100, 4104, 4112, 4128, 4099, 536, 577, 548, 113, 154, 79, 269, 108, 578, 224, 1036, 1057, 166, 519, 552, 195, 1089, 1044, 270, 641, 523, 275, 580, 291, 2065, 2058, 2066, 2176, 59, 169, 560, 114, 277, 156, 1280, 1058, 87, 197, 116, 170, 61, 531, 525, 642, 2060, 2081, 2113, 2068, 281, 278, 526, 177, 2304, 2082, 2072, 2084, 293, 388, 1048, 1060, 2055, 2177, 2114, 2560, 91, 584, 769, 198, 1031, 1153, 172, 120, 201, 336, 62, 282, 1090, 1536, 143, 103, 178, 294, 93, 644, 202, 592, 323, 392, 297, 770, 107, 180, 1035, 1064, 151, 209, 284, 648, 94, 204, 298, 400, 608, 352, 325, 533, 155, 210, 305, 547, 300, 109, 1092, 1154, 1043, 1037, 184, 534, 537, 115, 4101, 4160, 4105, 4102, 4113, 4106, 4114, 4224, 167, 225, 326, 306, 772, 157, 656, 329, 1072, 1038, 110, 117, 212, 171, 776, 330, 226, 549, 1096, 1281, 538, 387, 308, 216, 1045, 1156, 416, 271, 279, 158, 337, 550, 672, 118, 332, 579, 540, 389, 173, 121, 553, 199, 784, 179, 228, 338, 312, 704, 1059, 1282, 390, 174, 554, 581, 393, 283, 2059, 2088, 2116, 2178, 122, 448, 353, 561, 4108, 4129, 4161, 4116, 4352, 4130, 4120, 4132, 203, 63, 340, 394, 527, 582, 556, 181, 1050, 1537, 1104, 1061, 1049, 1046, 295, 285, 232, 124, 205, 182, 643, 562, 286, 585, 1160, 1284, 299, 354, 2067, 2061, 2096, 2062, 211, 401, 1288, 1062, 1538, 1120, 185, 396, 2120, 2305, 2069, 2180, 344, 586, 1091, 1065, 1168, 1052, 645, 593, 1093, 1066, 535, 240, 4103, 4225, 4162, 4608, 4107, 4136, 4164, 4226, 206, 95, 327, 564, 1540, 1073, 800, 402, 356, 307, 301, 417, 2083, 2306, 2074, 2561, 213, 568, 832, 588, 186, 646, 404, 227, 896, 594, 1098, 1296, 1184, 1544, 1312, 1552, 4115, 4109, 4144, 4110, 4168, 4353, 4117, 4228, 418, 302, 649, 771, 1216, 1568, 360, 539, 4131, 4354, 4122, 4609, 4176, 4133, 4121, 4118, 111, 331, 214, 309, 2128, 2085, 2073, 2070, 4232, 4356, 4360, 4134, 4610, 4192, 5120, 5121, 188, 449, 1094, 1068, 1155, 1105, 217, 408, 2184, 2308, 2312, 2086, 609, 596, 551, 650, 229, 159, 420, 310, 541, 773, 610, 657, 2562, 2144, 3072, 3073, 333, 119, 600, 339, 218, 368, 652, 230, 391, 313, 1074, 1097, 450, 542, 1039, 1344, 334, 233, 555, 774, 175, 123, 1157, 1076, 658, 612, 341, 777, 2115, 2089, 2192, 2076, 220, 314, 424, 395, 673, 583, 1047, 1158, 355, 287, 183, 234, 125, 557, 660, 616, 1408, 1100, 342, 316, 241, 778, 1161, 1106, 563, 345, 452, 397, 403, 207, 1080, 1051, 674, 558, 785, 432, 2117, 2090, 2564, 2097, 2122, 2320, 2208, 2568, 357, 187, 1121, 1063, 1283, 1108, 236, 664, 624, 587, 780, 705, 126, 242, 565, 398, 1162, 1169, 346, 456, 1285, 1053, 358, 405, 2336, 2576, 2240, 2592, 303, 569, 244, 595, 189, 566, 676, 361, 1067, 1122, 706, 589, 215, 786, 1539, 1112, 2118, 2092, 2179, 2129, 1164, 1054, 647, 348, 419, 406, 464, 680, 2098, 2121, 2063, 2368, 801, 362, 590, 409, 570, 788, 597, 572, 219, 311, 1170, 1095, 1286, 1289, 708, 598, 601, 651, 1185, 1600, 1069, 1124, 421, 792, 802, 611, 602, 410, 1664, 1075, 231, 688, 1172, 1070, 653, 248, 369, 190, 364, 654, 659, 335, 1099, 1290, 2181, 2100, 2071, 2182, 480, 315, 221, 370, 1297, 1541, 1128, 1186, 613, 422, 425, 451, 4163, 4137, 4240, 4124, 4165, 4138, 4612, 4145, 614, 543, 235, 412, 343, 372, 1077, 1217, 775, 317, 222, 426, 453, 237, 559, 833, 1176, 1101, 1188, 1792, 1292, 1298, 804, 712, 2432, 2124, 3074, 3076, 2185, 2130, 2104, 2075, 2145, 2087, 2307, 2132, 834, 661, 808, 779, 617, 604, 433, 720, 816, 836, 347, 897, 1542, 1078, 1107, 1081, 243, 662, 1545, 1136, 2186, 2193, 2309, 2077, 454, 318, 675, 618, 4170, 4368, 4256, 4616, 4384, 4624, 4288, 4640, 898, 781, 376, 428, 2091, 2146, 2563, 2136, 3080, 3088, 2188, 2078, 665, 736, 567, 840, 4166, 4140, 4227, 4177, 4146, 4169, 4111, 4416, 625, 238, 1159, 1102, 2194, 2119, 2310, 2313, 2209, 2624, 2093, 2148, 1313, 1218, 1109, 1300, 2688, 2099, 2196, 2094, 1546, 1082, 359, 457, 399, 787, 591, 678, 434, 677, 1192, 1163, 3104, 3075, 2123, 2314, 1123, 1110, 349, 245, 458, 666, 620, 363, 127, 191, 782, 407, 4229, 4148, 4119, 4230, 4480, 4172, 5122, 5124, 436, 626, 1084, 1304, 1113, 1314, 1553, 1548, 571, 465, 1220, 1165, 681, 246, 707, 350, 1125, 1171, 1200, 1166, 2321, 2565, 2152, 2210, 2101, 2241, 3077, 3136, 2200, 2125, 3081, 3078, 599, 668, 790, 460, 1554, 1345, 1055, 1224, 2212, 2816, 3089, 3082, 249, 682, 1114, 1569, 573, 411, 803, 789, 709, 365, 440, 628, 4233, 4178, 4152, 4123, 4193, 4135, 4355, 4180, 689, 374, 423, 466, 2316, 2322, 2566, 2102, 2131, 2105, 2569, 2160, 793, 250, 371, 481, 4234, 4241, 4357, 4125, 4139, 4194, 4611, 4184, 1316, 1346, 1556, 1287, 1173, 1126, 1129, 1328, 574, 413, 603, 366, 468, 655, 900, 805, 1320, 1187, 1116, 1071, 1291, 1409, 1570, 1348, 5128, 5136, 4236, 4126, 6144, 6145, 6146, 6148, 615, 684, 710, 429, 1232, 1410, 794, 252, 373, 605, 848, 690, 1174, 1177, 713, 632, 482, 806, 427, 904, 2183, 2126, 2337, 2242, 414, 223, 1189, 1130, 2133, 2324, 2570, 2106, 663, 692, 835, 619, 1079, 1352, 1560, 1601, 472, 455, 796, 809, 2216, 2187, 2147, 2134, 1572, 1137, 1178, 1103, 714, 721, 1293, 1132, 4242, 4167, 4358, 4361, 4257, 4672, 4141, 4196, 837, 716, 864, 810, 606, 912, 722, 696, 1602, 1248, 1190, 1543, 2108, 2328, 2137, 2338, 377, 435, 817, 319, 621, 812, 484, 430, 838, 667, 1576, 1219, 1294, 1665, 1547, 1299, 2577, 2572, 2244, 2189, 488, 239, 378, 459, 622, 627, 1604, 1315, 2149, 2195, 2224, 2190, 1083, 1193, 437, 380, 818, 461, 496, 669, 679, 724, 841, 629, 2578, 2369, 2079, 2248, 1584, 1138, 1301, 1180, 1111, 1221, 351, 467, 4736, 4147, 4244, 4142, 5152, 5123, 4171, 4362, 4369, 4613, 4200, 4258, 4149, 4289, 5125, 5184, 438, 737, 251, 462, 2138, 2593, 2340, 2370, 2580, 2311, 2197, 2150, 442, 441, 1140, 1194, 1085, 1555, 1549, 1666, 1305, 1302, 1550, 1201, 469, 247, 683, 842, 1317, 1412, 738, 899, 2153, 2352, 2344, 2211, 670, 783, 849, 820, 2140, 2095, 2315, 2433, 728, 928, 791, 367, 4248, 4173, 5129, 5126, 4260, 4864, 5137, 5130, 901, 630, 1115, 1608, 685, 844, 1793, 1222, 633, 711, 1196, 1144, 1225, 1360, 253, 691, 2594, 2372, 2256, 2434, 1086, 1306, 1167, 1127, 824, 902, 1202, 1318, 3090, 3200, 2198, 2201, 4364, 4370, 4614, 4150, 4179, 4153, 4617, 4208, 2213, 2154, 2103, 2376, 1117, 1668, 686, 740, 850, 375, 444, 470, 483, 415, 1226, 1616, 4231, 4174, 4385, 4290, 4181, 4372, 4618, 4154, 1347, 1416, 485, 905, 1321, 1794, 795, 473, 1131, 1204, 1175, 1233, 1308, 1672, 1118, 1228, 634, 744, 852, 960, 2584, 2625, 2596, 2161, 2202, 2127, 2317, 2156, 1322, 1424, 1632, 1376, 1349, 1557, 1179, 1234, 2626, 2272, 3084, 3105, 2214, 2567, 2600, 2243, 865, 693, 1329, 1571, 1324, 1133, 1208, 1558, 1561, 1139, 797, 906, 3137, 3092, 2318, 2689, 715, 807, 1191, 1249, 2571, 2323, 2628, 2339, 1350, 1330, 474, 636, 694, 254, 717, 575, 913, 798, 1796, 1181, 1680, 1353, 811, 379, 2107, 2217, 2608, 2162, 4264, 4235, 4195, 4182, 4156, 4376, 4185, 4386, 697, 431, 607, 489, 866, 723, 486, 908, 2325, 2204, 3328, 3106, 2135, 2245, 2164, 2218, 1134, 1141, 718, 813, 476, 856, 839, 725, 1236, 1195, 1800, 1354, 698, 914, 752, 868, 819, 814, 439, 929, 2109, 2579, 2573, 2690, 1250, 1573, 490, 623, 671, 739, 916, 463, 843, 381, 497, 930, 1562, 1411, 1332, 1240, 2329, 2326, 2574, 2225, 2341, 2436, 3096, 3108, 2139, 2632, 2817, 2246, 1440, 1295, 1303, 1182, 4625, 4620, 4292, 4237, 6152, 6160, 6176, 6147, 4197, 4243, 4272, 4238, 4626, 4417, 4127, 4296, 4186, 4641, 4388, 4418, 4628, 4359, 4245, 4198, 1361, 1574, 1696, 1142, 1356, 1603, 1564, 1413, 1197, 1145, 1577, 1223, 821, 726, 1808, 1203, 1252, 1362, 1336, 1728, 961, 872, 1414, 1198, 3079, 3201, 2220, 2168, 2249, 2384, 2110, 2330, 492, 631, 1578, 1605, 3138, 3584, 2191, 2151, 4201, 4400, 4392, 4259, 4188, 4143, 4363, 4481, 729, 700, 443, 741, 1417, 1307, 1146, 1472, 1377, 1585, 1227, 1087, 845, 920, 382, 822, 4642, 4420, 4304, 4482, 5138, 5248, 4246, 4249, 6149, 6208, 6153, 6150, 4261, 4202, 4151, 4424, 1364, 1418, 1551, 1606, 1580, 1205, 1319, 1309, 1256, 1148, 851, 730, 2226, 2342, 2141, 2692, 4632, 4673, 4644, 4209, 4250, 4175, 4365, 4204, 4674, 4320, 5132, 5153, 4262, 4615, 4648, 4291, 2250, 2640, 2371, 2440, 2345, 2818, 2155, 2228, 5185, 5140, 4366, 4737, 4619, 4371, 4676, 4387, 3083, 3112, 2199, 2257, 498, 880, 742, 445, 471, 635, 1229, 1206, 1667, 1586, 1310, 1609, 932, 687, 1323, 1378, 2332, 2696, 2142, 2252, 6161, 6154, 6162, 6272, 4155, 4265, 4656, 4210, 2346, 2448, 2656, 2400, 903, 825, 500, 846, 745, 826, 1235, 1425, 1209, 1420, 732, 446, 962, 936, 475, 853, 1368, 1610, 867, 637, 907, 487, 1669, 1617, 2373, 2581, 2203, 2258, 2353, 2595, 2348, 2157, 3140, 3202, 3091, 3085, 1559, 1264, 695, 746, 2232, 2582, 2585, 2163, 1230, 1119, 828, 753, 1351, 1588, 854, 857, 2215, 2273, 2374, 2354, 2820, 2205, 2704, 2377, 4373, 4252, 5376, 5154, 4183, 4293, 4212, 4266, 4157, 4627, 4621, 4738, 6156, 6177, 6209, 6164, 4377, 4374, 4622, 4273, 6400, 6178, 6168, 6180, 1824, 1426, 1380, 1331, 1325, 1441, 504, 799, 3120, 3086, 2158, 2165, 2260, 2219, 2824, 2378, 4389, 4484, 5144, 5156, 6151, 6273, 6210, 6656, 255, 964, 1237, 1592, 2274, 2597, 3144, 3329, 1856, 1612, 909, 719, 1210, 1670, 1428, 1251, 1920, 1618, 477, 915, 638, 748, 1442, 1326, 1673, 1795, 944, 869, 491, 699, 754, 858, 4187, 4680, 4865, 4294, 5127, 5249, 4268, 4216, 4297, 4432, 4158, 4378, 5186, 5632, 4239, 4199, 1384, 1563, 478, 968, 383, 910, 815, 976, 2586, 2435, 2356, 2264, 3093, 3204, 2464, 2319, 2327, 2206, 2385, 2598, 2720, 2166, 2380, 2627, 1135, 1355, 870, 917, 1238, 1333, 727, 493, 873, 701, 1212, 1473, 1241, 1432, 1633, 1620, 2588, 2437, 2221, 2169, 2601, 2247, 2832, 2227, 2276, 2386, 2360, 2752, 3107, 3330, 2438, 2222, 1575, 1674, 1253, 1183, 1444, 1334, 931, 756, 2602, 2629, 2441, 2331, 1565, 1797, 860, 499, 731, 823, 1634, 1681, 1357, 1143, 1624, 1363, 2170, 2496, 2401, 2609, 1242, 1392, 1676, 1254, 922, 874, 1415, 1337, 918, 502, 1474, 1566, 4274, 4390, 4189, 4740, 4298, 4688, 4419, 4488, 933, 743, 760, 881, 2251, 2111, 2388, 2442, 4393, 4866, 4203, 4276, 5131, 5160, 4247, 4305, 1358, 1257, 1579, 1798, 1199, 1147, 1682, 1636, 2575, 2630, 2604, 2229, 3098, 3585, 3152, 3109, 494, 702, 921, 501, 1365, 1801, 1244, 1338, 4380, 4744, 4190, 4300, 4394, 4496, 4704, 4448, 3097, 3094, 2343, 2333, 2280, 2172, 2253, 2230, 1448, 1419, 1697, 1607, 2691, 2610, 2334, 2633, 1379, 1311, 1207, 1258, 1149, 1581, 1684, 1640, 1366, 1340, 1265, 1802, 1587, 1369, 1476, 1421, 3208, 3332, 2347, 2402, 2259, 2449, 3336, 3110, 4421, 4629, 4251, 4306, 4401, 4643, 4396, 4205, 876, 847, 992, 447, 1427, 1231, 733, 827, 1698, 1582, 1809, 1456, 934, 882, 937, 963, 1381, 1211, 1260, 1688, 3586, 3168, 2233, 2444, 2392, 2634, 3139, 3113, 3216, 3100, 2693, 2641, 5188, 5250, 5139, 5133, 4280, 4630, 4633, 4211, 747, 505, 855, 924, 734, 829, 965, 938, 1648, 1611, 1804, 1729, 3141, 3114, 2583, 2288, 4263, 4321, 4422, 4402, 4868, 4253, 4752, 4425, 2254, 2143, 2375, 2612, 884, 506, 749, 945, 1150, 1266, 966, 755, 859, 940, 1589, 1422, 1370, 1480, 1382, 1429, 1327, 1593, 1268, 1619, 5168, 5134, 4206, 4213, 4308, 4267, 4872, 4426, 3588, 3121, 2848, 2450, 2404, 2355, 2349, 2465, 2261, 2616, 2880, 2636, 830, 911, 871, 639, 888, 479, 1213, 1590, 946, 750, 969, 508, 4322, 4645, 5192, 5377, 4634, 4483, 4404, 4312, 5141, 5252, 4512, 4367, 4375, 4254, 4433, 4646, 861, 757, 970, 919, 2234, 2694, 2452, 2275, 2944, 2642, 3146, 3344, 3232, 3592, 3360, 3600, 2466, 2350, 2697, 2819, 3264, 3616, 2408, 2587, 875, 862, 758, 948, 1700, 1385, 1730, 1613, 2159, 2379, 2262, 2357, 1239, 1810, 1671, 1372, 4768, 4214, 4428, 4675, 4636, 4485, 4269, 4217, 1443, 1430, 1488, 1704, 1825, 1386, 1614, 1433, 4649, 4295, 4880, 4275, 4324, 4434, 4408, 4800, 1594, 1812, 1621, 1596, 1243, 1335, 977, 923, 1732, 1622, 1625, 1675, 2236, 2497, 3142, 3116, 1445, 1816, 1826, 1635, 3203, 3153, 2265, 2456, 1626, 1434, 1255, 1712, 2657, 2644, 2599, 2698, 2277, 2207, 2468, 2358, 972, 761, 1677, 1272, 5155, 5378, 4486, 4270, 4650, 4677, 4489, 4379, 2589, 2821, 2658, 2705, 2381, 2167, 2648, 2387, 1393, 1214, 1388, 1678, 2266, 2416, 2700, 2278, 6155, 6184, 6212, 6274, 4218, 4544, 4449, 4657, 4299, 4159, 4436, 4490, 4623, 4678, 4652, 4277, 2439, 2361, 3122, 3145, 1683, 1359, 1504, 1339, 1245, 1394, 877, 952, 495, 703, 935, 978, 883, 762, 503, 925, 2498, 2590, 3087, 3392, 2382, 2281, 2603, 2822, 878, 735, 1637, 1446, 2223, 2171, 3205, 3124, 1449, 1475, 993, 885, 2706, 2660, 2389, 2825, 2268, 2362, 2472, 2443, 2721, 2631, 3095, 3206, 2403, 2335, 2231, 2282, 1638, 1567, 1259, 1436, 1367, 1396, 1799, 1341, 5146, 5633, 5200, 5157, 5145, 5142, 4391, 4381, 4328, 4220, 4301, 4278, 4739, 4658, 4382, 4681, 2173, 2605, 2708, 2664, 3456, 3148, 2390, 2364, 2289, 2826, 3209, 3154, 2611, 2393, 2500, 2445, 5256, 5380, 4395, 4450, 6163, 6157, 6192, 6158, 4307, 4497, 5384, 5158, 5634, 5216, 4281, 4492, 1246, 1450, 1477, 1261, 2451, 2255, 3128, 3099, 2722, 2606, 2833, 2480, 2405, 2235, 3169, 3111, 3331, 3156, 2284, 2712, 1583, 1857, 1828, 1736, 6216, 6401, 6165, 6276, 4440, 4682, 5187, 5161, 1858, 1685, 1832, 1803, 2672, 2635, 2828, 2753, 5264, 5148, 4741, 4689, 5189, 5162, 4631, 4336, 2174, 2290, 2613, 2446, 939, 994, 1641, 1628, 1457, 1744, 980, 926, 1840, 1860, 1371, 1921, 1267, 1686, 1478, 1342, 3210, 3217, 2394, 2504, 3333, 3101, 2406, 2453, 1699, 1642, 764, 941, 4302, 4191, 4423, 4660, 5636, 5169, 4896, 4498, 1922, 1805, 967, 886, 1400, 1452, 831, 947, 1689, 1760, 1591, 1864, 507, 889, 1649, 1262, 4452, 4403, 4397, 4513, 6179, 6402, 6170, 6657, 4309, 4664, 4928, 4684, 4282, 4742, 4500, 4323, 2351, 2617, 2292, 2643, 1383, 1481, 1423, 1811, 984, 751, 1615, 1702, 1458, 1701, 1373, 1269, 2237, 2614, 2724, 2409, 3115, 3170, 2754, 2637, 1482, 1690, 1644, 1387, 1151, 1215, 1806, 1431, 1460, 1650, 1595, 1489, 942, 996, 1705, 1270, 4992, 4690, 5194, 5392, 5280, 5640, 5408, 5648, 2263, 2834, 3587, 3160, 971, 890, 1731, 1374, 1623, 1692, 1814, 1484, 1273, 1706, 509, 949, 1597, 1435, 973, 1000, 892, 950, 1827, 1813, 3212, 3102, 2695, 2396, 2467, 2454, 2512, 2728, 4514, 4398, 4745, 4867, 5312, 5664, 4456, 4635, 4207, 4427, 4310, 4405, 6224, 6181, 6169, 6166, 4284, 4545, 5190, 5164, 5251, 5201, 4313, 4504, 2849, 2410, 2638, 2457, 2618, 2836, 2645, 2620, 2267, 2359, 3218, 3143, 3334, 3337, 2756, 2646, 2649, 2699, 3233, 3648, 3117, 3172, 2469, 2840, 2850, 2659, 2650, 2458, 3712, 3123, 2279, 2736, 1733, 1389, 1464, 1652, 3220, 3118, 2701, 2296, 2417, 2238, 2412, 2702, 2707, 2383, 3147, 3338, 1713, 1398, 1447, 1490, 2528, 2363, 2269, 2418, 6280, 6404, 6408, 6182, 4705, 4692, 4647, 4746, 4325, 4255, 4516, 4406, 4637, 4869, 4706, 4753, 863, 759, 1817, 1274, 3345, 3589, 3176, 3234, 6658, 6240, 7168, 7169, 4429, 4215, 4696, 4435, 1395, 1505, 1598, 1437, 1008, 510, 1627, 1390, 2661, 2470, 2473, 2499, 2662, 2591, 2283, 2460, 2391, 2420, 3125, 3265, 2823, 2365, 2270, 2474, 1492, 1679, 1924, 1829, 979, 953, 1639, 1708, 2501, 2285, 2607, 2881, 3224, 3149, 3236, 3840, 3340, 3346, 2852, 2760, 2882, 2709, 2856, 2827, 2665, 2652, 2481, 2768, 1734, 1453, 1818, 1276, 4314, 4464, 4748, 4326, 4487, 4409, 5170, 5193, 4546, 4638, 5135, 5440, 4430, 4329, 4651, 4870, 4271, 4219, 5253, 5172, 4754, 4708, 4437, 4873, 6211, 6185, 6288, 6172, 4316, 4410, 4520, 4491, 763, 974, 1397, 1629, 1872, 1714, 954, 879, 981, 982, 1737, 1656, 2864, 2884, 2395, 2945, 3590, 3126, 3155, 3129, 2291, 2710, 3593, 3184, 1506, 1830, 1451, 1928, 2502, 2366, 2723, 2666, 4769, 4679, 5143, 5254, 4451, 4383, 4279, 4330, 4221, 4653, 4756, 4712, 5504, 5196, 4438, 4412, 1438, 1247, 1687, 1716, 927, 995, 1859, 1643, 1496, 1479, 1820, 1833, 2946, 2829, 2424, 2476, 2713, 2784, 2615, 2888, 1738, 1745, 765, 956, 1861, 1740, 1888, 1834, 887, 985, 1630, 1936, 2673, 2286, 3207, 3150, 1746, 1720, 1401, 1459, 1841, 1343, 997, 986, 3361, 3266, 3157, 3348, 4337, 4874, 5257, 5202, 4659, 4441, 4548, 4493, 4499, 4303, 5176, 5147, 4770, 4654, 4881, 4528, 6213, 6186, 6660, 6193, 6218, 6416, 6304, 6664, 3594, 3130, 2407, 2505, 1645, 1836, 1508, 1454, 4453, 4283, 5217, 5159, 5379, 5204, 4332, 4760, 2447, 2835, 2639, 2726, 1862, 1691, 1512, 1263, 2482, 2725, 3240, 3211, 1402, 1483, 1646, 1651, 4720, 4683, 4876, 4801, 4222, 4338, 4661, 4494, 5258, 5265, 4442, 4552, 5381, 5149, 4454, 4501, 3171, 3158, 2397, 2293, 2506, 2714, 2668, 2411, 2175, 2239, 2830, 2455, 943, 891, 1461, 1404, 6432, 6672, 6336, 6688, 4399, 4665, 4340, 4691, 4285, 4662, 4772, 4457, 5163, 5218, 4802, 4685, 998, 766, 1842, 1485, 2484, 2674, 3132, 3352, 4311, 4882, 5635, 5208, 6214, 6188, 6275, 6225, 3161, 3362, 3601, 3596, 1520, 1693, 1703, 1748, 2619, 2513, 3268, 3213, 2729, 2294, 2755, 2398, 3173, 3219, 3248, 3214, 511, 988, 1865, 1653, 1375, 1491, 1462, 1761, 2647, 2716, 2838, 2508, 3602, 3393, 3103, 3272, 1275, 1486, 1466, 1465, 1001, 951, 1493, 1271, 1707, 1866, 1762, 1923, 2297, 2730, 3162, 3617, 1002, 893, 1694, 1807, 975, 894, 1873, 1844, 1752, 1952, 1815, 1391, 5260, 5150, 4743, 4444, 4515, 4502, 4560, 4776, 6194, 6217, 6159, 6464, 4897, 4458, 4686, 4505, 4666, 4884, 4693, 4668, 4315, 4407, 5266, 5191, 5382, 5385, 4804, 4694, 4697, 4747, 5281, 5696, 2621, 2459, 2851, 2837, 1925, 1654, 1709, 1868, 2757, 2413, 2488, 2676, 1657, 1735, 1009, 955, 1277, 1715, 1848, 1926, 2737, 2422, 2471, 2514, 2841, 2298, 2419, 2529, 3364, 3394, 3604, 3335, 5165, 5220, 4517, 4888, 4898, 4707, 4698, 4506, 5760, 5171, 4327, 4784, 5268, 5166, 4749, 4344, 4465, 4286, 4460, 4750, 4755, 4431, 5195, 5386, 6277, 6196, 6167, 6278, 4576, 4411, 4317, 4466, 3221, 3174, 3177, 3376, 2622, 2461, 2651, 2414, 2516, 2703, 2948, 2853, 1710, 1764, 1874, 1399, 5393, 5637, 5224, 5282, 4709, 4518, 4521, 4547, 3368, 3235, 3164, 3119, 1468, 1494, 1004, 1010, 1507, 1439, 1509, 1929, 3339, 3457, 3618, 3396, 2663, 2732, 2758, 2477, 3280, 3458, 2842, 2300, 4710, 4639, 4331, 4508, 4439, 4468, 5173, 5313, 2421, 2653, 2896, 2738, 3222, 3225, 2761, 2680, 1819, 1497, 1658, 1768, 2530, 2854, 2475, 2952, 1876, 1984, 957, 983, 2462, 2271, 3237, 3178, 1889, 1717, 1821, 1930, 1739, 1831, 1498, 1660, 4871, 4413, 4318, 4522, 4549, 4333, 4655, 4929, 2711, 2740, 2883, 2667, 3127, 3400, 3608, 3649, 2520, 2503, 2844, 2857, 3620, 3185, 3226, 3151, 5272, 5197, 5284, 5888, 5388, 5394, 4900, 4808, 6528, 6220, 7170, 7172, 6281, 6226, 6200, 6171, 958, 987, 1718, 1278, 1741, 1599, 1012, 999, 2762, 2769, 3341, 3180, 2885, 2764, 2912, 2858, 6241, 6183, 6403, 6228, 4930, 4757, 4904, 4875, 4713, 4700, 4529, 4816, 4912, 4932, 4443, 4993, 2654, 2960, 2770, 2744, 3650, 3296, 3238, 3591, 5638, 5174, 5203, 5177, 4339, 4758, 5641, 5232, 2425, 2483, 2865, 2367, 2669, 2860, 2532, 2478, 2886, 2715, 3624, 3267, 3342, 3713, 3595, 3347, 2536, 2287, 2426, 2507, 2670, 2675, 3652, 3363, 3131, 3241, 2485, 2428, 2866, 2509, 2544, 2717, 6282, 6289, 6405, 6173, 4550, 4414, 4771, 4714, 4994, 4877, 4472, 4524, 6187, 6242, 6659, 6232, 1937, 1822, 1835, 1403, 1721, 1455, 1016, 767, 2727, 2772, 2889, 2677, 1631, 1513, 1890, 1747, 3632, 3186, 3349, 3228, 3159, 3269, 2399, 2515, 1510, 1932, 1742, 1837, 1500, 1880, 1863, 1749, 2486, 2785, 2299, 2510, 2490, 2489, 3188, 3242, 7176, 7184, 6284, 6174, 4761, 4832, 4663, 4936, 4721, 4334, 5255, 5198, 6290, 6215, 6406, 6409, 6305, 6720, 6189, 6244, 5409, 5314, 5205, 5396, 1722, 1938, 989, 1003, 1776, 1892, 1843, 1838, 1463, 1953, 1514, 1647, 1695, 1763, 1940, 1487, 3133, 3603, 3597, 3714, 3353, 3350, 3598, 3249, 6784, 6195, 6292, 6190, 5642, 5178, 4455, 4553, 4495, 4883, 4687, 4774, 4530, 4773, 5288, 5259, 1867, 1405, 990, 1005, 1521, 1954, 1845, 1750, 2517, 2295, 2731, 2890, 1985, 1896, 1516, 1655, 1753, 1724, 1467, 1765, 3365, 3460, 2786, 2947, 2718, 2831, 2897, 2868, 2776, 2976, 2839, 2415, 2949, 2678, 3163, 3656, 2733, 2892, 3841, 3270, 7200, 7171, 6219, 6410, 5219, 5206, 4445, 4341, 4554, 4762, 4716, 4459, 4223, 4287, 4878, 4503, 4532, 4722, 5180, 5400, 5209, 5410, 5649, 5644, 1869, 1944, 1406, 1846, 1875, 1754, 1522, 1904, 1766, 1469, 959, 1011, 2681, 2759, 3244, 3192, 1495, 1659, 1956, 1711, 1927, 1849, 1013, 895, 1524, 1870, 1769, 1850, 1756, 1470, 1986, 1960, 4667, 4561, 5316, 5261, 4777, 4342, 4803, 4446, 5221, 5267, 5296, 5262, 6417, 6661, 6248, 6306, 6197, 6337, 7173, 7232, 6296, 6221, 7177, 7174, 4695, 4764, 4886, 4556, 5650, 5441, 5151, 5320, 6308, 6912, 7185, 7178, 4345, 4778, 5210, 5665, 1499, 1877, 1891, 1661, 1931, 1511, 1719, 1770, 3273, 3408, 2301, 2739, 3134, 3354, 3215, 3175, 4669, 4507, 4899, 4885, 4805, 4461, 4536, 4724, 2872, 2950, 3250, 3366, 3165, 3716, 2734, 2788, 2898, 2423, 2492, 2518, 2531, 2463, 3274, 3664, 3395, 3464, 2533, 2953, 3369, 3842, 2843, 2521, 3179, 3252, 3223, 3281, 3356, 3720, 3166, 3276, 2682, 2792, 2900, 3008, 1852, 1777, 1878, 1881, 3370, 3472, 3680, 3424, 3397, 3605, 3227, 3282, 4785, 4470, 4519, 4562, 6412, 6418, 6662, 6198, 2913, 2741, 3377, 3619, 3372, 3181, 3256, 3606, 6227, 6201, 6665, 6256, 4889, 4346, 4467, 4577, 3609, 3187, 2845, 2954, 2763, 2855, 3239, 3297, 5412, 5442, 5652, 5383, 5269, 5222, 5225, 5424, 4670, 4509, 4699, 4462, 4564, 4751, 4996, 4901, 1528, 1823, 1279, 1988, 3398, 3378, 2522, 2684, 5416, 5283, 5212, 5167, 5387, 5505, 5666, 5444, 4711, 4780, 4806, 4525, 5328, 5506, 4890, 4348, 2742, 2302, 2765, 2623, 2961, 2846, 3844, 3229, 4469, 4701, 4944, 4786, 5270, 5273, 4809, 4728, 4578, 4902, 4523, 5000, 6279, 6222, 6433, 6338, 3728, 3401, 2859, 2427, 2745, 2479, 2655, 2537, 2914, 2771, 2534, 2956, 1933, 1743, 1501, 1939, 1006, 1014, 1662, 1772, 1968, 1893, 1515, 1723, 1778, 1882, 1502, 1992, 1017, 1018, 1407, 1934, 4510, 4319, 5285, 5226, 6229, 6420, 6666, 6202, 4759, 4788, 4931, 4715, 5175, 5448, 5656, 5697, 1839, 2000, 1894, 1941, 3182, 3189, 2766, 2861, 4568, 4551, 4892, 4905, 6312, 6283, 6243, 6230, 2524, 2904, 2887, 2773, 1751, 1517, 1897, 1725, 5668, 5233, 5274, 5199, 4810, 4817, 5389, 5228, 4933, 4812, 4960, 4906, 4702, 5008, 4818, 4792, 5698, 5344, 5286, 5639, 6204, 6424, 6233, 6434, 4473, 4531, 4913, 4415, 4717, 4908, 4580, 4526, 3284, 3243, 3848, 3402, 2746, 2962, 2800, 2916, 2867, 2862, 2487, 2977, 3298, 3621, 2538, 2671, 4934, 4763, 5672, 5315, 5390, 5761, 5643, 5395, 6673, 6668, 6340, 6285, 4584, 4335, 4474, 4555, 4718, 4723, 5700, 5411, 6245, 6291, 6320, 6286, 5179, 5289, 4533, 4476, 4914, 4557, 4592, 4765, 2719, 2787, 2964, 2511, 2891, 2429, 2545, 2978, 4775, 4820, 4937, 4725, 6674, 6465, 6175, 6344, 5680, 5234, 5397, 5276, 5207, 5317, 4447, 4563, 4534, 4833, 4347, 4558, 6234, 6689, 6436, 6466, 6676, 6407, 6293, 6246, 4538, 4537, 5236, 5290, 3610, 3459, 3380, 3288, 3488, 3343, 3351, 3230, 3409, 3622, 3744, 3190, 3404, 3651, 3612, 3461, 5181, 5651, 5645, 5762, 5401, 5398, 5646, 5297, 4565, 4343, 4779, 4938, 5413, 5508, 4834, 4995, 1955, 1780, 1884, 1523, 3245, 3193, 3625, 3271, 2869, 2774, 3856, 3251, 1755, 1847, 1946, 1898, 3300, 3410, 3384, 3776, 3009, 2920, 3462, 3246, 2540, 2679, 3626, 3653, 2777, 2748, 2491, 2789, 6249, 6448, 6440, 6307, 4766, 4879, 4945, 4916, 6236, 6191, 6411, 6529, 4824, 5024, 4887, 4463, 3465, 3355, 3194, 3520, 1942, 1526, 1957, 1767, 3425, 3633, 3275, 3135, 1784, 1905, 1518, 1726, 2893, 2968, 2430, 2870, 1945, 1525, 1900, 1871, 3412, 3466, 3599, 3654, 3628, 3253, 3367, 3357, 991, 1020, 2016, 1471, 3304, 3196, 2899, 2778, 4997, 4726, 5211, 5704, 4781, 4940, 5889, 5318, 2546, 2928, 2790, 2493, 2519, 2683, 3277, 3254, 1757, 1851, 1958, 1906, 3715, 3634, 3358, 3657, 2980, 2735, 3371, 3426, 2951, 2873, 2548, 2894, 4729, 4807, 5292, 5240, 5321, 5456, 4349, 4787, 6690, 6468, 6352, 6530, 5182, 5402, 5263, 5223, 2793, 2874, 3283, 3473, 3257, 3468, 2780, 2494, 3010, 2984, 2523, 2901, 3416, 3658, 2915, 2685, 2955, 2535, 3717, 3665, 3607, 3312, 2743, 2794, 1961, 1987, 1771, 1529, 3278, 3167, 2876, 2801, 4920, 4998, 5298, 5414, 7186, 7296, 6294, 6297, 1879, 1948, 1758, 1853, 3399, 3636, 2902, 2905, 3872, 3474, 3428, 3379, 3373, 3489, 2552, 2847, 2303, 3012, 3285, 3640, 1007, 1015, 1989, 1962, 3904, 3660, 2957, 2767, 1908, 1530, 1773, 1969, 1990, 1779, 1883, 1964, 3258, 3718, 3476, 3299, 6309, 6250, 6199, 6472, 5213, 5764, 4782, 4836, 4946, 4471, 4540, 4566, 4579, 4511, 5322, 5712, 5443, 5512, 4581, 5001, 5417, 5890, 4891, 4569, 5227, 5300, 5271, 5329, 5404, 5768, 5214, 5324, 4730, 4840, 4948, 5056, 6680, 6721, 6692, 6257, 6298, 6223, 6413, 6252, 5418, 5520, 5728, 5472, 5445, 5653, 5275, 5330, 6722, 6368, 7180, 7201, 6310, 6663, 6696, 6339, 4961, 4789, 5425, 5667, 5420, 5229, 5304, 5654, 5657, 5235, 4893, 5002, 7233, 7188, 6414, 6785, 4811, 4903, 5287, 5345, 3968, 3666, 2525, 2963, 2686, 2796, 3490, 3374, 6667, 6419, 6724, 6435, 5446, 5426, 4570, 4732, 4790, 4350, 4813, 4671, 5009, 4894, 5892, 5277, 5776, 5449, 4907, 4475, 6203, 6313, 6704, 6258, 3721, 3843, 2992, 2917, 2539, 2747, 2802, 2906, 4793, 4527, 4703, 4585, 4962, 4819, 4582, 5004, 1854, 1935, 1895, 1663, 3432, 3611, 2526, 3016, 6421, 6300, 7424, 7202, 6231, 6341, 6260, 6314, 2431, 2958, 2863, 3024, 3183, 3403, 2918, 2965, 1912, 1503, 1019, 1021, 3286, 3381, 2775, 2541, 5230, 5237, 4814, 4909, 4572, 4952, 4935, 4821, 5332, 5291, 5896, 5450, 4794, 5010, 4848, 4964, 4915, 4910, 4535, 5025, 6205, 6675, 6669, 6786, 5346, 5669, 4586, 4719, 4767, 4835, 5012, 4559, 2921, 2749, 3260, 3521, 3289, 3480, 3681, 3668, 1970, 1774, 1993, 1532, 3623, 3722, 3301, 3231, 4939, 4477, 4593, 5026, 5658, 5507, 5428, 5336, 6425, 6422, 6670, 6321, 6437, 6532, 7192, 7204, 6235, 6728, 6913, 6342, 5536, 5391, 5399, 5278, 5457, 5670, 5792, 5238, 5452, 5699, 5660, 5509, 5293, 5241, 5673, 5319, 4917, 4822, 5904, 5299, 3492, 3382, 2979, 2804, 3613, 3845, 2908, 2547, 1885, 1781, 1994, 1943, 2779, 2871, 3682, 3729, 3405, 3191, 3672, 3411, 1899, 1886, 1782, 1972, 2001, 1947, 1996, 1785, 3290, 3440, 3724, 3302, 5348, 5458, 5432, 5824, 5057, 4968, 5510, 5294, 7175, 7297, 6316, 6264, 6345, 6480, 6206, 6426, 4588, 4727, 5674, 5701, 7234, 7680, 6287, 6247, 2970, 2922, 3463, 3385, 2966, 2550, 3522, 3614, 4825, 4796, 4539, 4837, 5513, 5403, 5242, 5568, 2981, 2791, 2808, 2929, 3406, 3305, 3627, 3846, 1901, 1976, 1519, 1727, 3247, 3195, 3730, 3684, 2542, 2750, 2969, 2549, 3413, 3849, 3292, 3386, 5473, 5681, 5323, 5183, 4941, 5016, 4478, 4918, 5460, 5514, 5647, 5702, 5676, 5301, 5415, 5405, 3496, 3467, 3745, 3655, 1959, 2002, 1907, 1786, 3427, 3359, 3255, 3306, 3197, 3629, 3732, 3688, 1527, 1949, 1902, 1759, 3414, 3388, 3313, 3850, 5352, 5244, 4947, 4826, 6322, 6438, 6237, 6788, 3635, 3417, 3524, 3469, 2924, 2895, 3040, 2495, 3475, 3279, 2781, 2875, 2017, 1909, 1963, 2018, 6346, 6736, 6467, 6536, 6441, 6914, 6251, 6324, 7179, 7208, 6295, 6353, 4594, 4976, 4838, 4541, 3746, 3630, 3857, 3504, 2982, 2930, 2985, 3011, 4567, 4731, 5325, 5302, 5763, 5682, 5406, 5705, 3429, 3259, 3308, 3736, 2795, 2553, 2903, 2972, 5028, 4783, 5419, 5474, 6428, 6792, 6238, 6348, 2782, 2877, 3013, 2986, 3696, 3659, 3852, 3777, 6442, 6544, 6752, 6496, 4999, 4921, 4596, 4942, 4841, 4922, 5331, 5521, 5305, 5516, 4828, 4542, 5058, 5032, 4571, 4949, 5464, 5706, 4963, 4733, 2004, 1950, 1788, 1965, 2932, 2554, 2797, 2993, 1991, 1910, 1855, 1971, 3198, 3314, 3014, 2803, 5003, 4583, 5765, 5713, 6469, 6677, 6299, 6354, 6449, 6691, 6444, 6253, 7236, 7298, 7187, 7181, 2907, 2988, 3637, 3470, 3418, 3528, 3430, 3477, 5655, 5360, 4791, 4842, 6328, 6678, 6681, 6259, 5326, 5215, 4924, 4849, 5447, 5684, 4950, 4953, 6311, 6369, 6470, 6450, 6916, 6301, 6800, 6473, 1022, 1023, 1531, 1913, 3375, 3641, 3316, 3667, 2878, 2959, 2919, 2687, 2936, 2527, 3261, 3638, 5920, 5522, 5476, 5427, 5421, 5537, 4600, 4895, 7216, 7182, 6254, 6261, 6356, 6315, 6920, 6474, 2994, 2798, 3017, 2556, 2909, 2805, 3018, 2967, 2008, 1775, 1966, 2020, 2923, 2910, 2806, 2996, 3748, 3433, 3778, 3661, 3287, 3858, 3719, 3420, 4351, 5060, 5333, 5688, 6370, 6693, 7240, 7425, 1995, 1914, 1533, 1973, 3491, 3478, 3536, 3752, 1997, 2024, 1916, 1974, 3873, 3434, 3662, 3481, 3642, 3860, 3669, 3644, 3291, 3383, 3025, 2971, 5952, 5708, 5005, 4815, 5306, 5766, 5524, 5347, 3780, 3670, 3673, 3723, 3493, 3864, 3874, 3683, 6016, 5714, 4573, 5011, 4734, 4844, 5538, 5422, 3674, 3482, 3303, 3760, 1887, 1783, 2032, 1534, 3020, 2809, 3725, 3320, 3441, 3262, 3436, 3726, 5769, 5891, 5040, 4965, 4587, 4795, 4850, 4954, 5480, 5659, 4574, 5064, 4479, 5006, 4911, 5072, 6682, 6531, 6452, 6360, 7189, 7300, 6560, 6415, 6423, 6302, 6481, 6694, 6816, 6262, 6476, 6723, 5231, 5451, 4966, 5013, 5334, 5429, 4823, 4589, 4969, 4797, 5308, 5569, 5337, 5528, 5729, 5716, 3731, 3407, 3552, 3387, 3293, 3442, 2925, 3000, 6684, 6533, 6317, 6265, 6697, 6343, 6928, 6323, 2543, 2751, 2983, 3026, 2003, 1977, 1787, 1998, 2931, 2810, 2551, 2973, 2926, 2783, 3685, 3494, 6372, 6482, 6456, 6848, 7203, 7426, 6534, 6318, 5671, 5770, 5349, 5279, 5540, 5430, 5027, 4852, 6698, 6725, 6537, 6427, 5661, 5893, 4956, 4595, 4827, 4919, 5730, 5777, 5453, 5239, 5720, 5459, 6266, 6592, 6497, 6705, 5338, 5488, 5772, 5350, 3497, 3523, 3041, 2933, 3686, 3615, 3307, 3484, 5018, 4970, 5511, 5433, 5014, 4598, 5570, 5662, 3415, 3444, 3847, 3389, 1978, 1903, 2005, 2006, 5029, 4839, 4856, 4977, 6347, 6207, 6484, 6538, 3294, 3498, 3525, 3309, 3631, 3905, 3876, 3784, 3906, 3733, 3880, 3851, 2987, 3042, 3689, 3676, 5454, 5353, 5675, 5894, 5295, 5243, 5778, 5732, 6671, 6726, 6700, 6325, 7194, 7681, 7248, 7205, 4590, 4798, 5017, 4597, 5461, 5897, 5340, 5434, 7193, 7190, 6439, 6429, 6376, 6268, 6349, 6326, 1951, 2019, 1789, 1980, 3505, 3792, 3028, 2974, 3888, 3908, 3419, 3969, 1911, 2009, 2021, 2010, 5544, 5515, 5793, 5703, 6787, 6706, 6430, 6729, 5475, 5407, 5303, 5354, 5245, 5677, 5780, 5736, 5462, 5436, 5361, 5898, 5683, 5465, 5572, 5517, 7304, 7428, 6443, 6498, 6355, 6545, 7432, 7206, 4972, 4943, 5088, 4543, 5523, 5327, 4829, 4923, 5794, 5678, 5905, 5552, 5030, 4978, 5033, 5059, 5477, 5307, 5356, 5784, 7682, 7264, 6329, 6540, 6488, 6730, 7235, 7209, 7312, 7196, 6789, 6737, 4843, 4601, 4951, 5020, 4830, 4925, 5061, 5034, 5744, 5707, 5900, 5825, 7237, 7210, 6679, 6384, 6350, 6239, 6471, 6708, 4980, 4602, 4845, 5041, 5246, 5362, 5062, 4851, 4955, 5036, 5685, 5518, 3315, 3734, 3526, 3390, 3747, 3690, 2812, 2989, 3970, 3853, 3015, 2934, 1967, 1915, 2022, 1790, 5466, 5576, 5478, 5525, 5423, 5689, 5364, 5715, 3448, 3500, 2879, 2995, 3737, 3808, 3639, 3912, 7684, 7217, 6944, 6546, 6500, 6451, 6445, 6561, 6357, 6712, 6976, 6732, 4926, 5007, 4967, 4735, 2555, 2937, 3697, 3310, 3431, 3529, 3471, 3859, 3032, 2799, 3663, 3750, 3506, 3749, 3421, 3317, 4984, 4575, 5309, 5686, 5042, 4846, 5065, 4604, 4957, 4853, 5066, 5015, 6330, 6790, 6548, 6371, 3530, 3738, 3692, 3435, 1535, 2012, 2025, 1975, 3199, 3263, 3854, 3479, 3508, 3698, 3643, 3537, 2990, 3044, 3753, 3318, 3019, 2938, 3779, 3422, 3671, 3740, 3862, 3532, 3321, 3754, 2557, 2997, 7040, 6738, 7242, 7440, 7328, 7688, 7456, 7696, 6562, 6446, 6793, 6915, 7360, 7712, 6504, 6683, 3645, 3483, 3021, 3048, 2026, 1917, 1999, 1918, 2940, 2998, 3875, 3861, 3781, 3437, 3512, 3700, 4971, 4958, 4854, 5044, 5796, 5481, 5826, 5709, 3761, 3446, 3495, 3538, 2911, 2807, 3865, 3322, 3443, 3553, 3646, 3485, 3056, 2558, 3675, 3438, 6255, 6475, 6358, 6453, 5335, 5906, 5767, 5468, 5539, 5526, 5584, 5800, 5921, 5482, 5710, 5529, 5690, 5908, 5717, 5692, 5339, 5431, 5073, 5019, 5828, 5718, 5721, 5771, 6332, 6593, 7238, 7212, 5541, 5912, 5922, 5731, 7299, 7249, 6361, 6552, 3540, 3727, 3972, 3877, 3027, 3001, 3687, 3756, 3782, 3501, 3866, 3324, 2811, 3022, 3445, 3677, 3920, 3762, 3002, 2927, 2033, 1979, 2028, 2034, 5722, 5530, 5351, 5808, 6753, 6740, 6695, 6794, 3029, 3030, 3785, 3704, 3554, 3878, 3499, 3976, 3486, 3295, 3735, 3764, 1981, 2007, 1982, 2011, 2975, 3043, 3907, 3691, 3544, 3527, 3868, 3881, 3786, 3793, 2813, 3004, 3909, 3788, 3936, 3882, 2935, 3033, 3678, 3984, 3794, 3768, 3449, 3507, 3889, 3391, 3045, 3034, 3693, 3884, 3556, 3502, 6373, 6303, 6564, 6454, 5068, 4857, 5773, 5368, 6685, 6917, 6754, 6801, 6477, 6263, 6744, 6483, 5489, 5310, 5484, 5774, 6362, 6512, 6796, 6374, 6535, 6457, 7218, 7241, 5779, 5455, 5600, 5435, 5341, 5490, 4973, 5048, 4591, 4799, 5031, 5074, 4979, 4858, 4599, 5021, 6594, 6686, 7183, 7488, 6478, 6377, 6699, 6918, 4974, 4831, 5733, 5542, 6319, 6267, 7301, 7220, 5545, 5571, 5089, 4981, 6802, 6756, 6485, 6921, 6364, 6458, 6568, 6539, 6817, 6727, 7191, 7302, 6499, 6431, 6327, 6378, 5734, 5663, 5355, 5532, 5463, 5492, 5895, 5437, 3910, 3739, 3560, 3311, 3450, 3531, 3694, 3699, 6269, 6701, 6804, 6760, 7552, 7244, 6486, 6460, 6385, 6922, 7305, 7250, 6707, 6489, 6596, 6541, 5342, 5546, 5573, 5357, 6547, 6351, 7224, 7195, 6818, 6702, 6929, 6576, 6501, 6331, 7265, 7207, 7427, 7252, 6380, 6808, 5679, 5953, 5924, 5832, 5954, 5781, 5928, 5899, 6768, 6731, 6924, 6849, 2991, 2939, 3509, 3452, 3046, 2814, 3890, 3533, 6270, 6386, 6709, 6542, 5035, 5090, 5737, 5724, 5553, 5840, 5076, 5022, 5936, 5956, 5467, 6017, 5363, 5782, 5574, 5438, 7306, 7313, 6490, 6600, 7429, 7197, 6502, 6549, 5795, 5738, 4860, 5037, 6018, 5901, 5063, 4982, 5496, 5548, 4927, 5043, 5785, 5856, 5687, 5960, 4603, 4985, 5745, 5358, 3568, 3741, 3751, 3796, 2559, 3036, 3913, 3701, 2036, 2023, 2040, 1791, 3423, 3539, 3510, 3809, 3323, 3534, 3514, 3513, 3049, 2999, 3541, 3319, 3755, 3914, 3810, 3971, 3050, 2941, 3742, 3855, 2013, 2027, 2014, 2029, 3023, 2942, 3921, 3892, 3800, 4000, 3863, 3439, 3973, 3702, 3757, 3916, 6447, 6713, 6388, 6739, 5479, 5577, 5519, 5907, 5080, 4847, 5711, 5798, 5554, 5797, 5469, 5365, 3705, 3783, 3057, 3003, 3325, 3763, 3896, 3974, 6333, 6710, 6820, 6505, 7211, 7266, 6850, 6733, 5578, 5786, 5740, 5483, 5247, 5311, 5902, 5527, 5556, 5746, 5691, 5585, 5038, 5092, 5801, 5366, 6359, 6930, 7683, 7256, 5067, 4986, 5827, 5470, 5719, 5788, 5910, 5580, 5369, 5802, 4605, 5045, 5693, 5531, 5069, 5096, 4988, 5046, 5923, 5909, 7308, 7198, 6791, 6492, 6563, 6550, 6608, 6824, 6945, 6506, 6734, 6553, 6714, 6932, 6741, 6716, 6363, 6455, 7314, 7239, 7430, 7433, 6852, 6742, 6745, 6795, 7329, 7744, 7213, 7268, 6565, 6936, 3758, 3812, 3922, 3447, 3516, 3542, 3052, 3058, 6946, 6755, 6746, 6554, 7808, 7219, 6375, 6832, 5829, 5485, 5560, 5748, 7316, 7214, 6797, 6392, 3555, 3487, 3557, 3977, 3867, 3545, 3706, 3816, 6513, 6334, 6508, 6798, 6803, 6479, 7243, 7434, 5809, 5494, 5543, 5586, 6624, 6459, 6365, 6514, 4959, 4855, 5913, 5370, 7441, 7685, 7272, 7330, 5491, 5601, 5694, 5533, 5104, 4606, 5723, 5486, 6757, 6566, 6569, 6595, 6758, 6687, 6379, 6556, 3924, 4032, 3005, 3031, 3937, 3765, 3869, 3978, 6487, 6516, 7221, 7361, 6919, 6461, 6366, 6570, 3787, 3879, 3546, 3708, 3006, 3035, 3766, 3326, 5588, 5775, 6020, 5925, 5075, 5049, 5735, 5804, 3789, 3647, 3060, 3047, 3985, 3870, 3883, 3451, 6597, 6381, 6703, 6977, 7320, 7245, 7332, 7936, 7436, 7442, 6948, 6856, 6978, 6805, 6952, 6923, 1983, 2035, 2037, 1919, 3769, 3503, 3064, 2815, 6761, 6748, 6577, 6864, 5830, 5549, 5914, 5372, 4859, 5070, 5493, 5725, 5968, 5810, 5050, 4975, 5077, 5078, 5833, 5752, 6960, 6980, 6491, 7041, 3679, 3561, 3938, 3795, 3558, 3980, 3790, 3885, 7686, 7222, 7251, 7225, 6387, 6806, 7689, 7280, 5602, 5926, 5547, 6024, 6598, 6462, 6819, 6762, 5534, 5343, 5783, 5812, 5023, 5091, 5955, 5739, 5592, 5575, 5916, 5929, 7042, 6925, 6520, 6572, 6809, 6880, 6711, 6984, 5834, 5841, 4861, 5052, 5957, 5836, 5984, 5930, 4983, 5081, 5726, 6032, 6769, 6382, 7303, 7246, 5842, 5816, 5497, 5555, 5937, 5439, 5093, 5082, 7457, 7362, 7253, 7444, 7690, 7226, 6503, 6601, 5741, 5932, 5604, 5550, 3548, 3928, 3911, 3797, 3770, 3986, 3037, 3051, 6543, 6931, 6735, 6822, 5958, 5787, 5608, 5359, 3824, 3940, 3891, 3886, 3511, 4001, 3562, 3695, 6578, 6821, 7336, 7307, 5498, 5579, 5742, 5747, 7267, 7254, 6493, 6389, 6602, 6810, 6764, 6507, 6271, 6335, 6926, 6551, 5039, 4987, 5557, 5500, 5094, 4862, 5938, 5581, 6580, 6770, 7228, 7448, 2030, 2038, 2041, 2042, 3743, 3811, 3988, 3535, 7257, 7458, 7697, 7692, 5616, 5789, 5799, 5844, 3915, 3453, 3038, 3053, 3569, 4002, 3893, 3798, 4033, 3944, 3564, 3703, 3801, 3772, 3515, 3813, 6715, 6609, 7364, 7309, 6825, 6390, 6851, 6494, 7269, 7315, 7344, 7310, 4607, 5084, 5961, 5749, 5471, 5587, 5558, 5857, 6743, 6812, 6934, 6604, 7698, 7489, 7199, 7368, 5371, 5582, 5562, 5561, 5097, 5047, 5589, 5367, 5803, 5962, 5858, 6019, 3917, 3992, 3454, 3894, 3923, 3802, 3570, 3952, 6393, 6826, 7258, 7713, 5098, 4989, 5790, 5903, 5071, 4990, 5969, 5940, 5848, 6048, 5911, 5487, 6717, 6555, 6947, 6933, 6021, 5750, 5805, 5964, 3814, 3517, 3007, 3059, 2015, 2044, 2031, 2039, 6853, 6509, 6584, 6772, 5753, 5831, 5105, 5051, 5373, 5811, 5944, 6022, 6833, 6518, 6567, 6610, 6937, 6394, 6515, 6625, 7460, 7490, 7700, 7431, 3543, 3707, 4004, 3759, 3975, 3897, 3061, 2943, 7317, 7270, 7273, 7472, 6718, 6557, 6747, 6510, 6612, 6799, 7044, 6949, 5806, 5860, 5970, 5495, 7464, 7331, 7260, 7215, 5564, 5590, 5100, 5106, 3572, 3918, 3817, 3898, 3804, 3518, 4034, 4008, 5603, 5535, 5605, 6025, 7435, 7553, 7714, 7492, 6759, 6828, 6854, 6573, 7376, 7554, 6938, 6396, 3547, 3925, 3939, 3709, 3979, 3559, 3767, 3818, 3900, 3825, 3926, 3929, 3576, 3871, 3327, 4036, 6517, 6749, 6992, 6834, 7318, 7321, 6857, 6776, 5915, 5593, 5754, 5864, 6626, 6950, 6571, 7048, 5972, 6080, 5053, 5079, 6558, 6367, 7333, 7274, 5985, 5813, 5917, 6026, 5835, 5927, 5594, 5756, 6807, 6836, 6979, 6763, 7223, 7496, 7704, 7745, 3981, 3791, 3549, 3987, 3054, 3062, 3710, 3820, 6616, 6599, 6940, 6953, 7716, 7281, 7322, 7247, 5054, 5083, 5814, 5374, 5837, 5695, 5108, 5095, 6858, 6865, 7437, 7276, 6981, 6860, 7008, 6954, 6750, 7056, 6866, 6840, 7746, 7392, 7334, 7687, 4016, 3941, 3563, 3771, 3826, 3930, 3550, 4040, 6521, 6579, 6961, 6463, 6765, 6956, 6628, 6574, 6982, 6811, 7720, 7363, 7438, 7809, 7691, 7443, 3065, 3066, 3455, 3982, 3887, 4048, 3942, 3989, 6632, 6383, 6522, 6603, 6766, 6771, 7748, 7459, 7227, 7337, 6581, 6524, 6962, 6605, 6640, 6813, 6033, 5918, 5931, 5499, 5817, 5551, 5112, 4863, 6823, 6868, 6985, 6773, 5727, 5609, 5986, 5843, 3799, 3565, 3945, 3773, 4003, 3828, 3932, 3571, 7728, 7282, 7445, 7324, 7255, 7365, 6495, 6611, 5606, 6028, 5838, 5933, 5596, 5976, 5959, 5845, 6582, 6881, 6395, 6606, 6586, 6585, 7284, 7338, 5818, 6034, 5085, 5099, 5872, 5988, 5939, 5934, 5559, 6049, 5610, 5743, 5791, 5859, 6036, 5583, 7229, 7699, 7693, 7810, 7449, 7446, 7694, 7345, 3803, 3895, 3994, 3946, 3990, 3574, 4005, 3815, 5963, 5501, 5086, 5101, 5617, 6050, 5941, 5846, 3832, 3953, 3566, 3774, 3993, 3573, 3948, 3919, 6613, 6391, 6827, 6986, 6081, 5992, 5612, 5751, 5849, 5820, 5563, 5861, 7461, 7556, 6882, 7043, 6814, 6927, 6993, 6964, 6872, 7072, 6935, 6511, 2043, 2045, 2046, 2047, 3039, 3068, 4064, 3519, 7045, 6774, 7259, 7752, 6829, 6988, 7937, 7366, 5965, 6040, 5502, 5942, 5971, 5850, 5618, 6000, 5862, 5565, 5055, 5107, 6777, 6855, 7340, 7288, 5591, 5755, 6052, 5807, 6023, 5945, 5109, 4991, 5620, 5966, 5865, 5946, 5852, 5566, 6082, 6056, 3805, 3899, 4006, 3954, 4009, 4035, 3819, 3577, 5595, 5973, 5987, 5757, 6027, 5607, 5815, 5866, 7369, 7504, 6397, 6835, 7230, 7450, 7311, 7271, 6968, 7046, 7346, 7462, 7261, 7812, 6830, 6884, 3927, 3996, 3806, 3901, 3055, 3063, 4037, 4010, 6994, 6519, 6588, 6614, 6627, 6559, 7370, 7760, 3956, 3578, 3821, 4017, 4038, 3827, 3931, 4012, 7491, 7560, 6629, 7049, 7465, 7938, 6939, 6617, 7275, 7348, 7319, 7377, 7452, 7816, 7262, 7372, 6778, 6888, 6996, 7104, 5948, 5873, 5974, 5977, 7466, 7568, 7776, 7520, 7493, 7701, 7323, 7378, 7009, 6837, 7473, 7715, 7468, 7277, 7352, 7702, 7705, 7283, 6941, 7050, 6859, 6951, 7335, 7393, 3902, 3983, 3943, 3711, 3960, 3551, 3067, 3069, 5624, 5919, 5375, 6084, 7494, 7474, 6618, 6780, 6838, 6398, 6861, 6719, 7057, 6942, 7940, 7325, 7824, 7497, 6955, 6523, 6841, 6575, 6751, 6633, 7010, 6867, 6630, 7052, 6029, 5839, 5597, 6035, 5102, 5110, 5758, 5868, 6064, 5989, 5611, 5819, 4018, 3822, 4041, 3580, 3933, 3829, 4042, 3991, 5874, 5978, 5598, 6088, 5113, 5114, 5503, 6030, 5935, 6096, 5990, 6037, 7278, 7285, 6862, 6957, 6620, 7000, 6983, 6869, 5847, 5613, 5993, 5821, 7380, 7339, 7944, 7498, 6842, 7058, 6896, 7012, 6963, 6958, 6583, 7073, 7394, 7717, 6634, 6767, 3947, 3934, 3830, 4020, 4049, 3995, 4044, 3833, 6815, 6883, 7060, 6607, 6987, 6525, 6641, 7074, 7706, 7555, 7476, 7384, 7584, 7439, 7447, 7326, 7505, 7718, 7840, 7286, 7500, 7747, 7708, 7557, 6051, 5876, 5980, 5619, 7341, 7289, 7721, 7367, 3949, 4024, 3567, 3775, 4007, 4050, 3955, 3834, 6965, 6870, 7952, 7347, 5851, 5943, 6042, 5994, 7396, 7506, 7480, 7872, 7105, 7016, 7558, 7342, 3575, 3997, 3950, 3807, 4065, 3957, 4011, 4066, 6636, 6775, 7722, 7749, 6873, 6844, 6587, 6885, 7561, 7451, 7290, 7616, 6038, 5622, 6053, 5863, 7521, 7729, 7371, 7231, 5880, 6001, 5614, 5822, 4052, 3998, 3836, 4013, 4039, 3958, 3903, 4019, 6989, 7064, 6526, 6966, 6041, 5621, 5996, 5967, 7508, 7562, 7695, 7750, 7724, 7349, 7463, 7453, 5087, 5116, 6112, 5567, 7400, 7292, 6995, 6874, 6642, 7024, 6886, 6589, 6615, 6779, 7373, 7350, 5853, 5947, 6054, 6002, 7811, 7730, 7454, 7753, 7076, 6831, 7467, 7522, 7047, 6969, 6644, 6990, 6889, 6970, 7379, 7569, 7353, 7564, 6876, 6590, 3070, 3071, 3579, 3961, 4056, 3823, 4014, 4068, 7106, 7080, 6619, 6997, 7512, 7754, 7011, 6781, 7051, 6631, 7813, 7761, 7703, 7408, 6839, 6890, 6057, 6083, 5867, 5625, 7374, 7263, 6972, 6897, 5975, 6044, 5854, 5949, 7495, 7732, 6998, 7001, 7968, 7570, 7524, 7475, 7469, 7585, 6648, 6943, 6399, 7108, 7381, 7736, 5103, 5111, 6085, 6058, 8000, 7756, 7053, 6863, 6004, 5626, 5869, 6065, 4043, 3962, 3581, 4021, 4045, 4072, 3964, 4022, 6086, 5875, 5979, 6060, 7354, 7814, 7572, 7395, 8064, 7762, 6621, 7059, 6782, 6892, 7586, 7470, 7817, 7939, 7088, 7013, 6635, 6843, 6898, 7002, 5950, 6031, 5991, 5759, 7528, 7707, 6622, 7112, 6527, 7054, 6959, 7120, 7279, 7499, 7014, 7061, 6008, 5599, 5115, 5117, 7382, 7477, 6871, 6637, 7017, 6845, 7356, 7617, 7385, 7576, 7777, 7764, 6066, 5870, 6089, 5628, 7719, 7818, 7397, 7327, 7588, 7478, 7075, 6900, 7709, 7941, 7004, 6643, 5981, 5877, 6090, 6039, 6875, 6967, 7778, 7825, 7501, 7287, 7768, 7507, 5995, 5982, 5878, 6068, 3935, 3831, 4080, 3582, 4051, 4025, 3835, 4046, 6097, 6043, 6092, 5881, 7386, 7536, 7820, 7398, 7066, 7018, 7559, 7481, 7062, 6646, 7618, 7710, 7077, 6887, 6904, 7025, 7502, 7401, 7723, 7942, 4026, 3951, 4053, 4054, 3999, 4067, 3837, 4028, 5997, 6072, 5615, 5823, 7343, 7291, 7826, 7780, 6638, 6846, 7065, 6645, 7509, 7945, 7388, 7482, 7592, 7563, 7841, 7751, 6055, 6098, 6003, 5882, 7523, 7455, 7351, 7402, 7293, 7725, 7828, 7784, 5623, 6045, 5998, 5855, 7510, 7484, 7409, 7946, 7731, 7513, 7620, 7565, 7020, 6991, 7136, 6591, 7571, 7375, 6877, 6971, 6113, 6005, 6059, 6114, 7842, 7726, 7953, 7600, 7078, 7026, 7081, 7107, 7525, 7355, 7404, 7832, 6891, 6649, 6999, 7068, 6878, 6973, 7109, 7082, 7792, 7755, 7948, 7873, 6100, 6046, 5884, 6061, 7028, 6650, 6893, 7089, 6087, 6006, 5951, 6067, 7294, 7410, 7110, 6899, 7003, 7084, 7733, 7566, 7514, 7624, 7526, 7573, 5118, 5119, 5627, 6009, 7471, 7737, 7412, 7763, 3959, 4057, 4069, 4058, 4015, 3963, 4070, 3838, 6974, 7055, 7015, 6783, 7032, 6623, 7357, 7734, 7090, 6894, 7113, 6652, 7005, 6901, 7114, 7063, 6104, 5871, 6062, 6116, 7019, 7006, 6902, 7092, 7844, 7529, 7874, 7757, 7383, 7954, 7815, 7516, 6091, 6010, 5629, 6069, 7587, 7574, 7632, 7848, 3583, 4060, 4073, 4023, 4074, 3965, 4047, 3966, 6093, 6120, 6012, 6070, 7969, 7530, 7758, 7577, 7738, 7956, 7765, 7740, 7387, 7479, 7121, 7067, 7876, 7766, 7769, 7819, 7589, 7960, 7970, 7779, 7770, 7578, 7399, 7856, 5983, 5879, 6128, 5630, 7116, 6905, 7821, 7416, 7537, 7358, 7532, 7822, 7827, 7503, 7648, 7483, 7389, 7538, 7021, 7096, 6639, 6847, 7079, 7122, 6099, 6073, 5883, 6094, 7027, 6906, 6647, 7069, 7022, 6879, 7781, 7590, 7593, 7619, 7137, 7029, 7782, 7711, 7403, 7580, 7511, 7540, 7943, 7485, 6074, 5999, 6101, 6102, 7390, 7594, 7621, 7405, 7727, 8001, 7972, 7880, 8002, 7829, 7976, 7947, 7083, 7138, 7785, 7772, 6047, 6115, 5885, 6076, 7601, 7888, 7124, 7070, 7984, 8004, 7515, 8065, 6007, 6105, 6117, 6106, 7411, 7830, 7622, 7486, 7843, 7786, 6908, 7085, 4081, 4027, 4076, 4082, 4029, 4055, 4030, 4059, 8066, 7949, 7111, 7030, 6063, 6011, 6118, 5886, 7544, 7596, 6975, 7091, 7833, 7904, 7735, 8008, 6651, 7033, 7793, 7406, 7527, 7625, 7567, 7955, 7128, 6895, 7759, 7846, 7602, 7845, 7517, 7413, 7626, 7834, 7788, 7531, 5631, 6108, 6121, 6071, 7295, 7359, 7950, 7575, 7604, 7794, 7739, 7633, 7086, 7140, 7849, 7414, 7115, 7034, 7875, 7518, 4084, 4071, 4088, 3839, 4061, 4075, 4062, 4077, 7767, 7836, 7958, 7628, 7417, 7850, 6653, 7093, 7741, 7579, 7117, 7144, 6122, 6013, 6095, 6014, 7036, 7094, 7971, 7957, 7877, 7533, 7608, 7796, 7857, 7542, 7591, 7634, 7007, 6903, 7961, 7418, 7539, 7649, 7742, 7581, 7152, 6654, 7771, 7534, 7636, 7823, 8068, 7973, 7123, 7097, 7783, 7852, 7878, 7597, 7962, 7420, 6907, 7118, 7541, 7773, 8016, 7858, 7098, 7023, 6129, 6075, 6124, 6130, 4031, 4083, 4085, 3967, 4078, 4086, 4089, 4090, 7125, 7126, 7881, 7800, 7650, 7974, 7595, 8072, 7582, 7391, 7831, 7860, 6077, 6103, 6078, 6107, 7071, 7139, 8003, 7787, 7640, 7623, 7964, 7977, 7882, 7889, 6909, 7100, 8005, 7884, 8032, 7978, 7031, 7129, 7774, 8080, 7890, 7864, 7545, 7603, 7985, 7487, 7141, 7130, 7789, 7980, 7652, 7598, 8006, 7835, 7656, 7407, 7546, 7627, 7790, 7795, 7087, 7035, 7605, 7548, 7142, 6910, 7986, 7629, 7664, 7837, 7847, 7892, 6655, 7132, 8009, 7797, 6132, 6119, 6136, 5887, 7519, 7635, 7606, 7905, 7419, 7630, 7610, 7609, 7145, 7095, 7637, 7415, 7851, 8010, 7906, 8067, 7146, 7037, 7838, 7951, 6109, 6123, 6110, 6125, 7119, 7038, 8017, 7988, 7896, 8096, 7959, 7535, 8069, 7798, 7853, 8012, 7801, 7879, 7153, 7099, 7421, 7859, 7992, 8070, 7854, 7908, 8018, 7543, 7612, 7638, 7148, 7154, 7651, 7583, 7653, 8073, 7963, 7641, 7802, 7912, 8020, 8128, 7101, 7127, 8033, 7861, 7965, 8074, 7883, 7975, 7642, 7804, 7102, 7131, 7862, 7422, 7885, 7743, 7156, 7143, 8081, 7966, 7979, 7547, 4063, 4092, 4079, 4087, 4091, 4093, 4094, 4095, 6079, 6131, 6133, 6015, 7865, 7599, 7160, 6911, 7775, 7657, 8034, 7891, 7654, 8076, 7886, 7981, 7644, 8024, 8007, 7893, 7866, 8082, 7133, 7147, 7920, 8036, 7987, 7982, 7607, 8097, 7658, 7791, 6126, 6134, 6137, 6138, 7839, 7907, 8084, 7631, 8011, 7549, 7134, 7149, 7665, 8098, 7989, 7894, 8129, 8040, 7660, 7799, 7897, 7868, 7611, 7909, 8013, 8088, 7550, 7990, 8019, 7898, 7666, 8048, 7910, 7613, 7103, 7155, 6111, 6140, 6127, 6135, 7639, 7803, 8100, 7855, 8071, 7993, 7157, 7039, 7668, 8014, 7913, 7994, 7900, 7614, 8130, 8104, 7643, 8021, 8035, 7805, 8075, 7655, 7863, 7914, 7996, 7921, 8022, 8025, 7672, 7967, 7423, 8132, 8077, 7887, 7645, 8083, 7150, 7158, 7806, 7916, 8112, 8037, 7659, 7867, 7922, 8026, 7646, 8136, 7161, 7162, 7551, 8078, 7983, 8144, 8038, 8085, 7895, 7661, 8041, 7869, 8099, 7924, 8028, 7667, 7899, 7991, 8090, 8042, 8086, 7670, 8101, 7911, 7928, 8049, 7662, 7870, 8089, 7669, 8044, 8015, 6139, 6141, 6142, 6143, 7135, 7164, 8160, 7615, 7901, 7995, 8102, 8050, 8105, 8131, 7915, 7673, 8023, 8092, 7902, 7997, 7151, 7159, 8133, 8106, 8052, 7674, 7917, 8113, 8134, 7923, 8027, 8108, 7998, 8079, 8039, 7807, 8056, 7647, 7163, 7165, 8114, 7918, 8137, 7676, 8029, 7925, 8138, 8087, 8043, 8030, 7926, 8116, 8145, 8091, 8140, 7929, 8045, 8120, 7663, 7871, 8103, 8146, 8051, 7930, 7671, 8093, 8046, 7903, 8161, 8053, 8107, 8162, 8148, 8094, 7932, 8109, 8135, 8054, 7999, 8115, 7166, 7167, 7675, 8057, 8152, 7919, 8110, 8164, 8139, 8058, 7677, 8117, 8141, 8168, 8060, 8118, 8031, 7927, 8176, 7678, 8147, 8121, 7931, 8142, 8122, 8047, 8149, 8150, 8095, 8163, 7933, 8124, 8055, 8153, 8165, 8154, 8111, 8059, 8166, 7934, 7679, 8156, 8169, 8119, 8170, 8061, 8143, 8062, 8177, 8123, 8172, 8178, 8125, 8151, 8126, 8155, 8180, 8167, 8184, 7935, 8157, 8171, 8158, 8173, 8127, 8179, 8181, 8063, 8174, 8182, 8185, 8186, 8159, 8188, 8175, 8183, 8187, 8189, 8190, 8191]

### Sequence Group 2: Q2_8192

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 67, 41, 144, 28, 69, 42, 516, 49, 74, 272, 1024, 1025, 160, 520, 288, 528, 192, 544, 70, 44, 131, 81, 50, 73, 15, 320, 133, 52, 23, 134, 384, 76, 137, 82, 56, 27, 97, 39, 259, 84, 138, 145, 261, 29, 1026, 1028, 43, 98, 515, 88, 140, 30, 146, 71, 262, 265, 161, 576, 45, 100, 640, 51, 148, 46, 75, 266, 273, 517, 104, 162, 1032, 1040, 53, 193, 2048, 2049, 2050, 2052, 152, 77, 164, 768, 268, 274, 518, 54, 83, 57, 521, 112, 135, 78, 289, 194, 85, 276, 522, 58, 1056, 1027, 168, 139, 99, 86, 60, 280, 89, 290, 529, 524, 196, 141, 101, 147, 1029, 1088, 176, 142, 530, 321, 31, 200, 90, 545, 292, 322, 532, 263, 149, 102, 105, 304, 296, 163, 92, 47, 267, 385, 1033, 1030, 546, 324, 2056, 2064, 2080, 2051, 208, 386, 150, 153, 165, 106, 55, 328, 536, 577, 548, 113, 154, 79, 1041, 1034, 269, 108, 578, 224, 166, 519, 552, 195, 270, 641, 523, 275, 580, 291, 1042, 1152, 59, 169, 560, 114, 277, 156, 87, 197, 116, 170, 61, 531, 525, 642, 1036, 1057, 2053, 2112, 2057, 2054, 281, 278, 526, 177, 4096, 4097, 4098, 4100, 4104, 4112, 4128, 4099, 293, 388, 91, 584, 1089, 1044, 769, 198, 172, 120, 201, 336, 62, 282, 1280, 1058, 143, 103, 178, 294, 93, 644, 202, 592, 323, 392, 1048, 1060, 297, 770, 107, 180, 151, 209, 284, 648, 1031, 1153, 94, 204, 2065, 2058, 2066, 2176, 298, 400, 608, 352, 325, 533, 155, 210, 305, 547, 300, 109, 1090, 1536, 184, 534, 537, 115, 167, 225, 326, 306, 1035, 1064, 772, 157, 656, 329, 2060, 2081, 2113, 2068, 110, 117, 212, 171, 1092, 1154, 776, 330, 226, 549, 538, 387, 308, 216, 1043, 1037, 416, 271, 279, 158, 1072, 1038, 337, 550, 672, 118, 332, 579, 540, 389, 173, 121, 553, 199, 784, 179, 228, 338, 312, 704, 1096, 1281, 390, 174, 2304, 2082, 2072, 2084, 554, 581, 1045, 1156, 4101, 4160, 4105, 4102, 4113, 4106, 4114, 4224, 393, 283, 122, 448, 353, 561, 1059, 1282, 203, 63, 340, 394, 527, 582, 556, 181, 295, 285, 232, 124, 205, 182, 643, 562, 286, 585, 1050, 1537, 2055, 2177, 2114, 2560, 299, 354, 1104, 1061, 211, 401, 185, 396, 1049, 1046, 344, 586, 645, 593, 535, 240, 206, 95, 327, 564, 800, 402, 1160, 1284, 356, 307, 301, 417, 2059, 2088, 2116, 2178, 1288, 1062, 213, 568, 832, 588, 186, 646, 404, 227, 896, 594, 418, 302, 1538, 1120, 649, 771, 360, 539, 1091, 1065, 1168, 1052, 111, 331, 214, 309, 2067, 2061, 2096, 2062, 4108, 4129, 4161, 4116, 4352, 4130, 4120, 4132, 188, 449, 217, 408, 609, 596, 551, 650, 1093, 1066, 229, 159, 420, 310, 1540, 1073, 2120, 2305, 2069, 2180, 541, 773, 1098, 1296, 610, 657, 333, 119, 600, 339, 218, 368, 652, 230, 391, 313, 2083, 2306, 2074, 2561, 450, 542, 1184, 1544, 334, 233, 555, 774, 175, 123, 658, 612, 1312, 1552, 341, 777, 220, 314, 1216, 1568, 2128, 2085, 2073, 2070, 424, 395, 673, 583, 1094, 1068, 355, 287, 183, 234, 1155, 1105, 125, 557, 660, 616, 2184, 2308, 2312, 2086, 1074, 1097, 1039, 1344, 4103, 4225, 4162, 4608, 4107, 4136, 4164, 4226, 342, 316, 241, 778, 563, 345, 452, 397, 1157, 1076, 1047, 1158, 403, 207, 674, 558, 785, 432, 357, 187, 236, 664, 624, 587, 2562, 2144, 2115, 2089, 1408, 1100, 780, 705, 126, 242, 565, 398, 1161, 1106, 346, 456, 358, 405, 1080, 1051, 2192, 2076, 2117, 2090, 1121, 1063, 303, 569, 244, 595, 189, 566, 4115, 4109, 4144, 4110, 4168, 4353, 4117, 4228, 676, 361, 706, 589, 215, 786, 647, 348, 2564, 2097, 2122, 2320, 419, 406, 464, 680, 801, 362, 1283, 1108, 590, 409, 1162, 1169, 1285, 1053, 570, 788, 3072, 3073, 2208, 2568, 597, 572, 219, 311, 1067, 1122, 1539, 1112, 2336, 2576, 2240, 2592, 708, 598, 601, 651, 421, 792, 802, 611, 1164, 1054, 602, 410, 1170, 1095, 231, 688, 653, 248, 369, 190, 364, 654, 659, 335, 1286, 1289, 480, 315, 221, 370, 1185, 1600, 1069, 1124, 613, 422, 2118, 2092, 2179, 2129, 425, 451, 1664, 1075, 4131, 4354, 4122, 4609, 4176, 4133, 4121, 4118, 614, 543, 235, 412, 2098, 2121, 2063, 2368, 343, 372, 1172, 1070, 775, 317, 222, 426, 1099, 1290, 453, 237, 2181, 2100, 2071, 2182, 559, 833, 804, 712, 1297, 1541, 1128, 1186, 834, 661, 808, 779, 1077, 1217, 617, 604, 1176, 1101, 433, 720, 816, 836, 347, 897, 1188, 1792, 1292, 1298, 243, 662, 454, 318, 675, 618, 1542, 1078, 2432, 2124, 2185, 2130, 4232, 4356, 4360, 4134, 4610, 4192, 4163, 4137, 898, 781, 376, 428, 2104, 2075, 2145, 2087, 1107, 1081, 665, 736, 567, 840, 625, 238, 2307, 2132, 2186, 2193, 1545, 1136, 1159, 1102, 359, 457, 1313, 1218, 399, 787, 591, 678, 1109, 1300, 434, 677, 349, 245, 458, 666, 620, 363, 127, 191, 2309, 2077, 3074, 3076, 782, 407, 1546, 1082, 1192, 1163, 436, 626, 4240, 4124, 4165, 4138, 4612, 4145, 4170, 4368, 2091, 2146, 2563, 2136, 571, 465, 1123, 1110, 681, 246, 707, 350, 1084, 1304, 599, 668, 790, 460, 1113, 1314, 249, 682, 573, 411, 803, 789, 709, 365, 2188, 2078, 2194, 2119, 1553, 1548, 1220, 1165, 440, 628, 689, 374, 2310, 2313, 2209, 2624, 2093, 2148, 2688, 2099, 423, 466, 793, 250, 1125, 1171, 1200, 1166, 5120, 5121, 4256, 4616, 4384, 4624, 4288, 4640, 1554, 1345, 1055, 1224, 371, 481, 574, 413, 1114, 1569, 1316, 1346, 603, 366, 468, 655, 2196, 2094, 2123, 2314, 900, 805, 615, 684, 1556, 1287, 710, 429, 2321, 2565, 2152, 2210, 4166, 4140, 4227, 4177, 4146, 4169, 4111, 4416, 1173, 1126, 794, 252, 3080, 3088, 2101, 2241, 1129, 1328, 373, 605, 848, 690, 713, 632, 1320, 1187, 482, 806, 1116, 1071, 427, 904, 1291, 1409, 414, 223, 663, 692, 1570, 1348, 4229, 4148, 4119, 4230, 4480, 4172, 4233, 4178, 835, 619, 1232, 1410, 2200, 2125, 2212, 2816, 472, 455, 796, 809, 1174, 1177, 1189, 1130, 714, 721, 837, 716, 864, 810, 606, 912, 2316, 2322, 2566, 2102, 1079, 1352, 722, 696, 377, 435, 817, 319, 2131, 2105, 2569, 2160, 4152, 4123, 4193, 4135, 4355, 4180, 4234, 4241, 1560, 1601, 621, 812, 1572, 1137, 484, 430, 2183, 2126, 2337, 2242, 1178, 1103, 1293, 1132, 838, 667, 488, 239, 2133, 2324, 2570, 2106, 378, 459, 1602, 1248, 1190, 1543, 1576, 1219, 4357, 4125, 5122, 5124, 4139, 4194, 4611, 4184, 3104, 3075, 2216, 2187, 2147, 2134, 2108, 2328, 622, 627, 437, 380, 1294, 1665, 1547, 1299, 818, 461, 496, 669, 679, 724, 841, 629, 2137, 2338, 2577, 2572, 2244, 2189, 2149, 2195, 351, 467, 1604, 1315, 1083, 1193, 438, 737, 1584, 1138, 251, 462, 442, 441, 469, 247, 1301, 1180, 683, 842, 1111, 1221, 1140, 1194, 4236, 4126, 4242, 4167, 4358, 4361, 4257, 4672, 3077, 3136, 2224, 2190, 738, 899, 670, 783, 1085, 1555, 1549, 1666, 849, 820, 1305, 1302, 2578, 2369, 2079, 2248, 728, 928, 1550, 1201, 791, 367, 901, 630, 2138, 2593, 2340, 2370, 4141, 4196, 4736, 4147, 4244, 4142, 4171, 4362, 2580, 2311, 2197, 2150, 1317, 1412, 685, 844, 633, 711, 1115, 1608, 1793, 1222, 1196, 1144, 1225, 1360, 253, 691, 1086, 1306, 824, 902, 686, 740, 850, 375, 444, 470, 483, 415, 4369, 4613, 4200, 4258, 5128, 5136, 4149, 4289, 1167, 1127, 1202, 1318, 1117, 1668, 1226, 1616, 485, 905, 1347, 1416, 2153, 2352, 2344, 2211, 795, 473, 1321, 1794, 2140, 2095, 2315, 2433, 3081, 3078, 2594, 2372, 634, 744, 852, 960, 6144, 6145, 6146, 6148, 4248, 4173, 4260, 4864, 1131, 1204, 865, 693, 1175, 1233, 797, 906, 2256, 2434, 2198, 2201, 2213, 2154, 2103, 2376, 4364, 4370, 4614, 4150, 4179, 4153, 4617, 4208, 1308, 1672, 715, 807, 1118, 1228, 474, 636, 1322, 1424, 1632, 1376, 694, 254, 717, 575, 2584, 2625, 2596, 2161, 913, 798, 1349, 1557, 2202, 2127, 3089, 3082, 1179, 1234, 1329, 1571, 1324, 1133, 811, 379, 1208, 1558, 697, 431, 607, 489, 1561, 1139, 866, 723, 486, 908, 2317, 2156, 2626, 2272, 718, 813, 476, 856, 1191, 1249, 1350, 1330, 2214, 2567, 2600, 2243, 2318, 2689, 2571, 2323, 839, 725, 1796, 1181, 4231, 4174, 4385, 4290, 4181, 4372, 4618, 4154, 1680, 1353, 698, 914, 2628, 2339, 3090, 3200, 752, 868, 1134, 1141, 819, 814, 1236, 1195, 5152, 5123, 4264, 4235, 4195, 4182, 4156, 4376, 1800, 1354, 1250, 1573, 2107, 2217, 2608, 2162, 1562, 1411, 1332, 1240, 439, 929, 490, 623, 2325, 2204, 2135, 2245, 671, 739, 916, 463, 4185, 4386, 4625, 4620, 4292, 4237, 4197, 4243, 843, 381, 1440, 1295, 1303, 1182, 1361, 1574, 2164, 2218, 2109, 2579, 2573, 2690, 3084, 3105, 497, 930, 1696, 1142, 821, 726, 961, 872, 2329, 2326, 2574, 2225, 1356, 1603, 492, 631, 2341, 2436, 2139, 2632, 1564, 1413, 1197, 1145, 729, 700, 443, 741, 1577, 1223, 1808, 1203, 3137, 3092, 2817, 2246, 2220, 2168, 2249, 2384, 1252, 1362, 845, 920, 1336, 1728, 382, 822, 1414, 1198, 851, 730, 2110, 2330, 3328, 3106, 5125, 5184, 4272, 4238, 4626, 4417, 4127, 4296, 1578, 1605, 1417, 1307, 498, 880, 1146, 1472, 4186, 4641, 4388, 4418, 4628, 4359, 4245, 4198, 2191, 2151, 2226, 2342, 742, 445, 471, 635, 932, 687, 1377, 1585, 903, 825, 1227, 1087, 4201, 4400, 4392, 4259, 4188, 4143, 4363, 4481, 2141, 2692, 2250, 2640, 2371, 2440, 3096, 3108, 1364, 1418, 500, 846, 2345, 2818, 2155, 2228, 745, 826, 1551, 1606, 1580, 1205, 1319, 1309, 2199, 2257, 2332, 2696, 732, 446, 1256, 1148, 1229, 1206, 1667, 1586, 962, 936, 475, 853, 867, 637, 1310, 1609, 1323, 1378, 1235, 1425, 5129, 5126, 4642, 4420, 6152, 6160, 6176, 6147, 907, 487, 695, 746, 3079, 3201, 2142, 2252, 2346, 2448, 2656, 2400, 828, 753, 1209, 1420, 4304, 4482, 4246, 4249, 4261, 4202, 4151, 4424, 1368, 1610, 854, 857, 2373, 2581, 2203, 2258, 1669, 1617, 1559, 1264, 1230, 1119, 504, 799, 2353, 2595, 2348, 2157, 255, 964, 1351, 1588, 1824, 1426, 1380, 1331, 3138, 3584, 2232, 2582, 909, 719, 477, 915, 1325, 1441, 638, 748, 944, 869, 1237, 1592, 491, 699, 1856, 1612, 4632, 4673, 4644, 4209, 4250, 4175, 5137, 5130, 2585, 2163, 2215, 2273, 2374, 2354, 3083, 3112, 754, 858, 1210, 1670, 1428, 1251, 478, 968, 4365, 4204, 4674, 4320, 4262, 4615, 4648, 4291, 4366, 4737, 4619, 4371, 4676, 4387, 5138, 5248, 1920, 1618, 1442, 1326, 1673, 1795, 383, 910, 2820, 2205, 2704, 2377, 2158, 2165, 2260, 2219, 3140, 3202, 2824, 2378, 2274, 2597, 2586, 2435, 1384, 1563, 1135, 1355, 815, 976, 870, 917, 2356, 2264, 3091, 3085, 2464, 2319, 2327, 2206, 727, 493, 1238, 1333, 873, 701, 1212, 1473, 4155, 4265, 4656, 4210, 4373, 4252, 4183, 4293, 1241, 1432, 931, 756, 1633, 1620, 1575, 1674, 3120, 3086, 2385, 2598, 860, 499, 1253, 1183, 4212, 4266, 4157, 4627, 4621, 4738, 5132, 5153, 2720, 2166, 2380, 2627, 1444, 1334, 1565, 1797, 6149, 6208, 6153, 6150, 4377, 4374, 4622, 4273, 2588, 2437, 2221, 2169, 731, 823, 922, 874, 1634, 1681, 918, 502, 1357, 1143, 1624, 1363, 2601, 2247, 2832, 2227, 933, 743, 1242, 1392, 2276, 2386, 2360, 2752, 760, 881, 1676, 1254, 3144, 3329, 2438, 2222, 1415, 1337, 1474, 1566, 1358, 1257, 494, 702, 2602, 2629, 3093, 3204, 1579, 1798, 921, 501, 2441, 2331, 2170, 2496, 4389, 4484, 4187, 4680, 5185, 5140, 4865, 4294, 1199, 1147, 1682, 1636, 1365, 1801, 876, 847, 2401, 2609, 3107, 3330, 2251, 2111, 2388, 2442, 992, 447, 1244, 1338, 733, 827, 1448, 1419, 934, 882, 1697, 1607, 937, 963, 1379, 1311, 4268, 4216, 4297, 4432, 4158, 4378, 5376, 5154, 2575, 2630, 2604, 2229, 1207, 1258, 1149, 1581, 747, 505, 855, 924, 1684, 1640, 1366, 1340, 4239, 4199, 4274, 4390, 4189, 4740, 4298, 4688, 2343, 2333, 2280, 2172, 1265, 1802, 734, 829, 2253, 2230, 2691, 2610, 1587, 1369, 1476, 1421, 4419, 4488, 5144, 5156, 4393, 4866, 4203, 4276, 2334, 2633, 3098, 3585, 2347, 2402, 3152, 3109, 965, 938, 1427, 1231, 1698, 1582, 1809, 1456, 4247, 4305, 4380, 4744, 5127, 5249, 4190, 4300, 884, 506, 1381, 1211, 2259, 2449, 2233, 2444, 3097, 3094, 2392, 2634, 2693, 2641, 2583, 2288, 6161, 6154, 6162, 6272, 4394, 4496, 4704, 4448, 4421, 4629, 4251, 4306, 4401, 4643, 4396, 4205, 749, 945, 1260, 1688, 1648, 1611, 966, 755, 2254, 2143, 2375, 2612, 2848, 2450, 3208, 3332, 859, 940, 1804, 1729, 1150, 1266, 1589, 1422, 1370, 1480, 830, 911, 871, 639, 1382, 1429, 5186, 5632, 4280, 4630, 4633, 4211, 4263, 4321, 4422, 4402, 5131, 5160, 4868, 4253, 4752, 4425, 1327, 1593, 1268, 1619, 2404, 2355, 2349, 2465, 3336, 3110, 2261, 2616, 888, 479, 1213, 1590, 2880, 2636, 2234, 2694, 1700, 1385, 1730, 1613, 946, 750, 1239, 1810, 1671, 1372, 1443, 1430, 2452, 2275, 2944, 2642, 1488, 1704, 969, 508, 2466, 2350, 3586, 3168, 2697, 2819, 2408, 2587, 6156, 6177, 6209, 6164, 4206, 4213, 4308, 4267, 861, 757, 1825, 1386, 970, 919, 1614, 1433, 3139, 3113, 3216, 3100, 2159, 2379, 2262, 2357, 875, 862, 1594, 1812, 2236, 2497, 2265, 2456, 5188, 5250, 4872, 4426, 4322, 4645, 4634, 4483, 1621, 1596, 758, 948, 2657, 2644, 2599, 2698, 1243, 1335, 1732, 1622, 1625, 1675, 1445, 1816, 4404, 4312, 5139, 5133, 4512, 4367, 4375, 4254, 5168, 5134, 4433, 4646, 4768, 4214, 4428, 4675, 3141, 3114, 2277, 2207, 977, 923, 1826, 1635, 972, 761, 1626, 1434, 2468, 2358, 3588, 3121, 2589, 2821, 3146, 3344, 2658, 2705, 2381, 2167, 2648, 2387, 2266, 2416, 1255, 1712, 877, 952, 2700, 2278, 2439, 2361, 1677, 1272, 495, 703, 1393, 1214, 1388, 1678, 935, 978, 1683, 1359, 1504, 1339, 1245, 1394, 1637, 1446, 1449, 1475, 2498, 2590, 3232, 3592, 2382, 2281, 2603, 2822, 2223, 2171, 2706, 2660, 3360, 3600, 2389, 2825, 1638, 1567, 1259, 1436, 2268, 2362, 3264, 3616, 4636, 4485, 4269, 4217, 4649, 4295, 4880, 4275, 883, 762, 1367, 1396, 2472, 2443, 2721, 2631, 4324, 4434, 4408, 4800, 5192, 5377, 4486, 4270, 6400, 6178, 6168, 6180, 4650, 4677, 5141, 5252, 503, 925, 1799, 1341, 1246, 1450, 878, 735, 3142, 3116, 2403, 2335, 1477, 1261, 993, 885, 2231, 2282, 3203, 3153, 1583, 1857, 1828, 1736, 4489, 4379, 4218, 4544, 4449, 4657, 5155, 5378, 4299, 4159, 4436, 4490, 4623, 4678, 4652, 4277, 2173, 2605, 2708, 2664, 939, 994, 1858, 1685, 3122, 3145, 3087, 3392, 1832, 1803, 1641, 1628, 2390, 2364, 2289, 2826, 2611, 2393, 2500, 2445, 1457, 1744, 1840, 1860, 980, 926, 764, 941, 4391, 4381, 4328, 4220, 4301, 4278, 4739, 4658, 1371, 1921, 1267, 1686, 3205, 3124, 3095, 3206, 4382, 4681, 5146, 5633, 6151, 6273, 6210, 6656, 2451, 2255, 2722, 2606, 2833, 2480, 2405, 2235, 2284, 2712, 2672, 2635, 1478, 1342, 967, 886, 3456, 3148, 2828, 2753, 1699, 1642, 831, 947, 1922, 1805, 1400, 1452, 2174, 2290, 2613, 2446, 1689, 1760, 507, 889, 1591, 1864, 1649, 1262, 4395, 4450, 5200, 5157, 4307, 4497, 4281, 4492, 984, 751, 1383, 1481, 942, 996, 1423, 1811, 3209, 3154, 2394, 2504, 2406, 2453, 3128, 3099, 5145, 5142, 4440, 4682, 4741, 4689, 4631, 4336, 4302, 4191, 4423, 4660, 4896, 4498, 5256, 5380, 1615, 1702, 1458, 1701, 3169, 3111, 2351, 2617, 2292, 2643, 2237, 2614, 1373, 1269, 1482, 1690, 4452, 4403, 4397, 4513, 6155, 6184, 6212, 6274, 1644, 1387, 971, 890, 2724, 2409, 2754, 2637, 1151, 1215, 1806, 1431, 2263, 2834, 2695, 2396, 2467, 2454, 2512, 2728, 2849, 2410, 3331, 3156, 5384, 5158, 4309, 4664, 4928, 4684, 4282, 4742, 2638, 2457, 3210, 3217, 3333, 3101, 2618, 2836, 1460, 1650, 509, 949, 973, 1000, 1595, 1489, 4500, 4323, 4992, 4690, 4514, 4398, 5634, 5216, 1705, 1270, 1731, 1374, 892, 950, 1623, 1692, 1814, 1484, 1273, 1706, 2645, 2620, 2267, 2359, 3115, 3170, 3587, 3160, 2756, 2646, 2649, 2699, 4745, 4867, 4456, 4635, 5187, 5161, 5264, 5148, 4207, 4427, 4310, 4405, 6163, 6157, 6192, 6158, 863, 759, 1008, 510, 2469, 2840, 2850, 2659, 1597, 1435, 1827, 1813, 1733, 1389, 1464, 1652, 4284, 4545, 4313, 4504, 4705, 4692, 4647, 4746, 3212, 3102, 2650, 2458, 1713, 1398, 1447, 1490, 5189, 5162, 4325, 4255, 4516, 4406, 5636, 5169, 3218, 3143, 2279, 2736, 2701, 2296, 2417, 2238, 979, 953, 1817, 1274, 1395, 1505, 1598, 1437, 2412, 2702, 2707, 2383, 3334, 3337, 2528, 2363, 6216, 6401, 6165, 6276, 4637, 4869, 5194, 5392, 4706, 4753, 4429, 4215, 4696, 4435, 4314, 4464, 2269, 2418, 3233, 3648, 763, 974, 1627, 1390, 3117, 3172, 2661, 2470, 1492, 1679, 954, 879, 2473, 2499, 3712, 3123, 1924, 1829, 981, 982, 4748, 4326, 4487, 4409, 6179, 6402, 6170, 6657, 2662, 2591, 2283, 2460, 2391, 2420, 3220, 3118, 1639, 1708, 1734, 1453, 2823, 2365, 2270, 2474, 4546, 4638, 5280, 5640, 4430, 4329, 4651, 4870, 1818, 1276, 927, 995, 1397, 1629, 1872, 1714, 1737, 1656, 1506, 1830, 3147, 3338, 2501, 2285, 1451, 1928, 1438, 1247, 2607, 2881, 2852, 2760, 4271, 4219, 4754, 4708, 5408, 5648, 4437, 4873, 4316, 4410, 5312, 5664, 6224, 6181, 6169, 6166, 3345, 3589, 3176, 3234, 1687, 1716, 1859, 1643, 4520, 4491, 4769, 4679, 5190, 5164, 4451, 4383, 1496, 1479, 1820, 1833, 2882, 2709, 2856, 2827, 3125, 3265, 2665, 2652, 3224, 3149, 2481, 2768, 4279, 4330, 5251, 5201, 4221, 4653, 4756, 4712, 765, 956, 1738, 1745, 2864, 2884, 2395, 2945, 3236, 3840, 3340, 3346, 2291, 2710, 2502, 2366, 1861, 1740, 1888, 1834, 887, 985, 1630, 1936, 1746, 1720, 1401, 1459, 2723, 2666, 3590, 3126, 2946, 2829, 2424, 2476, 3155, 3129, 2713, 2784, 997, 986, 1841, 1343, 1645, 1836, 1508, 1454, 6280, 6404, 6408, 6182, 5170, 5193, 5135, 5440, 4438, 4412, 4337, 4874, 4659, 4441, 4548, 4493, 1862, 1691, 943, 891, 2615, 2888, 2673, 2286, 3593, 3184, 3207, 3150, 1512, 1263, 1402, 1483, 5253, 5172, 5143, 5254, 4499, 4303, 4770, 4654, 2407, 2505, 3361, 3266, 2447, 2835, 2639, 2726, 3157, 3348, 2482, 2725, 1646, 1651, 1461, 1404, 4881, 4528, 4453, 4283, 4332, 4760, 4720, 4683, 1842, 1485, 998, 766, 2397, 2293, 2506, 2714, 2668, 2411, 2175, 2239, 2830, 2455, 3594, 3130, 6658, 6240, 6211, 6185, 5504, 5196, 4876, 4801, 1520, 1693, 511, 988, 1703, 1748, 1865, 1653, 3240, 3211, 2484, 2674, 1375, 1491, 1462, 1761, 1275, 1486, 1466, 1465, 2619, 2513, 3171, 3158, 1001, 951, 1493, 1271, 2729, 2294, 2755, 2398, 4222, 4338, 4661, 4494, 5257, 5202, 4442, 4552, 4454, 4501, 5176, 5147, 6288, 6172, 6213, 6186, 1707, 1866, 1762, 1923, 3132, 3352, 2647, 2716, 2838, 2508, 3161, 3362, 1694, 1807, 1873, 1844, 2297, 2730, 2621, 2459, 2851, 2837, 2757, 2413, 3601, 3596, 3268, 3213, 1752, 1952, 1815, 1391, 5217, 5159, 4399, 4665, 4340, 4691, 4285, 4662, 4772, 4457, 4802, 4685, 4311, 4882, 4743, 4444, 6660, 6193, 6218, 6416, 4515, 4502, 4560, 4776, 4897, 4458, 5379, 5204, 4686, 4505, 5258, 5265, 2488, 2676, 2737, 2422, 2471, 2514, 2841, 2298, 1002, 893, 1925, 1654, 1709, 1868, 1657, 1735, 5381, 5149, 4666, 4884, 7168, 7169, 6304, 6664, 4693, 4668, 4315, 4407, 5163, 5218, 5635, 5208, 1277, 1715, 975, 894, 3173, 3219, 3248, 3214, 1848, 1926, 1710, 1764, 3602, 3393, 3103, 3272, 2419, 2529, 2622, 2461, 1874, 1399, 1468, 1494, 3162, 3617, 3364, 3394, 2651, 2414, 2516, 2703, 6432, 6672, 6336, 6688, 4804, 4694, 4697, 4747, 1507, 1439, 1509, 1929, 2948, 2853, 2663, 2732, 4517, 4888, 4898, 4707, 5260, 5150, 4698, 4506, 3604, 3335, 2758, 2477, 3221, 3174, 2842, 2300, 5266, 5191, 4327, 4784, 4749, 4344, 4465, 4286, 1009, 955, 1819, 1497, 1658, 1768, 1876, 1984, 3177, 3376, 2421, 2653, 1889, 1717, 1821, 1930, 2896, 2738, 2761, 2680, 3368, 3235, 2530, 2854, 4460, 4750, 4755, 4431, 5382, 5385, 4576, 4411, 1739, 1831, 1004, 1010, 3164, 3119, 2475, 2952, 4317, 4466, 5281, 5696, 5165, 5220, 4709, 4518, 1498, 1660, 957, 983, 3339, 3457, 2462, 2271, 6214, 6188, 6275, 6225, 4521, 4547, 5760, 5171, 2711, 2740, 3618, 3396, 2883, 2667, 3280, 3458, 2520, 2503, 2844, 2857, 1718, 1278, 1741, 1599, 4710, 4639, 4331, 4508, 6194, 6217, 6159, 6464, 3222, 3225, 3237, 3178, 1937, 1822, 958, 987, 4439, 4468, 5268, 5166, 4871, 4413, 4318, 4522, 2762, 2769, 2885, 2764, 2912, 2858, 2654, 2960, 3127, 3400, 2770, 2744, 1835, 1403, 1721, 1455, 5195, 5386, 4549, 4333, 6277, 6196, 6167, 6278, 4655, 4929, 4900, 4808, 5393, 5637, 5224, 5282, 1631, 1513, 1890, 1747, 2425, 2483, 2865, 2367, 1012, 999, 1510, 1932, 3608, 3649, 2669, 2860, 1742, 1837, 1500, 1880, 3620, 3185, 2532, 2478, 1863, 1749, 1016, 767, 3226, 3151, 3341, 3180, 4930, 4757, 4904, 4875, 5173, 5313, 4713, 4700, 2886, 2715, 2536, 2287, 2426, 2507, 3650, 3296, 1722, 1938, 1776, 1892, 1843, 1838, 1463, 1953, 3238, 3591, 3624, 3267, 2670, 2675, 2485, 2428, 5272, 5197, 4529, 4816, 4912, 4932, 4443, 4993, 3342, 3713, 3595, 3347, 1514, 1647, 1695, 1763, 5284, 5888, 5388, 5394, 4339, 4758, 4550, 4414, 2866, 2509, 2544, 2717, 2727, 2772, 2889, 2677, 4771, 4714, 5638, 5174, 6528, 6220, 6281, 6226, 4994, 4877, 4472, 4524, 6200, 6171, 6241, 6183, 1940, 1487, 1867, 1405, 2399, 2515, 3652, 3363, 3131, 3241, 2486, 2785, 3632, 3186, 2299, 2510, 989, 1003, 1521, 1954, 2490, 2489, 2517, 2295, 5203, 5177, 4761, 4832, 4663, 4936, 4721, 4334, 6403, 6228, 6282, 6289, 5641, 5232, 5255, 5198, 4455, 4553, 5409, 5314, 4495, 4883, 4687, 4774, 1845, 1750, 1985, 1896, 3349, 3228, 2731, 2890, 3159, 3269, 3188, 3242, 1516, 1655, 1753, 1724, 5205, 5396, 4530, 4773, 4445, 4341, 4554, 4762, 4716, 4459, 4223, 4287, 6405, 6173, 7170, 7172, 1467, 1765, 990, 1005, 2786, 2947, 2718, 2831, 3133, 3603, 3597, 3714, 2897, 2868, 3353, 3350, 2776, 2976, 3598, 3249, 1869, 1944, 1406, 1846, 1875, 1754, 1522, 1904, 2839, 2415, 2949, 2678, 3365, 3460, 2733, 2892, 2681, 2759, 3163, 3656, 4878, 4503, 5642, 5178, 5288, 5259, 4532, 4722, 6187, 6242, 6659, 6232, 4667, 4561, 5219, 5206, 1766, 1469, 1495, 1659, 3841, 3270, 3244, 3192, 4777, 4342, 4803, 4446, 5180, 5400, 4695, 4764, 3273, 3408, 2301, 2739, 3134, 3354, 2872, 2950, 959, 1011, 1956, 1711, 2734, 2788, 2898, 2423, 2492, 2518, 2531, 2463, 3215, 3175, 3250, 3366, 4886, 4556, 5209, 5410, 4345, 4778, 4669, 4507, 3165, 3716, 3274, 3664, 1927, 1849, 1524, 1870, 4899, 4885, 4805, 4461, 6284, 6174, 6290, 6215, 5649, 5644, 5316, 5261, 4536, 4724, 4785, 4470, 1769, 1850, 1756, 1470, 2533, 2953, 3395, 3464, 1986, 1960, 1499, 1877, 2843, 2521, 3369, 3842, 6406, 6409, 6305, 6720, 6189, 6244, 6784, 6195, 4519, 4562, 4889, 4346, 5221, 5267, 5296, 5262, 1891, 1661, 1931, 1511, 2682, 2792, 2900, 3008, 5650, 5441, 5151, 5320, 4467, 4577, 4670, 4509, 3179, 3252, 2913, 2741, 1013, 895, 1719, 1770, 5210, 5665, 5412, 5442, 4699, 4462, 4564, 4751, 3223, 3281, 2845, 2954, 3356, 3720, 2763, 2855, 3166, 3276, 2522, 2684, 3370, 3472, 3680, 3424, 6292, 6190, 6219, 6410, 4996, 4901, 4711, 4780, 1852, 1777, 1878, 1881, 2742, 2302, 2765, 2623, 1528, 1823, 1279, 1988, 2961, 2846, 3397, 3605, 5652, 5383, 4806, 4525, 6417, 6661, 6248, 6306, 5269, 5222, 4890, 4348, 7176, 7184, 6197, 6337, 5225, 5424, 4469, 4701, 4944, 4786, 4809, 4728, 5416, 5283, 4578, 4902, 5212, 5167, 4523, 5000, 3227, 3282, 3377, 3619, 1933, 1743, 1501, 1939, 5387, 5505, 4510, 4319, 4759, 4788, 5666, 5444, 3372, 3181, 2859, 2427, 1662, 1772, 1006, 1014, 3256, 3606, 2745, 2479, 2655, 2537, 3609, 3187, 1968, 1893, 1515, 1723, 2914, 2771, 2534, 2956, 2766, 2861, 2524, 2904, 3239, 3297, 3398, 3378, 2887, 2773, 3844, 3229, 3728, 3401, 2746, 2962, 4931, 4715, 5328, 5506, 6296, 6221, 6308, 6912, 4568, 4551, 4892, 4905, 5270, 5273, 5285, 5226, 4810, 4817, 4933, 4812, 4960, 4906, 4702, 5008, 6412, 6418, 6662, 6198, 5175, 5448, 4818, 4792, 2800, 2916, 3182, 3189, 2867, 2862, 3284, 3243, 4473, 4531, 4913, 4415, 6227, 6201, 6665, 6256, 1778, 1882, 1502, 1992, 3848, 3402, 3298, 3621, 5656, 5697, 4717, 4908, 5668, 5233, 4580, 4526, 1407, 1934, 1839, 2000, 3610, 3459, 3380, 3288, 2487, 2977, 2538, 2671, 1894, 1941, 1017, 1018, 6279, 6222, 6433, 6338, 5274, 5199, 5389, 5228, 2719, 2787, 2964, 2511, 1751, 1517, 1897, 1725, 4934, 4763, 4584, 4335, 6229, 6420, 6666, 6202, 2891, 2429, 3488, 3343, 3351, 3230, 3409, 3622, 4474, 4555, 5698, 5344, 5286, 5639, 5672, 5315, 1955, 1780, 1884, 1523, 2545, 2978, 3744, 3190, 7200, 7171, 6312, 6283, 6243, 6230, 6204, 6424, 2869, 2774, 3009, 2920, 3404, 3651, 2540, 2679, 4718, 4723, 4533, 4476, 5390, 5761, 5643, 5395, 4914, 4557, 4592, 4765, 4775, 4820, 4937, 4725, 3612, 3461, 3245, 3193, 2777, 2748, 2491, 2789, 1755, 1847, 1946, 1898, 1942, 1526, 1957, 1767, 3625, 3271, 3856, 3251, 3300, 3410, 2893, 2968, 6233, 6434, 6673, 6668, 6340, 6285, 6245, 6291, 4447, 4563, 5700, 5411, 5179, 5289, 4534, 4833, 5680, 5234, 4347, 4558, 4538, 4537, 4565, 4343, 5397, 5276, 4779, 4938, 5207, 5317, 5236, 5290, 3384, 3776, 2430, 2870, 991, 1020, 1784, 1905, 7173, 7232, 6320, 6286, 4834, 4995, 4766, 4879, 3462, 3246, 2899, 2778, 1518, 1726, 1945, 1525, 3626, 3653, 3465, 3355, 2546, 2928, 3194, 3520, 5181, 5651, 5645, 5762, 4945, 4916, 5401, 5398, 2790, 2493, 2519, 2683, 1900, 1871, 2016, 1471, 2980, 2735, 3425, 3633, 2951, 2873, 3275, 3135, 1757, 1851, 1958, 1906, 3412, 3466, 2548, 2894, 1961, 1987, 1771, 1529, 2793, 2874, 3599, 3654, 6674, 6465, 6175, 6344, 4824, 5024, 5646, 5297, 4887, 4463, 4997, 4726, 6234, 6689, 6436, 6466, 3628, 3253, 3367, 3357, 2780, 2494, 3304, 3196, 6676, 6407, 6293, 6246, 5413, 5508, 4781, 4940, 4729, 4807, 5211, 5704, 5889, 5318, 5292, 5240, 3277, 3254, 3715, 3634, 3010, 2984, 2523, 2901, 2915, 2685, 3358, 3657, 1879, 1948, 1758, 1853, 5321, 5456, 4349, 4787, 5182, 5402, 4920, 4998, 3371, 3426, 3283, 3473, 2955, 2535, 2743, 2794, 4782, 4836, 4946, 4471, 4540, 4566, 4579, 4511, 5263, 5223, 5298, 5414, 5213, 5764, 5322, 5712, 4581, 5001, 5443, 5512, 6249, 6448, 6440, 6307, 4891, 4569, 5417, 5890, 6236, 6191, 6411, 6529, 7177, 7174, 6690, 6468, 4730, 4840, 4948, 5056, 2876, 2801, 3257, 3468, 1989, 1962, 1908, 1530, 1773, 1969, 1990, 1779, 3416, 3658, 2902, 2905, 3717, 3665, 3607, 3312, 3278, 3167, 2552, 2847, 1883, 1964, 1854, 1935, 2303, 3012, 3399, 3636, 3872, 3474, 3428, 3379, 2957, 2767, 2525, 2963, 5227, 5300, 4961, 4789, 5271, 5329, 4893, 5002, 6352, 6530, 6294, 6297, 6309, 6250, 6199, 6472, 5404, 5768, 4811, 4903, 5214, 5324, 4570, 4732, 1895, 1663, 1912, 1503, 1970, 1774, 1993, 1532, 5418, 5520, 5728, 5472, 4790, 4350, 4813, 4671, 3373, 3489, 2686, 2796, 2992, 2917, 3285, 3640, 2539, 2747, 3904, 3660, 2802, 2906, 3258, 3718, 6680, 6721, 6692, 6257, 5009, 4894, 5445, 5653, 3476, 3299, 2526, 3016, 3968, 3666, 3490, 3374, 6298, 6223, 7185, 7178, 5275, 5330, 5425, 5667, 5420, 5229, 4907, 4475, 5304, 5654, 4793, 4527, 1885, 1781, 1994, 1943, 3721, 3843, 2431, 2958, 3432, 3611, 3183, 3403, 2863, 3024, 2918, 2965, 4703, 4585, 5657, 5235, 4962, 4819, 4582, 5004, 6413, 6252, 6722, 6368, 4814, 4909, 4572, 4952, 5287, 5345, 5446, 5426, 6310, 6663, 6696, 6339, 1899, 1886, 1782, 1972, 2775, 2541, 3286, 3381, 6414, 6785, 6667, 6419, 4935, 4821, 5892, 5277, 2921, 2749, 3260, 3521, 2001, 1947, 1996, 1785, 5776, 5449, 4794, 5010, 6724, 6435, 7186, 7296, 3289, 3480, 2979, 2804, 1901, 1976, 1519, 1727, 4848, 4964, 5230, 5237, 4915, 4910, 5332, 5291, 5896, 5450, 5346, 5669, 6203, 6313, 6704, 6258, 3681, 3668, 3623, 3722, 2908, 2547, 3301, 3231, 5658, 5507, 5428, 5336, 4535, 5025, 4586, 4719, 3492, 3382, 3613, 3845, 1959, 2002, 1007, 1015, 2779, 2871, 2970, 2922, 3682, 3729, 2966, 2550, 3405, 3191, 3672, 3411, 2981, 2791, 3290, 3440, 6421, 6300, 6231, 6341, 4767, 4835, 5012, 4559, 2808, 2929, 3724, 3302, 3463, 3385, 3522, 3614, 4939, 4477, 5536, 5391, 5399, 5278, 5457, 5670, 6260, 6314, 6205, 6675, 6669, 6786, 7180, 7201, 3406, 3305, 2542, 2750, 3627, 3846, 2969, 2549, 3247, 3195, 3730, 3684, 3413, 3849, 2924, 2895, 4593, 5026, 5792, 5238, 4917, 4822, 5057, 4968, 6425, 6422, 6670, 6321, 5452, 5699, 4588, 4727, 6437, 6532, 6235, 6728, 5660, 5509, 5293, 5241, 1907, 1786, 1527, 1949, 3040, 2495, 3292, 3386, 4825, 4796, 4539, 4837, 5673, 5319, 5904, 5299, 7233, 7188, 6913, 6342, 6316, 6264, 6345, 6480, 5348, 5458, 4941, 5016, 5432, 5824, 4478, 4918, 2781, 2875, 3496, 3467, 2982, 2930, 3745, 3655, 1902, 1759, 2017, 1909, 2985, 3011, 3427, 3359, 3255, 3306, 3197, 3629, 2795, 2553, 2903, 2972, 5510, 5294, 4947, 4826, 6206, 6426, 7424, 7202, 5674, 5701, 5513, 5403, 4594, 4976, 5242, 5568, 6287, 6247, 6322, 6438, 4838, 4541, 4567, 4731, 1963, 2018, 2004, 1950, 3732, 3688, 3414, 3388, 3313, 3850, 2782, 2877, 3635, 3417, 3524, 3469, 3013, 2986, 3475, 3279, 1788, 1965, 1991, 1910, 5028, 4783, 5473, 5681, 4999, 4921, 5323, 5183, 6237, 6788, 6346, 6736, 6467, 6536, 7192, 7204, 3746, 3630, 3857, 3504, 2932, 2554, 3429, 3259, 5460, 5514, 4596, 4942, 6441, 6914, 6251, 6324, 4841, 4922, 5647, 5702, 5676, 5301, 5415, 5405, 6295, 6353, 6428, 6792, 4828, 4542, 5352, 5244, 2797, 2993, 3308, 3736, 3696, 3659, 3014, 2803, 2907, 2988, 3852, 3777, 1855, 1971, 1531, 1913, 5325, 5302, 5763, 5682, 5058, 5032, 4571, 4949, 4963, 4733, 5406, 5705, 5419, 5474, 5331, 5521, 5003, 4583, 4791, 4842, 7175, 7297, 6238, 6348, 3198, 3314, 3637, 3470, 2008, 1775, 1966, 2020, 3418, 3528, 2878, 2959, 2919, 2687, 3430, 3477, 6442, 6544, 6752, 6496, 4924, 4849, 5305, 5516, 3375, 3641, 3316, 3667, 2936, 2527, 3261, 3638, 3748, 3433, 3778, 3661, 2994, 2798, 3287, 3858, 5464, 5706, 4950, 4953, 6469, 6677, 6299, 6354, 1995, 1914, 1533, 1973, 3719, 3420, 3491, 3478, 5765, 5713, 5655, 5360, 5326, 5215, 4600, 4895, 3536, 3752, 3017, 2556, 2909, 2805, 3873, 3434, 6449, 6691, 6444, 6253, 4351, 5060, 5447, 5684, 5920, 5522, 5476, 5427, 7234, 7680, 6328, 6678, 3018, 2967, 3662, 3481, 2923, 2910, 3642, 3860, 5005, 4815, 4573, 5011, 5421, 5537, 4734, 4844, 5040, 4965, 5333, 5688, 4587, 4795, 5952, 5708, 6681, 6259, 6311, 6369, 6470, 6450, 7179, 7208, 3669, 3644, 2806, 2996, 3291, 3383, 3780, 3670, 4850, 4954, 5306, 5766, 5524, 5347, 4574, 5064, 6016, 5714, 5538, 5422, 5769, 5891, 4479, 5006, 1997, 2024, 1916, 1974, 3673, 3723, 3493, 3864, 3025, 2971, 3874, 3683, 3020, 2809, 3674, 3482, 3303, 3760, 2925, 3000, 1887, 1783, 2032, 1534, 6916, 6301, 6800, 6473, 6254, 6261, 6356, 6315, 3725, 3320, 2543, 2751, 3441, 3262, 3436, 3726, 7236, 7298, 6920, 6474, 6370, 6693, 6682, 6531, 5480, 5659, 5231, 5451, 4911, 5072, 4966, 5013, 2983, 3026, 3731, 3407, 3552, 3387, 3293, 3442, 6452, 6360, 7187, 7181, 6560, 6415, 6423, 6302, 4823, 4589, 5334, 5429, 4969, 4797, 5308, 5569, 3685, 3494, 3497, 3523, 3686, 3615, 3307, 3484, 5337, 5528, 5027, 4852, 5729, 5716, 5671, 5770, 7216, 7182, 6481, 6694, 4956, 4595, 5349, 5279, 6816, 6262, 6476, 6723, 5540, 5430, 5661, 5893, 2003, 1977, 1019, 1021, 2931, 2810, 3415, 3444, 2551, 2973, 3847, 3389, 3294, 3498, 2926, 2783, 6684, 6533, 6317, 6265, 4827, 4919, 5018, 4970, 3525, 3309, 3041, 2933, 3631, 3905, 3876, 3784, 5730, 5777, 5014, 4598, 5453, 5239, 5720, 5459, 6697, 6343, 6928, 6323, 5029, 4839, 5338, 5488, 2987, 3042, 3906, 3733, 1787, 1998, 1978, 1903, 6372, 6482, 6456, 6848, 4856, 4977, 5772, 5350, 3880, 3851, 3689, 3676, 2005, 2006, 1951, 2019, 7240, 7425, 6534, 6318, 5511, 5433, 5570, 5662, 5454, 5353, 4590, 4798, 6698, 6725, 7189, 7300, 5675, 5894, 5017, 4597, 6537, 6427, 6266, 6592, 5295, 5243, 5778, 5732, 5461, 5897, 4972, 4943, 3505, 3792, 3888, 3908, 3028, 2974, 2812, 2989, 6497, 6705, 7203, 7426, 6347, 6207, 6484, 6538, 3419, 3969, 3315, 3734, 1789, 1980, 1911, 2009, 5088, 4543, 5340, 5434, 4829, 4923, 5544, 5515, 5030, 4978, 5793, 5703, 5033, 5059, 5475, 5407, 6671, 6726, 6700, 6325, 5303, 5354, 5245, 5677, 3526, 3390, 3015, 2934, 3747, 3690, 2879, 2995, 3970, 3853, 3448, 3500, 3737, 3808, 2555, 2937, 4843, 4601, 4951, 5020, 5780, 5736, 5462, 5436, 2021, 2010, 1967, 1915, 3639, 3912, 3697, 3310, 6439, 6429, 6376, 6268, 5361, 5898, 4830, 4925, 3032, 2799, 3431, 3529, 2990, 3044, 3471, 3859, 6349, 6326, 6787, 6706, 5683, 5465, 5572, 5517, 3663, 3750, 3506, 3749, 2022, 1790, 1535, 2012, 6430, 6729, 7194, 7681, 6443, 6498, 7248, 7205, 5061, 5034, 5523, 5327, 5794, 5678, 5905, 5552, 4980, 4602, 5477, 5307, 6355, 6545, 6329, 6540, 3421, 3317, 3530, 3738, 3692, 3435, 3019, 2938, 3199, 3263, 3854, 3479, 3508, 3698, 2557, 2997, 7193, 7190, 6488, 6730, 6789, 6737, 6679, 6384, 4845, 5041, 5356, 5784, 5744, 5707, 5062, 4851, 6350, 6239, 6471, 6708, 6944, 6546, 7304, 7428, 3021, 3048, 3643, 3537, 3753, 3318, 3779, 3422, 4955, 5036, 5900, 5825, 5246, 5362, 5685, 5518, 5466, 5576, 4926, 5007, 4967, 4735, 5478, 5525, 2940, 2998, 3671, 3740, 3862, 3532, 3321, 3754, 5423, 5689, 5364, 5715, 6500, 6451, 6445, 6561, 7432, 7206, 6357, 6712, 4984, 4575, 5309, 5686, 6976, 6732, 6330, 6790, 5796, 5481, 5826, 5709, 2025, 1975, 1022, 1023, 2911, 2807, 3056, 2558, 5042, 4846, 5335, 5906, 5767, 5468, 5539, 5526, 3645, 3483, 3875, 3861, 3781, 3437, 3512, 3700, 6548, 6371, 7040, 6738, 5584, 5800, 5065, 4604, 6562, 6446, 7682, 7264, 6793, 6915, 6504, 6683, 3761, 3446, 3495, 3538, 3027, 3001, 3865, 3322, 3443, 3553, 3646, 3485, 2026, 1917, 1999, 1918, 4957, 4853, 5921, 5482, 5066, 5015, 5710, 5529, 7235, 7209, 7312, 7196, 6255, 6475, 6358, 6453, 4971, 4958, 5690, 5908, 6332, 6593, 6361, 6552, 5717, 5692, 4854, 5044, 6753, 6740, 6695, 6794, 2811, 3022, 3675, 3438, 3540, 3727, 3002, 2927, 3972, 3877, 3029, 3030, 3687, 3756, 3782, 3501, 5339, 5431, 5828, 5718, 5721, 5771, 5541, 5912, 7237, 7210, 6373, 6303, 5073, 5019, 5922, 5731, 5068, 4857, 5722, 5530, 6564, 6454, 7684, 7217, 3866, 3324, 2975, 3043, 3445, 3677, 3920, 3762, 6685, 6917, 7242, 7440, 6754, 6801, 6477, 6263, 6744, 6483, 6362, 6512, 5351, 5808, 4973, 5048, 6796, 6374, 6535, 6457, 5773, 5368, 4591, 4799, 2033, 1979, 2028, 2034, 3785, 3704, 3554, 3878, 5489, 5310, 5484, 5774, 5031, 5074, 5779, 5455, 5600, 5435, 5341, 5490, 5733, 5542, 5545, 5571, 6594, 6686, 7328, 7688, 6478, 6377, 6699, 6918, 6319, 6267, 6802, 6756, 7456, 7696, 6485, 6921, 3499, 3976, 3486, 3295, 3735, 3764, 3907, 3691, 3544, 3527, 3868, 3881, 2813, 3004, 3786, 3793, 5734, 5663, 5355, 5532, 6364, 6458, 7360, 7712, 3909, 3788, 3936, 3882, 2935, 3033, 3678, 3984, 4979, 4858, 5463, 5492, 6568, 6539, 6817, 6727, 3794, 3768, 3449, 3507, 3045, 3034, 3889, 3391, 4599, 5021, 5895, 5437, 5342, 5546, 4974, 4831, 7238, 7212, 6499, 6431, 5573, 5357, 5089, 4981, 1981, 2007, 1982, 2011, 3693, 3884, 3556, 3502, 6327, 6378, 7299, 7249, 5679, 5953, 5924, 5832, 6269, 6701, 6804, 6760, 5035, 5090, 5954, 5781, 7218, 7241, 7183, 7488, 5928, 5899, 5737, 5724, 6486, 6460, 6385, 6922, 6707, 6489, 6596, 6541, 3910, 3739, 2991, 2939, 3560, 3311, 3450, 3531, 5553, 5840, 5936, 5956, 5076, 5022, 4860, 5037, 3694, 3699, 3509, 3452, 3890, 3533, 3046, 2814, 5467, 6017, 5363, 5782, 7301, 7220, 7191, 7302, 6547, 6351, 6818, 6702, 6929, 6576, 6501, 6331, 3568, 3741, 2559, 3036, 3751, 3796, 3913, 3701, 6380, 6808, 6768, 6731, 5574, 5438, 5063, 4982, 3423, 3539, 3510, 3809, 2036, 2023, 2040, 1791, 7552, 7244, 6924, 6849, 5795, 5738, 4927, 5043, 6018, 5901, 5496, 5548, 6270, 6386, 6709, 6542, 3323, 3534, 3514, 3513, 3049, 2999, 3541, 3319, 5785, 5856, 4603, 4985, 5687, 5960, 5745, 5358, 5080, 4847, 5479, 5577, 5038, 5092, 5519, 5907, 7305, 7250, 6490, 6600, 6502, 6549, 7224, 7195, 5711, 5798, 5554, 5797, 7265, 7207, 6447, 6713, 6388, 6739, 6333, 6710, 5469, 5365, 5578, 5786, 5740, 5483, 5067, 4986, 6820, 6505, 6850, 6733, 5247, 5311, 5902, 5527, 6359, 6930, 6791, 6492, 3755, 3914, 3810, 3971, 3742, 3855, 3921, 3892, 6563, 6550, 6608, 6824, 6945, 6506, 7427, 7252, 3800, 4000, 3863, 3439, 3050, 2941, 3973, 3702, 6734, 6553, 7306, 7313, 7429, 7197, 6714, 6932, 5556, 5746, 4605, 5045, 5069, 5096, 5691, 5585, 3757, 3916, 3705, 3783, 2013, 2027, 2014, 2029, 5801, 5366, 5827, 5470, 4988, 5046, 5719, 5788, 3325, 3763, 3023, 2942, 3896, 3974, 3758, 3812, 5910, 5580, 5369, 5802, 6741, 6716, 6363, 6455, 7211, 7266, 7683, 7256, 6852, 6742, 6745, 6795, 3922, 3447, 3516, 3542, 3555, 3487, 3557, 3977, 4959, 4855, 5104, 4606, 6565, 6936, 6946, 6755, 5693, 5531, 5923, 5909, 5829, 5485, 5560, 5748, 7308, 7198, 6746, 6554, 5809, 5494, 5543, 5586, 7314, 7239, 6375, 6832, 6797, 6392, 6513, 6334, 5075, 5049, 5913, 5370, 5491, 5601, 5694, 5533, 3057, 3003, 3867, 3545, 3706, 3816, 3924, 4032, 3937, 3765, 3869, 3978, 3787, 3879, 3052, 3058, 6508, 6798, 6803, 6479, 7430, 7433, 6624, 6459, 6365, 6514, 7329, 7744, 4859, 5070, 5723, 5486, 7213, 7268, 6757, 6566, 5588, 5775, 5050, 4975, 1983, 2035, 2037, 1919, 3546, 3708, 3005, 3031, 6569, 6595, 7808, 7219, 6020, 5925, 5077, 5078, 3766, 3326, 3789, 3647, 3985, 3870, 3006, 3035, 6758, 6687, 6379, 6556, 6487, 6516, 7316, 7214, 5735, 5804, 5830, 5549, 6919, 6461, 6366, 6570, 5914, 5372, 5023, 5091, 5493, 5725, 5968, 5810, 3883, 3451, 3769, 3503, 3679, 3561, 3938, 3795, 5833, 5752, 5602, 5926, 7243, 7434, 6597, 6381, 5547, 6024, 5534, 5343, 6703, 6977, 6948, 6856, 3060, 3047, 3558, 3980, 3790, 3885, 3548, 3928, 7441, 7685, 7272, 7330, 5783, 5812, 5955, 5739, 3911, 3797, 3064, 2815, 3770, 3986, 3824, 3940, 5592, 5575, 5916, 5929, 6978, 6805, 6952, 6923, 7221, 7361, 6761, 6748, 7320, 7245, 6577, 6864, 4861, 5052, 5834, 5841, 6960, 6980, 6491, 7041, 7332, 7936, 7436, 7442, 6387, 6806, 6598, 6462, 5957, 5836, 5984, 5930, 4983, 5081, 5726, 6032, 5842, 5816, 5497, 5555, 6819, 6762, 7686, 7222, 3891, 3886, 3511, 4001, 3562, 3695, 3743, 3811, 7042, 6925, 6520, 6572, 7251, 7225, 6809, 6880, 5093, 5082, 5937, 5439, 5741, 5932, 5604, 5550, 5958, 5787, 5039, 4987, 6711, 6984, 6769, 6382, 3988, 3535, 3915, 3453, 3037, 3051, 3569, 4002, 3893, 3798, 4033, 3944, 3564, 3703, 3801, 3772, 7689, 7280, 7303, 7246, 5608, 5359, 5498, 5579, 6503, 6601, 7457, 7362, 6543, 6931, 6735, 6822, 7253, 7444, 6578, 6821, 5742, 5747, 5557, 5500, 3515, 3813, 3038, 3053, 3917, 3992, 3454, 3894, 5938, 5581, 5094, 4862, 6493, 6389, 6602, 6810, 6764, 6507, 6271, 6335, 6926, 6551, 7690, 7226, 5616, 5789, 4607, 5084, 5799, 5844, 5961, 5749, 3923, 3802, 3570, 3952, 3814, 3517, 3543, 3707, 3007, 3059, 4004, 3759, 3975, 3897, 3572, 3918, 7336, 7307, 6580, 6770, 5471, 5587, 5558, 5857, 5371, 5582, 5562, 5561, 6715, 6609, 7267, 7254, 5097, 5047, 5589, 5367, 6825, 6390, 6851, 6494, 5803, 5962, 5858, 6019, 7228, 7448, 6743, 6812, 6934, 6604, 7257, 7458, 5790, 5903, 5969, 5940, 6393, 6826, 6717, 6555, 6947, 6933, 6853, 6509, 3817, 3898, 3804, 3518, 4034, 4008, 3547, 3925, 7697, 7692, 7364, 7309, 5848, 6048, 5911, 5487, 6584, 6772, 6833, 6518, 6567, 6610, 6937, 6394, 5098, 4989, 6021, 5750, 5805, 5964, 5753, 5831, 3939, 3709, 3979, 3559, 3061, 2943, 3767, 3818, 5373, 5811, 5071, 4990, 7269, 7315, 7344, 7310, 5944, 6022, 5806, 5860, 7698, 7489, 7199, 7368, 3900, 3825, 3926, 3929, 3576, 3871, 3327, 4036, 6515, 6625, 6718, 6557, 5970, 5495, 5564, 5590, 3981, 3791, 3549, 3987, 3710, 3820, 3054, 3062, 7258, 7713, 7460, 7490, 6747, 6510, 6612, 6799, 5603, 5535, 5605, 6025, 7044, 6949, 6759, 6828, 7700, 7431, 6854, 6573, 7317, 7270, 6938, 6396, 4016, 3941, 3563, 3771, 2030, 2038, 2041, 2042, 5105, 5051, 5915, 5593, 5754, 5864, 5972, 6080, 7273, 7472, 6517, 6749, 5985, 5813, 5917, 6026, 6992, 6834, 6857, 6776, 7464, 7331, 6626, 6950, 5835, 5927, 5100, 5106, 7260, 7215, 6571, 7048, 5594, 5756, 5053, 5079, 7435, 7553, 6558, 6367, 6807, 6836, 7714, 7492, 6979, 6763, 7376, 7554, 6616, 6599, 6940, 6953, 5814, 5374, 5837, 5695, 7318, 7321, 7333, 7274, 6033, 5918, 5054, 5083, 6858, 6865, 6981, 6860, 7008, 6954, 6750, 7056, 7223, 7496, 6866, 6840, 5931, 5499, 5817, 5551, 3826, 3930, 3550, 4040, 3455, 3982, 3887, 4048, 5727, 5609, 5986, 5843, 6521, 6579, 6961, 6463, 5108, 5095, 5606, 6028, 7704, 7745, 6765, 6956, 5838, 5933, 5596, 5976, 7716, 7281, 6628, 6574, 3942, 3989, 3065, 3066, 3799, 3565, 3945, 3773, 5959, 5845, 5112, 4863, 7322, 7247, 7437, 7276, 6982, 6811, 6632, 6383, 6522, 6603, 7746, 7392, 5818, 6034, 5872, 5988, 5939, 5934, 5559, 6049, 4003, 3828, 3932, 3571, 3803, 3895, 3994, 3946, 7334, 7687, 7720, 7363, 6766, 6771, 6581, 6524, 7438, 7809, 7691, 7443, 5610, 5743, 5791, 5859, 6962, 6605, 6640, 6813, 6823, 6868, 6985, 6773, 6036, 5583, 5963, 5501, 6495, 6611, 7748, 7459, 3990, 3574, 4005, 3815, 3039, 3068, 3832, 3953, 7227, 7337, 6582, 6881, 7728, 7282, 6395, 6606, 5085, 5099, 5617, 6050, 6586, 6585, 6613, 6391, 5941, 5846, 6081, 5992, 7445, 7324, 6827, 6986, 7255, 7365, 7284, 7338, 5612, 5751, 5849, 5820, 5563, 5861, 5086, 5101, 6882, 7043, 6814, 6927, 3566, 3774, 3993, 3573, 3948, 3919, 4064, 3519, 7229, 7699, 7693, 7810, 6993, 6964, 7449, 7446, 3805, 3899, 4006, 3954, 4009, 4035, 3819, 3577, 6872, 7072, 7694, 7345, 5965, 6040, 5502, 5942, 5971, 5850, 5618, 6000, 6935, 6511, 7045, 6774, 7461, 7556, 6829, 6988, 6777, 6855, 7259, 7752, 5862, 5565, 5591, 5755, 7937, 7366, 7340, 7288, 7369, 7504, 6397, 6835, 7230, 7450, 6968, 7046, 5055, 5107, 6052, 5807, 6830, 6884, 6994, 6519, 3927, 3996, 3806, 3901, 4037, 4010, 3956, 3578, 6588, 6614, 6627, 6559, 7311, 7271, 7346, 7462, 7261, 7812, 7370, 7760, 6023, 5945, 5620, 5966, 5865, 5946, 5852, 5566, 6629, 7049, 7491, 7560, 6082, 6056, 5595, 5973, 6939, 6617, 7465, 7938, 5987, 5757, 6027, 5607, 6778, 6888, 6996, 7104, 7275, 7348, 7009, 6837, 5109, 4991, 5815, 5866, 7319, 7377, 6941, 7050, 7452, 7816, 6859, 6951, 3821, 4017, 4038, 3827, 3931, 4012, 3902, 3983, 7262, 7372, 6618, 6780, 7466, 7568, 7776, 7520, 5948, 5873, 5974, 5977, 6838, 6398, 6861, 6719, 5624, 5919, 5375, 6084, 7057, 6942, 7493, 7701, 7323, 7378, 7473, 7715, 6029, 5839, 5597, 6035, 3943, 3711, 3960, 3551, 4018, 3822, 4041, 3580, 7468, 7277, 6955, 6523, 5758, 5868, 5102, 5110, 7352, 7702, 6841, 6575, 6751, 6633, 7705, 7283, 6064, 5989, 5611, 5819, 7010, 6867, 6630, 7052, 6862, 6957, 6620, 7000, 7335, 7393, 7494, 7474, 6983, 6869, 7940, 7325, 7824, 7497, 6842, 7058, 6896, 7012, 7278, 7285, 6963, 6958, 7380, 7339, 3933, 3829, 4042, 3991, 2015, 2044, 2031, 2039, 5874, 5978, 5598, 6088, 7944, 7498, 7394, 7717, 5503, 6030, 5935, 6096, 7706, 7555, 7476, 7384, 6583, 7073, 6634, 6767, 5990, 6037, 5113, 5114, 6815, 6883, 7060, 6607, 5847, 5613, 5993, 5821, 6987, 6525, 7584, 7439, 7447, 7326, 7505, 7718, 6051, 5876, 5980, 5619, 6641, 7074, 7840, 7286, 3947, 3934, 3830, 4020, 4049, 3995, 4044, 3833, 6965, 6870, 7105, 7016, 7500, 7747, 6636, 6775, 3949, 4024, 3567, 3775, 4007, 4050, 3055, 3063, 7708, 7557, 7341, 7289, 6873, 6844, 6587, 6885, 5851, 5943, 6042, 5994, 6038, 5622, 6053, 5863, 7721, 7367, 7952, 7347, 7396, 7506, 6989, 7064, 3955, 3834, 3575, 3997, 3950, 3807, 4065, 3957, 7480, 7872, 6526, 6966, 5087, 5116, 5880, 6001, 7558, 7342, 6995, 6874, 5614, 5822, 6041, 5621, 7722, 7749, 7561, 7451, 6642, 7024, 7290, 7616, 6886, 6589, 6615, 6779, 5996, 5967, 6112, 5567, 4011, 4066, 4052, 3998, 3836, 4013, 4039, 3958, 7076, 6831, 7521, 7729, 7047, 6969, 7371, 7231, 5853, 5947, 6054, 6002, 7508, 7562, 6644, 6990, 6057, 6083, 5867, 5625, 6889, 6970, 7695, 7750, 7724, 7349, 7463, 7453, 6876, 6590, 7400, 7292, 3903, 4019, 3579, 3961, 4056, 3823, 4014, 4068, 7373, 7350, 7811, 7730, 7106, 7080, 6619, 6997, 7011, 6781, 7454, 7753, 5975, 6044, 5854, 5949, 7467, 7522, 7379, 7569, 7051, 6631, 6839, 6890, 6972, 6897, 7353, 7564, 6085, 6058, 6004, 5626, 5869, 6065, 6086, 5875, 7512, 7754, 6998, 7001, 7813, 7761, 7703, 7408, 7374, 7263, 6648, 6943, 5979, 6060, 5950, 6031, 6399, 7108, 7495, 7732, 7968, 7570, 7524, 7475, 7053, 6863, 6621, 7059, 4043, 3962, 3581, 4021, 2043, 2045, 2046, 2047, 5991, 5759, 6008, 5599, 6066, 5870, 6089, 5628, 7469, 7585, 6782, 6892, 7088, 7013, 7381, 7736, 6635, 6843, 8000, 7756, 6898, 7002, 7354, 7814, 7572, 7395, 6622, 7112, 8064, 7762, 7586, 7470, 5981, 5877, 6090, 6039, 7817, 7939, 6527, 7054, 7528, 7707, 7279, 7499, 6959, 7120, 7014, 7061, 4045, 4072, 3964, 4022, 3935, 3831, 4080, 3582, 5995, 5982, 5878, 6068, 6871, 6637, 7382, 7477, 7017, 6845, 7356, 7617, 6097, 6043, 6092, 5881, 7385, 7576, 7075, 6900, 5997, 6072, 5615, 5823, 7777, 7764, 7719, 7818, 7004, 6643, 7397, 7327, 7588, 7478, 7709, 7941, 6055, 6098, 5103, 5111, 6875, 6967, 7066, 7018, 7778, 7825, 7062, 6646, 4051, 4025, 3067, 3069, 3835, 4046, 4026, 3951, 7501, 7287, 7768, 7507, 7077, 6887, 7386, 7536, 6904, 7025, 7820, 7398, 7559, 7481, 7618, 7710, 7502, 7401, 6638, 6846, 7723, 7942, 7065, 6645, 7343, 7291, 7826, 7780, 7509, 7945, 7020, 6991, 6003, 5882, 5623, 6045, 7136, 6591, 7388, 7482, 6877, 6971, 7592, 7563, 7078, 7026, 7841, 7751, 5998, 5855, 6113, 6005, 7081, 7107, 7523, 7455, 7351, 7402, 7293, 7725, 6891, 6649, 6999, 7068, 6059, 6114, 6100, 6046, 7828, 7784, 7510, 7484, 4053, 4054, 3999, 4067, 3837, 4028, 3959, 4057, 7409, 7946, 6878, 6973, 7731, 7513, 7620, 7565, 7109, 7082, 7571, 7375, 5884, 6061, 6087, 6006, 7842, 7726, 7953, 7600, 7028, 6650, 7525, 7355, 6893, 7089, 7404, 7832, 7792, 7755, 7110, 6899, 7003, 7084, 7948, 7873, 5951, 6067, 5627, 6009, 7294, 7410, 7733, 7566, 6104, 5871, 6062, 6116, 7514, 7624, 6974, 7055, 7015, 6783, 7526, 7573, 7471, 7737, 7412, 7763, 7032, 6623, 7357, 7734, 4069, 4058, 4015, 3963, 4070, 3838, 3583, 4060, 7844, 7529, 7874, 7757, 7090, 6894, 7383, 7954, 6091, 6010, 5629, 6069, 7815, 7516, 7587, 7574, 7632, 7848, 7113, 6652, 7005, 6901, 7969, 7530, 7114, 7063, 7758, 7577, 7019, 7006, 7738, 7956, 7765, 7740, 6902, 7092, 7387, 7479, 7876, 7766, 6093, 6120, 6012, 6070, 7769, 7819, 7589, 7960, 7121, 7067, 7970, 7779, 7116, 6905, 7770, 7578, 4073, 4023, 3070, 3071, 4074, 3965, 4047, 3966, 7399, 7856, 7021, 7096, 5983, 5879, 6128, 5630, 7821, 7416, 6639, 6847, 7537, 7358, 7532, 7822, 7079, 7122, 7827, 7503, 7648, 7483, 7389, 7538, 7781, 7590, 7593, 7619, 7782, 7711, 7403, 7580, 6099, 6073, 5115, 5117, 7027, 6906, 7511, 7540, 6647, 7069, 7943, 7485, 7390, 7594, 7022, 6879, 7621, 7405, 7137, 7029, 7727, 8001, 7972, 7880, 7083, 7138, 8002, 7829, 5883, 6094, 6074, 5999, 4081, 4027, 4076, 4082, 4029, 4055, 4030, 4059, 7976, 7947, 7785, 7772, 6101, 6102, 6047, 6115, 7601, 7888, 7984, 8004, 7124, 7070, 6908, 7085, 7515, 8065, 7411, 7830, 5885, 6076, 6007, 6105, 7622, 7486, 7111, 7030, 7843, 7786, 6975, 7091, 8066, 7949, 7544, 7596, 7833, 7904, 6651, 7033, 6117, 6106, 6063, 6011, 7735, 8008, 7793, 7406, 7128, 6895, 7527, 7625, 7086, 7140, 7567, 7955, 7759, 7846, 7602, 7845, 6118, 5886, 5631, 6108, 7517, 7413, 7626, 7834, 7788, 7531, 7115, 7034, 7295, 7359, 7950, 7575, 7604, 7794, 6653, 7093, 7117, 7144, 7739, 7633, 7849, 7414, 7875, 7518, 7036, 7094, 7767, 7836, 7958, 7628, 7417, 7850, 6121, 6071, 5118, 5119, 7007, 6903, 7152, 6654, 7741, 7579, 7971, 7957, 7877, 7533, 7608, 7796, 7857, 7542, 7591, 7634, 7123, 7097, 7961, 7418, 7539, 7649, 7742, 7581, 6122, 6013, 6095, 6014, 6907, 7118, 7771, 7534, 7636, 7823, 7098, 7023, 8068, 7973, 7125, 7126, 7783, 7852, 7878, 7597, 7962, 7420, 7071, 7139, 7541, 7773, 8016, 7858, 6129, 6075, 6124, 6130, 7881, 7800, 7650, 7974, 7595, 8072, 7582, 7391, 7831, 7860, 8003, 7787, 7640, 7623, 7964, 7977, 6909, 7100, 7882, 7889, 8005, 7884, 8032, 7978, 7031, 7129, 7774, 8080, 7890, 7864, 7545, 7603, 7141, 7130, 7985, 7487, 6077, 6103, 6078, 6107, 7789, 7980, 7652, 7598, 8006, 7835, 7087, 7035, 7656, 7407, 7546, 7627, 7790, 7795, 7605, 7548, 7986, 7629, 7142, 6910, 7664, 7837, 6655, 7132, 7847, 7892, 8009, 7797, 7519, 7635, 7606, 7905, 6132, 6119, 6136, 5887, 7419, 7630, 7610, 7609, 7145, 7095, 7637, 7415, 4084, 4071, 4088, 3839, 4061, 4075, 4062, 4077, 7851, 8010, 7906, 8067, 7838, 7951, 8017, 7988, 7896, 8096, 7959, 7535, 7146, 7037, 8069, 7798, 7853, 8012, 7801, 7879, 6109, 6123, 6110, 6125, 7421, 7859, 7119, 7038, 7992, 8070, 7854, 7908, 8018, 7543, 7612, 7638, 7651, 7583, 7653, 8073, 7153, 7099, 7963, 7641, 7802, 7912, 8020, 8128, 8033, 7861, 7965, 8074, 7883, 7975, 7148, 7154, 6079, 6131, 6133, 6015, 7642, 7804, 7101, 7127, 7862, 7422, 7885, 7743, 8081, 7966, 7102, 7131, 7979, 7547, 7865, 7599, 7775, 7657, 8034, 7891, 7156, 7143, 7654, 8076, 7886, 7981, 7644, 8024, 8007, 7893, 7160, 6911, 7866, 8082, 7920, 8036, 7987, 7982, 7607, 8097, 7658, 7791, 7839, 7907, 8084, 7631, 8011, 7549, 7133, 7147, 7665, 8098, 7989, 7894, 8129, 8040, 7660, 7799, 7897, 7868, 7611, 7909, 7134, 7149, 8013, 8088, 7550, 7990, 8019, 7898, 7666, 8048, 7910, 7613, 7639, 7803, 7103, 7155, 8100, 7855, 8071, 7993, 7668, 8014, 7913, 7994, 7900, 7614, 8130, 8104, 7643, 8021, 4031, 4083, 4085, 3967, 4078, 4086, 4089, 4090, 8035, 7805, 8075, 7655, 7157, 7039, 7863, 7914, 7996, 7921, 8022, 8025, 7672, 7967, 7423, 8132, 8077, 7887, 7645, 8083, 7806, 7916, 7150, 7158, 8112, 8037, 7659, 7867, 6126, 6134, 6137, 6138, 7922, 8026, 7646, 8136, 7551, 8078, 7983, 8144, 8038, 8085, 7161, 7162, 7895, 7661, 8041, 7869, 8099, 7924, 8028, 7667, 7899, 7991, 8090, 8042, 8086, 7670, 8101, 7911, 7135, 7164, 7928, 8049, 7662, 7870, 8089, 7669, 8044, 8015, 8160, 7615, 7901, 7995, 8102, 8050, 8105, 8131, 7915, 7673, 8023, 8092, 7902, 7997, 8133, 8106, 8052, 7674, 4063, 4092, 4079, 4087, 4091, 4093, 4094, 4095, 7917, 8113, 8134, 7923, 8027, 8108, 7998, 8079, 8039, 7807, 8056, 7647, 8114, 7918, 8137, 7676, 8029, 7925, 8138, 8087, 6111, 6140, 6127, 6135, 8043, 8030, 7926, 8116, 8145, 8091, 8140, 7929, 8045, 8120, 7663, 7871, 8103, 8146, 7151, 7159, 8051, 7930, 7671, 8093, 8046, 7903, 8161, 8053, 8107, 8162, 8148, 8094, 7932, 8109, 8135, 8054, 7999, 8115, 7675, 8057, 8152, 7919, 8110, 8164, 8139, 8058, 7677, 8117, 6139, 6141, 6142, 6143, 8141, 8168, 8060, 8118, 8031, 7927, 8176, 7678, 8147, 8121, 7163, 7165, 7931, 8142, 8122, 8047, 8149, 8150, 8095, 8163, 7933, 8124, 8055, 8153, 8165, 8154, 8111, 8059, 8166, 7934, 7679, 8156, 8169, 8119, 7166, 7167, 8170, 8061, 8143, 8062, 8177, 8123, 8172, 8178, 8125, 8151, 8126, 8155, 8180, 8167, 8184, 7935, 8157, 8171, 8158, 8173, 8127, 8179, 8181, 8063, 8174, 8182, 8185, 8186, 8159, 8188, 8175, 8183, 8187, 8189, 8190, 8191]

### Sequence Group 3: Q3_8192

[0, 1, 2, 4, 8, 16, 32, 3, 5, 64, 1024, 2048, 4096, 9, 6, 17, 10, 18, 128, 12, 33, 65, 20, 256, 34, 24, 36, 7, 129, 66, 512, 11, 40, 68, 130, 19, 13, 48, 14, 72, 257, 1025, 21, 132, 35, 258, 26, 2049, 513, 80, 37, 25, 22, 4097, 136, 260, 264, 38, 514, 96, 67, 41, 144, 28, 69, 42, 516, 49, 1026, 74, 272, 160, 520, 288, 528, 192, 544, 70, 44, 131, 81, 2050, 50, 73, 15, 320, 133, 52, 1028, 23, 134, 384, 76, 4098, 137, 82, 56, 27, 97, 39, 259, 84, 138, 145, 261, 1032, 29, 43, 2052, 98, 515, 88, 140, 30, 146, 71, 262, 265, 161, 576, 45, 1040, 100, 640, 51, 148, 46, 75, 4100, 266, 273, 517, 2056, 104, 162, 53, 193, 1056, 152, 77, 164, 768, 268, 274, 518, 54, 83, 57, 521, 1027, 112, 135, 2064, 78, 289, 194, 85, 276, 4104, 522, 58, 168, 1029, 139, 99, 86, 60, 280, 89, 290, 529, 2080, 524, 196, 1088, 141, 101, 147, 176, 142, 530, 321, 31, 200, 1033, 4112, 90, 545, 292, 2051, 322, 532, 263, 149, 102, 105, 1030, 304, 296, 163, 92, 47, 267, 385, 546, 2053, 324, 1041, 208, 386, 4128, 150, 153, 165, 106, 55, 1034, 328, 536, 577, 548, 2112, 113, 154, 79, 269, 1042, 108, 578, 224, 166, 519, 552, 195, 4099, 1152, 270, 3072, 641, 523, 275, 580, 291, 59, 1036, 169, 560, 114, 277, 156, 2057, 87, 197, 1057, 116, 170, 4101, 61, 531, 525, 642, 281, 1089, 278, 526, 2054, 177, 293, 388, 91, 1044, 584, 769, 198, 172, 120, 4160, 201, 2065, 336, 1280, 62, 282, 143, 103, 178, 294, 1058, 93, 644, 2058, 202, 592, 323, 1048, 392, 5120, 297, 770, 107, 180, 151, 1060, 2066, 209, 284, 648, 94, 204, 298, 1031, 400, 608, 352, 2176, 6144, 325, 533, 1153, 155, 210, 305, 547, 300, 1090, 109, 2060, 184, 534, 537, 115, 167, 1536, 4105, 225, 326, 306, 772, 2081, 157, 1035, 656, 329, 110, 117, 212, 1064, 171, 2113, 776, 4102, 330, 226, 549, 1092, 538, 387, 308, 216, 2068, 1154, 416, 271, 279, 158, 337, 1043, 4113, 550, 672, 2304, 118, 332, 579, 1037, 540, 389, 173, 121, 1072, 2082, 553, 199, 784, 4106, 179, 1038, 228, 338, 312, 2072, 704, 390, 1096, 174, 554, 581, 393, 1281, 4114, 283, 2084, 122, 448, 353, 1045, 561, 203, 63, 340, 2055, 1156, 394, 527, 582, 4224, 556, 181, 1059, 2177, 295, 285, 232, 124, 1282, 205, 182, 643, 2114, 4108, 562, 1050, 286, 585, 299, 1537, 354, 211, 2560, 401, 185, 1104, 396, 344, 4129, 586, 645, 2059, 1061, 593, 535, 240, 206, 1049, 95, 2088, 327, 564, 4161, 1046, 800, 402, 356, 307, 2116, 1160, 301, 417, 213, 568, 1284, 832, 4116, 2178, 588, 186, 1288, 646, 404, 227, 896, 2067, 1062, 594, 418, 4352, 302, 1538, 649, 771, 2061, 360, 539, 1120, 111, 331, 214, 1091, 2096, 4130, 309, 188, 449, 1065, 217, 408, 2062, 609, 596, 1168, 551, 650, 4120, 229, 1052, 2120, 159, 420, 310, 1093, 541, 773, 2305, 610, 4132, 1066, 657, 333, 119, 1540, 3073, 600, 339, 218, 1073, 368, 652, 4103, 230, 2069, 1098, 391, 313, 450, 1296, 542, 2180, 334, 233, 4225, 1184, 555, 774, 175, 2083, 1544, 123, 658, 612, 1312, 2306, 4162, 341, 777, 220, 1552, 314, 424, 2074, 395, 1216, 673, 583, 4608, 355, 1568, 2561, 287, 183, 234, 1094, 125, 557, 2128, 4107, 660, 1068, 616, 342, 316, 2085, 1155, 241, 778, 1105, 563, 4136, 345, 2073, 452, 1074, 397, 403, 207, 2070, 1097, 674, 4164, 558, 1039, 785, 432, 2184, 357, 1344, 187, 236, 664, 4226, 2308, 1157, 624, 587, 1076, 780, 2312, 705, 126, 1047, 4115, 242, 565, 1158, 2086, 398, 346, 456, 1408, 358, 2562, 4109, 405, 1100, 303, 569, 244, 2144, 1161, 595, 189, 4144, 1106, 566, 2115, 676, 361, 1080, 706, 589, 2089, 1051, 4110, 215, 786, 647, 1121, 2192, 348, 419, 1063, 406, 4168, 464, 2076, 680, 1283, 801, 362, 1108, 2117, 590, 4353, 409, 1162, 570, 2090, 788, 597, 1169, 572, 219, 5121, 2564, 1285, 311, 708, 1053, 598, 2097, 601, 1067, 4117, 651, 421, 3074, 792, 1122, 802, 611, 1539, 2122, 4228, 602, 410, 1112, 231, 688, 2320, 1164, 653, 248, 4131, 1054, 2208, 369, 190, 364, 1170, 654, 2568, 4354, 659, 1095, 335, 480, 2336, 1286, 315, 221, 1289, 4122, 2576, 370, 613, 1185, 422, 425, 2240, 1600, 6145, 451, 614, 1069, 2592, 543, 235, 1124, 412, 4609, 2118, 343, 372, 1664, 775, 317, 2092, 1075, 222, 4176, 426, 1172, 2179, 453, 237, 1070, 559, 2129, 4133, 833, 1099, 804, 712, 2098, 1290, 834, 661, 4121, 1297, 2121, 808, 779, 1541, 617, 1128, 2063, 4118, 604, 433, 1186, 720, 2368, 816, 1077, 4232, 836, 347, 2181, 1217, 897, 243, 1176, 2100, 4356, 662, 454, 1101, 318, 3076, 675, 1188, 618, 4360, 898, 2071, 1792, 781, 376, 2182, 1292, 4134, 428, 1298, 665, 2432, 736, 1542, 567, 840, 4610, 2124, 1078, 625, 238, 1107, 2185, 359, 4192, 457, 1081, 399, 2130, 787, 1545, 591, 1136, 4163, 2104, 678, 434, 1159, 2075, 677, 349, 4137, 1102, 245, 2145, 458, 1313, 666, 1218, 4240, 2087, 620, 363, 1109, 2307, 127, 191, 4124, 1300, 782, 2132, 1546, 407, 436, 1082, 4165, 2186, 626, 571, 1192, 2193, 465, 1163, 681, 4138, 246, 2309, 1123, 707, 350, 3080, 4612, 1110, 599, 1084, 668, 2077, 790, 1304, 4145, 460, 2091, 249, 1113, 682, 1314, 2146, 5122, 573, 411, 1553, 2563, 803, 789, 1548, 4170, 709, 2136, 1220, 365, 440, 2188, 1165, 4368, 628, 1125, 689, 2078, 374, 1171, 4256, 423, 2194, 466, 1200, 793, 2119, 1166, 4616, 250, 371, 1554, 2310, 481, 1345, 574, 4384, 2313, 413, 1055, 603, 2209, 1224, 4624, 366, 468, 1114, 2624, 655, 1569, 900, 4288, 2093, 805, 1316, 615, 3088, 1346, 4640, 684, 710, 2148, 1556, 429, 1287, 4166, 2688, 794, 252, 1173, 373, 2099, 1126, 4140, 605, 848, 2196, 1129, 690, 1328, 4227, 2094, 713, 1320, 632, 2123, 482, 4177, 1187, 806, 2314, 1116, 427, 904, 6146, 2321, 1071, 414, 1291, 2565, 223, 663, 4146, 1409, 2152, 692, 1570, 835, 2210, 4169, 1348, 619, 472, 2101, 1232, 455, 4111, 1410, 2241, 796, 809, 1174, 3104, 4416, 714, 1177, 721, 2200, 1189, 837, 4229, 716, 2125, 1130, 864, 1079, 2212, 4148, 810, 1352, 606, 2816, 912, 5124, 1560, 722, 2316, 1601, 696, 1572, 4119, 2322, 377, 435, 1137, 2566, 817, 4230, 1178, 319, 2102, 1103, 621, 1293, 4480, 2131, 812, 484, 1132, 2105, 430, 4172, 1602, 838, 2569, 1248, 667, 4233, 3075, 488, 1190, 239, 2160, 1543, 4178, 378, 1576, 2183, 459, 1219, 622, 4152, 2126, 627, 1294, 437, 2337, 4123, 1665, 380, 2242, 1547, 818, 1299, 4193, 2133, 461, 496, 1604, 2324, 4135, 669, 1315, 2570, 679, 1083, 724, 4355, 2106, 1193, 841, 629, 2216, 4180, 1584, 351, 1138, 3077, 467, 1301, 4234, 2187, 438, 1180, 737, 2147, 4241, 1111, 251, 1221, 2134, 462, 4357, 442, 2108, 1140, 441, 1194, 2328, 5128, 469, 1085, 2137, 247, 1555, 4125, 683, 2338, 1549, 842, 1666, 4139, 2577, 738, 899, 2572, 1305, 6148, 670, 1302, 2244, 783, 1550, 3136, 4194, 849, 1201, 820, 2189, 1317, 4611, 728, 2149, 1412, 928, 1115, 4184, 2195, 791, 367, 2224, 1608, 4236, 901, 1793, 2190, 630, 1222, 4126, 2578, 685, 1196, 844, 2369, 4242, 1144, 633, 2079, 1225, 711, 4167, 1360, 2248, 253, 1086, 3081, 4358, 691, 1306, 824, 2138, 1167, 4361, 902, 2593, 1127, 686, 740, 4257, 2340, 1202, 850, 2370, 1318, 4672, 375, 2580, 1117, 444, 1668, 4141, 2311, 470, 1226, 2197, 483, 5136, 1616, 415, 2150, 1347, 485, 4196, 2153, 1416, 905, 3078, 1321, 4736, 795, 1794, 2352, 473, 4147, 1131, 2344, 634, 1204, 2211, 4244, 744, 1175, 852, 2140, 1233, 4142, 960, 2095, 1308, 865, 2315, 4171, 1672, 693, 2433, 1118, 4362, 797, 1228, 2594, 906, 1322, 4369, 2372, 715, 1424, 3089, 807, 4613, 1632, 474, 2256, 1376, 6152, 636, 2434, 1349, 694, 2198, 4200, 1557, 254, 2201, 1179, 717, 4258, 2213, 1234, 575, 1329, 4149, 2154, 913, 1571, 2103, 798, 4289, 1324, 3082, 811, 1133, 5152, 2376, 379, 1208, 2584, 697, 4248, 1558, 431, 2625, 607, 4173, 489, 2596, 1561, 866, 2161, 4260, 1139, 723, 2202, 1191, 4864, 486, 2127, 1249, 908, 2317, 4364, 1350, 718, 1330, 3090, 4370, 813, 1796, 2156, 476, 4614, 1181, 2626, 856, 1680, 2272, 4150, 839, 1353, 2214, 725, 4179, 1134, 2567, 698, 1141, 2600, 4153, 914, 1236, 2243, 752, 4617, 1195, 3200, 868, 1800, 5123, 2318, 819, 1354, 2689, 4208, 814, 1250, 439, 2571, 1573, 4231, 929, 2323, 1562, 490, 6160, 2628, 1411, 623, 2339, 4174, 1332, 671, 2107, 1240, 4385, 739, 3084, 1440, 916, 2217, 4290, 1295, 463, 2608, 1303, 4181, 843, 2162, 1182, 381, 4372, 2325, 1361, 497, 2204, 4618, 1574, 930, 2135, 1696, 4154, 821, 2245, 1142, 726, 4264, 3105, 1356, 1603, 2164, 5125, 961, 2218, 1564, 872, 2109, 4235, 1413, 492, 2579, 1197, 4195, 631, 2573, 1145, 729, 4182, 2690, 1577, 700, 2329, 4156, 1223, 443, 3137, 1808, 4376, 741, 2326, 1203, 845, 4185, 2574, 1252, 920, 2225, 4386, 1362, 382, 2341, 1336, 4625, 822, 2436, 1728, 2139, 6176, 1414, 851, 3092, 1198, 4620, 730, 2632, 1578, 498, 4292, 2817, 1605, 880, 5184, 2246, 1417, 742, 2220, 4237, 1307, 445, 2168, 1146, 4197, 2249, 471, 1472, 2384, 4243, 1377, 635, 3328, 1585, 4272, 932, 2110, 1227, 687, 4238, 2330, 1087, 903, 2191, 4626, 1364, 2151, 825, 4417, 1418, 2226, 500, 1551, 4127, 2342, 1606, 846, 3106, 4296, 1580, 745, 2141, 1205, 5129, 2692, 826, 1319, 2250, 4186, 732, 1309, 2640, 4641, 446, 1256, 2371, 1148, 4388, 3096, 962, 1229, 2440, 6147, 936, 1206, 2345, 4418, 475, 1667, 2818, 853, 4628, 2155, 1586, 867, 2228, 4359, 1310, 1609, 2199, 637, 4245, 1323, 3108, 907, 4198, 2257, 1378, 487, 2332, 4201, 1235, 695, 2696, 5126, 1425, 2142, 1209, 746, 4400, 2252, 1420, 828, 2346, 4392, 1368, 3079, 753, 4259, 1610, 2448, 854, 1669, 4188, 2656, 1617, 2400, 857, 4143, 1559, 2373, 504, 4363, 1264, 2581, 799, 3201, 4481, 1230, 1119, 2203, 4642, 255, 1351, 2258, 964, 6149, 2353, 1588, 909, 4420, 2595, 1824, 719, 2348, 5137, 1426, 3138, 1380, 4304, 477, 2157, 1331, 915, 4482, 2232, 1325, 2582, 4246, 638, 1441, 2585, 1237, 4249, 2163, 748, 1592, 4261, 2215, 944, 1856, 3584, 4202, 869, 2273, 1612, 4151, 1210, 2374, 491, 5130, 2354, 1670, 699, 2820, 4424, 1428, 1251, 2205, 4632, 754, 3083, 1920, 858, 4673, 2704, 1618, 2377, 4644, 478, 1442, 2158, 6208, 1326, 968, 2165, 1673, 4209, 2260, 383, 1795, 4250, 3112, 910, 2219, 4175, 1384, 1563, 2824, 815, 4365, 2378, 1135, 976, 5138, 2274, 1355, 2597, 4204, 1238, 870, 3140, 1333, 4674, 2586, 917, 1212, 4320, 2435, 1473, 2356, 4262, 727, 1241, 2264, 493, 4615, 3202, 1432, 873, 4648, 2464, 1633, 2319, 4291, 1620, 701, 2327, 5248, 1575, 2206, 931, 4366, 1674, 2385, 1253, 3091, 7168, 756, 1183, 2598, 4737, 860, 2720, 1444, 4619, 1334, 2166, 499, 4371, 2380, 1565, 731, 2627, 4676, 1797, 3085, 1634, 4387, 823, 2588, 1681, 4155, 2437, 922, 1357, 5132, 2221, 1143, 2169, 4265, 874, 1624, 3120, 4656, 918, 2601, 1363, 4210, 2247, 1242, 502, 2832, 4373, 1392, 2227, 933, 4252, 1676, 3086, 1254, 6153, 2276, 743, 1415, 4183, 2386, 1337, 2360, 4293, 760, 2752, 1474, 5153, 881, 2438, 1566, 4212, 3144, 1358, 494, 4266, 2222, 1257, 2602, 4157, 702, 2629, 1579, 4627, 1798, 2441, 921, 4621, 3329, 1199, 501, 4738, 2331, 1147, 2170, 4377, 1682, 2496, 876, 5185, 1636, 2401, 1365, 4374, 3093, 847, 1801, 2609, 4622, 992, 2251, 6150, 1244, 2111, 1338, 4273, 447, 2388, 1448, 4389, 3204, 1419, 2442, 4484, 733, 1697, 2575, 4187, 827, 2630, 1607, 5140, 2604, 1379, 934, 4680, 2229, 1311, 3107, 4865, 1207, 2343, 882, 4294, 1258, 2333, 937, 4268, 2280, 1149, 2172, 4216, 1581, 963, 3330, 4297, 1684, 2253, 1640, 6161, 2230, 747, 1366, 4432, 2691, 505, 2610, 5376, 1340, 3098, 1265, 4158, 855, 2334, 4378, 1802, 2633, 1587, 4239, 2347, 924, 3585, 4199, 1369, 734, 2402, 4274, 1476, 2259, 1421, 4390, 2449, 829, 1427, 5154, 2233, 1231, 3152, 4189, 965, 2444, 4740, 1698, 2392, 1582, 6154, 938, 2634, 1809, 4298, 2693, 1456, 3109, 4688, 884, 1381, 2641, 4419, 506, 2583, 5144, 1211, 2288, 1260, 4488, 2254, 749, 1688, 4393, 3097, 1648, 2143, 4866, 945, 2375, 1611, 4203, 2612, 1804, 4276, 966, 3094, 1729, 4247, 2848, 1150, 2450, 5156, 755, 2404, 1266, 6162, 859, 2355, 4305, 1589, 3208, 1422, 4380, 2349, 940, 2465, 4744, 1370, 2261, 4190, 1480, 830, 2616, 4300, 1382, 3332, 1429, 4394, 2880, 911, 2636, 5127, 1327, 1593, 4496, 2234, 871, 3336, 4704, 1268, 2694, 1619, 4448, 2452, 639, 6272, 2275, 1213, 1590, 4421, 2944, 888, 3110, 4629, 1700, 2642, 5249, 1385, 2466, 479, 4251, 2350, 1730, 3586, 4306, 1613, 946, 4401, 2697, 1239, 2819, 4643, 750, 2408, 4396, 1810, 2587, 1671, 5186, 3168, 969, 2159, 4205, 1372, 1443, 6156, 2379, 508, 2262, 4280, 1430, 3139, 4630, 1488, 2357, 861, 4633, 2236, 1704, 2497, 4211, 1825, 757, 4263, 3113, 1386, 2265, 5632, 1614, 2456, 4321, 970, 2657, 1433, 4422, 2644, 1594, 3216, 4402, 919, 2599, 4868, 1812, 1621, 2698, 6177, 1596, 2277, 4253, 875, 3100, 1243, 5131, 2207, 1335, 4752, 2468, 862, 2358, 4425, 1732, 3141, 4206, 1622, 2589, 758, 4213, 1625, 2821, 4308, 1675, 2658, 948, 5160, 3114, 1445, 4267, 2705, 1816, 2381, 6209, 977, 2167, 4872, 1826, 3588, 1635, 4426, 2648, 923, 4322, 2387, 1626, 2266, 4645, 1434, 972, 5188, 3121, 1255, 2416, 4634, 1712, 2700, 4483, 761, 2278, 1677, 4404, 3146, 1272, 4312, 2439, 877, 6164, 2361, 1393, 2498, 5250, 1214, 3344, 4512, 1388, 2590, 952, 4367, 2382, 1678, 4375, 2281, 1683, 495, 4254, 3232, 1359, 4433, 2603, 1504, 5139, 2822, 703, 2223, 4646, 1339, 3592, 4768, 1245, 2171, 935, 6400, 2706, 1394, 4214, 2660, 1637, 4428, 3360, 978, 2389, 4675, 1446, 2825, 5133, 1449, 2268, 1475, 4636, 3600, 883, 4485, 2362, 1638, 4269, 2472, 1567, 2443, 4217, 762, 3264, 5168, 1259, 2721, 6178, 1436, 2631, 503, 4649, 2403, 1367, 4295, 3616, 1396, 4880, 2335, 925, 2231, 4275, 1799, 2282, 5134, 1341, 3142, 4324, 1246, 2173, 878, 4434, 2605, 1450, 4408, 2708, 1477, 6168, 3116, 735, 2664, 4800, 1261, 2390, 4486, 1583, 2364, 5192, 1857, 3203, 4270, 993, 2289, 1828, 4650, 2826, 1736, 4677, 3153, 885, 4489, 2611, 1858, 2393, 5377, 1685, 2500, 4379, 939, 3122, 6180, 1832, 2445, 4218, 1803, 2451, 1641, 4544, 2255, 994, 4449, 3145, 1628, 5141, 2722, 1457, 4657, 2606, 980, 3087, 4299, 1744, 2833, 4159, 1840, 2480, 4436, 1860, 2405, 6151, 926, 3392, 5252, 1371, 2235, 1921, 4490, 2284, 764, 4623, 2712, 1267, 4678, 3205, 1686, 4652, 2672, 1478, 2635, 4277, 941, 3124, 5155, 1342, 2828, 6273, 1699, 2753, 4391, 967, 2174, 4381, 1642, 3095, 4328, 1922, 2290, 1805, 4220, 2613, 886, 5378, 1400, 1452, 4301, 3206, 831, 4278, 2446, 1689, 4739, 2394, 1760, 6210, 2504, 1591, 3456, 4658, 947, 2406, 5146, 1864, 2453, 4382, 1649, 3148, 4681, 507, 2351, 4395, 1262, 2617, 5633, 1383, 2292, 4450, 1481, 3209, 889, 4307, 2643, 1423, 6656, 2237, 1811, 4497, 3154, 1615, 4281, 2614, 984, 5200, 2724, 1702, 4492, 2409, 1458, 4440, 3128, 751, 4682, 2754, 1701, 4741, 2637, 1373, 3099, 6155, 1269, 2263, 5157, 942, 2834, 4689, 1482, 2695, 4631, 1690, 3169, 4336, 1644, 2396, 4302, 996, 2467, 5145, 1387, 3111, 4191, 1151, 2454, 6184, 1215, 2512, 4423, 971, 2728, 4660, 1806, 3331, 5142, 1431, 2849, 4896, 890, 2410, 1460, 4498, 3156, 1650, 4452, 2638, 1595, 4403, 2457, 509, 6212, 3210, 1489, 5256, 2618, 1705, 4397, 2836, 1270, 4513, 2645, 949, 4309, 3217, 1731, 4664, 2620, 1374, 5380, 2267, 1623, 4928, 3333, 973, 6274, 2359, 1692, 4684, 2756, 1814, 4282, 3101, 1484, 5384, 2646, 1000, 4742, 2649, 1273, 4500, 3115, 1706, 4323, 2699, 1597, 4992, 2469, 892, 6163, 2840, 1435, 5158, 3170, 1827, 4690, 2850, 1813, 4514, 2659, 950, 4398, 3587, 1733, 5634, 2650, 1389, 4745, 2458, 1464, 4867, 3160, 863, 6157, 2279, 2736, 4456, 1652, 4635, 3212, 1713, 5216, 2701, 1398, 4207, 2296, 759, 4427, 3102, 1447, 4310, 2417, 1490, 5187, 2238, 1817, 6192, 2412, 1008, 4405, 3218, 1274, 4284, 2702, 1395, 4545, 2707, 1505, 5161, 3143, 510, 4313, 2383, 1598, 4504, 2528, 3334, 6158, 1437, 2363, 4705, 1627, 4692, 2269, 979, 5264, 3337, 1390, 4647, 2418, 1492, 4746, 2661, 1679, 4325, 3233, 953, 5148, 2470, 1924, 6216, 2473, 1829, 4255, 3648, 1639, 4516, 2499, 4406, 2662, 763, 5189, 3117, 1708, 4637, 2591, 1734, 4869, 2283, 1453, 6401, 3172, 974, 4706, 2460, 1818, 5162, 2391, 1276, 4753, 2420, 4429, 1397, 3712, 4215, 2823, 1629, 5636, 2365, 954, 7169, 3123, 1872, 4696, 2270, 1714, 4435, 2474, 4314, 1737, 3220, 5169, 879, 2501, 4464, 1656, 2285, 4748, 3118, 1506, 4326, 2607, 1830, 6165, 2881, 5194, 981, 3147, 4487, 1451, 2852, 4409, 1928, 2760, 4546, 1438, 3338, 5392, 2882, 982, 4638, 2709, 6276, 1247, 3345, 4430, 1687, 2856, 4329, 1716, 2827, 5280, 1859, 3589, 4651, 927, 4870, 2665, 3176, 4271, 1643, 2652, 6179, 1496, 2481, 5640, 1479, 3234, 4219, 995, 4754, 2768, 1820, 4708, 2864, 1833, 5408, 3125, 2884, 6402, 1738, 4437, 2395, 1745, 4873, 3265, 765, 4316, 2945, 1861, 5648, 2291, 4410, 3224, 1740, 4520, 2710, 1888, 6170, 2502, 956, 4491, 3149, 5312, 1834, 2366, 4769, 1630, 2723, 4679, 3236, 1936, 4451, 2666, 5664, 1746, 2946, 6657, 887, 3840, 4383, 1720, 2829, 4279, 1401, 4330, 2424, 3340, 5190, 1459, 2476, 4221, 1841, 3346, 4653, 985, 6224, 2713, 1343, 4756, 2784, 3590, 5164, 1645, 4712, 2615, 1836, 4438, 2888, 997, 4412, 3126, 1508, 6181, 2673, 5251, 2286, 1454, 4337, 3155, 1862, 4874, 2407, 5201, 1691, 2505, 4659, 986, 3129, 4441, 2447, 6169, 1512, 2835, 4548, 1263, 3593, 5170, 1402, 4493, 2639, 3184, 4499, 1483, 2726, 4303, 943, 6166, 2482, 1646, 5193, 3207, 1651, 4770, 2725, 2397, 4654, 1461, 5135, 3150, 1404, 4881, 2293, 4528, 891, 2506, 6280, 3361, 1842, 4453, 2714, 5440, 1485, 3266, 4283, 1520, 2668, 4332, 1693, 4760, 2411, 3157, 6404, 998, 2175, 5253, 1703, 4720, 2239, 1748, 4683, 3348, 2830, 5172, 1865, 4876, 3594, 766, 6408, 2455, 1653, 4801, 2484, 4222, 3130, 1375, 5143, 2674, 4338, 1491, 2619, 4661, 1462, 3240, 5254, 2513, 6182, 511, 3211, 4494, 1761, 4442, 2729, 1275, 4552, 2294, 3171, 5504, 1486, 4454, 2755, 1466, 6658, 2398, 4501, 1465, 3158, 5196, 2647, 988, 4399, 3132, 4665, 1493, 2716, 4340, 1271, 6240, 2838, 3352, 5257, 1707, 2508, 4691, 1866, 4285, 2297, 3161, 5202, 1001, 4662, 2730, 1762, 6211, 3362, 1923, 4772, 2621, 4457, 2459, 1694, 5176, 3601, 4802, 1807, 2851, 4685, 951, 6185, 2837, 3596, 5147, 1873, 2757, 4311, 1844, 4882, 3268, 2413, 4743, 1752, 5217, 2488, 1952, 6288, 3213, 4444, 1002, 2676, 4515, 3173, 5159, 1815, 2737, 4502, 1391, 4560, 2422, 3219, 6172, 1925, 2471, 4776, 1654, 5379, 2514, 1709, 4897, 3248, 4458, 2841, 893, 5204, 3214, 6213, 1868, 2298, 4686, 2419, 4505, 1657, 3602, 5258, 1735, 4666, 2529, 3393, 6186, 1277, 4884, 2622, 975, 4693, 2461, 5265, 1715, 3103, 4668, 2651, 4315, 1848, 3272, 6660, 1926, 5381, 2414, 2516, 4407, 1710, 4804, 3162, 894, 5149, 2703, 4694, 3617, 1764, 6193, 2948, 4697, 1874, 2853, 5163, 3364, 4747, 1399, 2663, 4517, 1468, 7170, 3394, 2732, 4888, 1494, 5218, 2758, 1009, 4898, 3604, 4707, 2477, 1507, 5635, 3335, 6218, 1439, 2842, 4698, 2300, 4506, 1509, 3221, 5208, 1929, 4327, 2421, 3174, 4784, 1819, 6416, 2653, 955, 5260, 2896, 4749, 3177, 4344, 1497, 2738, 5150, 1658, 6304, 3376, 2761, 4465, 1768, 4286, 3368, 1876, 4460, 2680, 5266, 2530, 1984, 4750, 3235, 6664, 1004, 4755, 2854, 3164, 5191, 1889, 4431, 2475, 1717, 4576, 2952, 6432, 3119, 1821, 5382, 2462, 4411, 1930, 3339, 4317, 2271, 5385, 1010, 6672, 2711, 1739, 4466, 3457, 4709, 2740, 1831, 5281, 3618, 4518, 2883, 4521, 1498, 3396, 6336, 1660, 5696, 2667, 2520, 4547, 1718, 4710, 3280, 957, 5165, 2503, 6688, 3458, 4639, 1278, 2844, 4331, 1741, 5220, 2857, 3222, 4508, 1599, 6214, 2762, 4439, 3225, 1937, 4468, 2769, 5760, 1822, 3237, 4871, 2885, 4413, 983, 6188, 2764, 1835, 5171, 3178, 4318, 2912, 4522, 1403, 3127, 5268, 2858, 6275, 1721, 3400, 4549, 1455, 4333, 2654, 5166, 2960, 1631, 4655, 3608, 6225, 1513, 2770, 4929, 3649, 5195, 958, 4900, 2744, 3620, 4808, 1890, 6194, 2425, 5386, 1747, 2483, 4930, 3185, 4757, 1510, 5393, 2865, 3226, 6217, 1932, 4904, 2367, 4875, 1742, 3151, 5637, 2669, 4713, 987, 3341, 5224, 2860, 6159, 1837, 4700, 2532, 1500, 4529, 3180, 5282, 2478, 4816, 1880, 3650, 6464, 2886, 4912, 1863, 5173, 3296, 1749, 4932, 2715, 4443, 2536, 6277, 1012, 3238, 5313, 2287, 4993, 1722, 4339, 3591, 1938, 5272, 2426, 6196, 3624, 4758, 1776, 2507, 4550, 3267, 5197, 1892, 4414, 2670, 7172, 1843, 2675, 4771, 3342, 5284, 1838, 4714, 2485, 3713, 4994, 999, 6167, 2428, 5888, 1463, 3595, 4877, 2866, 4472, 1953, 6278, 3347, 2509, 5388, 1514, 4524, 2544, 5394, 3652, 4761, 1647, 2717, 6528, 1695, 4832, 3363, 5638, 2727, 1763, 4663, 3131, 4936, 2772, 6220, 1016, 3241, 5174, 2889, 4721, 1940, 4334, 2677, 5203, 1487, 3632, 6281, 2399, 4455, 1867, 4553, 3186, 5177, 2515, 1405, 4495, 3349, 6226, 2486, 4883, 1521, 3228, 5641, 2785, 4687, 767, 5232, 3159, 6200, 1954, 2299, 4774, 3269, 4530, 1845, 5255, 2510, 6171, 2490, 1750, 4773, 3188, 4445, 2489, 5198, 1985, 4341, 3242, 1896, 6241, 2517, 4554, 3133, 5409, 1516, 4762, 2295, 3603, 5314, 1655, 6183, 2731, 4716, 3597, 4459, 989, 2890, 5205, 3714, 6403, 1753, 4223, 2786, 4287, 2947, 1724, 5396, 3353, 4878, 1467, 6228, 2718, 5642, 3350, 1765, 4503, 2831, 4532, 3598, 5178, 1869, 6282, 2897, 4722, 3249, 1944, 4667, 2868, 5288, 3365, 6289, 1003, 4561, 2776, 3460, 5259, 1406, 4777, 2976, 4342, 3163, 6405, 1846, 5219, 2839, 1875, 4803, 2415, 4446, 3656, 7176, 1754, 5206, 2949, 3841, 4695, 1522, 5180, 2678, 4764, 3270, 6173, 1904, 4886, 2733, 3244, 5400, 990, 4556, 2892, 6187, 3192, 4345, 1766, 5209, 2681, 3273, 4778, 1469, 5410, 2759, 6242, 3408, 4669, 1495, 4507, 2301, 5649, 3134, 1659, 6659, 2739, 4899, 3354, 4885, 1956, 5644, 2872, 4805, 3215, 1711, 6232, 2950, 5316, 3175, 4461, 1927, 4536, 2734, 6284, 1005, 5261, 2788, 3250, 4724, 1849, 5221, 2898, 4785, 3366, 6174, 1524, 4470, 2423, 5267, 3165, 1870, 4519, 2492, 6290, 3716, 4562, 1769, 5296, 2518, 4889, 3274, 6215, 1850, 2531, 5262, 3664, 4346, 1756, 4467, 2463, 5650, 3395, 6406, 1470, 4577, 2533, 3464, 5441, 959, 4670, 2953, 6409, 3369, 4509, 1986, 5151, 2843, 4699, 3842, 6305, 1960, 2521, 5320, 3179, 4462, 1499, 4564, 2682, 5210, 3252, 6720, 1877, 4751, 2792, 5665, 3223, 1891, 4996, 2900, 6189, 3281, 4901, 3008, 5412, 1661, 4711, 3356, 7184, 2913, 5442, 1931, 4780, 3720, 2741, 4806, 1011, 6244, 3166, 5652, 2845, 4525, 1511, 5383, 3276, 6784, 2954, 4890, 1719, 4348, 3370, 5269, 2763, 1770, 4469, 3472, 6195, 2855, 5222, 1852, 4701, 3680, 4944, 2522, 6292, 1777, 5225, 3424, 4786, 2684, 5424, 1878, 3397, 6190, 2742, 4809, 1881, 5416, 3605, 4728, 2302, 6219, 1013, 4578, 3227, 5283, 2765, 4902, 1528, 6410, 3282, 5212, 2623, 3377, 4523, 1823, 5000, 2961, 6417, 3619, 5167, 1279, 4510, 2846, 5387, 3372, 6661, 1988, 4319, 2859, 4759, 3181, 5505, 1933, 6248, 2427, 4788, 3256, 1743, 5666, 2745, 4931, 3606, 6306, 1501, 5444, 2479, 4715, 2655, 4568, 2537, 6197, 1939, 5328, 3609, 4551, 2914, 5506, 895, 6337, 3187, 4892, 2771, 4905, 1662, 3239, 5270, 2534, 7200, 1772, 4810, 3297, 5273, 2956, 4817, 1968, 6296, 3398, 5285, 2766, 4933, 3378, 4812, 1893, 6221, 2861, 5226, 3844, 4960, 1515, 5175, 2524, 6308, 3229, 4906, 1723, 5448, 2904, 4702, 3728, 6912, 1778, 5008, 2887, 3401, 5656, 1882, 4818, 2773, 6412, 3182, 5697, 2746, 4792, 1006, 5668, 3189, 6418, 2962, 4473, 1502, 4531, 3284, 5233, 2800, 6662, 1992, 4913, 3243, 5274, 2916, 4415, 3848, 6198, 1407, 5199, 2867, 4717, 3402, 5389, 1934, 6227, 2862, 4908, 3298, 4580, 1839, 5228, 2487, 6201, 3621, 4526, 2000, 5698, 2977, 4934, 3610, 6665, 2538, 5344, 1894, 4763, 3459, 7171, 2671, 4584, 1941, 5286, 3380, 4335, 2719, 6256, 1014, 5639, 3288, 4474, 2787, 5672, 3488, 6279, 1751, 4555, 2964, 5315, 3343, 4718, 1517, 6222, 2511, 4723, 3351, 5390, 2891, 1897, 4533, 6433, 3230, 5761, 2429, 4476, 1725, 6338, 3409, 5643, 2545, 4914, 1955, 5395, 3622, 6229, 2978, 4557, 3744, 4592, 1780, 5700, 2869, 6420, 3190, 4765, 1884, 5411, 2774, 6666, 3404, 4775, 1523, 5179, 3651, 4820, 3009, 6202, 3612, 5289, 1755, 4937, 2920, 4725, 3461, 6312, 1017, 5680, 2540, 4447, 3245, 5234, 2679, 7173, 1847, 4563, 3193, 5397, 2777, 6283, 1946, 4534, 3625, 5276, 2748, 4833, 3271, 6243, 1898, 5207, 2491, 4347, 3856, 5317, 1942, 6230, 2789, 4558, 3251, 4538, 2893, 6204, 1526, 5236, 3300, 4537, 2968, 5290, 1957, 6424, 4565, 3410, 5181, 2430, 6233, 3384, 4343, 1767, 5651, 2870, 4779, 3776, 6434, 1784, 5645, 3462, 4938, 2899, 5762, 3246, 6673, 1905, 4834, 2778, 4995, 3626, 6668, 1018, 5401, 2546, 4766, 3653, 5398, 2928, 6340, 1518, 4879, 3465, 2790, 1726, 5646, 3355, 7232, 2493, 4945, 3194, 5297, 1945, 4916, 2519, 6285, 3520, 5413, 1525, 4824, 3425, 6245, 2683, 5508, 3633, 5024, 1900, 5211, 2980, 6291, 3275, 4887, 2735, 4463, 1871, 6320, 3135, 5704, 2951, 4997, 2016, 3412, 5889, 2873, 6286, 3466, 4726, 1471, 5318, 2548, 6674, 3599, 4781, 1757, 5292, 3654, 4940, 2894, 6465, 3628, 5240, 1851, 4729, 2793, 6175, 3253, 5321, 2874, 4807, 991, 5456, 3367, 6344, 2780, 4349, 1958, 5182, 3357, 7177, 2494, 4787, 3304, 5402, 1906, 4920, 3196, 6234, 3010, 5263, 3277, 4998, 1961, 6689, 2984, 5223, 3254, 4782, 2523, 4836, 1987, 6436, 3715, 5298, 2901, 4946, 1771, 6466, 3634, 5414, 2915, 4471, 3358, 6676, 1529, 5213, 3657, 4540, 2685, 5764, 3371, 6407, 1879, 4566, 2955, 5322, 3426, 6293, 2535, 4579, 1948, 5712, 3283, 4511, 2743, 6246, 1758, 5443, 3473, 4581, 3257, 6249, 2794, 5512, 1853, 5001, 3468, 7174, 2876, 5417, 3416, 4891, 1020, 5890, 2801, 6448, 3658, 4569, 2902, 5227, 1989, 6440, 3717, 4730, 3665, 5300, 1962, 6307, 2905, 4840, 3607, 5271, 2552, 4948, 1908, 6236, 3312, 5329, 2847, 5056, 3278, 6191, 1530, 5404, 3167, 4961, 2303, 6411, 3399, 5768, 1773, 4789, 3012, 6529, 3636, 5214, 2957, 4893, 1969, 5324, 3872, 6690, 2767, 5002, 3474, 5418, 1990, 6468, 3428, 4811, 2525, 5520, 3379, 7185, 1779, 4903, 2963, 5728, 3373, 4570, 2686, 6352, 5472, 1883, 4732, 3489, 6530, 3285, 5445, 2796, 4790, 1964, 6294, 3640, 5653, 2992, 4350, 3904, 6297, 1854, 5275, 2917, 4813, 3660, 6309, 3258, 5330, 1935, 4671, 2539, 5425, 3718, 6250, 2747, 5009, 1007, 5667, 3476, 6199, 4894, 3299, 5420, 2802, 7178, 1895, 4907, 3968, 5229, 2906, 6472, 3666, 4475, 1663, 5304, 2526, 6680, 3490, 4793, 3374, 5654, 1912, 4527, 3016, 6721, 3721, 4703, 2431, 4585, 6692, 1503, 5657, 3843, 4962, 2958, 6257, 3432, 5235, 1970, 4819, 3611, 6298, 2863, 5287, 3183, 4582, 1774, 6223, 3024, 5345, 3403, 5004, 3286, 6413, 5446, 1993, 4814, 2918, 5426, 3381, 7186, 2965, 4909, 1532, 5892, 3260, 6252, 3521, 4572, 2775, 5277, 1885, 6722, 3289, 4952, 5776, 2541, 6368, 3480, 4935, 1781, 5449, 2921, 6310, 3681, 4821, 3668, 5230, 1994, 6663, 2749, 4794, 3623, 5237, 6696, 2979, 5010, 3722, 5332, 1943, 6339, 3301, 4848, 2804, 5291, 3231, 7296, 1015, 4964, 2908, 5896, 3492, 6414, 4915, 3382, 5450, 1899, 6785, 2547, 4910, 3613, 5346, 2779, 4535, 1886, 6667, 3845, 5669, 5025, 3682, 6419, 2871, 5658, 3729, 4586, 1782, 6724, 2970, 5507, 3405, 4719, 3191, 6435, 1972, 5428, 4767, 2922, 6203, 3672, 5336, 2966, 4835, 2001, 7180, 3411, 5536, 3290, 5012, 2550, 6313, 5391, 1947, 4559, 3440, 6704, 2981, 5399, 3724, 4939, 3302, 6258, 1996, 5278, 4477, 2791, 6421, 3463, 5457, 3385, 4593, 1785, 6300, 2808, 5670, 3522, 5026, 6231, 2929, 5792, 1901, 4917, 3614, 6341, 3406, 5238, 2542, 4822, 3305, 7201, 5452, 1976, 5699, 2750, 6260, 3627, 5057, 3846, 6314, 1519, 5660, 2969, 4968, 6205, 3247, 5509, 2549, 4588, 3195, 6675, 1727, 5293, 3730, 4727, 6669, 2924, 5241, 3684, 4825, 1959, 6786, 3413, 5673, 2895, 4796, 3849, 6425, 5319, 3040, 4539, 2002, 7233, 3292, 5904, 3386, 4837, 2495, 6422, 5299, 1019, 4941, 3496, 6670, 3467, 5348, 2781, 5016, 6321, 3745, 5458, 1907, 4478, 2875, 6437, 3655, 5432, 3427, 4918, 6532, 1786, 5824, 2982, 6235, 3359, 5510, 3255, 4947, 2930, 7188, 5294, 1527, 4826, 3306, 6728, 2985, 5674, 3197, 4594, 6913, 1949, 5701, 3629, 4976, 3011, 6342, 3732, 5513, 3688, 4838, 6316, 1902, 5403, 2795, 4541, 3414, 6264, 2553, 5242, 6345, 3388, 4567, 1759, 5568, 3313, 6480, 2903, 5473, 4731, 3850, 7424, 2017, 5681, 3635, 5028, 2972, 6206, 5323, 3417, 4783, 2782, 6426, 1909, 5183, 3524, 4999, 6287, 3469, 5460, 2877, 6247, 3475, 4921, 1963, 5514, 6322, 3279, 4596, 3013, 5647, 3746, 6438, 2018, 5702, 4942, 3630, 7202, 2986, 5676, 3857, 4841, 3504, 6237, 5301, 2004, 6788, 2932, 4922, 3429, 5415, 6346, 2554, 4828, 3259, 5405, 1950, 6736, 3308, 4542, 5352, 2797, 6467, 3736, 5244, 3696, 7192, 5058, 1788, 5325, 2993, 6536, 3659, 5032, 3852, 5302, 6441, 3014, 4571, 1965, 5763, 3777, 6914, 4949, 3198, 6251, 2803, 5682, 3314, 4963, 1991, 6324, 5406, 2907, 5705, 3637, 6295, 3470, 4733, 5419, 2988, 7204, 1021, 5003, 3418, 6353, 5474, 3528, 4583, 2878, 6428, 1910, 5331, 4791, 3430, 6792, 3477, 5521, 2959, 6238, 3375, 5305, 4842, 1855, 6348, 3641, 5516, 2919, 4924, 6442, 3316, 5464, 3667, 7175, 1971, 4849, 5706, 2687, 6544, 3261, 4950, 3638, 5765, 6752, 2936, 5713, 1531, 6496, 3748, 4953, 5655, 3433, 6469, 2527, 4600, 3778, 5360, 6677, 1913, 4895, 3661, 7297, 2994, 5326, 5215, 3287, 6299, 2798, 4351, 5447, 3858, 6354, 2008, 5060, 3719, 6449, 5684, 3017, 5005, 3420, 6691, 3491, 5920, 4815, 1775, 6444, 2556, 5522, 3478, 7234, 5476, 3536, 4573, 2909, 6253, 5427, 1966, 5011, 3752, 6328, 3873, 5421, 6678, 2805, 4734, 3434, 5537, 2020, 6681, 5333, 3662, 6259, 3018, 4844, 5688, 3481, 6311, 3642, 5040, 1995, 5952, 7680, 2967, 4965, 3860, 6369, 3669, 5708, 5306, 3644, 6470, 2923, 4587, 6450, 1914, 5766, 3291, 4795, 3383, 6916, 5524, 2910, 5347, 3780, 6301, 4850, 1533, 7179, 3670, 6016, 2806, 4954, 6800, 3673, 5714, 3723, 6473, 4574, 1973, 5538, 2996, 6254, 5422, 3493, 5064, 3864, 6261, 3025, 5769, 6356, 3874, 4479, 1997, 5891, 7208, 3683, 5006, 2971, 6315, 3674, 5480, 5659, 3482, 6920, 2024, 4911, 6474, 3020, 5231, 3303, 5072, 6370, 3760, 5451, 2809, 6693, 5334, 1916, 4966, 3725, 7236, 3320, 5429, 6682, 2925, 5013, 3441, 5308, 6531, 3262, 5569, 1974, 6452, 4823, 3436, 5337, 3000, 6360, 4589, 3726, 7298, 3731, 5528, 4969, 1887, 6560, 2543, 5729, 3407, 6415, 5716, 3552, 4797, 2751, 6423, 5671, 3387, 6302, 1783, 5027, 5770, 3293, 6481, 2983, 5349, 7187, 3442, 4852, 3685, 5279, 6694, 3026, 4956, 1022, 6816, 5540, 3494, 5430, 3497, 6262, 4595, 3523, 6476, 2931, 5661, 4827, 2032, 6723, 3686, 5893, 7181, 3615, 5730, 2810, 4919, 6684, 3307, 5777, 3484, 6533, 5018, 1534, 5453, 2551, 6317, 5239, 3415, 6265, 3444, 4970, 5720, 2973, 7216, 3847, 5014, 6697, 2003, 5459, 3389, 6343, 5338, 3294, 4598, 2926, 6928, 5488, 3498, 6323, 3525, 5029, 5772, 1977, 7182, 2783, 5350, 6372, 3309, 4839, 3631, 5511, 6482, 3905, 5433, 1787, 6456, 4856, 3041, 6848, 5570, 3876, 4977, 3784, 6534, 5662, 2933, 7240, 3906, 5454, 4590, 1998, 6318, 3733, 5353, 6698, 2987, 4798, 3880, 6725, 5675, 3851, 5894, 6537, 3689, 5017, 1978, 7425, 5295, 3042, 4597, 3676, 6427, 5243, 3505, 6266, 3028, 5778, 6592, 3792, 4972, 1903, 5732, 6497, 3888, 5461, 7189, 3908, 4943, 2974, 5897, 6705, 3419, 5088, 3969, 6347, 5340, 2005, 6207, 5434, 2812, 4543, 3315, 6484, 5544, 3734, 7300, 3526, 5515, 6538, 2989, 4829, 5793, 2006, 6671, 3390, 4923, 6726, 3747, 5703, 3015, 6700, 5475, 3690, 5030, 6325, 3970, 5407, 1951, 7203, 5303, 3853, 6439, 2934, 4978, 5354, 3448, 6429, 5033, 3500, 6376, 2879, 5245, 6268, 3737, 5677, 2019, 5059, 7426, 3808, 5780, 6349, 3639, 5736, 2995, 6326, 4843, 3912, 5462, 6787, 3697, 4601, 1789, 6706, 5436, 2555, 7194, 5361, 3310, 4951, 3431, 6430, 5898, 3529, 6729, 5683, 2937, 6443, 1980, 5020, 7681, 3471, 5465, 4830, 3859, 6498, 3663, 5572, 6355, 3032, 5517, 6545, 3750, 4925, 3506, 5523, 6329, 1911, 5327, 7248, 2799, 5061, 3749, 6540, 5794, 3421, 6488, 5678, 3317, 5034, 2990, 6730, 5905, 2009, 6789, 5552, 3530, 7205, 3738, 4980, 5477, 3692, 6737, 4602, 3044, 6679, 3435, 5307, 6384, 3199, 5356, 6350, 2021, 4845, 3263, 5784, 7193, 3019, 5744, 6239, 3854, 5041, 6471, 3479, 5707, 2938, 6708, 5900, 2010, 5062, 7190, 3508, 5825, 3698, 6944, 5246, 3643, 6546, 4851, 2557, 6500, 5362, 3537, 4955, 3753, 6451, 5685, 1967, 7304, 5518, 3318, 6445, 5036, 2997, 6561, 3779, 5466, 6357, 3422, 5576, 4926, 3671, 6712, 5478, 3021, 7428, 1915, 5525, 6976, 3740, 5007, 6732, 3862, 5423, 5689, 3532, 6330, 3048, 4967, 7432, 3321, 5364, 6790, 3754, 5715, 6548, 2022, 4735, 3645, 6371, 5309, 2940, 5686, 7040, 3483, 4984, 7206, 3875, 5796, 6738, 3861, 5481, 1790, 6562, 4575, 2998, 6446, 5826, 3781, 7682, 5709, 3437, 5042, 3512, 6793, 5335, 2911, 6915, 4846, 3700, 6504, 5906, 1535, 6683, 5767, 3761, 7264, 3446, 5065, 6255, 2807, 5468, 5539, 3495, 6475, 4604, 3538, 6358, 5526, 3865, 7235, 5584, 3056, 6453, 1023, 4957, 6332, 3322, 5800, 6593, 3443, 5921, 4853, 3553, 7209, 5482, 2558, 6361, 5710, 3646, 6552, 3485, 5066, 6753, 2012, 5529, 6740, 3675, 5690, 7312, 3027, 5015, 6695, 3438, 5908, 5717, 3540, 6794, 3727, 5692, 6373, 3001, 4971, 7196, 2025, 5339, 6303, 3972, 5431, 6564, 3877, 4958, 6454, 3687, 5828, 7237, 2811, 5718, 6685, 3756, 4854, 3782, 5721, 6917, 1975, 5771, 6754, 3501, 5044, 7210, 3022, 5541, 6801, 3866, 5912, 6477, 3324, 5073, 6263, 3445, 5922, 7684, 3677, 5731, 6744, 3002, 5019, 6483, 2026, 5722, 3920, 6362, 5530, 3762, 5068, 7217, 3785, 5351, 6512, 2927, 5808, 6796, 3704, 4857, 6374, 3554, 5773, 7242, 1917, 5368, 6535, 3878, 4973, 6457, 3029, 5489, 6594, 3499, 5310, 7440, 3976, 5484, 6686, 3486, 5048, 6478, 3030, 5774, 6377, 3295, 5779, 1999, 4591, 7328, 3735, 5455, 6699, 3764, 5600, 6918, 3907, 4799, 6319, 2975, 5435, 7688, 3691, 5341, 6267, 3544, 5031, 6802, 3527, 5490, 6756, 1918, 5733, 7456, 3043, 5074, 6485, 3868, 5542, 6921, 3881, 5545, 6364, 3786, 5571, 7696, 3793, 4979, 6458, 2813, 5734, 6568, 3909, 5663, 6539, 2033, 4858, 7360, 3788, 5355, 6817, 3936, 5532, 6727, 3004, 4599, 6499, 3882, 5463, 7712, 3678, 5492, 6431, 3984, 5021, 6327, 3794, 5895, 6378, 1979, 5437, 7238, 2935, 5342, 6269, 3768, 4974, 6701, 3449, 5546, 6804, 5573, 3507, 7212, 4831, 3889, 6760, 5357, 3033, 6486, 5679, 3391, 6460, 5953, 2028, 7299, 5089, 3693, 6385, 5924, 3884, 6922, 5832, 3045, 7249, 4981, 3556, 6707, 5954, 3502, 6489, 5781, 3910, 6596, 5035, 3739, 7218, 5928, 2034, 6541, 5899, 3034, 6547, 5737, 6351, 3560, 5090, 7241, 3311, 5724, 6818, 3450, 5553, 6702, 3531, 5076, 7183, 2991, 5840, 6929, 3694, 5936, 6576, 1981, 5956, 6501, 3699, 5022, 7488, 3509, 5467, 6331, 6017, 3452, 6380, 4860, 2939, 6808, 5363, 3890, 7301, 5782, 3533, 6768, 5574, 3568, 6731, 5037, 3741, 7220, 5438, 2007, 6924, 5795, 6849, 3046, 5063, 6270, 3751, 5738, 7191, 3796, 6018, 6386, 3913, 5901, 6709, 2814, 4982, 5496, 3701, 5548, 7302, 4927, 3423, 6542, 5785, 3539, 6490, 5856, 1982, 6600, 5687, 3510, 7552, 5043, 2559, 6502, 5960, 6549, 3809, 5745, 7244, 3323, 4603, 6447, 3534, 5358, 6713, 3514, 5479, 6388, 3513, 5577, 7305, 4985, 2011, 6739, 5519, 3036, 6333, 5907, 3541, 7250, 5711, 3319, 6710, 5080, 3755, 6820, 5798, 6505, 3914, 5554, 7224, 3049, 4847, 6850, 3810, 5797, 6733, 3971, 5469, 7195, 5365, 3742, 6359, 5038, 2036, 6930, 5578, 3855, 6791, 5786, 2999, 7265, 5740, 6492, 3921, 5092, 6563, 3892, 5483, 7207, 3800, 5247, 6550, 5311, 4000, 6608, 5067, 3050, 6824, 5902, 3863, 7427, 5527, 2023, 6945, 4986, 6506, 3439, 5556, 7252, 3973, 5746, 6734, 3702, 5691, 6553, 4605, 3757, 7306, 5585, 2941, 6714, 5801, 3916, 6932, 5366, 6741, 3705, 5045, 7313, 3783, 5827, 6716, 2040, 5470, 6363, 5719, 3325, 7429, 5069, 3023, 6455, 5788, 3763, 6852, 5910, 7197, 3896, 5580, 6742, 3974, 5096, 6745, 5369, 3758, 7211, 5802, 2942, 6795, 5693, 3812, 6565, 4988, 6936, 3922, 5531, 7266, 1791, 5923, 6946, 3447, 5909, 6755, 5046, 3516, 7683, 5829, 3542, 6746, 5485, 6554, 3057, 5560, 7256, 3555, 4959, 6375, 3487, 6832, 5748, 7308, 3557, 5809, 6797, 3977, 5494, 6392, 4855, 3867, 7198, 5543, 2013, 6513, 5586, 6334, 3003, 5913, 6508, 3545, 5104, 7314, 3706, 5370, 6798, 5491, 3816, 6803, 5601, 3924, 7239, 4606, 6479, 4032, 5694, 6624, 3052, 7430, 5533, 6459, 3937, 5723, 6365, 3765, 5075, 7433, 5486, 2027, 6514, 5588, 3869, 6757, 5775, 7329, 3978, 5049, 6566, 3058, 6020, 6569, 5925, 3787, 7744, 5735, 3879, 6595, 6758, 4859, 3546, 7213, 5804, 3708, 6687, 5830, 6379, 3766, 5549, 7268, 3005, 5070, 6556, 5914, 2014, 6487, 5372, 3326, 6516, 5493, 7808, 3789, 6919, 5725, 6461, 3647, 5050, 7219, 3985, 5968, 6366, 5810, 3870, 6570, 5833, 3031, 7316, 4975, 6597, 3883, 5752, 6381, 3451, 7214, 5602, 6703, 3769, 5926, 6977, 5077, 3503, 7243, 5547, 2029, 6948, 6024, 6856, 3679, 5534, 7434, 3561, 6978, 5078, 6805, 3006, 5343, 7441, 5783, 3938, 6952, 5812, 3795, 6923, 5955, 7685, 3558, 5023, 6761, 3980, 7272, 5739, 6748, 3790, 5592, 6577, 5575, 3035, 7330, 5091, 3885, 6864, 5916, 6960, 1983, 5929, 7221, 6980, 3548, 5834, 6491, 3928, 5841, 7361, 4861, 3911, 7041, 5957, 6387, 3797, 7320, 5836, 3060, 6806, 5984, 6598, 3770, 5052, 7245, 5930, 3986, 6462, 5726, 6819, 3824, 7332, 6032, 3940, 6762, 5842, 7042, 3891, 4983, 7936, 5816, 2035, 6925, 5497, 3886, 6520, 7436, 5555, 3047, 6572, 5937, 7442, 3511, 5081, 6809, 5439, 4001, 6880, 7686, 5741, 3562, 6711, 5932, 3695, 6984, 5093, 7222, 3743, 5604, 6769, 6382, 3811, 5550, 7251, 5958, 3064, 6503, 5787, 3988, 6601, 5082, 7225, 3535, 6543, 5608, 6931, 2037, 5359, 7689, 5498, 3915, 6735, 7280, 5579, 3453, 6822, 5039, 3569, 6578, 5742, 7303, 2815, 5747, 6821, 6493, 4002, 5557, 7246, 5500, 3893, 6389, 4987, 6602, 3798, 7457, 5938, 6810, 4033, 5581, 7362, 5616, 3944, 6764, 5789, 3564, 6507, 7253, 5094, 3703, 6271, 5799, 6335, 1919, 5844, 7444, 6926, 3037, 5961, 7690, 4862, 3801, 6551, 5749, 6580, 3772, 7226, 5471, 6770, 3515, 5587, 6715, 5558, 3813, 7336, 6609, 4607, 3917, 7307, 5857, 6825, 3992, 5371, 6390, 7267, 3051, 5582, 6851, 5562, 3454, 6494, 5561, 7254, 3894, 6743, 5084, 7228, 3923, 5589, 6812, 5367, 3802, 6934, 7448, 5803, 2030, 6604, 5962, 6393, 3570, 7257, 5097, 6826, 3952, 5858, 7458, 6019, 3038, 6717, 6555, 5790, 3814, 7697, 5903, 6947, 3517, 5047, 6933, 7692, 3543, 5969, 6853, 5940, 3707, 7364, 6509, 5848, 4004, 6584, 6048, 7309, 3759, 5098, 6772, 7269, 3975, 5911, 6833, 5487, 3053, 6518, 7315, 6021, 3897, 6567, 5750, 6610, 2038, 5805, 7344, 6937, 3572, 4989, 7310, 5964, 3918, 6394, 6515, 5753, 3817, 7698, 5831, 6625, 7489, 3898, 5373, 6718, 5071, 3804, 6557, 5811, 7199, 3518, 6747, 5944, 7368, 3007, 6022, 6510, 6612, 4034, 5806, 7258, 4990, 4008, 6799, 7713, 5860, 3547, 7044, 5970, 6949, 7460, 3925, 5495, 6759, 5564, 3939, 7490, 6828, 5590, 2041, 6854, 5105, 7700, 3709, 6573, 5603, 7431, 5535, 3979, 6938, 6396, 5605, 3059, 7317, 6025, 6517, 3559, 7270, 5915, 6749, 3767, 5051, 6992, 7273, 5593, 3818, 6834, 5754, 7472, 3900, 6857, 5864, 7464, 3825, 5972, 6776, 6626, 3926, 6080, 7331, 5100, 6950, 3929, 7260, 5985, 6571, 3061, 5813, 7048, 7215, 3576, 5917, 6558, 6026, 7435, 3871, 6367, 5106, 6807, 3327, 5835, 7553, 6836, 2042, 5927, 7714, 6979, 5594, 4036, 7492, 5756, 6763, 3981, 6616, 5814, 7376, 3791, 5053, 6599, 7554, 5374, 3549, 6940, 5837, 6953, 3987, 7318, 5695, 6858, 7321, 2943, 6033, 6865, 5918, 3710, 7333, 6981, 5079, 3820, 6860, 5931, 7274, 7008, 4016, 5499, 7223, 6954, 3941, 5817, 7496, 5551, 6750, 3563, 7056, 5727, 7704, 3771, 5609, 6866, 7745, 5054, 3826, 6840, 7716, 5986, 3930, 6521, 5843, 6579, 7281, 2015, 5606, 6961, 7322, 3054, 6028, 6463, 5838, 7247, 3550, 6765, 5083, 7437, 4040, 6956, 5933, 6628, 5596, 3455, 7276, 6574, 5976, 7746, 3982, 6982, 5959, 7392, 3887, 5845, 6811, 6632, 5108, 4048, 7334, 6383, 5818, 3942, 7687, 6034, 6522, 7720, 3989, 5872, 6603, 7363, 5988, 3062, 6766, 5939, 6771, 3799, 7438, 5934, 6581, 7809, 3565, 5095, 6524, 5559, 3945, 7691, 6962, 6049, 7443, 3773, 6605, 5610, 6640, 7748, 4003, 5743, 6813, 5791, 7459, 2044, 6823, 5859, 7227, 3828, 6868, 5112, 7337, 6985, 3932, 6036, 6773, 5583, 7728, 3571, 6495, 5963, 7282, 3803, 6611, 5501, 7445, 6582, 3065, 5617, 7324, 6881, 4863, 3895, 7255, 6050, 6395, 7365, 3994, 5941, 6606, 6586, 5846, 3946, 7284, 6585, 6081, 3990, 7338, 5992, 6613, 7229, 3574, 5612, 6391, 7699, 5751, 4005, 6827, 7693, 5085, 6986, 3815, 7810, 5849, 6882, 7043, 3832, 5820, 7449, 5563, 6814, 3953, 7446, 5861, 6927, 7694, 3066, 5965, 6993, 7345, 6040, 3566, 6964, 7461, 5099, 2031, 6872, 7556, 5502, 7072, 3774, 7259, 5942, 6935, 5971, 3993, 6511, 7752, 5850, 7045, 3573, 7937, 5618, 6774, 7366, 3948, 6000, 6829, 7340, 5086, 3919, 6988, 7288, 5862, 6777, 4064, 7369, 5565, 6855, 7504, 3519, 5591, 6397, 7230, 5755, 3805, 6835, 7450, 6052, 6968, 3899, 7311, 5807, 7046, 7271, 6023, 3039, 6830, 5101, 6884, 7346, 4006, 5945, 6994, 7462, 5620, 3954, 6519, 7261, 5966, 6588, 4009, 7812, 5865, 6614, 7370, 4035, 5946, 6627, 7760, 5852, 3819, 6559, 7491, 5566, 6629, 3577, 7560, 5055, 7049, 7465, 6082, 3927, 6939, 7938, 6056, 6617, 2039, 7275, 5595, 6778, 7348, 3996, 5973, 6888, 7319, 5987, 3806, 6996, 7377, 7104, 5757, 7452, 3901, 7009, 6027, 7816, 6837, 3068, 5107, 7262, 6941, 5607, 4037, 7372, 7050, 5815, 7466, 6859, 4010, 5866, 7568, 6951, 5948, 3956, 7776, 6618, 5873, 7520, 3578, 6780, 5974, 7493, 6838, 5977, 3821, 7701, 6398, 5109, 7323, 4017, 6861, 5624, 7378, 6719, 4038, 7473, 5919, 7057, 7715, 5375, 3827, 6942, 7468, 6084, 6955, 3931, 7277, 6029, 6523, 7352, 5839, 4012, 6841, 7702, 5597, 6575, 3902, 6751, 6633, 6035, 7705, 7010, 3983, 4991, 7283, 6867, 5758, 3055, 7335, 6630, 5868, 7393, 7052, 3943, 6064, 7494, 6862, 7474, 3711, 5989, 6957, 7940, 5611, 6620, 3960, 7325, 5819, 7000, 7824, 5874, 2043, 6983, 7497, 5978, 6869, 3551, 7278, 6842, 5102, 7285, 7058, 4018, 5598, 7380, 6896, 6088, 7339, 3822, 7012, 7944, 5503, 6963, 4041, 7498, 6030, 6958, 7394, 5935, 3580, 6583, 7717, 6096, 7073, 7706, 3933, 6634, 5990, 7555, 6767, 6037, 3829, 7476, 6815, 5110, 7384, 6883, 4042, 7584, 5847, 7060, 7439, 3991, 5613, 6607, 7447, 6987, 5993, 3063, 7326, 6525, 5821, 7505, 6641, 3947, 6051, 7718, 7074, 7840, 5876, 3934, 6965, 7286, 5980, 6870, 7500, 3830, 5619, 7747, 7105, 7708, 5851, 4020, 7016, 7557, 5113, 6636, 7341, 4049, 6775, 5943, 7289, 6873, 6042, 3995, 7721, 6844, 7367, 5994, 6587, 4044, 7952, 6038, 6885, 7347, 6989, 3833, 5622, 7396, 7064, 6053, 7506, 3949, 6526, 7480, 5863, 6966, 7872, 4024, 5880, 7558, 6995, 7342, 6001, 3567, 6874, 7722, 5114, 6642, 7749, 2045, 7024, 5614, 7561, 6886, 5822, 7451, 3775, 6589, 7290, 6041, 6615, 7616, 4007, 5621, 7521, 6779, 7729, 5996, 4050, 7076, 7371, 6831, 5967, 7231, 3067, 7047, 6112, 7508, 6969, 7562, 5567, 3955, 6644, 7695, 5853, 7750, 6990, 3834, 7724, 5947, 6889, 7349, 6970, 5087, 3575, 7463, 6876, 6054, 7453, 6590, 3997, 7400, 6002, 7292, 7106, 7373, 3950, 6057, 7080, 7350, 6619, 6083, 7811, 3807, 6997, 5867, 7730, 7011, 7454, 4065, 5625, 7753, 6781, 7467, 5975, 7051, 3957, 7522, 6631, 6044, 7379, 6839, 4011, 5854, 7569, 7353, 6890, 5949, 7564, 4066, 6972, 7512, 5116, 6897, 7754, 6998, 4052, 6085, 7813, 7761, 6058, 7001, 3998, 7703, 6648, 6004, 7408, 6943, 7374, 3836, 5626, 7263, 6399, 7495, 5869, 7108, 4013, 7732, 7053, 6065, 7968, 6863, 7570, 4039, 6086, 7524, 6621, 7475, 5875, 7059, 3069, 7469, 6782, 5979, 7585, 7381, 3958, 6892, 6060, 7736, 7088, 8000, 5950, 3903, 7013, 7756, 7354, 6031, 6635, 7814, 4019, 6843, 5103, 7572, 7395, 6898, 5991, 3579, 8064, 7002, 7762, 5759, 6622, 7586, 3961, 7470, 6008, 7112, 7817, 6527, 5599, 7939, 2046, 7054, 7528, 6066, 7707, 6959, 7279, 4056, 5870, 7120, 7499, 7382, 6089, 7014, 3823, 7477, 7061, 5628, 7356, 7617, 6871, 4014, 5981, 7385, 6637, 7576, 5877, 7017, 4068, 7777, 7764, 6090, 6845, 7719, 7075, 7818, 4043, 6039, 7397, 6900, 7327, 5111, 7004, 3962, 7588, 7478, 5995, 6643, 7709, 6875, 3581, 5982, 7941, 7778, 6967, 7825, 5878, 7066, 4021, 7501, 7287, 6068, 7018, 7768, 7062, 4045, 6097, 7507, 7386, 6646, 6043, 7536, 7077, 4072, 7820, 7398, 6092, 6887, 7559, 7481, 5881, 3964, 6904, 7618, 7025, 5997, 7710, 7502, 4022, 6638, 7401, 6072, 6846, 7723, 7942, 5615, 3935, 7065, 7343, 6645, 7291, 5823, 7826, 7020, 3831, 7780, 6055, 7509, 6991, 7945, 7136, 6098, 3070, 7388, 7482, 6591, 5115, 7592, 7563, 6877, 4080, 7841, 6003, 6971, 7751, 7523, 5882, 7078, 3582, 7455, 7351, 7026, 5623, 7402, 7081, 7293, 4051, 6045, 7725, 7107, 7828, 7784, 5998, 6891, 4025, 7510, 6649, 7484, 5855, 7409, 6999, 7946, 3835, 6113, 7731, 7068, 7513, 6878, 6005, 7620, 4046, 7565, 6973, 7571, 6059, 7375, 7109, 7842, 4026, 6114, 7726, 7082, 7953, 7600, 6100, 7028, 7525, 3951, 6650, 7355, 6046, 7404, 6893, 7832, 7792, 4053, 5884, 7089, 7755, 7948, 7110, 6061, 7873, 7294, 4054, 6899, 7410, 6087, 7003, 7733, 7566, 7084, 3999, 5117, 7514, 7624, 6974, 6006, 7526, 7573, 7055, 4067, 7471, 5951, 7737, 7015, 7412, 7763, 6067, 6783, 3837, 7357, 7734, 7032, 5627, 7844, 7529, 6623, 4028, 7874, 6009, 7757, 7090, 7383, 6894, 7954, 6104, 3959, 7815, 7113, 7516, 7587, 5871, 6652, 7574, 7632, 4057, 7005, 6062, 7848, 7969, 6901, 7530, 6116, 7758, 7114, 4069, 7577, 7738, 6091, 7063, 7956, 7765, 7740, 7019, 2047, 6010, 7387, 7479, 7006, 7876, 5629, 7766, 6902, 4058, 7769, 7819, 6069, 7092, 7589, 7960, 7121, 7970, 4015, 6093, 7779, 7067, 7770, 7578, 6120, 7116, 7399, 7856, 3963, 6905, 6012, 7821, 7416, 7021, 7537, 7358, 6070, 4070, 7532, 7096, 7822, 7827, 5983, 6639, 7503, 7648, 6847, 3838, 7483, 5879, 7389, 7079, 7538, 7781, 7122, 5118, 7590, 3583, 7593, 7619, 7027, 6128, 7782, 7711, 6906, 7403, 7580, 3071, 5630, 6647, 7511, 7540, 7069, 7943, 6099, 7485, 7390, 4060, 7022, 7594, 7621, 6073, 6879, 7405, 7727, 8001, 5883, 4073, 7137, 7972, 7880, 7029, 8002, 6094, 7829, 7083, 7976, 4023, 7947, 7785, 6074, 7138, 7772, 7601, 7124, 7888, 5999, 7984, 4074, 8004, 7070, 7515, 8065, 6101, 6908, 7411, 7830, 7622, 7085, 3965, 6102, 7486, 7843, 7111, 7786, 8066, 6047, 7949, 7030, 4047, 7544, 7596, 6975, 7833, 6115, 7904, 7735, 7091, 8008, 7793, 3966, 5885, 6651, 7406, 7527, 7625, 7033, 6076, 7567, 7955, 7759, 4081, 7128, 7846, 7602, 6007, 6895, 7845, 7517, 7413, 7086, 6105, 4027, 7626, 7834, 7788, 7140, 7531, 7295, 6117, 7359, 7115, 7950, 7575, 4076, 7034, 6106, 7604, 7794, 7739, 6653, 7633, 7849, 6063, 7414, 4082, 7093, 7875, 7518, 7767, 7117, 6011, 7836, 7958, 7628, 7144, 7417, 4029, 7850, 6118, 7741, 7036, 7579, 7971, 7957, 5886, 7094, 7877, 7533, 4055, 7608, 7007, 7796, 5631, 7857, 7542, 6903, 7591, 7634, 7961, 7152, 4030, 5119, 7418, 7539, 7649, 6654, 7742, 7581, 6108, 7771, 7123, 7534, 7636, 4059, 7823, 7097, 6121, 8068, 7973, 7783, 6907, 7852, 7878, 6071, 7597, 7118, 4084, 7962, 7420, 7541, 7773, 7098, 6122, 8016, 7858, 7881, 7023, 7800, 4071, 7650, 6013, 7974, 7125, 7595, 8072, 7582, 7126, 7391, 6095, 7831, 7860, 8003, 4088, 7071, 7787, 7640, 7623, 6014, 7139, 7964, 7977, 7882, 7889, 6909, 8005, 3839, 6129, 7884, 8032, 7100, 7978, 7774, 8080, 7890, 6075, 7031, 7864, 7545, 7603, 4061, 7985, 7129, 7487, 6124, 7789, 7980, 7141, 7652, 7598, 8006, 7835, 6130, 7130, 4075, 7656, 7407, 7546, 7627, 7087, 7790, 6077, 7795, 7605, 7548, 7035, 7986, 7629, 7664, 4062, 7837, 6103, 7142, 7847, 7892, 8009, 6910, 7797, 7519, 7635, 6078, 7606, 6655, 4077, 7905, 7419, 7630, 7610, 7609, 6107, 7132, 7637, 7415, 7851, 8010, 7145, 7906, 8067, 7838, 4031, 6132, 7951, 7095, 8017, 7988, 7896, 8096, 7146, 7959, 6119, 7535, 8069, 7798, 7853, 7037, 4083, 8012, 7801, 7879, 6136, 7421, 7119, 7859, 7992, 8070, 7854, 7038, 7908, 8018, 5887, 7543, 4085, 7612, 7638, 7153, 7651, 7583, 7653, 8073, 7963, 6109, 7099, 7641, 7802, 7912, 8020, 8128, 7148, 3967, 8033, 7861, 6123, 7965, 8074, 7154, 7883, 7975, 7642, 7804, 7862, 7101, 6110, 7422, 7885, 7743, 4078, 8081, 7966, 7127, 7979, 7547, 7865, 7599, 6125, 7775, 7657, 7102, 8034, 7891, 7654, 8076, 7886, 7131, 4086, 7981, 6079, 7644, 8024, 8007, 7893, 7156, 7866, 8082, 7920, 8036, 7987, 6131, 7982, 7143, 7607, 8097, 7658, 4089, 7791, 7839, 7907, 7160, 8084, 7631, 6133, 8011, 7549, 7665, 6911, 8098, 7989, 7894, 8129, 8040, 7660, 7799, 6015, 4090, 7133, 7897, 7868, 7611, 7909, 8013, 8088, 7147, 7550, 7990, 8019, 7898, 6126, 7666, 8048, 7134, 7910, 7613, 7639, 7803, 4063, 8100, 7855, 8071, 7149, 7993, 6134, 7668, 8014, 7913, 7994, 7900, 7614, 7103, 8130, 8104, 7643, 8021, 8035, 6137, 7805, 4092, 8075, 7155, 7655, 7863, 7914, 7996, 7921, 8022, 8025, 7157, 7672, 7967, 7423, 6138, 8132, 8077, 7887, 7645, 8083, 7039, 7806, 7916, 8112, 4079, 8037, 7659, 7867, 7922, 8026, 6111, 7150, 7646, 8136, 7551, 8078, 7983, 8144, 8038, 8085, 7158, 7895, 7661, 8041, 7869, 8099, 6140, 7924, 8028, 4087, 7667, 7899, 7161, 7991, 8090, 8042, 8086, 7670, 8101, 7911, 7928, 8049, 7162, 7662, 6127, 7870, 8089, 7669, 8044, 8015, 8160, 7615, 7901, 7995, 7135, 8102, 4091, 8050, 8105, 8131, 7915, 7673, 8023, 6135, 8092, 7902, 7997, 7164, 8133, 8106, 8052, 7674, 7917, 8113, 8134, 7923, 8027, 8108, 7998, 8079, 7151, 8039, 7807, 8056, 6139, 7647, 8114, 4093, 7918, 8137, 7676, 8029, 7925, 8138, 8087, 7159, 8043, 8030, 7926, 8116, 8145, 8091, 8140, 7929, 8045, 8120, 7663, 6141, 7871, 8103, 8146, 7163, 8051, 7930, 7671, 8093, 8046, 7903, 8161, 8053, 8107, 4094, 8162, 8148, 8094, 7932, 8109, 8135, 7165, 8054, 7999, 8115, 7675, 8057, 6142, 8152, 7919, 8110, 8164, 8139, 8058, 7677, 8117, 8141, 8168, 8060, 8118, 8031, 7927, 7166, 8176, 7678, 8147, 8121, 7931, 8142, 8122, 8047, 8149, 8150, 8095, 4095, 8163, 7933, 8124, 8055, 8153, 8165, 6143, 8154, 8111, 8059, 8166, 7934, 7679, 7167, 8156, 8169, 8119, 8170, 8061, 8143, 8062, 8177, 8123, 8172, 8178, 8125, 8151, 8126, 8155, 8180, 8167, 8184, 7935, 8157, 8171, 8158, 8173, 8127, 8179, 8181, 8063, 8174, 8182, 8185, 8186, 8159, 8188, 8175, 8183, 8187, 8189, 8190, 8191]

### Sequence Group 4: Q4_8192

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 67, 41, 144, 28, 69, 42, 516, 49, 74, 272, 160, 1024, 520, 288, 528, 192, 544, 70, 44, 131, 81, 50, 73, 15, 320, 133, 52, 23, 134, 384, 76, 137, 82, 56, 27, 97, 39, 259, 84, 138, 145, 261, 29, 43, 98, 515, 88, 140, 30, 146, 1025, 71, 262, 265, 2048, 161, 576, 45, 100, 640, 1026, 51, 148, 46, 75, 266, 273, 517, 104, 162, 53, 193, 1028, 152, 77, 164, 768, 268, 274, 518, 54, 83, 57, 521, 112, 1032, 135, 78, 289, 194, 85, 276, 522, 58, 168, 139, 99, 86, 60, 280, 89, 290, 529, 524, 196, 141, 1040, 101, 147, 176, 2049, 142, 530, 321, 31, 200, 90, 1056, 545, 292, 322, 532, 2050, 263, 149, 102, 105, 304, 4096, 296, 1027, 163, 92, 1029, 47, 267, 385, 546, 324, 2052, 208, 386, 150, 153, 165, 106, 55, 328, 1088, 536, 577, 548, 1033, 113, 154, 79, 269, 108, 578, 2056, 224, 166, 519, 552, 195, 270, 1030, 641, 1041, 523, 275, 580, 291, 59, 169, 560, 114, 277, 156, 87, 1034, 197, 116, 170, 2064, 61, 1042, 531, 525, 642, 281, 278, 526, 177, 293, 388, 1152, 91, 584, 769, 198, 2080, 172, 120, 201, 336, 62, 282, 4097, 143, 1036, 1057, 103, 178, 294, 93, 1089, 644, 202, 2051, 592, 323, 392, 2053, 297, 770, 4098, 107, 180, 1044, 151, 209, 284, 1280, 648, 94, 204, 298, 400, 608, 2112, 1058, 352, 325, 533, 155, 210, 305, 2057, 4100, 547, 300, 109, 1048, 184, 534, 1060, 537, 115, 1031, 167, 225, 326, 2054, 306, 772, 157, 2065, 656, 329, 110, 117, 212, 171, 1153, 776, 1090, 4104, 330, 1536, 2058, 226, 549, 1035, 538, 387, 308, 216, 416, 271, 279, 158, 337, 2066, 550, 672, 1064, 118, 332, 579, 540, 1092, 2176, 389, 173, 1154, 121, 553, 199, 784, 179, 228, 4112, 338, 312, 1043, 704, 1037, 390, 174, 554, 581, 1072, 393, 2060, 283, 2081, 122, 448, 353, 2113, 561, 1038, 203, 63, 4128, 340, 394, 1096, 1281, 527, 582, 556, 181, 295, 1045, 285, 232, 124, 2068, 205, 182, 643, 2304, 1156, 562, 286, 585, 4099, 299, 354, 2082, 1059, 4101, 211, 401, 1282, 185, 1050, 396, 344, 586, 645, 1537, 593, 535, 240, 2072, 1104, 206, 95, 327, 2084, 564, 800, 402, 2055, 4160, 356, 307, 301, 417, 1061, 213, 1049, 568, 1046, 832, 4105, 588, 1160, 1284, 186, 2177, 646, 404, 2114, 1288, 227, 896, 594, 418, 2560, 302, 649, 771, 360, 539, 2059, 4102, 111, 1062, 331, 1538, 4113, 214, 309, 1120, 1091, 2088, 188, 449, 1065, 217, 408, 609, 596, 2116, 551, 650, 229, 159, 4106, 420, 2178, 310, 1168, 541, 1052, 773, 610, 657, 333, 1093, 119, 1066, 2067, 4114, 2061, 600, 339, 1540, 218, 2096, 368, 652, 1073, 230, 391, 313, 4224, 450, 542, 1098, 334, 1296, 233, 555, 2062, 774, 175, 123, 1184, 658, 2120, 612, 341, 2305, 777, 220, 314, 2069, 1544, 424, 1312, 395, 4108, 673, 4129, 583, 355, 1552, 2180, 1216, 4161, 287, 183, 234, 1568, 125, 557, 1094, 660, 616, 342, 316, 2083, 1068, 241, 778, 2306, 563, 2074, 1155, 345, 452, 397, 2561, 4116, 403, 1105, 207, 2128, 1074, 4352, 674, 558, 785, 1097, 432, 1039, 357, 187, 1344, 236, 664, 1157, 624, 4130, 587, 780, 1076, 2085, 1047, 705, 2073, 126, 242, 2070, 1158, 565, 398, 2184, 346, 456, 2308, 4120, 358, 405, 303, 569, 2312, 1408, 4132, 244, 1100, 1161, 595, 1106, 189, 4103, 566, 676, 1080, 1051, 1121, 361, 2086, 706, 589, 2562, 1063, 215, 786, 647, 348, 2144, 2115, 419, 406, 464, 680, 4225, 801, 2089, 4162, 1283, 362, 1108, 590, 409, 1162, 4608, 570, 1169, 788, 1285, 2192, 1053, 4107, 2076, 597, 1067, 572, 1122, 219, 311, 2117, 708, 598, 2090, 1539, 601, 651, 421, 792, 4136, 802, 2564, 611, 1112, 602, 1164, 410, 231, 2097, 4164, 688, 653, 1054, 248, 1170, 2122, 4226, 369, 2320, 190, 364, 1095, 654, 2208, 1286, 659, 1289, 335, 480, 4115, 315, 4109, 221, 3072, 370, 1185, 613, 2568, 1600, 4144, 422, 425, 2336, 451, 1069, 614, 543, 1124, 235, 412, 2576, 343, 372, 2240, 1664, 775, 317, 2592, 4110, 2118, 1075, 222, 1172, 426, 4168, 2092, 453, 4353, 237, 1070, 559, 1099, 2179, 1290, 4117, 833, 804, 712, 1297, 834, 661, 1541, 808, 779, 2129, 1128, 617, 604, 2098, 1186, 433, 4228, 720, 2121, 816, 1077, 2063, 1217, 836, 2368, 347, 897, 2181, 1176, 4131, 243, 1101, 2100, 662, 4354, 2071, 1188, 4122, 454, 318, 675, 1792, 618, 2182, 1292, 4609, 898, 781, 1298, 1542, 376, 428, 1078, 665, 4176, 736, 567, 1107, 2432, 1081, 1545, 840, 2124, 2185, 625, 238, 2130, 1136, 359, 457, 2104, 399, 787, 2075, 2145, 4133, 591, 678, 434, 4121, 677, 2087, 1159, 4118, 1102, 349, 1313, 1218, 245, 4232, 1109, 458, 4356, 666, 1300, 620, 1546, 1082, 2307, 1192, 4360, 363, 2132, 127, 1163, 191, 2186, 1123, 782, 407, 2193, 436, 626, 2309, 2077, 1110, 571, 465, 681, 2091, 246, 4134, 707, 2146, 4610, 1084, 350, 1304, 599, 668, 2563, 1113, 4192, 4163, 790, 1314, 1553, 460, 1548, 2136, 1220, 4137, 249, 2188, 682, 1165, 573, 1125, 411, 803, 2078, 1171, 789, 2194, 1200, 709, 365, 4240, 440, 628, 4124, 689, 3073, 2119, 374, 1166, 423, 2310, 1554, 4165, 466, 793, 2313, 4138, 1345, 250, 371, 1055, 481, 574, 1224, 2209, 4612, 413, 2624, 1114, 603, 366, 2093, 1569, 4145, 2148, 1316, 1346, 468, 1556, 655, 900, 4170, 2688, 805, 4368, 615, 3074, 1287, 684, 1173, 710, 2099, 1126, 4256, 429, 794, 2196, 252, 1129, 373, 605, 1328, 848, 690, 2094, 5120, 2123, 713, 632, 2314, 1320, 482, 4616, 806, 2321, 4384, 1187, 2565, 1116, 427, 2152, 1071, 904, 4624, 2210, 1291, 4288, 414, 1409, 2101, 223, 1570, 4640, 2241, 1348, 4166, 663, 3076, 692, 835, 1232, 619, 472, 2200, 1410, 4140, 455, 796, 2125, 1174, 1177, 809, 714, 2212, 1189, 721, 4227, 837, 2816, 716, 1130, 2316, 1079, 1352, 864, 2322, 2566, 4177, 810, 2102, 1560, 4146, 606, 1601, 2131, 912, 4169, 2105, 2569, 1572, 4111, 722, 696, 377, 4416, 1137, 435, 2160, 1178, 4229, 1103, 817, 1293, 1132, 319, 621, 4148, 1602, 812, 4119, 484, 3080, 1248, 430, 1190, 2183, 1543, 2126, 1576, 4230, 838, 2337, 2242, 667, 1219, 488, 2133, 1294, 239, 378, 2324, 2570, 459, 622, 2106, 2216, 1665, 4480, 627, 437, 2187, 380, 4172, 4233, 2147, 1547, 4178, 1299, 818, 1604, 1315, 461, 4152, 2134, 1083, 4123, 496, 4193, 669, 1193, 1584, 679, 1138, 1301, 2108, 1180, 4135, 724, 2328, 841, 1111, 629, 2137, 1221, 351, 467, 2338, 2577, 1140, 438, 2572, 2244, 1194, 737, 251, 4355, 462, 2189, 442, 4180, 441, 3088, 2149, 4234, 1085, 469, 2195, 1555, 4241, 247, 683, 2224, 1549, 4357, 1666, 4125, 842, 1305, 1302, 738, 4139, 1550, 2190, 1201, 4194, 899, 2578, 1317, 670, 1412, 783, 2369, 1115, 4611, 849, 2079, 1608, 1793, 820, 2248, 1222, 728, 928, 4184, 2138, 791, 4236, 367, 3104, 2593, 1196, 901, 1144, 630, 2340, 2370, 1225, 4126, 685, 844, 2580, 4242, 1360, 633, 711, 1086, 253, 691, 2311, 1306, 5121, 2197, 4167, 824, 2150, 1167, 902, 4358, 686, 2153, 1127, 4361, 1202, 2352, 1318, 1117, 740, 6144, 1668, 850, 375, 4257, 2344, 1226, 4672, 444, 3075, 1616, 2211, 470, 1347, 4141, 483, 2140, 1416, 4196, 415, 3077, 485, 2095, 905, 1321, 795, 473, 2315, 1794, 4736, 634, 744, 2433, 5122, 2594, 1131, 852, 960, 2372, 1204, 865, 4147, 693, 2256, 4244, 1175, 2434, 1233, 1308, 797, 2198, 2201, 1672, 4142, 4171, 2213, 1118, 1228, 4362, 906, 1322, 2154, 715, 1424, 4369, 2103, 2376, 1632, 4613, 807, 3136, 474, 636, 4200, 1376, 694, 254, 2584, 1349, 4258, 1557, 717, 2625, 1179, 1234, 575, 913, 4149, 2596, 1329, 798, 4289, 811, 3081, 5124, 2161, 379, 1571, 2202, 1324, 2127, 1133, 4248, 697, 2317, 2156, 4173, 1208, 431, 2626, 1558, 4260, 607, 2272, 1561, 2214, 489, 4864, 2567, 2600, 1139, 4364, 866, 723, 2243, 486, 4370, 1191, 4614, 2318, 1249, 4150, 1350, 3078, 908, 1330, 1796, 718, 813, 4179, 2689, 1181, 4153, 476, 4617, 856, 3089, 1680, 1353, 839, 1134, 2571, 1141, 2323, 1236, 4208, 725, 2628, 2339, 698, 1195, 914, 2107, 1800, 752, 868, 2217, 2608, 5128, 2162, 819, 2325, 2204, 1354, 4231, 814, 4174, 439, 2135, 929, 4385, 4290, 3082, 2245, 1250, 4181, 1573, 490, 2164, 1562, 4372, 1411, 623, 4618, 2218, 1332, 4154, 1240, 4264, 671, 1440, 1295, 739, 1303, 4235, 1182, 2109, 1361, 4195, 916, 3090, 2579, 1574, 463, 1696, 843, 2573, 2690, 1142, 4182, 381, 2329, 2326, 1356, 1603, 497, 2574, 2225, 1564, 930, 821, 4156, 2341, 2436, 726, 4376, 961, 3200, 2139, 1413, 4185, 1197, 872, 2632, 2817, 1145, 4386, 4625, 492, 2246, 1577, 4620, 1223, 4292, 631, 1808, 1203, 729, 4237, 2220, 1252, 5136, 2168, 1362, 4197, 700, 2249, 1336, 443, 4243, 1728, 741, 2384, 1414, 4272, 1198, 2110, 1578, 1605, 845, 2330, 6145, 1417, 920, 382, 4238, 2191, 3084, 1307, 4626, 822, 3105, 2151, 1146, 2226, 851, 1472, 4417, 730, 2342, 2141, 1377, 4127, 498, 3137, 880, 2692, 4296, 1585, 742, 445, 2250, 1227, 4186, 471, 635, 2640, 1087, 5152, 2371, 1364, 4641, 932, 2440, 1418, 687, 4388, 4418, 2345, 1551, 4628, 1606, 2818, 1580, 1205, 1319, 903, 6146, 2155, 1309, 4359, 825, 4245, 2228, 1256, 1148, 4198, 500, 3092, 1229, 2199, 846, 1206, 4201, 2257, 2332, 1667, 4400, 745, 3328, 826, 2696, 732, 1586, 446, 962, 2142, 2252, 1310, 4392, 1609, 936, 2346, 5123, 2448, 1323, 475, 853, 4259, 2656, 1378, 867, 4188, 637, 3106, 5125, 2400, 4143, 1235, 2373, 1425, 2581, 1209, 4363, 907, 2203, 2258, 1420, 4481, 1368, 4642, 2353, 1610, 1669, 4420, 487, 6148, 1617, 2595, 695, 1559, 4304, 2348, 2157, 1264, 4482, 746, 3096, 828, 2232, 753, 4246, 1230, 4249, 854, 2582, 1119, 4261, 1351, 3108, 857, 2585, 1588, 1824, 504, 799, 4202, 2163, 1426, 4151, 255, 4424, 964, 3079, 5184, 2215, 1380, 909, 1331, 2273, 1325, 2374, 1441, 4632, 719, 2354, 2820, 4673, 1237, 477, 2205, 1592, 4644, 915, 2704, 2377, 1856, 5129, 2158, 4209, 2165, 2260, 1612, 4250, 638, 4175, 748, 2219, 944, 4365, 1210, 4204, 3201, 2824, 1670, 4674, 1428, 3138, 869, 6152, 1251, 4320, 1920, 491, 699, 4262, 2378, 1618, 4615, 1442, 4648, 754, 3584, 1326, 1673, 858, 1795, 4291, 2274, 1384, 2597, 1563, 4366, 478, 3083, 2586, 5126, 2435, 968, 1135, 383, 2356, 2264, 1355, 4737, 910, 2464, 2319, 5137, 2327, 1238, 815, 2206, 2385, 1333, 4619, 976, 4371, 2598, 2720, 870, 4676, 4387, 3112, 2166, 1212, 4155, 1473, 917, 2380, 2627, 1241, 4265, 1432, 4656, 4210, 2588, 1633, 4373, 1620, 3140, 4252, 727, 1575, 1674, 493, 1253, 4183, 2437, 1183, 5130, 2221, 1444, 4293, 873, 3202, 2169, 1334, 701, 4212, 1565, 931, 2601, 2247, 1797, 4266, 1634, 2832, 2227, 1681, 1357, 756, 2276, 6160, 2386, 1143, 860, 499, 4157, 2360, 3091, 5138, 2752, 4627, 731, 3085, 2438, 1624, 2222, 4621, 1363, 4738, 823, 2602, 2629, 1242, 4377, 4374, 3120, 922, 2441, 1392, 4622, 1676, 4273, 874, 2331, 1254, 4389, 1415, 918, 4484, 2170, 1337, 5248, 2496, 1474, 4187, 502, 2401, 1566, 933, 4680, 1358, 4865, 2609, 1257, 4294, 1579, 3086, 2251, 1798, 1199, 1147, 743, 2111, 6176, 2388, 1682, 4268, 760, 4216, 2442, 3144, 1636, 1365, 4297, 881, 3329, 2575, 1801, 2630, 494, 1244, 4432, 2604, 2229, 2343, 1338, 4158, 702, 3093, 921, 2333, 4378, 1448, 501, 876, 2280, 2172, 1419, 4239, 5132, 847, 2253, 1697, 5153, 2230, 1607, 4199, 992, 4274, 2691, 1379, 447, 4390, 4189, 3204, 5185, 2610, 1311, 4740, 1207, 2334, 1258, 2633, 1149, 4298, 1581, 733, 6147, 2347, 1684, 4688, 1640, 4419, 2402, 1366, 1340, 4488, 827, 3107, 6149, 1265, 2259, 934, 1802, 4393, 2449, 3330, 2233, 1587, 4866, 882, 3098, 937, 2444, 2392, 963, 1369, 4203, 747, 2634, 2693, 1476, 4276, 1421, 3585, 505, 2641, 5140, 2583, 1427, 855, 924, 4247, 2288, 1231, 4305, 734, 4380, 829, 3152, 5376, 2254, 1698, 4744, 1582, 2143, 1809, 2375, 1456, 4190, 4300, 2612, 2848, 1381, 4394, 1211, 4496, 2450, 1260, 1688, 4704, 965, 6208, 2404, 1648, 5154, 2355, 1611, 4448, 2349, 2465, 1804, 4421, 938, 4629, 3109, 884, 2261, 506, 4251, 1729, 4306, 3097, 2616, 1150, 4401, 1266, 3094, 749, 2880, 6153, 1589, 1422, 945, 966, 4643, 2636, 3208, 1370, 4396, 1480, 4205, 755, 3332, 5144, 2234, 1382, 859, 1429, 4280, 2694, 1327, 2452, 1593, 4630, 940, 3336, 2275, 5156, 2944, 4633, 1268, 830, 2642, 2466, 1619, 4211, 911, 2350, 2697, 1213, 5127, 2819, 1590, 4263, 2408, 2587, 1700, 4321, 871, 4422, 6150, 2159, 639, 4402, 1385, 4868, 3110, 2379, 1730, 4253, 1613, 3586, 888, 6161, 2262, 1239, 4752, 1810, 4425, 479, 4206, 2357, 1671, 4213, 1372, 3168, 4308, 946, 3139, 1443, 1430, 750, 1488, 4267, 2236, 1704, 5249, 2497, 1825, 4872, 969, 3113, 2265, 5186, 2456, 508, 1386, 861, 2657, 2644, 1614, 4426, 1433, 2599, 2698, 5632, 2277, 1594, 757, 2207, 6154, 2468, 1812, 4322, 970, 4645, 2358, 3216, 5131, 2589, 4634, 4483, 3100, 2821, 1621, 2658, 4404, 1596, 4312, 919, 2705, 2381, 1243, 4512, 1335, 4367, 3141, 4375, 2167, 1732, 4254, 1622, 3114, 4433, 875, 6162, 1625, 4646, 1675, 862, 1445, 4768, 2648, 1816, 5160, 2387, 1826, 4214, 758, 3588, 2266, 1635, 948, 4428, 1626, 4675, 2416, 2700, 1434, 4636, 1255, 3121, 2278, 5188, 2439, 1712, 1677, 977, 2361, 6272, 2498, 1272, 4485, 923, 4269, 2590, 3146, 5250, 2382, 1393, 4217, 972, 3344, 2281, 1214, 2603, 4649, 1388, 4295, 2822, 2223, 2171, 1678, 4880, 4275, 3232, 761, 2706, 4324, 1683, 4434, 877, 2660, 2389, 1359, 4408, 1504, 5139, 4800, 2825, 1339, 5133, 2268, 1245, 4486, 952, 4270, 2362, 1394, 495, 4650, 1637, 4677, 3592, 5168, 2472, 1446, 4489, 1449, 3360, 2443, 1475, 6156, 1638, 4379, 1567, 703, 2721, 6177, 2631, 1259, 4218, 1436, 4544, 2403, 3600, 1367, 1396, 4449, 935, 3264, 6209, 2335, 1799, 2231, 978, 1341, 4657, 2282, 3616, 2173, 5134, 2605, 4299, 883, 3142, 762, 2708, 2664, 4159, 1246, 4436, 503, 2390, 2364, 1450, 4490, 5192, 3116, 925, 2289, 1477, 5377, 2826, 1261, 4623, 878, 4678, 2611, 1583, 4652, 735, 4277, 4391, 3203, 5141, 2393, 1857, 4381, 1828, 2500, 1736, 2445, 1858, 4328, 1685, 4220, 6164, 2451, 1832, 4301, 1803, 3153, 4278, 2255, 1641, 1628, 4739, 993, 3122, 6400, 2722, 1457, 5252, 2606, 1744, 4658, 2833, 3145, 2480, 1840, 4382, 885, 4681, 3087, 939, 2405, 2235, 994, 1860, 4395, 3392, 2284, 2712, 1371, 4450, 1921, 3205, 980, 2672, 6178, 5155, 2635, 1267, 926, 764, 4307, 2828, 3124, 1686, 4497, 5378, 4281, 941, 3095, 5146, 2753, 1478, 4492, 1342, 4440, 2174, 1699, 2290, 1642, 4682, 4741, 3206, 2613, 5633, 2446, 1922, 4689, 1805, 4631, 2394, 2504, 1400, 4336, 1452, 967, 6168, 2406, 1689, 5200, 2453, 1760, 4302, 2351, 2617, 1591, 4191, 886, 4423, 3456, 6180, 2292, 831, 4660, 1864, 4896, 3148, 3209, 2643, 1649, 4498, 1262, 3154, 947, 2237, 6151, 2614, 1383, 1481, 4452, 507, 4403, 2724, 3128, 1423, 4397, 1811, 3099, 4513, 889, 3169, 5157, 2409, 1615, 984, 1702, 4309, 2754, 1458, 5145, 2637, 1701, 4664, 751, 3111, 2263, 5142, 2834, 4928, 1373, 942, 2695, 2396, 1269, 4684, 5256, 2467, 2454, 1482, 5380, 2512, 1690, 4282, 2728, 6273, 2849, 1644, 4742, 996, 4500, 6210, 3331, 5384, 2410, 4323, 1387, 4992, 3156, 2638, 1151, 2457, 4690, 1215, 4514, 3210, 971, 6656, 2618, 1806, 4398, 1431, 4745, 3217, 4867, 2836, 1460, 4456, 1650, 3333, 4635, 890, 3101, 6155, 1595, 1489, 509, 1705, 4207, 2645, 3115, 1270, 5158, 2620, 1731, 4427, 949, 3170, 2267, 5634, 2359, 973, 1374, 4310, 2756, 2646, 1623, 4405, 1692, 3587, 2649, 5216, 2699, 5187, 2469, 1814, 1000, 2840, 6184, 2850, 1484, 4284, 892, 4545, 2659, 3160, 5161, 2650, 1273, 4313, 4504, 3212, 2458, 1706, 2279, 4705, 1597, 4692, 6212, 2736, 2701, 1435, 4647, 1827, 4746, 3102, 4325, 2296, 4255, 1813, 3218, 4516, 950, 6274, 2417, 1733, 4406, 1389, 5264, 1464, 4637, 2238, 1652, 5148, 2412, 1713, 4869, 863, 4706, 3143, 2702, 1398, 759, 4753, 1447, 4429, 3334, 5189, 2707, 1490, 4215, 1817, 3337, 2383, 5162, 2528, 6163, 1274, 1395, 1008, 2363, 6157, 2269, 1505, 4696, 1598, 4435, 2418, 3233, 5636, 2661, 1437, 4314, 510, 3648, 6192, 2470, 1627, 2473, 4464, 1390, 4748, 2499, 3117, 2662, 5169, 2591, 4326, 4487, 3172, 979, 2283, 2460, 4409, 1492, 4546, 953, 2391, 2420, 1679, 4638, 1924, 5194, 3712, 4430, 2823, 1829, 5392, 2365, 1639, 4329, 763, 4651, 6158, 1708, 4870, 974, 4271, 1734, 4219, 3123, 5280, 2270, 1453, 4754, 1818, 3220, 2474, 1276, 6216, 1397, 4708, 1629, 4437, 2501, 6401, 2285, 1872, 4873, 1714, 3118, 4316, 2607, 3147, 1737, 1656, 4410, 954, 3338, 6165, 2881, 1506, 5640, 2852, 1830, 4520, 2760, 3345, 2882, 5408, 2709, 4491, 879, 3589, 981, 2856, 2827, 4769, 1451, 4679, 3176, 2665, 2652, 1928, 4451, 5648, 3234, 982, 2481, 6276, 5312, 2768, 1438, 4383, 927, 4279, 2864, 3125, 1247, 4330, 5664, 4221, 4653, 3265, 5190, 2884, 1687, 4756, 1716, 4712, 2395, 1859, 2945, 1643, 4438, 1496, 4412, 3224, 6179, 5164, 2291, 1479, 4337, 1820, 3149, 4874, 2710, 6402, 1833, 4659, 1738, 995, 3236, 6170, 2502, 1745, 5251, 2366, 1861, 4441, 2723, 3840, 2666, 1740, 4548, 765, 4493, 3340, 6657, 2946, 2829, 956, 1888, 4499, 3346, 3590, 2424, 5201, 2476, 4303, 1834, 3126, 887, 2713, 6224, 2784, 5170, 1630, 4770, 985, 4654, 2615, 3155, 1936, 4881, 5193, 3129, 4528, 997, 3593, 5135, 2888, 1746, 4453, 1720, 4283, 2673, 1401, 5440, 2286, 1459, 4332, 4760, 3184, 2407, 5253, 2505, 4720, 1841, 4683, 2447, 2835, 1343, 4876, 1645, 5172, 6181, 2639, 1836, 5143, 2726, 1508, 4801, 2482, 6169, 2725, 1454, 4222, 986, 4338, 3207, 6166, 3150, 5254, 2397, 4661, 1862, 4494, 3361, 3266, 2293, 1691, 6280, 4442, 1512, 4552, 3157, 943, 2506, 6404, 2714, 1263, 1402, 4454, 3348, 4501, 2668, 3594, 1483, 4399, 1646, 3130, 4665, 891, 3240, 6408, 5504, 2411, 1651, 998, 1461, 4340, 2175, 3211, 1404, 5196, 2239, 5257, 4691, 766, 3171, 2830, 5202, 2455, 4285, 1842, 4662, 2484, 2674, 1485, 4772, 5176, 3158, 2619, 5147, 2513, 1520, 5217, 2729, 1693, 4457, 2294, 6182, 2755, 1703, 4802, 511, 4685, 6658, 3132, 5159, 2398, 1748, 4311, 4882, 3352, 2647, 1865, 2716, 4743, 1653, 4444, 3161, 6240, 6211, 2838, 1375, 4515, 1491, 4502, 3362, 3601, 4560, 2508, 4776, 1462, 3596, 4897, 988, 3268, 6185, 2297, 1761, 1275, 5379, 1486, 4458, 2730, 3213, 1466, 5204, 2621, 1465, 4686, 1001, 4505, 3173, 2459, 5258, 2851, 951, 1493, 4666, 3219, 5265, 2837, 1271, 4884, 1707, 3248, 2757, 5381, 2413, 6288, 5149, 2488, 1866, 1002, 2676, 6172, 2737, 1762, 4693, 5163, 4668, 2422, 3214, 5218, 2471, 1923, 4315, 4407, 3602, 6213, 2514, 1694, 2841, 4804, 1807, 4694, 6186, 3393, 2298, 5635, 2419, 4697, 1873, 4747, 3103, 4517, 2529, 2622, 4888, 1844, 4898, 3272, 893, 6660, 2461, 1752, 4707, 1952, 5208, 3162, 4698, 2651, 1815, 5260, 2414, 1391, 4506, 975, 4327, 3617, 6193, 1925, 894, 4784, 1654, 4749, 3364, 3394, 5150, 2516, 1709, 4344, 1868, 3604, 2703, 5266, 2948, 6218, 1657, 1735, 4465, 2853, 6416, 2663, 1277, 4286, 1715, 3335, 4460, 2732, 3221, 5191, 2758, 1848, 4750, 1009, 3174, 6304, 2477, 1926, 5382, 2842, 1710, 4755, 2300, 3177, 2421, 5385, 2653, 4431, 4576, 3376, 955, 2896, 2738, 4411, 1764, 4317, 7168, 2761, 2680, 1874, 4466, 1399, 5281, 3368, 4709, 2530, 6664, 5696, 2854, 1468, 4518, 1004, 4521, 6432, 3235, 1494, 4547, 5165, 4710, 1507, 4639, 3164, 5220, 2475, 1439, 4331, 1509, 4508, 3119, 2952, 1929, 6672, 1819, 4439, 1497, 4468, 3339, 6336, 5760, 2462, 1658, 4871, 1768, 3457, 4413, 2271, 3618, 6688, 1876, 1984, 1010, 3396, 6214, 2711, 1889, 5171, 2740, 1717, 4318, 2883, 3280, 2667, 5268, 2520, 4522, 957, 3458, 6188, 2503, 2844, 4549, 1821, 4333, 3222, 3225, 2857, 5166, 2762, 4655, 5195, 3237, 983, 2769, 6275, 2885, 5386, 1930, 4929, 958, 4900, 2764, 3178, 1739, 4808, 5393, 3127, 4930, 4757, 3400, 5637, 2912, 1831, 4904, 1498, 4875, 6225, 1660, 5224, 2858, 1718, 4713, 1278, 4700, 3608, 6194, 5282, 2654, 4529, 1741, 3649, 4816, 2960, 6217, 1599, 4912, 1937, 5173, 3620, 6159, 2770, 1822, 5313, 2744, 1835, 4932, 2425, 6464, 3185, 2483, 1403, 4443, 987, 4993, 3226, 6277, 3151, 5272, 2865, 1721, 4339, 3341, 3180, 2367, 5197, 2669, 6196, 4758, 1455, 3650, 1012, 2860, 6167, 2532, 5284, 1631, 4550, 3296, 4414, 2478, 3238, 1513, 4771, 5888, 3591, 4714, 999, 3624, 6278, 5388, 2886, 1890, 4994, 1747, 4877, 2715, 3267, 1510, 5394, 2536, 5638, 4472, 4524, 3342, 2287, 5174, 2426, 4761, 1932, 4832, 2507, 2670, 1742, 4663, 1837, 5203, 3713, 6528, 5177, 2675, 1500, 5641, 2485, 1880, 4936, 2428, 6220, 6281, 1863, 4721, 1016, 4334, 3595, 6226, 3347, 5232, 2866, 1749, 4455, 4553, 3652, 3363, 2509, 1722, 6200, 4495, 1938, 4883, 3131, 6171, 2544, 6241, 2717, 1776, 1892, 4687, 3241, 3632, 4774, 2727, 3186, 4530, 1843, 3349, 4773, 767, 3228, 6183, 2772, 5255, 1838, 5198, 1463, 4445, 2889, 3159, 1953, 5409, 2677, 5314, 4341, 989, 3269, 2399, 5205, 2515, 4554, 1514, 4762, 3188, 5396, 2486, 1647, 4716, 5642, 3242, 2785, 5178, 2299, 6403, 5288, 2510, 1695, 4459, 2490, 6228, 2489, 1763, 4223, 5259, 4287, 6282, 3133, 5219, 2517, 1940, 4878, 4503, 3603, 6289, 2295, 1487, 2731, 4532, 1867, 4722, 3597, 6405, 3714, 6173, 5206, 2890, 4667, 1405, 4561, 3353, 3350, 4777, 2786, 6187, 4342, 1521, 4803, 3598, 1003, 3249, 6242, 2947, 1954, 1845, 5180, 3365, 4446, 2718, 3460, 1750, 5400, 2831, 1985, 4695, 990, 4764, 3163, 6659, 5209, 2897, 1005, 1896, 4886, 3656, 3841, 5410, 2868, 5649, 4556, 1516, 3270, 2776, 5644, 2976, 6232, 5316, 1655, 4345, 2839, 6284, 2415, 1753, 4778, 5261, 3244, 4669, 2949, 3192, 5221, 2678, 1724, 4507, 4899, 3273, 6174, 2733, 1467, 5267, 2892, 1765, 4885, 6290, 3408, 2681, 5296, 2759, 4805, 4461, 3134, 4536, 2301, 2739, 4724, 1869, 4785, 3354, 7169, 6215, 2872, 1944, 4470, 1406, 5262, 3215, 4519, 2950, 6406, 5650, 2734, 1846, 4562, 959, 4889, 3175, 6409, 3250, 1875, 5441, 4346, 1754, 4467, 3366, 3165, 5151, 2788, 1522, 4577, 1904, 4670, 3716, 2898, 5320, 2423, 6305, 1766, 1469, 4509, 3274, 6720, 5210, 2492, 1495, 4699, 1659, 3664, 4462, 2518, 3395, 6189, 5665, 2531, 1956, 1011, 3464, 6244, 2463, 1711, 5412, 2533, 5442, 4564, 2953, 3369, 2843, 5652, 2521, 4751, 4996, 3842, 6784, 2682, 2792, 4901, 1927, 4711, 7170, 3179, 2900, 5383, 3008, 4780, 1849, 5269, 3252, 4806, 2913, 6195, 2741, 5222, 1524, 4525, 1013, 4890, 6292, 3223, 1870, 4348, 5225, 3281, 4469, 4701, 3356, 5424, 2845, 1769, 4944, 1850, 4786, 3720, 6190, 1756, 6219, 1470, 4809, 1986, 4728, 3166, 3276, 6410, 5416, 2954, 4578, 1960, 3370, 4902, 2763, 3472, 6417, 1499, 1877, 5283, 3680, 6661, 2855, 1891, 5212, 2522, 1661, 4523, 2684, 6248, 3424, 2742, 5167, 2302, 5000, 895, 3397, 6306, 3605, 5387, 2765, 1931, 4510, 3227, 3282, 2623, 5505, 2961, 6197, 4319, 5666, 3377, 1006, 2846, 6337, 2859, 5444, 1511, 4759, 7172, 4788, 2427, 3619, 1719, 4931, 5328, 3372, 4715, 4568, 3181, 6296, 5506, 2745, 1770, 4551, 1852, 4892, 6221, 3256, 1777, 5270, 2479, 5273, 4905, 1878, 4810, 3606, 6308, 5285, 2655, 4817, 1881, 4933, 3609, 2537, 6912, 1528, 4812, 1823, 5226, 3187, 6412, 5175, 2914, 1279, 5448, 2771, 1988, 4960, 2534, 6418, 3239, 6662, 1933, 1014, 4906, 3297, 6198, 3398, 5656, 2956, 1743, 4702, 3378, 3844, 2766, 5697, 2861, 6227, 5008, 1501, 3229, 6201, 2524, 6665, 2904, 5668, 1939, 4818, 3728, 3401, 4792, 2887, 3182, 4473, 5233, 3189, 4531, 1017, 3284, 6256, 2773, 5274, 1662, 5199, 1772, 4913, 2746, 3243, 1968, 5389, 2962, 5228, 4415, 4717, 3848, 2800, 5698, 2916, 4908, 1893, 4580, 7176, 5344, 2867, 1515, 4526, 1723, 5286, 3402, 6279, 5639, 2862, 6222, 5672, 2487, 1778, 4934, 2977, 6433, 6338, 1882, 4763, 5315, 4584, 3298, 6229, 3621, 5390, 2538, 1502, 4335, 4474, 3610, 6420, 3459, 2671, 1992, 6666, 4555, 1407, 4718, 3380, 6202, 3288, 6312, 5761, 2719, 1934, 4723, 3488, 3343, 4533, 2787, 3351, 6283, 4476, 1839, 3230, 1018, 3409, 6243, 2964, 5643, 2000, 5395, 3622, 4914, 2511, 3744, 1894, 5700, 2891, 5411, 4557, 991, 3190, 6230, 5179, 2429, 4592, 1941, 4765, 3404, 3651, 5289, 2545, 5680, 4775, 5234, 3612, 2978, 5397, 2869, 6204, 5276, 1751, 4820, 2774, 6424, 3009, 1517, 4937, 5207, 3461, 4725, 6233, 3245, 5317, 2920, 1897, 4447, 4563, 3193, 6434, 6673, 1725, 5236, 2540, 1955, 4534, 3625, 6668, 3271, 6340, 5290, 2679, 4833, 4347, 3856, 3251, 4558, 2777, 6285, 4538, 1780, 4537, 3300, 7184, 3410, 6245, 2748, 1884, 1523, 5181, 3384, 4565, 2491, 6291, 3776, 5651, 2789, 1755, 4343, 1020, 4779, 3462, 6320, 3246, 5645, 5762, 1847, 4938, 3626, 3653, 5401, 2893, 5398, 4834, 1946, 3465, 2968, 5646, 2430, 6286, 5297, 1898, 4995, 3355, 6674, 5413, 2870, 1942, 4766, 5508, 3194, 4879, 2899, 3520, 6465, 5211, 2778, 1526, 4945, 3425, 6175, 2546, 1957, 5704, 2928, 5889, 4916, 6344, 3633, 2790, 5318, 2493, 4824, 5024, 3275, 6234, 2519, 2683, 4887, 1767, 4463, 3135, 7200, 3412, 6689, 5292, 2980, 4997, 1784, 5240, 3466, 4726, 2735, 6436, 6466, 5321, 1905, 4781, 1007, 4940, 3599, 6676, 3654, 1518, 5456, 3628, 4729, 4807, 3253, 3367, 5182, 2951, 1726, 4349, 1945, 4787, 3357, 6407, 5402, 2873, 6293, 1525, 1900, 4920, 3304, 3196, 6246, 5263, 2548, 4998, 1871, 3277, 4782, 2894, 3254, 6249, 5223, 2016, 5298, 3715, 6448, 2793, 1471, 5414, 2874, 5213, 4836, 2780, 3634, 2494, 5764, 3010, 4946, 4471, 3358, 6440, 3657, 5322, 2984, 1757, 4540, 7171, 3371, 2523, 5712, 2901, 6307, 4566, 5443, 3426, 4579, 2915, 6236, 2685, 5512, 1851, 4511, 7173, 4581, 6191, 3283, 1958, 5001, 5417, 3473, 4891, 4569, 3257, 6411, 5890, 2955, 1906, 4730, 1961, 4840, 3468, 6529, 3416, 1987, 6690, 5227, 4948, 1771, 5056, 3658, 3717, 6468, 5300, 2535, 4961, 1529, 4789, 3665, 2743, 3607, 6352, 1879, 1948, 5271, 3312, 6530, 5329, 2794, 1758, 5404, 2876, 1853, 4893, 2801, 6294, 3278, 6297, 5768, 2902, 1015, 3167, 6309, 3399, 5214, 2905, 5324, 5002, 3636, 3872, 2552, 5418, 2847, 6250, 4811, 5520, 3474, 6199, 2303, 6472, 3012, 5728, 1989, 4903, 7232, 3428, 4570, 2957, 3379, 4732, 5472, 3373, 4790, 4350, 3489, 6680, 2767, 5445, 1962, 5653, 1908, 4813, 6721, 3285, 1530, 5275, 2525, 5330, 4671, 5009, 3640, 6692, 5425, 2963, 4894, 1773, 4907, 3904, 7177, 6257, 1969, 4475, 1990, 5667, 3660, 6298, 5420, 2686, 6223, 5229, 2796, 1779, 4793, 2992, 6413, 3258, 6252, 1883, 5304, 4527, 3718, 6722, 3476, 5654, 2917, 1964, 4703, 3299, 6368, 3968, 2539, 5657, 2747, 6310, 4585, 1854, 3666, 6663, 3490, 6696, 5235, 2802, 1935, 4962, 3374, 3721, 4819, 2906, 3843, 6339, 4582, 5287, 3432, 1019, 3611, 6414, 2526, 5345, 1895, 5446, 7174, 5004, 3016, 3183, 1663, 5426, 2431, 5892, 4814, 4909, 3403, 6785, 5277, 2958, 4572, 1912, 4952, 7185, 3286, 5776, 2863, 5449, 4935, 1503, 5230, 3381, 6667, 5237, 3024, 6419, 5332, 1970, 4821, 2918, 6724, 6435, 1774, 4794, 5291, 3260, 5010, 6203, 3521, 5896, 2965, 1993, 4848, 4964, 3289, 6313, 3480, 6704, 1532, 6258, 1885, 4915, 3681, 6421, 3668, 6300, 5450, 2775, 4910, 3623, 3722, 4535, 2541, 3301, 6231, 5025, 1781, 3231, 7178, 3492, 6341, 2921, 5346, 1994, 5669, 3382, 4586, 2749, 6260, 3613, 5658, 2979, 5507, 4719, 1021, 3845, 6314, 3682, 5428, 5336, 1943, 4767, 3729, 3405, 5536, 2804, 5391, 4835, 5399, 3191, 2908, 5278, 2547, 6205, 5457, 1899, 5012, 7186, 6675, 5670, 2779, 1886, 4559, 5792, 3672, 4939, 6669, 3411, 6786, 5238, 2871, 1782, 4477, 3290, 6425, 6422, 1972, 5452, 2970, 5699, 4593, 3440, 6670, 3724, 6321, 5660, 2922, 5026, 4917, 3302, 6437, 3463, 2966, 6532, 4822, 2001, 5057, 3385, 7296, 3522, 6235, 5509, 2550, 1947, 5293, 3614, 4968, 2981, 6728, 3406, 6913, 5241, 1996, 1022, 4588, 3305, 6342, 3627, 5673, 5319, 3846, 4727, 3247, 3195, 5904, 2791, 5299, 4825, 1785, 3730, 6316, 5348, 2808, 6264, 5458, 1901, 4796, 3684, 3413, 6345, 5432, 2929, 4539, 5824, 3849, 4837, 2542, 3292, 6480, 5510, 1976, 5294, 3386, 6206, 2750, 1519, 5674, 2969, 5701, 4941, 6426, 3496, 2549, 5513, 2924, 5016, 4478, 3467, 6287, 7180, 5403, 2895, 1727, 4918, 3745, 7201, 3655, 6247, 5242, 3040, 6322, 4947, 5568, 3427, 4826, 2495, 6438, 6237, 5473, 1959, 4594, 7233, 4976, 3359, 6788, 3255, 2002, 5681, 3306, 4838, 4541, 3197, 6346, 3629, 5323, 2781, 1907, 4567, 1786, 4731, 3732, 6736, 3688, 5183, 6467, 5460, 1527, 5028, 3414, 3388, 6536, 5514, 2875, 4783, 1949, 3313, 2982, 3850, 6441, 5647, 1902, 5702, 3635, 6914, 5676, 2930, 1759, 5301, 2985, 5415, 4999, 3011, 3417, 6251, 5405, 2795, 4921, 3524, 6324, 3469, 5352, 2553, 5244, 4596, 7188, 3475, 2903, 5325, 2972, 6295, 4942, 5302, 3279, 6353, 2782, 6428, 2877, 5763, 2017, 4841, 7424, 3746, 4922, 6792, 3630, 4828, 5682, 3857, 4542, 5058, 3504, 6238, 6348, 5406, 1909, 5705, 1963, 5032, 3429, 6442, 3259, 2018, 6544, 5419, 4571, 4949, 3308, 3736, 6752, 5474, 3013, 4963, 2004, 4733, 3696, 7202, 3659, 6496, 1950, 1788, 5331, 3852, 6469, 5521, 2986, 6677, 5305, 2932, 1965, 5003, 2554, 6299, 3777, 6354, 5516, 5464, 3198, 6449, 3314, 5706, 2797, 5765, 4583, 3637, 3470, 2993, 5713, 3014, 6691, 4791, 5655, 3418, 6444, 3528, 6253, 5360, 2803, 1991, 4842, 7192, 3430, 4924, 2907, 3477, 6328, 4849, 5326, 3375, 4950, 3641, 6678, 2988, 5215, 1910, 5447, 7204, 4953, 6681, 3316, 1855, 5684, 2878, 5920, 4600, 4895, 3667, 6259, 5522, 2959, 4351, 1971, 5060, 3261, 7175, 3638, 6311, 5476, 5005, 1531, 5427, 3748, 6369, 5421, 2919, 6470, 5537, 1913, 4815, 2687, 6450, 3433, 6916, 2008, 5333, 3778, 4573, 6301, 3661, 5688, 2936, 1775, 5011, 3287, 6800, 3858, 6473, 5952, 2527, 6254, 1966, 3719, 6261, 3420, 6356, 5708, 2994, 4734, 3491, 3478, 4844, 2798, 3536, 6315, 5040, 5306, 3752, 7297, 3873, 6920, 3017, 5766, 2020, 5524, 7234, 4965, 2556, 3434, 5347, 2909, 6016, 4587, 4795, 3662, 6474, 3481, 5714, 5538, 1995, 4850, 7680, 3642, 5422, 2805, 5769, 4954, 5891, 3860, 6370, 5480, 3018, 6693, 5659, 1914, 4574, 7179, 6682, 6531, 1533, 5064, 5231, 3669, 4479, 6452, 3644, 6360, 5451, 2967, 1973, 5006, 3291, 6560, 3383, 6415, 1997, 6423, 5334, 4911, 3780, 6302, 3670, 6481, 5429, 2923, 5072, 3673, 6694, 3723, 2910, 3493, 6816, 4966, 2024, 3864, 7208, 3874, 6262, 5308, 2806, 1916, 5569, 3683, 5013, 2996, 6476, 3674, 6723, 5337, 5528, 1023, 3482, 6684, 3303, 5729, 5716, 7236, 4823, 3760, 3725, 5671, 3025, 5770, 4589, 5349, 3320, 6533, 5279, 2971, 6317, 5540, 1974, 4969, 7298, 3441, 6265, 5430, 3020, 4797, 5661, 3262, 5027, 6697, 3436, 6343, 5893, 1887, 5730, 3726, 6928, 6323, 1783, 5777, 2809, 5453, 4852, 6372, 3731, 6482, 5239, 2925, 4956, 4595, 3407, 6456, 3552, 7187, 6848, 2032, 4827, 3387, 7181, 3293, 6534, 5720, 3000, 6318, 5459, 3442, 4919, 2543, 6698, 3685, 6725, 5338, 1534, 7216, 5018, 3494, 6537, 3497, 5488, 5772, 3523, 4970, 3686, 6427, 3615, 5350, 2751, 5511, 5014, 2003, 3307, 6266, 3484, 5433, 6592, 5570, 1977, 4598, 3415, 3444, 6497, 5662, 2983, 5029, 5454, 3847, 3026, 3389, 6705, 5353, 1787, 5675, 7182, 6347, 5894, 2931, 1998, 5295, 2810, 5243, 4839, 6207, 3294, 6484, 5778, 2551, 4856, 3498, 6538, 7240, 5732, 2973, 5461, 4977, 3525, 7425, 3309, 6671, 5897, 2926, 6726, 4590, 5340, 3631, 6700, 2783, 6325, 6439, 5434, 1978, 4798, 7189, 3905, 5017, 6429, 3876, 5544, 3784, 4597, 4972, 3906, 6376, 3733, 6268, 5515, 1903, 2005, 4943, 3880, 6349, 3851, 5793, 6326, 5703, 5088, 3689, 3676, 6787, 5475, 3041, 4543, 2006, 3505, 7300, 3792, 6706, 5407, 1951, 5303, 3888, 6430, 5354, 2933, 6729, 5245, 2987, 5677, 4829, 3042, 3908, 6443, 5780, 5736, 3419, 6498, 3969, 5462, 3028, 5436, 4923, 7203, 3315, 2974, 5361, 2812, 6355, 5030, 5898, 3734, 6545, 7426, 6329, 5683, 2989, 2019, 4978, 7194, 3526, 5033, 6540, 3390, 6488, 5059, 5465, 3747, 4843, 3690, 6730, 6789, 5572, 1789, 5517, 7681, 4601, 3970, 6737, 3853, 1980, 6679, 5523, 4951, 5020, 3448, 6384, 3500, 5327, 3015, 4830, 1911, 4925, 3737, 7248, 3808, 6350, 5794, 2009, 5678, 3639, 6239, 5905, 2934, 6471, 5552, 2021, 2879, 6708, 3912, 6944, 5477, 5307, 3697, 6546, 3310, 5356, 2995, 5784, 5061, 3431, 3529, 6500, 5744, 2555, 6451, 5707, 3471, 6445, 3859, 6561, 5900, 2937, 5034, 7205, 3663, 4980, 3032, 3750, 6357, 4602, 5825, 3506, 7193, 3749, 6712, 2799, 5246, 2010, 5362, 7190, 4845, 6976, 3421, 5685, 2990, 5518, 5041, 5062, 3317, 6732, 7304, 5466, 5576, 1967, 4851, 3530, 7428, 3738, 6330, 5478, 4955, 5525, 3692, 6790, 5423, 3044, 6548, 5689, 1915, 5036, 7432, 6371, 3435, 7040, 2022, 5364, 3199, 4926, 6738, 3263, 6562, 5715, 3019, 1790, 5007, 3854, 6446, 3479, 6793, 5309, 6915, 5686, 3508, 6504, 3698, 6683, 5796, 2938, 4967, 3643, 3537, 2557, 3753, 6255, 4735, 5481, 3318, 7206, 3779, 6475, 5826, 2997, 1535, 5709, 7682, 4984, 3021, 3422, 6358, 5335, 5906, 4575, 3671, 6453, 3740, 5767, 5468, 7264, 5042, 7235, 3862, 5539, 3048, 5526, 4846, 5584, 3532, 6332, 5800, 2940, 6593, 5921, 2012, 5065, 7209, 3321, 6361, 6552, 4604, 5482, 3754, 4957, 6753, 3645, 6740, 5710, 2025, 5529, 3483, 6695, 3875, 6794, 1975, 6373, 5690, 4853, 6303, 3861, 6564, 5908, 2998, 5066, 3781, 6454, 3437, 7312, 3512, 6685, 2026, 3700, 7196, 3761, 6917, 5717, 2911, 6754, 5692, 3446, 5015, 2807, 6801, 3495, 6477, 5339, 5431, 7237, 3538, 6263, 3865, 5828, 5718, 7210, 4971, 3322, 3443, 5721, 3056, 5771, 4958, 5541, 3553, 6744, 3646, 5912, 6483, 5922, 1917, 4854, 7684, 3485, 6362, 5731, 2558, 5044, 5722, 3675, 6512, 3438, 6796, 5530, 1999, 5351, 7217, 6374, 6535, 1918, 5808, 3027, 5773, 5073, 6457, 3540, 6594, 5368, 3001, 5019, 3727, 6686, 3972, 7242, 6478, 5489, 5068, 3877, 7440, 3687, 6377, 5310, 2811, 6699, 5484, 3756, 6918, 3022, 6319, 3782, 6267, 5774, 2033, 7328, 3501, 4857, 6802, 3866, 5779, 3324, 4973, 3445, 6756, 3677, 6485, 5455, 5600, 1979, 3920, 6921, 3762, 5435, 6364, 5341, 5048, 3785, 3704, 6458, 5490, 3002, 4591, 5733, 3554, 7688, 3878, 6568, 5542, 2028, 5545, 7456, 6539, 5571, 2927, 5734, 3029, 5663, 4799, 6817, 3499, 6727, 5355, 5532, 3976, 6499, 7696, 5463, 3030, 5492, 5031, 7360, 3486, 6431, 5895, 2975, 6327, 5074, 5437, 3295, 6378, 7712, 6269, 6701, 2034, 4979, 7238, 3735, 4858, 6804, 3764, 6760, 5342, 3907, 4599, 3691, 6486, 3544, 6460, 5546, 1981, 7212, 5021, 3527, 6385, 3868, 5573, 6922, 5357, 4974, 3881, 6707, 3786, 5679, 3043, 4831, 2007, 3793, 7299, 3909, 6489, 5953, 1982, 5924, 3788, 6596, 5832, 2813, 6541, 5954, 5781, 3004, 3936, 6547, 5928, 5899, 7249, 6351, 3882, 5737, 2935, 5724, 5089, 7218, 3678, 6818, 5553, 3033, 6702, 5840, 3984, 6929, 7241, 6576, 5936, 3045, 4981, 7183, 3794, 5035, 6501, 3768, 6331, 5090, 5956, 3449, 7488, 3507, 6380, 6808, 5467, 2011, 6017, 7301, 5076, 6768, 3889, 6731, 5363, 5022, 4860, 3391, 6924, 3693, 7220, 5782, 2036, 5037, 3884, 7191, 3556, 6849, 5574, 5438, 3502, 6270, 5795, 3034, 6386, 5738, 2023, 7302, 6709, 3910, 6542, 6018, 5901, 3739, 6490, 3560, 6600, 5496, 2991, 5548, 5063, 3311, 3450, 6502, 5785, 6549, 5856, 3531, 6447, 3694, 6713, 5687, 2939, 4982, 7552, 3699, 3046, 3509, 6388, 4927, 5960, 3452, 7244, 7305, 6739, 5745, 2814, 2040, 5358, 7250, 5043, 6333, 3890, 6710, 5479, 5577, 4603, 3533, 6820, 7224, 5519, 5907, 7195, 4985, 3568, 7265, 3741, 6505, 5711, 5080, 5798, 3751, 6850, 5554, 2559, 6733, 5797, 1791, 4847, 7207, 3796, 6359, 6930, 5469, 3913, 5038, 6791, 3701, 6492, 5365, 2013, 3423, 6563, 3539, 6550, 5578, 6608, 5786, 6824, 3510, 6945, 5740, 3036, 5092, 3809, 3323, 7427, 3534, 6506, 5483, 3514, 7252, 3513, 6734, 5247, 3049, 6553, 5311, 7306, 5067, 2999, 3541, 6714, 5902, 5527, 7313, 3319, 6932, 3755, 5556, 5746, 7429, 4986, 7197, 3914, 5691, 3050, 5585, 4605, 5801, 3810, 6741, 7211, 5366, 6716, 5827, 2027, 5045, 7266, 3971, 6363, 6455, 5069, 5470, 3742, 6852, 3855, 6742, 5719, 2014, 5788, 7683, 6745, 3921, 6795, 2029, 6565, 5910, 5096, 6936, 3892, 6946, 5580, 2941, 4988, 3800, 6755, 4000, 7256, 6746, 5369, 3863, 7308, 3439, 6554, 5802, 3023, 6375, 5693, 3973, 2942, 6832, 3702, 6797, 5531, 5923, 7198, 3757, 6392, 3916, 5909, 7314, 5046, 3705, 3783, 6513, 5829, 5485, 5560, 3325, 6334, 3763, 5748, 6508, 5809, 4959, 7239, 3896, 6798, 5494, 3057, 4855, 5543, 3974, 7430, 3758, 6803, 5586, 1983, 5913, 7433, 6479, 6624, 5370, 3003, 5491, 5104, 6459, 3812, 6365, 5601, 5694, 3922, 6514, 3447, 7329, 6757, 5533, 4606, 7744, 3516, 6566, 5723, 3052, 6569, 5486, 3542, 6595, 7213, 6758, 3555, 6687, 2035, 7268, 3487, 5075, 6379, 3557, 6556, 5588, 3977, 5049, 3867, 6487, 3545, 6516, 5775, 6020, 7808, 3706, 6919, 3816, 5925, 6461, 5735, 4859, 3924, 4032, 5804, 3058, 5070, 5830, 3937, 7219, 3765, 6366, 5549, 2037, 5914, 7316, 6570, 5372, 3005, 5493, 5725, 6597, 3869, 6381, 5968, 5810, 7214, 6703, 7243, 5833, 3031, 5752, 5050, 7434, 3978, 6977, 5602, 3006, 6948, 5926, 3787, 6856, 7441, 6978, 6805, 4975, 7685, 3879, 5077, 6952, 3546, 6923, 5547, 3708, 7272, 3766, 6761, 3326, 6748, 6024, 1919, 7330, 5078, 6577, 3789, 6864, 5534, 5023, 3647, 6960, 3985, 7221, 5343, 2030, 3870, 7361, 3883, 6980, 5783, 5812, 3451, 6491, 5955, 3035, 7041, 5739, 5592, 7320, 3769, 6387, 5575, 5916, 7245, 6806, 3503, 5929, 3060, 5834, 5091, 7332, 3679, 6598, 5841, 6462, 5957, 3561, 6819, 7936, 6762, 5836, 3047, 4861, 7436, 3938, 7042, 3795, 6925, 5052, 5984, 3558, 7442, 7686, 6520, 6572, 2038, 5930, 7222, 4983, 6809, 3980, 6880, 5726, 5081, 3790, 6711, 3885, 7251, 6032, 7225, 5093, 3548, 7689, 3928, 6984, 5842, 5816, 3911, 6769, 5497, 3064, 6382, 5555, 2041, 7280, 3797, 6503, 6601, 5937, 3770, 6543, 3986, 6931, 5439, 5741, 3824, 3940, 6735, 5932, 6822, 5604, 6578, 3891, 6821, 5550, 2815, 5082, 7303, 3886, 7246, 3511, 6493, 5958, 4001, 7457, 7362, 6389, 5787, 3037, 5608, 7253, 5039, 6602, 3562, 6810, 5359, 5498, 7444, 3695, 6764, 7690, 5579, 5742, 7226, 4987, 7336, 3743, 6507, 5747, 5094, 5557, 3811, 6271, 7307, 5500, 6335, 2042, 4862, 7267, 3988, 6926, 6551, 5938, 3535, 6580, 3915, 6770, 5581, 2015, 7254, 6715, 3453, 6609, 5616, 6825, 5789, 6390, 3569, 6851, 5799, 3051, 4607, 4002, 3893, 7228, 6494, 5844, 3798, 7448, 4033, 6743, 5961, 3038, 6812, 5749, 7257, 3053, 3944, 6934, 5471, 5587, 7458, 7697, 6604, 3564, 5558, 7692, 5084, 7364, 3703, 6393, 5857, 5371, 5582, 3801, 6826, 7309, 5562, 6717, 5561, 5097, 7269, 3772, 6555, 6947, 5047, 5589, 3515, 7315, 3813, 6933, 5367, 2044, 5803, 7344, 6853, 6509, 6584, 5962, 5098, 6772, 3917, 6833, 5858, 3992, 6518, 3454, 7310, 6567, 6019, 7698, 3894, 6610, 5790, 3007, 6937, 5903, 3923, 7489, 6394, 3802, 6515, 5969, 7199, 3570, 6625, 3952, 6718, 5940, 7368, 4989, 3814, 3517, 6557, 5848, 6048, 7258, 3543, 6747, 3707, 5911, 6510, 5487, 5071, 7713, 4004, 6021, 3059, 4990, 5750, 3759, 7460, 7490, 6612, 5805, 2031, 5964, 7700, 6799, 7044, 5753, 5831, 6949, 3975, 6759, 5373, 5811, 7431, 6828, 3897, 7317, 6854, 5944, 5105, 7270, 3572, 6573, 6022, 3061, 6938, 5806, 3918, 6396, 7273, 6517, 6749, 7472, 3817, 5051, 6992, 3898, 6834, 5860, 3804, 3518, 6857, 4034, 6776, 5970, 5495, 7464, 6626, 4008, 6950, 5564, 5100, 3547, 3925, 7331, 5590, 5603, 3939, 7260, 3709, 6571, 5535, 5605, 7215, 7048, 6025, 2943, 5915, 5593, 7435, 3979, 6558, 5754, 5864, 7553, 6367, 7714, 5972, 3054, 6080, 5106, 7492, 3559, 6807, 5985, 6836, 5813, 3767, 6979, 7376, 6763, 6616, 5053, 7554, 3818, 6599, 3900, 6940, 5917, 3825, 7318, 7321, 6953, 3926, 6858, 2039, 7333, 5079, 6865, 3929, 6981, 6026, 5054, 3576, 6860, 3871, 7274, 5835, 7223, 3327, 7496, 4036, 7008, 5927, 5594, 3981, 5756, 3062, 6954, 5814, 5374, 7704, 3791, 6750, 5837, 7745, 7056, 3549, 5695, 6033, 7716, 3987, 6866, 5918, 6840, 5931, 6521, 7281, 6579, 5499, 3065, 5083, 7322, 3710, 7247, 3820, 6961, 5817, 4016, 7437, 7276, 6463, 6765, 5551, 7746, 5108, 6956, 3941, 6628, 5727, 7392, 3563, 6574, 3771, 7334, 5609, 7687, 5095, 7720, 3826, 6982, 5986, 5843, 3930, 6811, 7363, 5606, 6632, 2043, 7438, 3550, 6383, 6522, 6028, 4040, 6603, 3455, 6766, 5838, 5933, 7809, 3982, 6771, 5596, 6581, 5976, 6524, 3887, 5959, 3066, 5112, 7691, 4048, 7443, 6962, 5845, 3942, 7748, 7459, 6605, 5818, 3039, 6034, 7227, 6640, 3989, 6813, 5872, 5988, 7337, 7728, 6823, 7282, 5939, 7445, 4863, 7324, 3799, 6868, 5934, 5559, 3565, 6985, 7255, 6049, 6773, 5085, 7365, 3945, 6495, 6611, 5610, 3773, 7284, 4003, 6582, 5743, 2045, 7338, 6881, 6395, 6606, 5791, 6586, 3828, 6585, 5859, 3932, 3571, 7229, 6613, 6036, 7699, 3803, 6391, 5583, 3068, 6827, 5963, 7693, 7810, 3895, 6986, 5501, 7449, 7446, 6882, 3994, 5617, 7694, 5099, 7345, 3946, 7043, 6050, 5941, 7461, 3990, 6814, 7556, 5846, 6927, 6081, 5086, 7259, 3574, 6993, 5101, 5992, 4005, 7752, 7937, 6964, 2046, 5612, 7366, 6872, 7072, 5751, 6935, 3815, 6511, 5849, 7340, 7045, 3832, 7288, 6774, 5820, 7369, 3953, 6829, 5563, 3055, 6988, 5861, 3566, 7504, 6777, 6855, 7230, 3774, 6397, 3993, 6835, 5965, 7450, 3573, 3948, 6968, 6040, 5502, 7311, 7046, 3919, 6830, 5942, 5055, 7271, 4064, 7346, 5971, 5850, 3519, 7462, 7261, 6884, 5618, 6000, 7812, 6994, 6519, 5862, 5565, 7370, 3805, 6588, 5591, 5755, 7760, 6614, 7491, 6627, 6052, 5107, 7560, 3899, 6559, 5807, 6629, 4006, 7049, 7465, 6939, 6617, 7938, 3954, 6778, 4009, 6888, 6023, 4035, 7275, 6996, 3819, 7104, 5945, 7348, 7009, 3577, 6837, 5620, 5109, 3927, 3996, 7319, 5966, 7377, 3806, 7452, 3901, 6941, 5865, 5946, 7816, 5852, 3063, 5566, 6082, 7262, 7372, 7050, 6056, 7466, 6859, 7568, 5595, 5973, 7776, 4037, 6951, 5987, 6618, 5757, 6780, 7520, 6838, 6398, 4991, 7493, 4010, 7701, 3956, 6861, 6027, 3578, 7323, 7378, 6719, 7057, 7473, 5102, 6942, 3821, 6955, 5607, 4017, 6523, 4038, 7715, 5815, 7468, 7277, 3827, 6841, 5866, 5948, 3931, 7352, 5873, 6575, 5974, 7702, 4012, 6751, 5977, 7705, 6633, 3902, 5624, 5919, 7283, 3983, 7010, 5375, 6867, 6084, 6630, 7335, 6029, 3067, 5110, 7393, 3943, 7494, 7052, 5839, 3711, 7474, 7940, 6862, 6957, 5597, 7325, 6620, 3960, 7000, 6035, 7824, 7497, 6983, 3551, 7278, 7285, 5113, 7380, 4018, 6869, 5758, 5868, 3822, 6842, 7339, 6064, 7058, 7944, 4041, 6896, 7012, 5989, 3580, 3933, 6963, 5611, 5819, 7498, 6958, 6583, 5874, 7073, 3829, 5978, 7394, 4042, 7717, 6634, 5598, 7706, 7555, 6767, 6088, 3069, 5503, 7476, 7384, 3991, 6815, 6030, 7584, 7439, 6883, 7447, 5935, 7326, 5114, 7505, 3947, 7060, 6096, 7718, 3934, 6607, 7840, 5990, 6987, 5087, 7286, 3830, 6525, 6037, 4020, 7500, 7747, 6641, 2047, 7708, 7074, 6965, 5847, 6870, 4049, 7105, 5613, 7557, 3995, 7341, 7016, 5993, 7289, 4044, 5821, 3070, 6636, 6051, 7721, 7367, 6775, 7952, 7347, 6873, 3833, 5876, 7396, 7506, 3949, 6844, 5980, 5619, 7480, 6587, 7872, 6885, 5851, 5116, 7558, 4024, 7342, 5943, 3567, 7722, 7749, 6989, 6042, 7561, 7064, 6526, 5994, 7451, 3775, 6966, 6038, 7290, 6995, 7616, 6874, 5622, 7521, 4007, 6642, 6053, 7024, 4050, 7729, 6886, 6589, 7371, 3955, 6615, 3834, 6779, 5863, 7231, 7508, 3575, 7076, 5880, 7562, 6831, 3997, 6001, 5103, 7695, 3950, 7750, 5614, 7724, 3807, 7349, 7463, 7047, 5822, 6041, 7453, 6969, 5621, 5996, 7400, 7292, 6644, 5967, 7373, 6990, 7350, 6112, 7811, 4065, 6889, 5567, 6970, 6876, 7730, 6590, 7106, 7454, 3957, 7753, 4011, 7080, 5853, 4066, 7467, 6619, 6997, 7522, 7011, 4052, 6781, 5947, 3998, 3836, 7379, 6054, 7569, 7353, 4013, 7051, 6002, 6057, 7564, 7512, 6083, 5867, 7754, 7813, 6631, 5625, 7761, 6839, 7703, 5975, 6044, 7408, 4039, 6890, 5854, 6972, 5949, 6897, 7374, 6998, 5111, 7263, 3958, 7495, 7001, 3903, 7732, 7968, 6648, 6943, 7570, 6399, 4019, 7108, 6085, 7524, 7053, 3579, 7475, 7469, 7585, 3961, 6863, 6058, 6004, 4056, 7381, 5626, 6621, 7736, 3823, 7059, 5869, 8000, 4014, 6065, 6086, 7756, 6782, 6892, 5875, 7088, 7354, 5979, 7814, 4068, 7572, 7013, 6060, 7395, 8064, 6635, 6843, 5950, 7762, 7586, 4043, 6898, 6031, 7470, 7817, 7002, 7939, 7528, 5115, 7707, 3962, 6622, 5991, 3581, 7112, 7279, 5759, 6527, 7499, 4021, 7054, 6008, 4045, 7382, 6959, 5599, 7477, 7120, 6066, 7014, 4072, 5870, 7356, 3964, 7617, 7061, 6089, 7385, 7576, 5628, 3071, 5981, 7777, 7764, 6871, 7719, 7818, 6637, 7397, 5877, 7327, 7588, 4022, 7017, 6090, 7478, 6845, 7709, 7075, 5117, 7941, 3935, 7778, 6039, 3831, 7825, 7501, 6900, 7287, 7004, 6643, 5995, 4080, 6875, 5982, 7768, 7507, 6967, 5878, 7386, 3582, 6068, 7066, 7536, 7820, 7018, 7398, 7559, 7062, 4051, 6097, 7481, 7618, 4025, 6646, 6043, 7710, 7077, 7502, 6092, 5118, 7401, 3835, 7723, 7942, 4046, 7343, 7291, 6887, 5881, 7826, 6904, 5997, 7780, 7509, 7025, 7945, 6638, 7388, 6072, 7482, 4026, 6846, 5615, 7065, 7592, 6645, 7020, 7563, 3951, 4053, 6991, 5823, 7841, 7751, 7136, 7523, 6591, 4054, 6055, 7455, 3999, 7351, 6098, 7402, 7293, 7725, 6877, 6003, 5882, 7828, 7784, 5623, 7510, 7484, 6971, 6045, 7409, 7078, 7946, 5998, 7731, 4067, 7026, 5855, 7081, 7107, 7513, 6891, 7620, 3837, 7565, 6649, 4028, 7571, 6999, 7068, 7375, 6878, 3959, 6973, 6113, 7842, 4057, 7726, 7953, 7600, 4069, 6005, 6059, 7525, 7355, 6114, 7404, 7832, 7109, 6100, 7792, 7755, 6046, 5884, 7948, 7082, 7028, 6061, 6650, 7873, 7294, 4058, 7410, 6893, 7733, 7566, 7089, 7110, 7514, 7624, 4015, 6899, 6087, 7526, 7003, 7573, 7471, 7737, 3963, 7084, 6006, 4070, 7412, 5951, 6974, 7763, 3838, 7055, 6067, 7357, 7734, 5627, 7844, 7015, 6009, 6783, 7529, 6104, 7874, 3583, 7757, 7032, 5871, 7383, 7954, 6623, 6062, 7815, 7516, 7090, 7587, 7574, 6894, 7632, 7848, 7969, 4060, 7113, 6116, 6652, 7530, 7005, 7758, 4073, 7577, 6091, 4023, 7738, 6901, 7956, 7114, 6010, 4074, 5629, 7765, 7740, 7063, 6069, 7387, 7479, 6093, 7876, 7766, 7019, 7769, 7819, 7006, 7589, 6120, 7960, 7970, 3965, 6902, 6012, 7779, 7092, 7770, 5119, 7578, 4047, 7399, 3966, 7856, 7821, 7121, 7416, 7067, 6070, 7537, 7116, 7358, 7532, 5983, 7822, 4081, 5879, 6905, 7827, 7021, 7503, 7648, 4027, 6128, 7483, 7389, 7096, 7538, 6639, 7781, 5630, 7590, 4076, 7593, 7619, 7782, 7711, 6847, 6099, 7403, 7580, 6073, 7511, 7540, 7079, 7943, 7122, 7485, 5883, 4082, 7027, 6094, 6906, 7390, 6647, 7594, 4029, 7069, 7621, 7405, 7022, 7727, 6879, 4055, 6074, 8001, 4030, 7972, 7880, 8002, 7829, 5999, 6101, 7976, 7947, 7785, 7772, 7137, 6102, 7601, 7888, 6047, 7984, 7029, 7083, 7138, 8004, 7515, 4059, 8065, 7124, 7411, 7070, 6908, 7830, 4084, 7085, 6115, 7622, 7486, 7843, 7786, 4071, 5885, 8066, 7949, 6076, 7544, 7596, 7111, 6007, 7833, 7904, 6105, 7735, 7030, 6117, 6975, 8008, 7793, 4088, 7406, 7091, 7527, 7625, 6651, 7567, 7955, 7033, 7759, 7128, 7846, 7602, 7845, 3839, 6895, 6106, 7517, 7086, 7413, 4061, 6063, 7626, 7834, 7788, 7140, 6011, 7531, 6118, 7295, 7359, 7115, 5886, 7950, 7575, 7604, 7794, 7034, 7739, 7633, 6653, 7849, 7414, 7875, 4075, 7093, 5631, 7117, 7518, 7767, 4062, 7836, 4077, 7958, 7144, 7628, 7036, 6108, 7417, 7850, 7741, 6121, 7579, 7971, 6071, 7957, 7094, 7877, 7533, 7608, 6122, 7796, 7857, 7007, 7542, 6903, 7591, 7634, 4031, 7961, 7418, 7539, 7152, 7649, 7742, 6013, 7581, 6654, 7771, 7534, 6095, 4083, 6014, 7123, 7636, 7097, 7823, 8068, 7973, 7783, 6907, 7852, 7118, 7878, 6129, 7597, 4085, 7962, 7420, 7541, 7773, 6075, 8016, 7858, 7881, 7800, 7098, 7650, 7974, 6124, 7023, 7125, 7595, 8072, 3967, 7126, 7582, 7071, 7391, 4078, 6130, 7831, 7860, 8003, 7787, 7640, 6077, 7623, 7964, 7977, 7882, 7139, 6103, 7889, 8005, 6078, 7884, 6909, 7100, 8032, 4086, 7978, 7031, 7774, 7129, 8080, 7141, 7890, 7864, 7545, 7603, 4089, 6107, 7985, 7487, 7789, 6132, 7980, 7652, 7598, 7130, 6119, 8006, 7835, 7656, 7087, 7407, 7546, 7627, 7790, 7035, 7795, 7142, 7605, 7548, 4090, 6910, 6136, 7986, 7629, 4063, 7664, 7837, 7847, 6655, 5887, 7892, 8009, 7797, 6109, 7519, 7635, 7606, 7132, 7905, 7419, 7630, 7610, 7609, 7145, 7095, 7637, 7415, 4092, 7851, 8010, 7146, 7906, 6123, 8067, 7838, 7951, 6110, 8017, 6125, 7988, 7037, 7896, 8096, 7959, 7535, 7119, 8069, 7038, 7798, 7853, 4079, 8012, 7801, 7879, 7421, 7859, 7992, 7153, 8070, 7854, 6079, 7099, 7908, 8018, 7543, 7612, 7148, 7638, 7651, 6131, 7583, 7653, 8073, 7963, 7641, 7802, 7912, 8020, 8128, 7154, 8033, 7861, 6133, 7101, 7965, 4087, 7127, 8074, 7102, 7883, 7975, 7642, 7804, 7862, 7422, 6015, 7885, 7743, 8081, 6126, 7966, 7979, 7547, 7131, 7865, 7599, 7156, 7775, 7657, 7143, 8034, 7891, 7654, 4091, 6134, 8076, 7886, 7981, 7644, 8024, 8007, 7160, 6137, 7893, 7866, 8082, 7920, 8036, 7987, 6911, 7982, 7607, 8097, 7133, 7658, 7791, 4093, 7839, 7907, 6138, 8084, 7631, 8011, 6111, 7549, 7665, 7147, 8098, 7989, 7894, 8129, 7134, 7149, 8040, 4094, 7660, 7799, 7897, 7868, 7611, 7909, 6140, 8013, 8088, 7550, 7990, 7103, 8019, 7898, 7666, 8048, 7910, 7613, 7639, 7803, 8100, 7155, 7855, 6127, 8071, 7993, 7668, 7157, 8014, 7913, 7994, 7900, 7614, 8130, 8104, 7643, 8021, 8035, 7805, 7039, 8075, 7150, 7655, 7863, 7914, 7996, 7921, 8022, 6135, 8025, 7672, 7967, 7423, 8132, 8077, 7158, 7887, 7645, 8083, 7161, 7806, 7916, 8112, 8037, 7659, 7867, 7922, 8026, 6139, 7646, 8136, 7551, 8078, 7983, 7162, 8144, 8038, 7135, 8085, 4095, 7895, 7661, 8041, 7869, 8099, 6141, 7924, 8028, 7667, 7899, 7164, 7991, 8090, 8042, 8086, 7670, 8101, 6142, 7911, 7928, 8049, 7151, 7662, 7870, 8089, 7669, 8044, 8015, 8160, 7615, 7901, 7995, 8102, 8050, 8105, 8131, 7915, 7673, 8023, 8092, 7902, 7997, 7159, 8133, 8106, 8052, 7674, 7917, 8113, 8134, 7923, 8027, 8108, 7998, 8079, 7163, 8039, 7807, 8056, 7647, 8114, 7918, 8137, 7676, 8029, 7925, 8138, 7165, 8087, 8043, 8030, 7926, 8116, 6143, 8145, 8091, 8140, 7166, 7929, 8045, 8120, 7663, 7871, 8103, 8146, 8051, 7930, 7671, 8093, 8046, 7903, 8161, 8053, 8107, 8162, 8148, 8094, 7932, 8109, 8135, 8054, 7999, 8115, 7675, 8057, 8152, 7919, 8110, 8164, 8139, 8058, 7677, 8117, 8141, 8168, 8060, 7167, 8118, 8031, 7927, 8176, 7678, 8147, 8121, 7931, 8142, 8122, 8047, 8149, 8150, 8095, 8163, 7933, 8124, 8055, 8153, 8165, 8154, 8111, 8059, 8166, 7934, 7679, 8156, 8169, 8119, 8170, 8061, 8143, 8062, 8177, 8123, 8172, 8178, 8125, 8151, 8126, 8155, 8180, 8167, 8184, 7935, 8157, 8171, 8158, 8173, 8127, 8179, 8181, 8063, 8174, 8182, 8185, 8186, 8159, 8188, 8175, 8183, 8187, 8189, 8190, 8191]

### Sequence Group 5: Q5_8192

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 67, 41, 144, 28, 69, 42, 516, 49, 74, 272, 160, 1026, 520, 288, 528, 192, 544, 70, 44, 131, 81, 50, 73, 15, 320, 133, 52, 23, 134, 384, 76, 137, 82, 56, 27, 97, 39, 259, 84, 138, 145, 261, 29, 43, 98, 515, 88, 140, 30, 146, 1028, 71, 262, 265, 2048, 161, 576, 45, 100, 640, 1025, 51, 148, 46, 75, 266, 273, 517, 104, 162, 53, 193, 1032, 152, 77, 164, 768, 268, 274, 518, 54, 83, 57, 521, 112, 1024, 135, 78, 289, 194, 85, 276, 522, 58, 168, 139, 99, 86, 60, 280, 89, 290, 529, 524, 196, 141, 1040, 101, 147, 176, 2049, 142, 530, 321, 31, 200, 90, 1056, 545, 292, 322, 532, 2050, 263, 149, 102, 105, 304, 4096, 296, 1030, 163, 92, 1033, 47, 267, 385, 546, 324, 2052, 208, 386, 150, 153, 165, 106, 55, 328, 1088, 536, 577, 548, 1034, 113, 154, 79, 269, 108, 578, 2056, 224, 166, 519, 552, 195, 270, 1041, 641, 1036, 523, 275, 580, 291, 59, 169, 560, 114, 277, 156, 87, 1152, 197, 116, 170, 2064, 61, 1042, 531, 525, 642, 281, 278, 526, 177, 293, 388, 1057, 91, 584, 769, 198, 2080, 172, 120, 201, 336, 62, 282, 4097, 143, 1029, 1044, 103, 178, 294, 93, 1058, 644, 202, 2051, 592, 323, 392, 2053, 297, 770, 4098, 107, 180, 1280, 151, 209, 284, 1027, 648, 94, 204, 298, 400, 608, 2112, 1089, 352, 325, 533, 155, 210, 305, 2057, 4100, 547, 300, 109, 1048, 184, 534, 1060, 537, 115, 1090, 167, 225, 326, 2054, 306, 772, 157, 2065, 656, 329, 110, 117, 212, 171, 1038, 776, 1064, 4104, 330, 1153, 2058, 226, 549, 1043, 538, 387, 308, 216, 416, 271, 279, 158, 337, 2066, 550, 672, 1092, 118, 332, 579, 540, 1072, 2176, 389, 173, 1037, 121, 553, 199, 784, 179, 228, 4112, 338, 312, 1536, 704, 1154, 390, 174, 554, 581, 1046, 393, 2060, 283, 2081, 122, 448, 353, 2113, 561, 1096, 203, 63, 4128, 340, 394, 1049, 1281, 527, 582, 556, 181, 295, 1059, 285, 232, 124, 2068, 205, 182, 643, 2304, 1156, 562, 286, 585, 4099, 299, 354, 2082, 1045, 4101, 211, 401, 1104, 185, 1061, 396, 344, 586, 645, 1282, 593, 535, 240, 2072, 1050, 206, 95, 327, 2084, 564, 800, 402, 2055, 4160, 356, 307, 301, 417, 1160, 213, 1066, 568, 1120, 832, 4105, 588, 1035, 1537, 186, 2177, 646, 404, 2114, 1091, 227, 896, 594, 418, 2560, 302, 649, 771, 360, 539, 2059, 4102, 111, 1052, 331, 1168, 4113, 214, 309, 1062, 1284, 2088, 188, 449, 1073, 217, 408, 609, 596, 2116, 551, 650, 229, 159, 4106, 420, 2178, 310, 1093, 541, 1288, 773, 610, 657, 333, 1065, 119, 1098, 2067, 4114, 2061, 600, 339, 1184, 218, 2096, 368, 652, 1031, 230, 391, 313, 4224, 450, 542, 1538, 334, 1076, 233, 555, 2062, 774, 175, 123, 1155, 658, 2120, 612, 341, 2305, 777, 220, 314, 2069, 1105, 424, 1068, 395, 4108, 673, 4129, 583, 355, 1296, 2180, 1094, 4161, 287, 183, 234, 1051, 125, 557, 1216, 660, 616, 342, 316, 2083, 1157, 241, 778, 2306, 563, 2074, 1074, 345, 452, 397, 2561, 4116, 403, 1112, 207, 2128, 1540, 4352, 674, 558, 785, 1100, 432, 1039, 357, 187, 1162, 236, 664, 1312, 624, 4130, 587, 780, 1080, 2085, 1122, 705, 2073, 126, 242, 2070, 1063, 565, 398, 2184, 346, 456, 2308, 4120, 358, 405, 303, 569, 2312, 1544, 4132, 244, 1158, 1097, 595, 1283, 189, 4103, 566, 676, 1169, 1054, 1108, 361, 2086, 706, 589, 2562, 1344, 215, 786, 647, 348, 2144, 2115, 419, 406, 464, 680, 4225, 801, 2089, 4162, 1069, 362, 1164, 590, 409, 1286, 4608, 570, 1121, 788, 1552, 2192, 1106, 4107, 2076, 597, 1075, 572, 1186, 219, 311, 2117, 708, 598, 2090, 1289, 601, 651, 421, 792, 4136, 802, 2564, 611, 1047, 602, 1172, 410, 231, 2097, 4164, 688, 653, 1128, 248, 1070, 2122, 4226, 369, 2320, 190, 364, 1568, 654, 2208, 1095, 659, 1161, 335, 480, 4115, 315, 4109, 221, 3074, 370, 1285, 613, 2568, 1408, 4144, 422, 425, 2336, 451, 1077, 614, 543, 1298, 235, 412, 2576, 343, 372, 2240, 1185, 775, 317, 2592, 4110, 2118, 1539, 222, 1099, 426, 4168, 2092, 453, 4353, 237, 1124, 559, 1170, 2179, 1292, 4117, 833, 804, 712, 1082, 834, 661, 1053, 808, 779, 2129, 1217, 617, 604, 2098, 1541, 433, 4228, 720, 2121, 816, 1101, 2063, 1176, 836, 2368, 347, 897, 2181, 1136, 4131, 243, 1297, 2100, 662, 4354, 2071, 1600, 4122, 454, 318, 675, 1110, 618, 2182, 1081, 4609, 898, 781, 1314, 1220, 376, 428, 1546, 665, 4176, 736, 567, 1107, 2432, 1192, 1078, 840, 2124, 2185, 625, 238, 2130, 1159, 359, 457, 2104, 399, 787, 2075, 2145, 4133, 591, 678, 434, 4121, 677, 2087, 1290, 4118, 1542, 349, 1300, 1102, 245, 4232, 1188, 458, 4356, 666, 1113, 620, 1553, 1163, 2307, 1313, 4360, 363, 2132, 127, 1067, 191, 2186, 1125, 782, 407, 2193, 436, 626, 2309, 2077, 1218, 571, 465, 681, 2091, 246, 4134, 707, 2146, 4610, 1346, 350, 1084, 599, 668, 2563, 1548, 4192, 4163, 790, 1165, 1320, 460, 1123, 2136, 1200, 4137, 249, 2188, 682, 1664, 573, 1171, 411, 803, 2078, 1116, 789, 2194, 1304, 709, 365, 4240, 440, 628, 4124, 689, 3076, 2119, 374, 1224, 423, 2310, 1556, 4165, 466, 793, 2313, 4138, 1130, 250, 371, 1174, 481, 574, 1348, 2209, 4612, 413, 2624, 1109, 603, 366, 2093, 1545, 4145, 2148, 1287, 1055, 468, 1570, 655, 900, 4170, 2688, 805, 4368, 615, 3073, 1166, 684, 1409, 710, 2099, 1187, 4256, 429, 794, 2196, 252, 1114, 373, 605, 1232, 848, 690, 2094, 5122, 2123, 713, 632, 2314, 1316, 482, 4616, 806, 2321, 4384, 1132, 2565, 1083, 427, 2152, 1177, 904, 4624, 2210, 1569, 4288, 414, 1291, 2101, 223, 1126, 4640, 2241, 1554, 4166, 663, 3080, 692, 835, 1328, 619, 472, 2200, 1137, 4140, 455, 796, 2125, 1189, 1601, 809, 714, 2212, 1248, 721, 4227, 837, 2816, 716, 1086, 2316, 1302, 1352, 864, 2322, 2566, 4177, 810, 2102, 1173, 4146, 606, 1194, 2131, 912, 4169, 2105, 2569, 1103, 4111, 722, 696, 377, 4416, 1424, 435, 2160, 1293, 4229, 1560, 817, 1129, 1792, 319, 621, 4148, 1180, 812, 4119, 484, 3072, 1345, 430, 1572, 2183, 1138, 2126, 1299, 4230, 838, 2337, 2242, 667, 1219, 488, 2133, 1111, 239, 378, 2324, 2570, 459, 622, 2106, 2216, 1410, 4480, 627, 437, 2187, 380, 4172, 4233, 2147, 1201, 4178, 1608, 818, 1178, 1294, 461, 4152, 2134, 1543, 4123, 496, 4193, 669, 1190, 1317, 679, 1140, 1079, 2108, 1221, 4135, 724, 2328, 841, 1305, 629, 2137, 1584, 351, 467, 2338, 2577, 1360, 438, 2572, 2244, 1115, 737, 251, 4355, 462, 2189, 442, 4180, 441, 3088, 2149, 4234, 1666, 469, 2195, 1549, 4241, 247, 683, 2224, 1196, 4357, 1226, 4125, 842, 1412, 1127, 738, 4139, 1144, 2190, 1308, 4194, 899, 2578, 1602, 670, 1318, 783, 2369, 1085, 4611, 849, 2079, 1555, 1193, 820, 2248, 1576, 728, 928, 4184, 2138, 791, 4236, 367, 3104, 2593, 1376, 901, 1233, 630, 2340, 2370, 1321, 4126, 685, 844, 2580, 4242, 1204, 633, 711, 1118, 253, 691, 2311, 1301, 5124, 2197, 4167, 824, 2150, 1175, 902, 4358, 686, 2153, 1668, 4361, 1222, 2352, 1416, 1133, 740, 6144, 1347, 850, 375, 4257, 2344, 1558, 4672, 444, 3078, 1306, 2211, 470, 1167, 4141, 483, 2140, 1547, 4196, 415, 3081, 485, 2095, 905, 1202, 795, 473, 2315, 1240, 4736, 634, 744, 2433, 5121, 2594, 1616, 852, 960, 2372, 1322, 865, 4147, 693, 2256, 4244, 1131, 2434, 1794, 1350, 797, 2198, 2201, 1225, 4142, 4171, 2213, 1604, 1571, 4362, 906, 1252, 2154, 715, 1141, 4369, 2103, 2376, 1330, 4613, 807, 3136, 474, 636, 4200, 1179, 694, 254, 2584, 1550, 4258, 1665, 717, 2625, 1071, 1315, 575, 913, 4149, 2596, 1440, 798, 4289, 811, 3082, 5128, 2161, 379, 1208, 2202, 1353, 2127, 1191, 4248, 697, 2317, 2156, 4173, 1564, 431, 2626, 1142, 4260, 607, 2272, 1228, 2214, 489, 4864, 2567, 2600, 1324, 4364, 866, 723, 2243, 486, 4370, 1573, 4614, 2318, 1181, 4150, 1234, 3089, 908, 1793, 1561, 718, 813, 4179, 2689, 1364, 4153, 476, 4617, 856, 3084, 1117, 1411, 839, 1329, 2571, 1295, 2323, 1146, 4208, 725, 2628, 2339, 698, 1472, 914, 2107, 1249, 752, 868, 2217, 2608, 5120, 2162, 819, 2325, 2204, 1349, 4231, 814, 4174, 439, 2135, 929, 4385, 4290, 3200, 2245, 1197, 4181, 1578, 490, 2164, 1139, 4372, 1680, 623, 4618, 2218, 1632, 4154, 1336, 4264, 671, 1198, 1362, 739, 1603, 4235, 1557, 2109, 1413, 4195, 916, 3090, 2579, 1303, 463, 1236, 843, 2573, 2690, 1135, 4182, 381, 2329, 2326, 1672, 1354, 497, 2574, 2225, 1586, 930, 821, 4156, 2341, 2436, 726, 4376, 961, 3105, 2139, 1203, 4185, 1182, 872, 2632, 2817, 1418, 4386, 4625, 492, 2246, 1250, 4620, 1332, 4292, 631, 1574, 1223, 729, 4237, 2220, 1145, 5136, 2168, 1605, 4197, 700, 2249, 1796, 443, 4243, 1307, 741, 2384, 1378, 4272, 1562, 2110, 1356, 1205, 845, 2330, 6145, 1319, 920, 382, 4238, 2191, 3077, 1585, 4626, 822, 3092, 2151, 1425, 2226, 851, 1229, 4417, 730, 2342, 2141, 1609, 4127, 498, 3106, 880, 2692, 4296, 1256, 742, 445, 2250, 1392, 4186, 471, 635, 2640, 1148, 5152, 2371, 1696, 4641, 932, 2440, 1580, 687, 4388, 4418, 2345, 1210, 4628, 1420, 2818, 1612, 1325, 1800, 903, 6146, 2155, 1134, 4359, 825, 4245, 2228, 1235, 1361, 4198, 500, 3328, 1577, 2199, 846, 1670, 4201, 2257, 2332, 1195, 4400, 745, 3075, 826, 2696, 732, 1264, 446, 962, 2142, 2252, 1426, 4392, 1620, 936, 2346, 5126, 2448, 1377, 475, 853, 4259, 2656, 1310, 867, 4188, 637, 3137, 5129, 2400, 4143, 1551, 2373, 1230, 2581, 1414, 4363, 907, 2203, 2258, 1206, 4481, 1667, 4642, 2353, 1588, 1333, 4420, 487, 6148, 1808, 2595, 695, 1441, 4304, 2348, 2157, 1087, 4482, 746, 3096, 828, 2232, 753, 4246, 1610, 4249, 854, 2582, 1237, 4261, 1326, 3108, 857, 2585, 1368, 1209, 504, 799, 4202, 2163, 1355, 4151, 255, 4424, 964, 3138, 5184, 2215, 1242, 909, 1673, 2273, 1559, 2374, 1309, 4632, 719, 2354, 2820, 4673, 1143, 477, 2205, 1617, 4644, 915, 2704, 2377, 1448, 5130, 2158, 4209, 2165, 2260, 1380, 4250, 638, 4175, 748, 2219, 944, 4365, 1728, 4204, 3086, 2824, 1331, 4674, 1227, 3112, 869, 6152, 1592, 4320, 1428, 491, 699, 4262, 2378, 1253, 4615, 1351, 4648, 754, 3201, 1183, 1565, 858, 1618, 4291, 2274, 1417, 2597, 1476, 4366, 478, 3091, 2586, 5137, 2435, 968, 1260, 383, 2356, 2264, 1212, 4737, 910, 2464, 2319, 5132, 2327, 1801, 815, 2206, 2385, 1579, 4619, 976, 4371, 2598, 2720, 870, 4676, 4387, 3140, 2166, 1684, 4155, 1633, 917, 2380, 2627, 1337, 4265, 1241, 4656, 4210, 2588, 1606, 4373, 1824, 3120, 4252, 727, 1150, 1442, 493, 1357, 4183, 2437, 1251, 5248, 2221, 1676, 4293, 873, 3085, 2169, 1384, 701, 4212, 1566, 931, 2601, 2247, 1323, 4266, 1798, 2832, 2227, 1365, 1473, 756, 2276, 6160, 2386, 1334, 860, 499, 4157, 2360, 3584, 5138, 2752, 4627, 731, 3202, 2438, 1648, 2222, 4621, 1238, 4738, 823, 2602, 2629, 1575, 4377, 4374, 3094, 922, 2441, 1199, 4622, 1674, 4273, 874, 2331, 1432, 4389, 1421, 918, 4484, 2170, 1636, 5153, 2496, 1254, 4187, 502, 2401, 1795, 933, 4680, 1366, 4865, 2609, 1338, 4294, 1682, 3144, 2251, 1587, 1211, 1488, 743, 2111, 6176, 2388, 1358, 4268, 760, 4216, 2442, 3097, 1244, 1581, 4297, 881, 3329, 2575, 1147, 2630, 494, 1379, 4432, 2604, 2229, 2343, 1272, 4158, 702, 3107, 921, 2333, 4378, 1624, 501, 876, 2280, 2172, 1415, 4239, 5125, 847, 2253, 1856, 5140, 2230, 1444, 4199, 992, 4274, 2691, 1697, 447, 4390, 4189, 3204, 5154, 2610, 1607, 4740, 1436, 2334, 1369, 2633, 1257, 4298, 1704, 733, 6147, 2347, 1797, 4688, 1669, 4419, 2402, 1340, 1231, 4488, 827, 3093, 6149, 1590, 2259, 934, 1634, 4393, 2449, 3152, 2233, 1474, 4866, 882, 3109, 937, 2444, 2392, 963, 1419, 4203, 747, 2634, 2693, 1265, 4276, 1119, 3330, 505, 2641, 5376, 2583, 1381, 855, 924, 4247, 2288, 1810, 4305, 734, 4380, 829, 3098, 5123, 2254, 1563, 4744, 1213, 2143, 1611, 2375, 1363, 4190, 4300, 2612, 2848, 1430, 4394, 1258, 4496, 2450, 1688, 1386, 4704, 965, 6208, 2404, 1614, 5185, 2355, 1730, 4448, 2349, 2465, 1239, 4421, 938, 4629, 3208, 884, 2261, 506, 4251, 1327, 4306, 3114, 2616, 1589, 4401, 1804, 3168, 749, 2880, 6153, 1370, 1640, 945, 966, 4643, 2636, 3083, 1456, 4396, 1681, 4205, 755, 3585, 5144, 2234, 1266, 859, 1427, 4280, 2694, 1593, 2452, 1388, 4630, 940, 3139, 2275, 5156, 2944, 4633, 1214, 830, 2642, 2466, 1809, 4211, 911, 2350, 2697, 1621, 5186, 2819, 1582, 4263, 2408, 2587, 1832, 4321, 871, 4422, 6150, 2159, 639, 4402, 1480, 4868, 3100, 2379, 1698, 4253, 1335, 3216, 888, 6161, 2262, 1372, 4752, 1245, 4425, 479, 4206, 2357, 1422, 4213, 1268, 3110, 4308, 946, 3332, 1732, 1677, 750, 1802, 4267, 2236, 1626, 5134, 2497, 1393, 4872, 969, 3121, 2265, 5160, 2456, 508, 1613, 861, 2657, 2644, 1446, 4426, 1857, 2599, 2698, 5249, 2277, 1339, 757, 2207, 6154, 2468, 1382, 4322, 970, 4645, 2358, 3141, 5139, 2589, 4634, 4483, 3336, 2821, 1700, 2658, 4404, 1243, 4312, 919, 2705, 2381, 1594, 4512, 1433, 4367, 3113, 4375, 2167, 1826, 4254, 1504, 3146, 4433, 875, 6162, 1635, 4646, 1259, 862, 1920, 4768, 2648, 1675, 5188, 2387, 1445, 4214, 758, 3232, 2266, 1149, 948, 4428, 1359, 4675, 2416, 2700, 1816, 4636, 1596, 3079, 2278, 5168, 2439, 1671, 1712, 977, 2361, 6272, 2498, 1385, 4485, 923, 4269, 2590, 3586, 5133, 2382, 1622, 4217, 972, 3124, 2281, 1434, 2603, 4649, 1311, 4295, 2822, 2223, 2171, 1729, 4880, 4275, 3203, 761, 2706, 4324, 1396, 4434, 877, 2660, 2389, 1207, 4408, 1475, 5632, 4800, 2825, 1449, 5250, 2268, 1812, 4486, 952, 4270, 2362, 1686, 495, 4650, 1262, 4677, 3153, 5142, 2472, 1644, 4489, 1619, 3116, 2443, 1341, 6156, 1429, 4379, 1825, 703, 2721, 6177, 2631, 1371, 4218, 1638, 4544, 2403, 3344, 1567, 1736, 4449, 935, 3142, 6209, 2335, 1685, 2231, 978, 1625, 4657, 2282, 3099, 2173, 5192, 2605, 4299, 883, 3264, 762, 2708, 2664, 4159, 1246, 4436, 503, 2390, 2364, 1458, 4490, 5145, 3205, 925, 2289, 1394, 5377, 2826, 1269, 4623, 878, 4678, 2611, 1478, 4652, 735, 4277, 4391, 3122, 5155, 2393, 1799, 4381, 1678, 2500, 1860, 2445, 1443, 4328, 1637, 4220, 6164, 2451, 1481, 4301, 1373, 3160, 4278, 2255, 1699, 1255, 4739, 993, 3588, 6400, 2722, 1591, 5252, 2606, 1828, 4658, 2833, 3148, 2480, 1452, 4382, 885, 4681, 3087, 939, 2405, 2235, 994, 1400, 4395, 3210, 2284, 2712, 1744, 4450, 1656, 3360, 980, 2672, 6178, 5141, 2635, 1689, 926, 764, 4307, 2828, 3128, 1270, 4497, 5200, 4281, 941, 3170, 5157, 2753, 1628, 4492, 1367, 4440, 2174, 1805, 2290, 1457, 4682, 4741, 3111, 2613, 5378, 2446, 1921, 4689, 1583, 4631, 2394, 2504, 1387, 4336, 1642, 967, 6168, 2406, 1267, 5146, 2453, 1484, 4302, 2351, 2617, 1450, 4191, 886, 4423, 3592, 6180, 2292, 831, 4660, 1683, 4896, 3206, 3145, 2643, 1342, 4498, 1811, 3331, 947, 2237, 6151, 2614, 1705, 1431, 4452, 507, 4403, 2724, 3217, 1261, 4397, 1840, 3102, 4513, 889, 3156, 5256, 2409, 1650, 984, 1760, 4309, 2754, 1490, 5162, 2637, 1615, 4664, 751, 3392, 2263, 5216, 2834, 4928, 1702, 942, 2695, 2396, 1858, 4684, 5131, 2467, 2454, 1423, 5633, 2512, 1460, 4282, 2728, 6273, 2849, 1383, 4742, 996, 4500, 6210, 3117, 5187, 2410, 4323, 1692, 4992, 3212, 2638, 1641, 2457, 4690, 1814, 4514, 3334, 971, 6656, 2618, 1477, 4398, 1273, 4745, 3169, 4867, 2836, 1512, 4456, 1733, 3600, 4635, 890, 3154, 6155, 1598, 1374, 509, 1806, 4207, 2645, 3123, 1922, 5148, 2620, 1649, 4427, 949, 3234, 2267, 5264, 2359, 973, 1397, 4310, 2756, 2646, 1489, 4405, 1708, 3337, 2649, 5158, 2699, 5380, 2469, 1627, 1000, 2840, 6184, 2850, 1690, 4284, 892, 4545, 2659, 3095, 5169, 2650, 1274, 4313, 4504, 3220, 2458, 1438, 2279, 4705, 1817, 4692, 6212, 2736, 2701, 1390, 4647, 1464, 4746, 3176, 4325, 2296, 4255, 1868, 3118, 4516, 950, 6274, 2417, 1151, 4406, 1731, 5189, 1506, 4637, 2238, 1827, 5384, 2412, 1597, 4869, 863, 4706, 3616, 2702, 1451, 759, 4753, 1864, 4429, 3143, 5161, 2707, 1714, 4215, 1701, 3209, 2383, 5194, 2528, 6163, 1395, 1803, 1008, 2363, 6157, 2269, 1623, 4696, 1482, 4435, 2418, 3333, 5280, 2661, 1276, 4314, 510, 3456, 6192, 2470, 1435, 2473, 4464, 1652, 4748, 2499, 3125, 2662, 5127, 2591, 4326, 4487, 3346, 979, 2283, 2460, 4409, 1492, 4546, 953, 2391, 2420, 1928, 4638, 1829, 5634, 3233, 4430, 2823, 1389, 5172, 2365, 1738, 4329, 763, 4651, 6158, 1872, 4870, 974, 4271, 1453, 4219, 3587, 5251, 2270, 1643, 4754, 1713, 3147, 2474, 1818, 6216, 1215, 4708, 1402, 4437, 2501, 6401, 2285, 1629, 4873, 1520, 3172, 4316, 2607, 3218, 1830, 1691, 4410, 954, 3340, 6165, 2881, 1459, 5201, 2852, 1734, 4520, 2760, 3130, 2882, 5164, 2709, 4491, 879, 3101, 981, 2856, 2827, 4769, 1505, 4679, 3265, 2665, 2652, 1706, 4451, 5392, 3589, 982, 2481, 6276, 5190, 2768, 1924, 4383, 927, 4279, 2864, 3149, 1833, 4330, 5147, 4221, 4653, 3224, 5312, 2884, 1639, 4756, 1447, 4712, 2395, 1746, 2945, 1343, 4438, 1679, 4412, 3184, 6179, 5253, 2291, 1820, 4337, 1761, 3345, 4874, 2710, 6402, 1479, 4659, 1275, 995, 3648, 6170, 2502, 1740, 5170, 2366, 1401, 4441, 2723, 3158, 2666, 1888, 4548, 765, 4493, 3129, 6657, 2946, 2829, 956, 1496, 4499, 3362, 3268, 2424, 5208, 2476, 4303, 1861, 3594, 887, 2713, 6224, 2784, 5636, 1437, 4770, 985, 4654, 2615, 3155, 1720, 4881, 5196, 3240, 4528, 997, 3126, 5135, 2888, 1630, 4453, 1813, 4283, 2673, 1462, 5258, 2286, 1398, 4332, 4760, 3207, 2407, 5408, 2505, 4720, 1645, 4683, 2447, 2835, 1848, 4876, 1687, 5176, 6181, 2639, 1247, 5218, 2726, 1716, 4801, 2482, 6169, 2725, 1936, 4222, 986, 4338, 3338, 6166, 3590, 5159, 2397, 4661, 1483, 4494, 3348, 3150, 2293, 1651, 6280, 4442, 1745, 4552, 3236, 943, 2506, 6404, 2714, 1859, 1508, 4454, 3161, 4501, 2668, 3601, 1834, 4399, 1454, 3211, 4665, 891, 3361, 6408, 5640, 2411, 1841, 998, 1595, 4340, 2175, 3115, 1278, 5254, 2239, 5193, 4691, 766, 3173, 2830, 5379, 2455, 4285, 1465, 4662, 2484, 2674, 1709, 4772, 5265, 3266, 2619, 5150, 2513, 1764, 5204, 2729, 1646, 4457, 2294, 6182, 2755, 1737, 4802, 511, 4685, 6658, 3394, 5440, 2398, 1485, 4311, 4882, 3132, 2647, 1404, 2716, 4743, 1693, 4444, 3596, 6240, 6211, 2838, 1866, 4515, 1952, 4502, 3213, 3368, 4560, 2508, 4776, 1491, 3171, 4897, 988, 3248, 6185, 2297, 1657, 1752, 5165, 1807, 4458, 2730, 3712, 1399, 5260, 2621, 1844, 4686, 1001, 4505, 3219, 2459, 5382, 2851, 951, 1654, 4666, 3164, 5217, 2837, 1926, 4884, 1707, 3352, 2757, 5648, 2413, 6288, 5202, 2488, 1391, 1002, 2676, 6172, 2737, 1468, 4693, 5171, 4668, 2422, 3272, 5282, 2471, 1836, 4315, 4407, 3604, 6213, 2514, 1494, 2841, 4804, 1873, 4694, 6186, 3178, 2298, 5385, 2419, 4697, 1271, 4747, 3222, 4517, 2529, 2622, 4888, 1694, 4898, 3396, 893, 6660, 2461, 1923, 4707, 1461, 5143, 3157, 4698, 2651, 1748, 5268, 2414, 1715, 4506, 975, 4327, 3593, 6193, 1862, 894, 4784, 1815, 4749, 3335, 3103, 5224, 2516, 1497, 4344, 1653, 3618, 2703, 5166, 2948, 6218, 1510, 1762, 4465, 2853, 6416, 2663, 1842, 4286, 1375, 3214, 4460, 2732, 3457, 5664, 2758, 1703, 4750, 1009, 3235, 6304, 2477, 1466, 5191, 2842, 1874, 4755, 2300, 3162, 2421, 5257, 2653, 4431, 4576, 3280, 955, 2896, 2738, 4411, 1739, 4317, 7170, 2761, 2680, 1486, 4466, 1930, 5381, 3364, 4709, 2530, 6664, 5504, 2854, 1889, 4518, 1004, 4521, 6432, 3180, 1658, 4547, 5173, 4710, 1821, 4639, 3131, 5394, 2475, 1718, 4331, 1929, 4508, 3225, 2952, 1599, 6672, 1507, 4439, 1776, 4468, 3617, 6336, 5281, 2462, 1405, 4871, 1735, 3339, 4413, 2271, 3174, 6688, 1831, 1493, 1010, 3602, 6214, 2711, 1984, 5635, 2740, 1455, 4318, 2883, 3376, 2667, 5195, 2520, 4522, 957, 3185, 6188, 2503, 2844, 4549, 1865, 4333, 3237, 3649, 2857, 5220, 2762, 4655, 5266, 3296, 983, 2769, 6275, 2885, 5388, 1710, 4929, 958, 4900, 2764, 3134, 1514, 4808, 5178, 3350, 4930, 4757, 3400, 5149, 2912, 1876, 4904, 1768, 4875, 6225, 1721, 5313, 2858, 1938, 4713, 1660, 4700, 3221, 6194, 5637, 2654, 4529, 1500, 3242, 4816, 2960, 6217, 1403, 4912, 1892, 5197, 3151, 6159, 2770, 1819, 5272, 2744, 1741, 4932, 2425, 6464, 3472, 2483, 1516, 4443, 987, 4993, 3341, 6277, 3608, 5232, 2865, 1932, 4339, 3177, 3840, 2367, 5393, 2669, 6196, 4758, 1463, 3228, 1012, 2860, 6167, 2532, 5696, 1843, 4550, 3393, 4414, 2478, 3620, 1749, 4771, 5206, 3186, 4714, 999, 3347, 6278, 5177, 2886, 1838, 4994, 1277, 4877, 2715, 3267, 1647, 5410, 2536, 5316, 4472, 4524, 3159, 2287, 5642, 2426, 4761, 1925, 4832, 2507, 2670, 1498, 4663, 1742, 5203, 3458, 6528, 5288, 2675, 1513, 5174, 2485, 1880, 4936, 2428, 6220, 6281, 1717, 4721, 1016, 4334, 3249, 6226, 3656, 5255, 2866, 1953, 4455, 4553, 3226, 3342, 2509, 1837, 6200, 4495, 1867, 4883, 3591, 6171, 2544, 6241, 2717, 1631, 1469, 4687, 3238, 3365, 4774, 2727, 3188, 4530, 1747, 3127, 4773, 767, 3269, 6183, 2772, 5386, 1904, 5638, 1724, 4445, 2889, 3353, 1524, 5396, 2677, 5198, 4341, 989, 3632, 2399, 5284, 2515, 4554, 1406, 4762, 3408, 5209, 2486, 1754, 4716, 5649, 3163, 2785, 5259, 2299, 6403, 5409, 2510, 1822, 4459, 2490, 6228, 2489, 1835, 4223, 5163, 4287, 6282, 3714, 5221, 2517, 1499, 4878, 4503, 3597, 6289, 2295, 1944, 2731, 4532, 1863, 4722, 3244, 6405, 3274, 6173, 5314, 2890, 4667, 1890, 4561, 3460, 3175, 4777, 2786, 6187, 4342, 1467, 4803, 3192, 1003, 3356, 6242, 2947, 1522, 1763, 5442, 3650, 4446, 2718, 3366, 1695, 5180, 2831, 1850, 4695, 990, 4764, 3133, 6659, 5644, 2897, 1005, 1937, 4886, 3603, 3241, 5261, 2868, 5416, 4556, 1722, 3624, 2776, 5219, 2976, 6232, 5296, 1845, 4345, 2839, 6284, 2415, 1495, 4778, 5760, 3424, 4669, 2949, 3281, 5267, 2678, 1655, 4507, 4899, 3369, 6174, 2733, 1765, 5212, 2892, 1956, 4885, 6290, 3252, 2681, 5400, 2759, 4805, 4461, 3166, 4536, 2301, 2739, 4724, 1487, 4785, 3349, 7172, 6215, 2872, 1750, 4470, 1869, 5320, 3223, 4519, 2950, 6406, 5652, 2734, 1521, 4562, 959, 4889, 3716, 6409, 3270, 1896, 5226, 4346, 1263, 4467, 3464, 3181, 5270, 2788, 1940, 4577, 1770, 4670, 3395, 2898, 5444, 2423, 6305, 1877, 1509, 4509, 3606, 6720, 5205, 2492, 1711, 4699, 1756, 3354, 4462, 2518, 3215, 6189, 5641, 2531, 1846, 1011, 3595, 6244, 2463, 1960, 5383, 2533, 5151, 4564, 2953, 3250, 2843, 5666, 2521, 4751, 4996, 3288, 6784, 2682, 2792, 4901, 1784, 4711, 7169, 3664, 2900, 5262, 3008, 4780, 1870, 5505, 3370, 4806, 2913, 6195, 2741, 5283, 1662, 4525, 1013, 4890, 6292, 3179, 1985, 4348, 5210, 3842, 4469, 4701, 3398, 5328, 2845, 1753, 4944, 1927, 4786, 3273, 6190, 1528, 6219, 1849, 4809, 1882, 4728, 3652, 3619, 6410, 5412, 2954, 4578, 1766, 3300, 4902, 2763, 3189, 6417, 1511, 1954, 5228, 3378, 6661, 2855, 1719, 5179, 2522, 1777, 4523, 2684, 6248, 3227, 2742, 5273, 2302, 5000, 895, 3598, 6306, 3713, 5665, 2765, 1439, 4510, 3119, 3363, 2623, 5387, 2961, 6197, 4319, 5222, 3488, 1006, 2846, 6337, 2859, 5650, 1878, 4759, 7176, 4788, 2427, 3256, 1891, 4931, 5424, 3401, 4715, 4568, 3239, 6296, 5233, 2745, 1939, 4551, 1661, 4892, 6221, 3612, 1502, 5285, 2479, 5697, 4905, 1986, 4810, 3190, 6308, 5344, 2655, 4817, 1852, 4933, 3276, 2537, 6912, 1934, 4812, 1723, 5182, 3372, 6412, 5398, 2914, 1772, 5448, 2771, 1515, 4960, 2534, 6418, 3621, 6662, 1897, 1014, 4906, 3229, 6198, 3282, 5269, 2956, 1470, 4702, 3841, 3609, 2766, 5290, 2861, 6227, 5008, 1743, 3412, 6201, 2524, 6665, 2904, 5199, 1931, 4818, 3165, 3459, 4792, 2887, 3377, 4473, 5520, 3343, 4531, 1017, 3194, 6256, 2773, 5389, 1968, 5656, 1881, 4913, 2746, 3520, 1894, 5225, 2962, 5888, 4415, 4717, 3297, 2800, 5276, 2916, 4908, 1769, 4580, 7168, 5441, 2867, 1517, 4526, 1778, 5668, 3397, 6279, 5234, 2862, 6222, 5395, 2487, 1941, 4934, 2977, 6433, 6338, 1823, 4763, 5315, 4584, 3245, 6229, 3626, 5207, 2538, 1659, 4335, 4474, 3187, 6420, 3728, 2671, 1992, 6666, 4555, 1875, 4718, 3680, 6202, 3384, 6312, 5506, 2719, 1755, 4723, 3246, 3410, 4533, 2787, 3651, 6283, 4476, 1501, 3605, 1018, 3461, 6243, 2964, 5297, 1900, 5704, 3351, 4914, 2511, 3284, 1725, 5274, 2891, 5390, 4557, 991, 3183, 6230, 5639, 2429, 4592, 1933, 4765, 3720, 3402, 5286, 2545, 5413, 4775, 5236, 3634, 2978, 5175, 2869, 6204, 5317, 1839, 4820, 2774, 6424, 3009, 1525, 4937, 5401, 3251, 4725, 6233, 3230, 5680, 2920, 1955, 4447, 4563, 3466, 6434, 6673, 1988, 5456, 2540, 1884, 4534, 3298, 6668, 3380, 6340, 5211, 2679, 4833, 4347, 3622, 3271, 4558, 2777, 6285, 4538, 1726, 4537, 3193, 7184, 3653, 6245, 2748, 1948, 1780, 5762, 3844, 4565, 2491, 6291, 3355, 5645, 2789, 1518, 4343, 1020, 4779, 3426, 6320, 3610, 5292, 5322, 1767, 4938, 3404, 3253, 5508, 2893, 5223, 4834, 1905, 3367, 2968, 5240, 2430, 6286, 5404, 1851, 4995, 3633, 6674, 5698, 2870, 1893, 4766, 5414, 3473, 4879, 2899, 3277, 6465, 5181, 2778, 1945, 4945, 3657, 6175, 2546, 1757, 5651, 2928, 5289, 4916, 6344, 3304, 2790, 5672, 2493, 4824, 5024, 3440, 6234, 2519, 2683, 4887, 1530, 4463, 3196, 7200, 3744, 6689, 5472, 2980, 4997, 1958, 5329, 3628, 4726, 2735, 6436, 6466, 5417, 1471, 4781, 1007, 4940, 3258, 6676, 3468, 2000, 5300, 3660, 4729, 4807, 3373, 3848, 5214, 2951, 1847, 4349, 1898, 4787, 3182, 6407, 5397, 2873, 6293, 1523, 1942, 4920, 3283, 3409, 6246, 5271, 2548, 4998, 1961, 3625, 4782, 2894, 3718, 6249, 5764, 1871, 5318, 3243, 6448, 2793, 1771, 5512, 2874, 5229, 4836, 2780, 3312, 2494, 5443, 3010, 4946, 4471, 3474, 6440, 3668, 5654, 2984, 1529, 4540, 7174, 3425, 2523, 5402, 2901, 6307, 4566, 5263, 3358, 4579, 2915, 6236, 2685, 5643, 1912, 4511, 7177, 4581, 6191, 3599, 1758, 5001, 5298, 3278, 4891, 4569, 3462, 6411, 5336, 2955, 1989, 4730, 1946, 4840, 3254, 6529, 3715, 1526, 6690, 5712, 4948, 1906, 5056, 3636, 3381, 6468, 5418, 2535, 4961, 1883, 4789, 3856, 2743, 3489, 6352, 1773, 1957, 5227, 3135, 6530, 5890, 2794, 1853, 5446, 2876, 1976, 4893, 2801, 6294, 3658, 6297, 5321, 2902, 1015, 3285, 6309, 3374, 5700, 2905, 5667, 5002, 3416, 3257, 2552, 5348, 2847, 6250, 4811, 5237, 3403, 6199, 2303, 6472, 3012, 5426, 1751, 4903, 7232, 3290, 4570, 2957, 3721, 4732, 5275, 3607, 4790, 4350, 3357, 6680, 2767, 5646, 1993, 5761, 1503, 4813, 6721, 3191, 1962, 5167, 2525, 5411, 4671, 5009, 3665, 6692, 5536, 2963, 4894, 1781, 4907, 3496, 7178, 6257, 1885, 4475, 1908, 5304, 3428, 6298, 5449, 2686, 6223, 5287, 2796, 2016, 4793, 2992, 6413, 3776, 6252, 1854, 5660, 4527, 3379, 6722, 3275, 5238, 2917, 1532, 4703, 3640, 6368, 3476, 2539, 5324, 2747, 6310, 4585, 1972, 3301, 6663, 3399, 6696, 5420, 2802, 1774, 4962, 3231, 3613, 4819, 2906, 3666, 6339, 4582, 5669, 3465, 1019, 3524, 6414, 2526, 5277, 1895, 5330, 7185, 5004, 3016, 3308, 1987, 5889, 2431, 5657, 4814, 4909, 3260, 6785, 5460, 2958, 4572, 1969, 4952, 7180, 3849, 5213, 2863, 5507, 4935, 1782, 5425, 3627, 6667, 5391, 3024, 6419, 5242, 1279, 4821, 2918, 6724, 6435, 1943, 4794, 5568, 3732, 5010, 6203, 3681, 5345, 2965, 1899, 4848, 4964, 3385, 6313, 3289, 6704, 1994, 6258, 1663, 4915, 3654, 6421, 3872, 6300, 5445, 2775, 4910, 3198, 3490, 4535, 2541, 3405, 6231, 5025, 1964, 3299, 7296, 3724, 6341, 2921, 5293, 1785, 5674, 3432, 4586, 2749, 6260, 3614, 5235, 2979, 5776, 4719, 1021, 3371, 6314, 3846, 5728, 5432, 1935, 4767, 3413, 3521, 5294, 2804, 5458, 4835, 5699, 3382, 2908, 5653, 2547, 6205, 5509, 1886, 5012, 7186, 6675, 5399, 2779, 2001, 4559, 5332, 3696, 4939, 6669, 3286, 6786, 5231, 2871, 1407, 4477, 3623, 6425, 6422, 1779, 5768, 2970, 5450, 4593, 3247, 6670, 3722, 6321, 5682, 2922, 5026, 4917, 3480, 6437, 3469, 2966, 6532, 4822, 1990, 5057, 3684, 7201, 3302, 6235, 5299, 2550, 1970, 5278, 3843, 4968, 2981, 6728, 3414, 6913, 5514, 1879, 1022, 4588, 3386, 6342, 3730, 5346, 5428, 3635, 4727, 3259, 3536, 5670, 2791, 5319, 4825, 1902, 3406, 6316, 5241, 2808, 6264, 5701, 1947, 4796, 3292, 3629, 6345, 5892, 2929, 4539, 5403, 3195, 4837, 2542, 3427, 6480, 5474, 1759, 5658, 3320, 6206, 2750, 1907, 5452, 2969, 5301, 4941, 6426, 3672, 2549, 5415, 2924, 5016, 4478, 3463, 6287, 7173, 5681, 2895, 1527, 4918, 3904, 7188, 3492, 6247, 5521, 3040, 6322, 4947, 5325, 3745, 4826, 2495, 6438, 6237, 5705, 1996, 4594, 7202, 4976, 3655, 6788, 3484, 1786, 5352, 3417, 4838, 4541, 3305, 6346, 3752, 5488, 2781, 1959, 4567, 2002, 4731, 3845, 6736, 3717, 5244, 6467, 5792, 1913, 5028, 3388, 3279, 6536, 5676, 2875, 4783, 1949, 3638, 2982, 3682, 6441, 5306, 2017, 5516, 3522, 6914, 5708, 2930, 1534, 5421, 2985, 5896, 4999, 3011, 3467, 6251, 5230, 2795, 4921, 3313, 6324, 3167, 5331, 2553, 5457, 4596, 7424, 3429, 2903, 5673, 2972, 6295, 4942, 5766, 3858, 6353, 2782, 6428, 2877, 5291, 1788, 4841, 7171, 3611, 4922, 6792, 3261, 4828, 5360, 3659, 4542, 5058, 3411, 6238, 6348, 5522, 1910, 5716, 1965, 5032, 3478, 6442, 3306, 2004, 6544, 5473, 4571, 4949, 3736, 3434, 6752, 5406, 3013, 4963, 1901, 4733, 3662, 7233, 3778, 6496, 1966, 1775, 5647, 3287, 6469, 5326, 2986, 6677, 5510, 2932, 2008, 5003, 2554, 6299, 3375, 6354, 5302, 5763, 3637, 6449, 3852, 5684, 2797, 5429, 4583, 3418, 3688, 2993, 5904, 3014, 6691, 4791, 5537, 3504, 6444, 3729, 6253, 5183, 2803, 1531, 4842, 7192, 3314, 4924, 2907, 3475, 6328, 4849, 5706, 3641, 4950, 3436, 6678, 2988, 5333, 1971, 5422, 7204, 4953, 6681, 3262, 1950, 5464, 2878, 5305, 4600, 4895, 3857, 6259, 5451, 2959, 4351, 1909, 5060, 3669, 7234, 3630, 6311, 5338, 5005, 1991, 5769, 3880, 6369, 5655, 2919, 6470, 5405, 2018, 4815, 2687, 6450, 3528, 6916, 1727, 5239, 3746, 4573, 6301, 3383, 5713, 2936, 1916, 5011, 3420, 6800, 3293, 6473, 5544, 2527, 6254, 1855, 3470, 6261, 3316, 6356, 5476, 2994, 4734, 3780, 3725, 4844, 2798, 3850, 6315, 5040, 5824, 3674, 7182, 3441, 6920, 3017, 5427, 1974, 5323, 7208, 4965, 2556, 3661, 5688, 2909, 5524, 4587, 4795, 3494, 6474, 3905, 5349, 5447, 1995, 4850, 7297, 3387, 5279, 2805, 5661, 4954, 5714, 3430, 6370, 5513, 3018, 6693, 5572, 2020, 4574, 7187, 6682, 6531, 1977, 5064, 5356, 3748, 4479, 6452, 3291, 6360, 5308, 2967, 1787, 5006, 3642, 6560, 3481, 6415, 1914, 6423, 5897, 4911, 3874, 6302, 3552, 6481, 5675, 2923, 5072, 3683, 6694, 3307, 2910, 3968, 6816, 4966, 2005, 3723, 7236, 3493, 6262, 5780, 2806, 1887, 5729, 3197, 5013, 2996, 6476, 3407, 6723, 5433, 5337, 1023, 3864, 6684, 3644, 5702, 5920, 7216, 4823, 3719, 3760, 5246, 3025, 5538, 4589, 5453, 3433, 6533, 5347, 2971, 6317, 5772, 1963, 4969, 7181, 3670, 6265, 5480, 3020, 4797, 5662, 3482, 5027, 6697, 3359, 6343, 5419, 1998, 5894, 3777, 6928, 6323, 1783, 5461, 2809, 5569, 4852, 6372, 3444, 6482, 5430, 2925, 4956, 4595, 3255, 6456, 3523, 7680, 6848, 2024, 4827, 3497, 7298, 3860, 6534, 5744, 3000, 6318, 5334, 3734, 4919, 2543, 6698, 3310, 6725, 5671, 1980, 7190, 5018, 3692, 6537, 3667, 5295, 5770, 3389, 4970, 3477, 6427, 3873, 5528, 2751, 5517, 5014, 1903, 3419, 6266, 3686, 5732, 6592, 5350, 1973, 4598, 3615, 3784, 6497, 5891, 2983, 5029, 5462, 3733, 3026, 3673, 6705, 5434, 2003, 5778, 7240, 6347, 5683, 2931, 1789, 5307, 2810, 5584, 4839, 6207, 3294, 6484, 5454, 2551, 4856, 3506, 6538, 7193, 5340, 2973, 5677, 4977, 3442, 7425, 3317, 6671, 5243, 2926, 6726, 4590, 5475, 3526, 6700, 2783, 6325, 6439, 5368, 1997, 4798, 7203, 3847, 5017, 6429, 3726, 5720, 3908, 4597, 4972, 3491, 6376, 3685, 6268, 5511, 2032, 1978, 4943, 3529, 6349, 3421, 5952, 6326, 5540, 5088, 3747, 3303, 6787, 5793, 3041, 4543, 1917, 3639, 7300, 3876, 6706, 5703, 2010, 5532, 3500, 6430, 5465, 2933, 6729, 5353, 2987, 5800, 4829, 3042, 3448, 6443, 5893, 5765, 3792, 6498, 3704, 5436, 3028, 5327, 4923, 7189, 3737, 2974, 5686, 2812, 6355, 5030, 5730, 3318, 6545, 7248, 6329, 5570, 2989, 1519, 4978, 7205, 3676, 5033, 6540, 3415, 6488, 5059, 5515, 3853, 4843, 3505, 6730, 6789, 5361, 2019, 5215, 7426, 4601, 3969, 6737, 3631, 2006, 6679, 5477, 4951, 5020, 3435, 6384, 3690, 5906, 3015, 4830, 1951, 4925, 3315, 7194, 3532, 6350, 5659, 1911, 5309, 3498, 6239, 5707, 2934, 6471, 5459, 2021, 2879, 6708, 3731, 6944, 5526, 5354, 3390, 6546, 3859, 5784, 2995, 5482, 5061, 3753, 3479, 6500, 5710, 2555, 6451, 5826, 3309, 6445, 3888, 6561, 5335, 2937, 5034, 7304, 3698, 4980, 3032, 3808, 6357, 4602, 5423, 3538, 7210, 3663, 6712, 2799, 5685, 2009, 5900, 7264, 4845, 6976, 3750, 5466, 2990, 5736, 5041, 5062, 3906, 6732, 7179, 5552, 5777, 1790, 4851, 3471, 7681, 3508, 6330, 5362, 4955, 5523, 3431, 6790, 5689, 3044, 6548, 5484, 2026, 5036, 7235, 6371, 3740, 7040, 1975, 5310, 3689, 4926, 6738, 3862, 6562, 5905, 3019, 2012, 5007, 3525, 6446, 3321, 6793, 5717, 6915, 5678, 3560, 6504, 3781, 6683, 5928, 2938, 4967, 3646, 3422, 2557, 3854, 6255, 4735, 5576, 3970, 7196, 3697, 6475, 5794, 2997, 1967, 5431, 7312, 4984, 3021, 3445, 6358, 5468, 5341, 4575, 3537, 6453, 3756, 5518, 5364, 7206, 5042, 7428, 3675, 5828, 3048, 5773, 4846, 5898, 3738, 6332, 5722, 2940, 6593, 5489, 1915, 5065, 7217, 3322, 6361, 6552, 4604, 5709, 3486, 4957, 6753, 3865, 6740, 5542, 2025, 5953, 3438, 6695, 3512, 6794, 2022, 6373, 5435, 4853, 6303, 3916, 6564, 5478, 2998, 5066, 3199, 6454, 3779, 7237, 3554, 6685, 1981, 3875, 7432, 3645, 6917, 5796, 2911, 6754, 5339, 3499, 5015, 2807, 6801, 3912, 6477, 5690, 5529, 7209, 3762, 6263, 3749, 5922, 5600, 7242, 4971, 3443, 3851, 5731, 3056, 5355, 4958, 6016, 3671, 6744, 3530, 5771, 6483, 5541, 1918, 4854, 7328, 3324, 6362, 5245, 2558, 5044, 5455, 3483, 6512, 3700, 6796, 5912, 2033, 5692, 7175, 6374, 6535, 1999, 5767, 3027, 5808, 5073, 6457, 3540, 6594, 5481, 3001, 5019, 3976, 6686, 3877, 7682, 6478, 5718, 5068, 3437, 7220, 3786, 6377, 5530, 2811, 6699, 5407, 3920, 6918, 3022, 6319, 3501, 6267, 5825, 2028, 7299, 3691, 4857, 6802, 3761, 5492, 3866, 4973, 3263, 6756, 3450, 6485, 5303, 5571, 1533, 3677, 6921, 3568, 5545, 6364, 5908, 5048, 3878, 3739, 6458, 5782, 3002, 4591, 5358, 3507, 7249, 3782, 6568, 5740, 2011, 5715, 7212, 6539, 5437, 2927, 5525, 3029, 5921, 4799, 6817, 3553, 6727, 5467, 5734, 3754, 6499, 7440, 5663, 3030, 5832, 5031, 7238, 3972, 6431, 5781, 2975, 6327, 5074, 5721, 3881, 6378, 7195, 6269, 6701, 1982, 4979, 7360, 3687, 4858, 6804, 3495, 6760, 5342, 3794, 4599, 3391, 6486, 3727, 6460, 5554, 2034, 7301, 5021, 3868, 6385, 3809, 5490, 6922, 5365, 4974, 3527, 6707, 3323, 5574, 3043, 4831, 1979, 3788, 7218, 3449, 6489, 5895, 2023, 5774, 3936, 6596, 5956, 2813, 6541, 5539, 5733, 3004, 3544, 6547, 5577, 5469, 7256, 6351, 3909, 5795, 2935, 5351, 5089, 7684, 3485, 6818, 5687, 3033, 6702, 5924, 3768, 6929, 7244, 6576, 5548, 3045, 4981, 7183, 3678, 5035, 6501, 3861, 6331, 5090, 5496, 3510, 7306, 3446, 6380, 6808, 5840, 2013, 5752, 7456, 5076, 6768, 3693, 6731, 5785, 5022, 4860, 3896, 6924, 3735, 7224, 5366, 2036, 5037, 3295, 7266, 3764, 6849, 5724, 5463, 3984, 6270, 5901, 3034, 6386, 5553, 2007, 7207, 6709, 3531, 6542, 6017, 5679, 3699, 6490, 3793, 6600, 5483, 2991, 5738, 5063, 3907, 3556, 6502, 5363, 6549, 5580, 3882, 6447, 3502, 6713, 5546, 2939, 4982, 7688, 3889, 3046, 3643, 6388, 4927, 5779, 3326, 7302, 7241, 6739, 5438, 2814, 2030, 5907, 7427, 5043, 6333, 3513, 6710, 5801, 5527, 4603, 3757, 6820, 7313, 5357, 5936, 7198, 4985, 3812, 7252, 3694, 6505, 5746, 5080, 5856, 3785, 6850, 5586, 2559, 6733, 5711, 2014, 4847, 7488, 3533, 6359, 6930, 5798, 3452, 5038, 6791, 3741, 6492, 5954, 2040, 3914, 6563, 4000, 6550, 5519, 6608, 5556, 6824, 3539, 6945, 5479, 3036, 5092, 3705, 3800, 7213, 3855, 6506, 5788, 3447, 7308, 3892, 6734, 5737, 3049, 6553, 5910, 7430, 5067, 2999, 3702, 6714, 5573, 5369, 7265, 3974, 6932, 3755, 5608, 5829, 7696, 4986, 7250, 3439, 5694, 3050, 5470, 4605, 5902, 3516, 6741, 7219, 6018, 6716, 5745, 1535, 5045, 7330, 3884, 6363, 6455, 5069, 5493, 3542, 6852, 3921, 6742, 5585, 2027, 5804, 7433, 6745, 3319, 6795, 2029, 6565, 5723, 5096, 6936, 3742, 6946, 5786, 2941, 4988, 3971, 6755, 3509, 7191, 6746, 5370, 3796, 7316, 3763, 6554, 5534, 3023, 6375, 5913, 3910, 2942, 6832, 3863, 6797, 5486, 5560, 7272, 3545, 6392, 3701, 5964, 7214, 5046, 3558, 3810, 6513, 5247, 5827, 5602, 3890, 6334, 3423, 5923, 6508, 5693, 4959, 7712, 3751, 6798, 5547, 3057, 4855, 5960, 3514, 7239, 3922, 6803, 5810, 2035, 5797, 7305, 6479, 6624, 5491, 3003, 5899, 5104, 6459, 3787, 6365, 5719, 5578, 3534, 6514, 3978, 7429, 6757, 5372, 4606, 7552, 3937, 6566, 5531, 3052, 6569, 5748, 3706, 6595, 7221, 6758, 3869, 6687, 2037, 7442, 3766, 5075, 6379, 3977, 6556, 5588, 3647, 5049, 3555, 6487, 3824, 6516, 6024, 5925, 7329, 3453, 6919, 3783, 5485, 6461, 5834, 4859, 3879, 3541, 5968, 3058, 5070, 5549, 4032, 7683, 3503, 6366, 5739, 1791, 5809, 7243, 6570, 5914, 3005, 5311, 5498, 6597, 3913, 6381, 5725, 5616, 7268, 6703, 7314, 5926, 3031, 5787, 5050, 7436, 3758, 6977, 5555, 3006, 6948, 5830, 3562, 6856, 7226, 6978, 6805, 4975, 7197, 3924, 5077, 6952, 3816, 6923, 5601, 3769, 7361, 3986, 6761, 3708, 6748, 5802, 2038, 7685, 5078, 6577, 3548, 6864, 6020, 5023, 3451, 6960, 3940, 7245, 5929, 2041, 3867, 7320, 3789, 6980, 5735, 5543, 3564, 6491, 5842, 3035, 7041, 5439, 5775, 7280, 3980, 6387, 5916, 5857, 7441, 6806, 3511, 5575, 3060, 5371, 5091, 7744, 3891, 6598, 5836, 6462, 5497, 3797, 6819, 7254, 6762, 5984, 3047, 4861, 7225, 3886, 7042, 3325, 6925, 5052, 5592, 3695, 7458, 7364, 6520, 6572, 1919, 5957, 7690, 4983, 6809, 3973, 6880, 5533, 5081, 3546, 6711, 3790, 7251, 5816, 7336, 5093, 3561, 7222, 3928, 6984, 5726, 5909, 3765, 6769, 5558, 3064, 6382, 5494, 2042, 7303, 4001, 6503, 6601, 5741, 3885, 6543, 3915, 6931, 5944, 5783, 3679, 3517, 6735, 5343, 6822, 5812, 6578, 3795, 6821, 6032, 2815, 5082, 7434, 3952, 7686, 3772, 6493, 5579, 3572, 7444, 7246, 6389, 5747, 3037, 5841, 7332, 5039, 6602, 3454, 6810, 5955, 5604, 7257, 3802, 6764, 7697, 5930, 5550, 7307, 4987, 7457, 3870, 6507, 5937, 5094, 5691, 3883, 6271, 7211, 5374, 6335, 2039, 4862, 7269, 3547, 6926, 6551, 5561, 3992, 6580, 3911, 6770, 5805, 2044, 7362, 6715, 3938, 6609, 5860, 6825, 5742, 6390, 3515, 6851, 5833, 3051, 4607, 3570, 3811, 7490, 6494, 5581, 3743, 7228, 3898, 6743, 5500, 3038, 6812, 5789, 7692, 3053, 3985, 6934, 5962, 6048, 7309, 7464, 6604, 3770, 5587, 7267, 5084, 7344, 3893, 6393, 5753, 5848, 5903, 3543, 6826, 7808, 5495, 6717, 5940, 5097, 7315, 3703, 6555, 6947, 5047, 5750, 3813, 7260, 4004, 6933, 6022, 2043, 5803, 7448, 6853, 6509, 6584, 5487, 5098, 6772, 3535, 6833, 5564, 3798, 6518, 3917, 7368, 6567, 5932, 7700, 3569, 6610, 5590, 3007, 6937, 5969, 3944, 7274, 6394, 3311, 6515, 5367, 7318, 3988, 6625, 3818, 6718, 5790, 7492, 4989, 3925, 3557, 6557, 6019, 5557, 7253, 3759, 6747, 3804, 5844, 6510, 5811, 5071, 7689, 3894, 5958, 3059, 4990, 5911, 4008, 7431, 7199, 6612, 5593, 2031, 5749, 7714, 6799, 7044, 5606, 5858, 6949, 3832, 6759, 5938, 5471, 7310, 6828, 3918, 7553, 6854, 5799, 5105, 7331, 3710, 6573, 5562, 3061, 6938, 5970, 4033, 6396, 7258, 6517, 6749, 7376, 3801, 5051, 6992, 3975, 6834, 5835, 3576, 3897, 6857, 3930, 6776, 5582, 6026, 7460, 6626, 3814, 6950, 5985, 5100, 3559, 4002, 7276, 5754, 5917, 3767, 7227, 3825, 6571, 5814, 6025, 7321, 7048, 5695, 2943, 5603, 5872, 7713, 3487, 6558, 5501, 5831, 7435, 6367, 7270, 5927, 3054, 5589, 5106, 7698, 3926, 6807, 6080, 6836, 5551, 3939, 6979, 7472, 6763, 6616, 5053, 7281, 3987, 6599, 3709, 6940, 5961, 3550, 7333, 7745, 6953, 4034, 6858, 1983, 7392, 5079, 6865, 3900, 6981, 5806, 5054, 3982, 6860, 3771, 7230, 5610, 7446, 3820, 7496, 3563, 7008, 5972, 5864, 3945, 5817, 3062, 6954, 6034, 5756, 7317, 3518, 6750, 5596, 7338, 7056, 3791, 5499, 5988, 7247, 3979, 6866, 5915, 6840, 5837, 6521, 7568, 6579, 5612, 3065, 5083, 7437, 4016, 7704, 3929, 6961, 6028, 3942, 7273, 7936, 6463, 6765, 5559, 7324, 5108, 6956, 3817, 6628, 5939, 7489, 3565, 6574, 3826, 7716, 5845, 7282, 5095, 7443, 3989, 6982, 5934, 5373, 3871, 6811, 7363, 5743, 6632, 2046, 7255, 3707, 6383, 6522, 6021, 4040, 6603, 3923, 6766, 5594, 5838, 7554, 3803, 6771, 5609, 6581, 5976, 6524, 3549, 5813, 3066, 5112, 7345, 3948, 7752, 6962, 6049, 3773, 7322, 7438, 6605, 5933, 3039, 5963, 7687, 6640, 3981, 6813, 5727, 5565, 7334, 7461, 6823, 7284, 5843, 7223, 4863, 7365, 3887, 6868, 6000, 5820, 3573, 6985, 7449, 5620, 6773, 5085, 7728, 4003, 6495, 6611, 5502, 4036, 7504, 3932, 6582, 5850, 2047, 7259, 6881, 6395, 6606, 5918, 6586, 3774, 6585, 5931, 3996, 3828, 7810, 6613, 5595, 7693, 3566, 6391, 6040, 3068, 6827, 5959, 7340, 7370, 3815, 6986, 5986, 7556, 7271, 6882, 3953, 5563, 7288, 5099, 7452, 3899, 7043, 5618, 5859, 7746, 3941, 6814, 7462, 5791, 6927, 5946, 5086, 7229, 3993, 6993, 5101, 6033, 3805, 7699, 7337, 6964, 2015, 5818, 7720, 6872, 7072, 5941, 6935, 3578, 6511, 5591, 7520, 7045, 4006, 7377, 6774, 5751, 7465, 3519, 6829, 5861, 3055, 6988, 6052, 4048, 7348, 6777, 6855, 7262, 3895, 6397, 3946, 6835, 5583, 7445, 3571, 3990, 6968, 5846, 5965, 7319, 7046, 4009, 6830, 5617, 5055, 7812, 3919, 7366, 5992, 5359, 3819, 7560, 7277, 6884, 6036, 5866, 7491, 6994, 6519, 5973, 5605, 7702, 3577, 6588, 5807, 5852, 7450, 6614, 7311, 6627, 5942, 5107, 7691, 3960, 6559, 6056, 6629, 3806, 7049, 7346, 6939, 6617, 7384, 4037, 6778, 3994, 6888, 5880, 3574, 7760, 6996, 3954, 7104, 5966, 7466, 7009, 3931, 6837, 5758, 5109, 3821, 4005, 7275, 6081, 7938, 3901, 7494, 4024, 6941, 5849, 6023, 7369, 5624, 3063, 5945, 5978, 7748, 7715, 7050, 5862, 7396, 6859, 7285, 5607, 6050, 7474, 3799, 6951, 5815, 6618, 5873, 6780, 7323, 6838, 6398, 4991, 7694, 4041, 7809, 3551, 6861, 5535, 4010, 7215, 7459, 6719, 7057, 7584, 5102, 6942, 3829, 6955, 5974, 3933, 6523, 3956, 7352, 5987, 7497, 7335, 4064, 6841, 6035, 5757, 3902, 7708, 5598, 6575, 6082, 7286, 3580, 6751, 5948, 7372, 6633, 4020, 6030, 5819, 7468, 3822, 7010, 5868, 6867, 5611, 6630, 7717, 5993, 3067, 5110, 7325, 3943, 7378, 7052, 5566, 4035, 7937, 7705, 6862, 6957, 5839, 7508, 6620, 4017, 7000, 6027, 7261, 7555, 6983, 3830, 7473, 7439, 5113, 7290, 3327, 6869, 6064, 5977, 3991, 6842, 7616, 5990, 7058, 7393, 3947, 6896, 7012, 5865, 4042, 3711, 6963, 5613, 5874, 7493, 6958, 6583, 6037, 7073, 4012, 5919, 7341, 3833, 7722, 6634, 5755, 7283, 7824, 6767, 6088, 3069, 5971, 7776, 7480, 3983, 6815, 5851, 7342, 7506, 6883, 7747, 5597, 7701, 5114, 7557, 3934, 7060, 5996, 7447, 4049, 6607, 7380, 5821, 6987, 5087, 7279, 3455, 6525, 6029, 3827, 7816, 7498, 6641, 2045, 7730, 7074, 6965, 5935, 6870, 4038, 7105, 5621, 7347, 4018, 7326, 7016, 6051, 7562, 3927, 6084, 3070, 6636, 5980, 7394, 7476, 6775, 7718, 7367, 6873, 3950, 5822, 7289, 7749, 3995, 6844, 6044, 5876, 7940, 6587, 7451, 6885, 5614, 5116, 7522, 3807, 7706, 5863, 3955, 7500, 7349, 6989, 6001, 7463, 7064, 6526, 5947, 7729, 3575, 6966, 5989, 7569, 6995, 7373, 6874, 6041, 7753, 4044, 6642, 5853, 7024, 3834, 7400, 6886, 6589, 7536, 4007, 6615, 4050, 6779, 5626, 7292, 7840, 3961, 7076, 6054, 7724, 6831, 3997, 5567, 5103, 7354, 4065, 7564, 6096, 7756, 3582, 7469, 7944, 7047, 5943, 5994, 7278, 6969, 5619, 6038, 7379, 7505, 6644, 6057, 7721, 6990, 7814, 5967, 7339, 3836, 6889, 5867, 6970, 6876, 7408, 6590, 7106, 7570, 3958, 7764, 4013, 7080, 5625, 4052, 7521, 6619, 6997, 7454, 7011, 3949, 6781, 6008, 4014, 3823, 7695, 5854, 7374, 7558, 4056, 7051, 6085, 6042, 7350, 7811, 5622, 6002, 7732, 7477, 6631, 5979, 7952, 6839, 7585, 5869, 6053, 7231, 3579, 6890, 5949, 6972, 6072, 6897, 7754, 6998, 5111, 7381, 4019, 7470, 7001, 3998, 7512, 7353, 6648, 6943, 7499, 6399, 3957, 7108, 5847, 7386, 7053, 4039, 7817, 7703, 7453, 4066, 6863, 6089, 5599, 3775, 7287, 6058, 6621, 7761, 3964, 7059, 5877, 7592, 3903, 5981, 6004, 7524, 6782, 6892, 6112, 7088, 7872, 5950, 7475, 4022, 7371, 7013, 5628, 7736, 7572, 6635, 6843, 6068, 7397, 7495, 4043, 6898, 5870, 7327, 7709, 7002, 7762, 7561, 5115, 7620, 4068, 6622, 5991, 4025, 7112, 7404, 6083, 6527, 7356, 3835, 7054, 6065, 3962, 7945, 6959, 5878, 7723, 7120, 5375, 7014, 4053, 6039, 7828, 3935, 7777, 7061, 5995, 7481, 7385, 6090, 3071, 5759, 7750, 7968, 6871, 7294, 7586, 6637, 7501, 6060, 7395, 7820, 4011, 7017, 5881, 7528, 6845, 7710, 7075, 5117, 7467, 4046, 7942, 6031, 3831, 7509, 7617, 6900, 7478, 7004, 6643, 5982, 4072, 6875, 6097, 7792, 7382, 6967, 5503, 7719, 4028, 5875, 7066, 7343, 7818, 7018, 7576, 7565, 7062, 3951, 6086, 7780, 7398, 4021, 6646, 6066, 7939, 7077, 7510, 5975, 5118, 7482, 4051, 7826, 7731, 3837, 7355, 7632, 6887, 5998, 7502, 6904, 6043, 7388, 7725, 7025, 7291, 6638, 7523, 5855, 7416, 4045, 6846, 6003, 7065, 7768, 6645, 7020, 7559, 4080, 4026, 6991, 5623, 8000, 7588, 7136, 7841, 6591, 3965, 6092, 7751, 4058, 7580, 5882, 7513, 7401, 7848, 6877, 6055, 6098, 7941, 7813, 6009, 7484, 7375, 6971, 6045, 7734, 7078, 7778, 6113, 7618, 3567, 7026, 5630, 7081, 7107, 7563, 6891, 7409, 4067, 7263, 6649, 4054, 7525, 6999, 7068, 7954, 6878, 3999, 6973, 5884, 7707, 3959, 7357, 7755, 7507, 4069, 6006, 6061, 7574, 7402, 6100, 7832, 7530, 7109, 5997, 7758, 7874, 6062, 5871, 7383, 7082, 7028, 6104, 6650, 7471, 7733, 4057, 7948, 6893, 7514, 7784, 7089, 7110, 7600, 7825, 3838, 6899, 5627, 7410, 7003, 7571, 7737, 7532, 4074, 7084, 6067, 4023, 7358, 6046, 6974, 7953, 4060, 7055, 6005, 7765, 7726, 6087, 7976, 7015, 6114, 6783, 7624, 5823, 7842, 4015, 7479, 7032, 6012, 7516, 7389, 6623, 5951, 7566, 7412, 7090, 7876, 7821, 6894, 7946, 7770, 7537, 3963, 7113, 6070, 6652, 7757, 7005, 7590, 4073, 8001, 6091, 4070, 7483, 6901, 7526, 7114, 6116, 4029, 6073, 7844, 7387, 7063, 5883, 7738, 7577, 6010, 7970, 7648, 7019, 7779, 7403, 7006, 8064, 6101, 7819, 7589, 3966, 6902, 5983, 7293, 7092, 7503, 5119, 7960, 4081, 7740, 4047, 7815, 7856, 7121, 7529, 7067, 6059, 7766, 7116, 7578, 7455, 6094, 7873, 4076, 5879, 6905, 7540, 7021, 7351, 7619, 3581, 6120, 7593, 7956, 7096, 7830, 6639, 7406, 6076, 7788, 4059, 7763, 7485, 7573, 7969, 6847, 5999, 7515, 7782, 6069, 7711, 7880, 7079, 7829, 7122, 7769, 6099, 4030, 7027, 5885, 6906, 7390, 6647, 7602, 4082, 7069, 7538, 7413, 7022, 7622, 6879, 4027, 6093, 7943, 4071, 7822, 8004, 7587, 7781, 6128, 6074, 7625, 7517, 7843, 7399, 7137, 6013, 7735, 7972, 6106, 7596, 7029, 7083, 7138, 7544, 7888, 4061, 7800, 7124, 7833, 7070, 6908, 7414, 4084, 7085, 5615, 7772, 7511, 7949, 7601, 4055, 6115, 8065, 7727, 6102, 7531, 7786, 7111, 6047, 7411, 7628, 6007, 7594, 7030, 6117, 6975, 7827, 7486, 4078, 7955, 7091, 7849, 7575, 6651, 7405, 7984, 7033, 7794, 7128, 7904, 7634, 7759, 4062, 6895, 6105, 7846, 7086, 8002, 4088, 5886, 7567, 7604, 7527, 7140, 6122, 7836, 6071, 7785, 7958, 7115, 6108, 7621, 7417, 7656, 7877, 7034, 7742, 7518, 6653, 7950, 8066, 7793, 3583, 7093, 6063, 7117, 7541, 7633, 4075, 7852, 4077, 7771, 7144, 7834, 7036, 6011, 7418, 7582, 7961, 6121, 7534, 7608, 6118, 8012, 7094, 7295, 7875, 7650, 6077, 7971, 7741, 7007, 7595, 6903, 8008, 7858, 4083, 7845, 7539, 7947, 7152, 7767, 7626, 6014, 7420, 6654, 7579, 7796, 6129, 4085, 6095, 7123, 7636, 7097, 8072, 7973, 7533, 7882, 6907, 8016, 7118, 7597, 6124, 7787, 3839, 7857, 7962, 7359, 7546, 5629, 7773, 7664, 7974, 7835, 7098, 7603, 7878, 6107, 7023, 7125, 7649, 7850, 4086, 7126, 8068, 7071, 7977, 4089, 6078, 7783, 7591, 7890, 7487, 7823, 6130, 7964, 7905, 7623, 7419, 7139, 6075, 7884, 7545, 6119, 8032, 6909, 7100, 7640, 3967, 8005, 7031, 7581, 7129, 7864, 7141, 7774, 7957, 7606, 7542, 4090, 6109, 7789, 7992, 7831, 6132, 7391, 7860, 8080, 7130, 6103, 7627, 7795, 7889, 7087, 8003, 7652, 7978, 7598, 7035, 7985, 7142, 7739, 7422, 4087, 6910, 6126, 7609, 7853, 4092, 7908, 7790, 7881, 6655, 6110, 7629, 7548, 7837, 6136, 8010, 8096, 7635, 7132, 7801, 7896, 7951, 7543, 7988, 7145, 7095, 7798, 8070, 4091, 7851, 7535, 7146, 7612, 5631, 7980, 7638, 8017, 6123, 7415, 6125, 7838, 7037, 8067, 7605, 7892, 7859, 7119, 8006, 7038, 7959, 7641, 4079, 7797, 7654, 7906, 7986, 7519, 7847, 7153, 7610, 8018, 6131, 7099, 7883, 7630, 8074, 8033, 7148, 7802, 7965, 6133, 7862, 8073, 7743, 7651, 7920, 7549, 7879, 7975, 7637, 7154, 8128, 7599, 5887, 7101, 8009, 4031, 7127, 7854, 7102, 7658, 8020, 7912, 7865, 8082, 7804, 6134, 7644, 7547, 8036, 6137, 7963, 7885, 7660, 7131, 8076, 7607, 7156, 7987, 7893, 7143, 7982, 7421, 7791, 4094, 6015, 8069, 7642, 7886, 7657, 8024, 7861, 7160, 6138, 8097, 7981, 8011, 7775, 7613, 7891, 6911, 8048, 7868, 7668, 7133, 7550, 7898, 4095, 7966, 7979, 6135, 7643, 8088, 8007, 6140, 8034, 7611, 7147, 7666, 7907, 7839, 7994, 7134, 7149, 8081, 4063, 7866, 7989, 7639, 7799, 7909, 8100, 6139, 7631, 7894, 8013, 7665, 7103, 8040, 7407, 8084, 7914, 8021, 7653, 7855, 7900, 7990, 7155, 8104, 6127, 7928, 8014, 7806, 7157, 8129, 7897, 8071, 7672, 7993, 8026, 7910, 7655, 8098, 7863, 7921, 7039, 7583, 7150, 8022, 8035, 8083, 7805, 7646, 8130, 6079, 7996, 8078, 7867, 7916, 7659, 8041, 7158, 7614, 7887, 8075, 7161, 8112, 8025, 8038, 7913, 7661, 7922, 8085, 7967, 6142, 7803, 8136, 8019, 7899, 7645, 7162, 8044, 7869, 7135, 8077, 4093, 7983, 7669, 8099, 8132, 8028, 6143, 7870, 8092, 7924, 7662, 7164, 7911, 8049, 7995, 8037, 8089, 7901, 6111, 7674, 8102, 7615, 7151, 8144, 7991, 8042, 7667, 8086, 8105, 8015, 7915, 7673, 8056, 7902, 8133, 8090, 7670, 8050, 8027, 7917, 8101, 7997, 8120, 7159, 7895, 8137, 7647, 8106, 7925, 8029, 8052, 8160, 7998, 7676, 8116, 7918, 7163, 8039, 8131, 8113, 7926, 7423, 8087, 8043, 8138, 7807, 8108, 7929, 7165, 8079, 8030, 8145, 7551, 7923, 6141, 8134, 8114, 8023, 7166, 8046, 8091, 7903, 8051, 7671, 8140, 7930, 8103, 8146, 8057, 8093, 8161, 7678, 7932, 8054, 8109, 8148, 8045, 8110, 7919, 8152, 7675, 8115, 8094, 8053, 8135, 8162, 7871, 8060, 7999, 8118, 8139, 8164, 8121, 7931, 8058, 8149, 8031, 7167, 8107, 8142, 7927, 8168, 8124, 8047, 8117, 8147, 7933, 8141, 8176, 8122, 8061, 8154, 7663, 8163, 8150, 8095, 8055, 8165, 8153, 7934, 8170, 8119, 8156, 8111, 8059, 8169, 8166, 8125, 8062, 8177, 8143, 8172, 7677, 8155, 8126, 8178, 8123, 8167, 8157, 8180, 8151, 8174, 8158, 8184, 7679, 8171, 8173, 8179, 8181, 7935, 8182, 8185, 8063, 8186, 8183, 8188, 8187, 8175, 8127, 8190, 8191, 8159, 8189]

### Sequence Group 5: Q5_16384

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 67, 41, 144, 28, 69, 42, 516, 49, 74, 272, 160, 1026, 520, 288, 528, 192, 544, 70, 44, 131, 81, 50, 73, 15, 320, 133, 52, 23, 134, 384, 76, 137, 82, 56, 27, 97, 39, 259, 84, 138, 145, 261, 29, 43, 98, 515, 88, 140, 30, 146, 1028, 71, 262, 265, 2048, 161, 576, 45, 100, 640, 1025, 51, 148, 46, 75, 266, 273, 517, 104, 162, 53, 193, 1032, 152, 77, 164, 768, 268, 274, 518, 54, 83, 57, 521, 112, 1024, 135, 78, 289, 194, 85, 276, 522, 58, 168, 139, 99, 86, 60, 280, 89, 290, 529, 524, 196, 141, 1040, 101, 147, 176, 2049, 142, 530, 321, 31, 200, 90, 1056, 545, 292, 322, 532, 2050, 263, 149, 102, 105, 304, 4096, 296, 1030, 163, 92, 1033, 47, 267, 385, 546, 324, 2052, 208, 386, 150, 153, 165, 106, 55, 328, 1088, 536, 577, 548, 1034, 113, 154, 79, 269, 108, 578, 2056, 224, 166, 519, 552, 195, 270, 1041, 641, 1036, 523, 275, 580, 291, 59, 169, 560, 114, 277, 156, 87, 1152, 197, 116, 170, 2064, 61, 1042, 531, 525, 642, 281, 278, 526, 177, 293, 388, 1057, 91, 584, 769, 198, 2080, 172, 120, 201, 336, 62, 282, 4097, 143, 1029, 1044, 103, 178, 294, 93, 1058, 644, 202, 2051, 592, 323, 392, 2053, 297, 770, 4098, 107, 180, 1280, 151, 209, 284, 1027, 648, 94, 204, 298, 400, 608, 2112, 1089, 352, 325, 533, 155, 210, 305, 2057, 4100, 547, 300, 109, 1048, 184, 534, 1060, 537, 115, 8192, 1090, 167, 225, 326, 2054, 306, 772, 157, 2065, 656, 329, 110, 117, 212, 171, 1038, 776, 1064, 4104, 330, 1153, 2058, 226, 549, 1043, 538, 387, 308, 216, 416, 271, 279, 158, 337, 2066, 550, 672, 1092, 118, 332, 579, 540, 1072, 2176, 389, 173, 1037, 121, 553, 199, 784, 179, 228, 4112, 338, 312, 1536, 704, 1154, 390, 174, 554, 581, 1046, 393, 2060, 283, 2081, 122, 448, 353, 2113, 561, 1096, 203, 63, 4128, 340, 394, 1049, 1281, 527, 582, 556, 181, 295, 1059, 285, 232, 124, 2068, 205, 182, 643, 2304, 1156, 562, 286, 585, 4099, 299, 354, 2082, 1045, 4101, 211, 401, 1104, 185, 1061, 396, 344, 586, 645, 1282, 593, 535, 240, 8193, 2072, 1050, 206, 95, 327, 2084, 564, 800, 402, 2055, 4160, 356, 307, 301, 417, 1160, 213, 1066, 568, 1120, 832, 4105, 588, 1035, 8194, 1537, 186, 2177, 646, 404, 2114, 1091, 227, 896, 594, 418, 2560, 302, 649, 771, 360, 539, 2059, 4102, 111, 1052, 331, 1168, 4113, 214, 309, 1062, 1284, 2088, 188, 8196, 449, 1073, 217, 408, 609, 596, 2116, 551, 650, 229, 159, 4106, 420, 2178, 310, 1093, 541, 1288, 773, 610, 657, 333, 1065, 119, 1098, 2067, 4114, 2061, 600, 339, 1184, 218, 2096, 368, 652, 1031, 230, 391, 313, 4224, 450, 8200, 542, 1538, 334, 1076, 233, 555, 2062, 774, 175, 123, 1155, 658, 2120, 612, 341, 2305, 777, 220, 314, 2069, 1105, 424, 1068, 395, 4108, 673, 4129, 583, 355, 1296, 2180, 1094, 4161, 287, 183, 234, 1051, 125, 557, 1216, 660, 616, 342, 316, 2083, 1157, 241, 778, 2306, 563, 8208, 2074, 1074, 345, 452, 397, 2561, 4116, 403, 1112, 207, 2128, 1540, 4352, 674, 558, 785, 1100, 432, 1039, 357, 187, 1162, 236, 664, 1312, 624, 4130, 587, 780, 1080, 8224, 2085, 1122, 705, 2073, 126, 242, 2070, 1063, 565, 398, 2184, 346, 456, 2308, 4120, 358, 405, 303, 569, 2312, 1544, 4132, 244, 1158, 1097, 595, 1283, 189, 4103, 566, 676, 1169, 8195, 1054, 1108, 361, 2086, 706, 8197, 589, 2562, 1344, 215, 786, 647, 348, 2144, 2115, 419, 406, 464, 680, 4225, 801, 2089, 4162, 1069, 362, 1164, 590, 409, 1286, 4608, 570, 1121, 788, 1552, 2192, 1106, 4107, 2076, 597, 1075, 8256, 572, 1186, 219, 311, 2117, 708, 598, 2090, 1289, 601, 651, 421, 792, 4136, 802, 8201, 2564, 611, 1047, 602, 1172, 410, 231, 2097, 4164, 688, 653, 1128, 248, 1070, 2122, 4226, 369, 2320, 190, 364, 1568, 654, 2208, 1095, 8198, 659, 1161, 335, 480, 4115, 315, 4109, 221, 3074, 8209, 370, 1285, 613, 2568, 1408, 4144, 422, 425, 2336, 451, 1077, 614, 543, 1298, 235, 412, 2576, 343, 372, 2240, 1185, 775, 317, 2592, 4110, 8202, 2118, 1539, 222, 1099, 426, 4168, 2092, 453, 4353, 237, 1124, 559, 1170, 2179, 1292, 4117, 833, 8210, 804, 712, 1082, 834, 661, 1053, 808, 779, 2129, 1217, 617, 604, 2098, 1541, 433, 4228, 720, 2121, 816, 1101, 8320, 2063, 1176, 836, 2368, 347, 897, 2181, 1136, 4131, 243, 1297, 2100, 662, 4354, 2071, 1600, 4122, 454, 318, 675, 1110, 618, 2182, 1081, 4609, 898, 781, 1314, 1220, 376, 428, 1546, 665, 4176, 736, 8204, 567, 1107, 8225, 2432, 1192, 1078, 840, 2124, 2185, 625, 8257, 238, 2130, 1159, 359, 457, 2104, 399, 787, 2075, 2145, 4133, 591, 678, 434, 4121, 677, 2087, 1290, 4118, 1542, 349, 1300, 1102, 245, 4232, 1188, 458, 4356, 666, 1113, 620, 1553, 8212, 1163, 2307, 1313, 4360, 363, 2132, 127, 1067, 8448, 191, 2186, 1125, 782, 407, 2193, 436, 626, 2309, 2077, 1218, 571, 465, 681, 2091, 246, 4134, 707, 8226, 2146, 4610, 1346, 350, 1084, 599, 668, 2563, 1548, 4192, 4163, 790, 1165, 1320, 460, 1123, 2136, 1200, 4137, 249, 2188, 682, 1664, 8216, 573, 1171, 411, 803, 2078, 1116, 8228, 789, 2194, 1304, 709, 365, 4240, 440, 628, 4124, 689, 3076, 8199, 2119, 374, 1224, 423, 2310, 1556, 4165, 466, 793, 2313, 4138, 1130, 250, 371, 1174, 481, 574, 1348, 2209, 4612, 413, 2624, 1109, 603, 366, 2093, 1545, 4145, 8321, 2148, 1287, 1055, 8258, 468, 1570, 655, 900, 4170, 2688, 805, 4368, 615, 3073, 8704, 1166, 684, 1409, 710, 2099, 1187, 4256, 429, 8203, 794, 2196, 252, 1114, 373, 605, 1232, 848, 690, 2094, 5122, 2123, 713, 632, 2314, 1316, 482, 4616, 806, 2321, 4384, 1132, 8232, 2565, 1083, 427, 2152, 1177, 904, 4624, 2210, 1569, 8260, 4288, 414, 1291, 2101, 223, 1126, 4640, 2241, 1554, 4166, 663, 3080, 8322, 692, 835, 1328, 619, 472, 2200, 1137, 4140, 455, 796, 2125, 1189, 1601, 809, 714, 2212, 1248, 721, 4227, 837, 8211, 2816, 716, 1086, 8205, 2316, 1302, 1352, 864, 2322, 2566, 4177, 8240, 810, 2102, 1173, 4146, 606, 1194, 2131, 912, 4169, 2105, 2569, 1103, 4111, 722, 696, 377, 4416, 1424, 435, 2160, 1293, 4229, 1560, 8206, 817, 1129, 1792, 319, 621, 4148, 1180, 812, 4119, 484, 3072, 8264, 1345, 430, 1572, 8449, 2183, 1138, 2126, 1299, 4230, 838, 2337, 2242, 667, 1219, 8213, 488, 2133, 1111, 239, 378, 2324, 2570, 459, 622, 2106, 2216, 1410, 4480, 627, 437, 2187, 380, 4172, 4233, 8324, 2147, 1201, 4178, 1608, 818, 1178, 1294, 461, 4152, 2134, 1543, 4123, 496, 4193, 669, 1190, 1317, 679, 1140, 8227, 1079, 2108, 1221, 4135, 724, 8450, 2328, 841, 1305, 8218, 629, 2137, 1584, 351, 467, 2338, 2577, 1360, 8705, 438, 2572, 2244, 1115, 737, 251, 4355, 462, 2189, 442, 4180, 441, 3088, 8272, 2149, 4234, 1666, 469, 2195, 1549, 4241, 247, 683, 2224, 1196, 4357, 1226, 4125, 842, 1412, 1127, 738, 4139, 1144, 2190, 1308, 4194, 899, 2578, 1602, 670, 1318, 8229, 783, 2369, 1085, 4611, 8217, 849, 2079, 1555, 1193, 8214, 820, 2248, 1576, 728, 928, 4184, 2138, 8328, 791, 4236, 367, 3104, 8452, 2593, 1376, 901, 1233, 630, 2340, 2370, 1321, 4126, 685, 8456, 844, 2580, 4242, 1204, 633, 711, 1118, 253, 691, 2311, 1301, 5124, 2197, 4167, 824, 2150, 1175, 902, 4358, 686, 2153, 1668, 4361, 1222, 8230, 2352, 1416, 1133, 8706, 740, 6144, 1347, 850, 375, 4257, 2344, 1558, 8288, 4672, 444, 3078, 8259, 1306, 2211, 470, 1167, 4141, 483, 2140, 1547, 4196, 415, 3081, 8233, 485, 2095, 905, 1202, 795, 473, 2315, 1240, 4736, 634, 744, 2433, 5121, 2594, 1616, 852, 960, 2372, 1322, 865, 4147, 693, 8336, 2256, 4244, 1131, 8220, 2434, 1794, 1350, 797, 2198, 2201, 1225, 4142, 8261, 4171, 2213, 1604, 1571, 8234, 4362, 906, 1252, 2154, 715, 1141, 4369, 2103, 2376, 1330, 4613, 807, 3136, 8708, 474, 636, 4200, 1179, 694, 254, 2584, 1550, 4258, 1665, 8241, 717, 2625, 1071, 1315, 575, 913, 4149, 2596, 1440, 798, 4289, 811, 3082, 8266, 5128, 2161, 379, 1208, 8464, 2202, 1353, 2127, 1191, 4248, 697, 2317, 2156, 4173, 1564, 8352, 431, 2626, 1142, 4260, 607, 2272, 1228, 2214, 489, 4864, 2567, 2600, 1324, 9218, 4364, 866, 723, 2243, 486, 4370, 1573, 4614, 8712, 2318, 1181, 4150, 1234, 3089, 8480, 908, 1793, 1561, 718, 813, 4179, 2689, 1364, 4153, 476, 4617, 856, 3084, 8720, 1117, 1411, 839, 1329, 8384, 2571, 1295, 2323, 1146, 4208, 725, 8736, 2628, 2339, 698, 1472, 8262, 914, 2107, 1249, 752, 868, 2217, 2608, 5120, 2162, 8236, 819, 2325, 2204, 1349, 4231, 814, 4174, 439, 2135, 929, 4385, 4290, 3200, 8323, 2245, 1197, 4181, 1578, 490, 2164, 1139, 4372, 1680, 623, 4618, 2218, 1632, 4154, 1336, 8273, 4264, 671, 1198, 1362, 739, 1603, 4235, 8242, 1557, 2109, 1413, 4195, 916, 3090, 8265, 2579, 1303, 463, 1236, 8207, 843, 2573, 2690, 1135, 4182, 8512, 381, 2329, 2326, 1672, 1354, 8325, 497, 2574, 2225, 1586, 930, 821, 4156, 2341, 8244, 2436, 726, 4376, 961, 3105, 8215, 2139, 1203, 4185, 1182, 872, 2632, 2817, 1418, 4386, 4625, 8326, 492, 2246, 1250, 4620, 1332, 4292, 631, 1574, 1223, 729, 4237, 2220, 1145, 5136, 2168, 1605, 4197, 700, 2249, 1796, 443, 4243, 1307, 8576, 741, 2384, 1378, 4272, 1562, 8268, 8329, 2110, 1356, 1205, 8274, 845, 2330, 6145, 1319, 920, 382, 4238, 2191, 3077, 8248, 1585, 8219, 4626, 822, 3092, 8289, 2151, 1425, 2226, 851, 1229, 4417, 730, 2342, 2141, 1609, 4127, 498, 3106, 8231, 880, 2692, 4296, 1256, 742, 445, 2250, 1392, 4186, 471, 635, 2640, 1148, 5152, 2371, 1696, 4641, 932, 2440, 1580, 687, 4388, 4418, 8451, 2345, 1210, 4628, 1420, 8276, 2818, 1612, 1325, 1800, 8330, 903, 6146, 2155, 1134, 4359, 8337, 825, 4245, 2228, 1235, 1361, 8453, 4198, 500, 3328, 8221, 1577, 2199, 846, 1670, 4201, 2257, 8235, 2332, 1195, 4400, 745, 3075, 8290, 826, 2696, 732, 1264, 446, 962, 2142, 2252, 1426, 4392, 1620, 8707, 936, 2346, 5126, 2448, 1377, 475, 853, 4259, 2656, 1310, 867, 4188, 637, 3137, 8280, 5129, 2400, 4143, 1551, 8332, 2373, 1230, 2581, 1414, 4363, 907, 2203, 2258, 1206, 4481, 1667, 8222, 4642, 2353, 1588, 1333, 8338, 4420, 487, 6148, 1808, 2595, 695, 1441, 4304, 2348, 2157, 1087, 9220, 4482, 746, 3096, 8263, 828, 2232, 753, 4246, 1610, 4249, 8454, 854, 2582, 1237, 4261, 1326, 3108, 8457, 857, 2585, 1368, 1209, 504, 799, 4202, 2163, 10240, 1355, 4151, 255, 4424, 964, 3138, 8353, 5184, 2215, 1242, 909, 1673, 8768, 2273, 1559, 2374, 1309, 4632, 719, 8237, 2354, 2820, 4673, 1143, 8292, 477, 2205, 1617, 4644, 915, 2704, 2377, 1448, 5130, 2158, 8832, 4209, 2165, 2260, 1380, 9217, 4250, 638, 4175, 748, 2219, 944, 4365, 1728, 4204, 3086, 8243, 2824, 1331, 4674, 1227, 3112, 8340, 869, 6152, 1592, 4320, 1428, 491, 699, 4262, 2378, 1253, 4615, 1351, 8238, 4648, 754, 3201, 8267, 1183, 1565, 858, 1618, 4291, 8458, 2274, 1417, 2597, 1476, 4366, 478, 3091, 8465, 2586, 5137, 2435, 968, 1260, 8709, 383, 2356, 2264, 1212, 4737, 8296, 910, 2464, 2319, 5132, 2327, 1801, 8354, 815, 2206, 2385, 1579, 4619, 976, 4371, 2598, 8245, 2720, 870, 4676, 4387, 3140, 8385, 2166, 1684, 9224, 4155, 1633, 917, 2380, 2627, 1337, 4265, 1241, 4656, 8344, 4210, 2588, 1606, 4373, 1824, 3120, 8269, 4252, 727, 1150, 1442, 493, 1357, 4183, 8356, 2437, 1251, 5248, 2221, 1676, 4293, 873, 3085, 8960, 2169, 1384, 701, 4212, 1566, 8460, 931, 2601, 2247, 1323, 4266, 1798, 8466, 8710, 2832, 2227, 1365, 1473, 8246, 756, 2276, 6160, 2386, 1334, 860, 499, 4157, 2360, 3584, 8275, 5138, 2752, 8249, 4627, 731, 3202, 8713, 2438, 1648, 2222, 4621, 1238, 4738, 823, 2602, 2629, 1575, 4377, 4374, 3094, 8304, 922, 2441, 1199, 4622, 1674, 4273, 874, 2331, 1432, 4389, 1421, 918, 4484, 2170, 1636, 5153, 2496, 1254, 9216, 4187, 502, 2401, 1795, 933, 4680, 1366, 4865, 8327, 8270, 2609, 1338, 4294, 1682, 8481, 3144, 8386, 2251, 1587, 1211, 1488, 8277, 743, 2111, 6176, 2388, 1358, 4268, 8468, 760, 4216, 2442, 3097, 8714, 1244, 1581, 8250, 4297, 881, 3329, 8360, 2575, 1147, 2630, 494, 1379, 4432, 2604, 8331, 2229, 2343, 1272, 4158, 702, 3107, 8291, 921, 2333, 4378, 1624, 501, 876, 2280, 2172, 1415, 4239, 5125, 8278, 847, 2253, 1856, 5140, 2230, 1444, 4199, 992, 4274, 2691, 1697, 447, 4390, 4189, 3204, 8252, 5154, 2610, 1607, 4740, 1436, 8472, 2334, 1369, 2633, 1257, 4298, 1704, 8281, 733, 6147, 2347, 1797, 4688, 1669, 8482, 8721, 4419, 2402, 1340, 1231, 8716, 4488, 827, 3093, 6149, 8388, 1590, 2259, 934, 1634, 4393, 2449, 3152, 8333, 2233, 1474, 9232, 4866, 882, 3109, 8293, 937, 2444, 2392, 963, 1419, 4203, 8339, 747, 2634, 2693, 1265, 4276, 1119, 3330, 8368, 505, 2641, 5376, 2583, 1381, 855, 924, 4247, 2288, 10241, 1810, 4305, 734, 4380, 829, 3098, 8334, 5123, 2254, 1563, 4744, 1213, 8722, 2143, 1611, 2375, 1363, 4190, 4300, 8513, 2612, 2848, 1430, 4394, 1258, 8223, 4496, 2450, 1688, 1386, 8392, 4704, 965, 6208, 2404, 1614, 5185, 2355, 8282, 1730, 4448, 2349, 2465, 1239, 9248, 4421, 938, 4629, 3208, 8737, 884, 2261, 506, 4251, 1327, 4306, 3114, 8484, 8514, 2616, 1589, 4401, 1804, 3168, 8724, 749, 2880, 6153, 1370, 1640, 945, 966, 4643, 2636, 3083, 10242, 1456, 4396, 1681, 8455, 4205, 755, 3585, 8341, 5144, 2234, 1266, 859, 1427, 4280, 8294, 2694, 1593, 2452, 1388, 4630, 940, 3139, 8297, 2275, 5156, 2944, 4633, 1214, 8496, 830, 2642, 2466, 1809, 4211, 12288, 911, 2350, 2697, 1621, 5186, 2819, 1582, 8488, 4263, 2408, 2587, 1832, 9222, 4321, 871, 4422, 6150, 8355, 2159, 639, 4402, 1480, 4868, 3100, 8284, 2379, 1698, 9225, 4253, 1335, 3216, 8239, 888, 6161, 2262, 1372, 4752, 1245, 4425, 8459, 479, 4206, 2357, 1422, 4213, 1268, 3110, 8577, 4308, 946, 3332, 8738, 1732, 1677, 750, 1802, 4267, 8516, 2236, 10244, 1626, 5134, 2497, 1393, 4872, 969, 3121, 8400, 2265, 5160, 2456, 508, 1613, 8578, 861, 2657, 2644, 1446, 4426, 1857, 8342, 8345, 2599, 2698, 5249, 2277, 1339, 8357, 757, 2207, 6154, 2468, 1382, 4322, 970, 4645, 2358, 3141, 8298, 5139, 2589, 8247, 4634, 4483, 3336, 8520, 2821, 1700, 2658, 9280, 4404, 1243, 4312, 919, 2705, 2381, 1594, 4512, 1433, 4367, 3113, 8728, 4375, 2167, 1826, 4254, 1504, 3146, 8769, 4433, 875, 6162, 1635, 4646, 1259, 862, 1920, 4768, 8740, 2648, 1675, 5188, 2387, 1445, 9226, 4214, 758, 3232, 8305, 2266, 1149, 948, 4428, 1359, 4675, 8346, 8271, 2416, 2700, 1816, 4636, 1596, 8461, 3079, 8300, 2278, 5168, 2439, 1671, 1712, 8770, 977, 2361, 6272, 2498, 10248, 1385, 4485, 8416, 923, 4269, 2590, 3586, 8358, 5133, 2382, 1622, 8711, 4217, 972, 3124, 8744, 2281, 1434, 2603, 4649, 1311, 4295, 2822, 8387, 2223, 2171, 1729, 4880, 4275, 3203, 8462, 761, 2706, 9233, 4324, 1396, 4434, 877, 2660, 2389, 1207, 4408, 1475, 5632, 8833, 4800, 2825, 1449, 5250, 2268, 1812, 9228, 4486, 952, 4270, 2362, 1686, 495, 4650, 1262, 4677, 8715, 3153, 8467, 5142, 2472, 1644, 4489, 1619, 8772, 3116, 8483, 2443, 1341, 6156, 1429, 4379, 1825, 8251, 703, 2721, 6177, 2631, 1371, 4218, 1638, 8361, 8752, 4544, 2403, 3344, 8306, 1567, 1736, 8469, 4449, 935, 3142, 6209, 8348, 2335, 1685, 2231, 978, 1625, 4657, 2282, 3099, 8279, 2173, 5192, 2605, 9344, 4299, 883, 3264, 8389, 762, 2708, 2664, 4159, 1246, 4436, 8308, 503, 2390, 2364, 1458, 4490, 5145, 3205, 8362, 925, 2289, 1394, 5377, 2826, 1269, 4623, 878, 4678, 2611, 10256, 1478, 4652, 735, 4277, 4391, 3122, 8253, 5155, 2393, 1799, 9234, 4381, 1678, 8723, 2500, 1860, 2445, 1443, 4328, 1637, 4220, 8717, 8834, 6164, 2451, 1481, 4301, 1373, 8473, 3160, 8470, 4278, 2255, 1699, 1255, 8718, 4739, 993, 3588, 6400, 8369, 2722, 1591, 5252, 2606, 8485, 1828, 4658, 2833, 3148, 8580, 2480, 1452, 9249, 4382, 885, 4681, 3087, 8283, 939, 2405, 2235, 994, 1400, 4395, 3210, 8776, 8961, 2284, 2712, 1744, 4450, 1656, 3360, 8390, 980, 2672, 6178, 5141, 2635, 1689, 926, 764, 4307, 2828, 3128, 10272, 1270, 4497, 5200, 8364, 4281, 941, 3170, 8312, 5157, 2753, 1628, 4492, 1367, 4440, 8393, 2174, 1805, 2290, 1457, 4682, 4741, 3111, 8528, 2613, 5378, 2446, 1921, 4689, 1583, 8254, 4631, 2394, 2504, 1387, 4336, 1642, 8474, 12289, 967, 6168, 2406, 1267, 5146, 2453, 1484, 8335, 9221, 4302, 2351, 2617, 1450, 9236, 4191, 886, 4423, 3592, 6180, 8295, 8370, 2292, 831, 4660, 1683, 4896, 3206, 8486, 3145, 8285, 2643, 1342, 9250, 4498, 1811, 3331, 8836, 947, 2237, 6151, 2614, 1705, 1431, 4452, 8394, 507, 4403, 2724, 3217, 10243, 1261, 4397, 1840, 3102, 8784, 4513, 889, 3156, 8515, 5256, 2409, 1650, 984, 1760, 4309, 8584, 2754, 10245, 1490, 5162, 2637, 1615, 4664, 751, 3392, 8489, 2263, 5216, 2834, 4928, 1702, 8962, 942, 2695, 2396, 1858, 4684, 5131, 12290, 8299, 2467, 2454, 1423, 5633, 2512, 1460, 8372, 4282, 2728, 6273, 2849, 1383, 9472, 4742, 996, 4500, 6210, 3117, 8343, 5187, 2410, 8401, 4323, 1692, 4992, 3212, 8476, 2638, 1641, 2457, 9219, 4690, 1814, 4514, 3334, 8840, 971, 6656, 2618, 1477, 4398, 1273, 4745, 3169, 8286, 8396, 4867, 2836, 1512, 4456, 1733, 3600, 8490, 4635, 890, 3154, 6155, 8592, 1598, 1374, 509, 1806, 4207, 8800, 2645, 3123, 10304, 1922, 5148, 2620, 1649, 9281, 4427, 949, 3234, 8544, 2267, 5264, 2359, 973, 1397, 4310, 8517, 8725, 2756, 2646, 1489, 4405, 1708, 8347, 3337, 8402, 2649, 5158, 2699, 5380, 2469, 1627, 8497, 1000, 2840, 6184, 2850, 10249, 1690, 4284, 12292, 892, 4545, 2659, 3095, 8739, 5169, 2650, 1274, 8492, 4313, 4504, 3220, 8301, 2458, 1438, 2279, 9240, 4705, 1817, 4692, 6212, 8376, 2736, 2701, 1390, 4647, 1464, 4746, 3176, 8726, 4325, 2296, 9252, 4255, 1868, 3118, 8729, 4516, 950, 6274, 2417, 1151, 4406, 1731, 5189, 8307, 1506, 4637, 2238, 1827, 5384, 2412, 1597, 9282, 4869, 863, 4706, 3616, 8359, 2702, 1451, 759, 4753, 1864, 4429, 8417, 3143, 8518, 10246, 5161, 2707, 1714, 4215, 1701, 8498, 3209, 8964, 2383, 5194, 2528, 6163, 1395, 1803, 8349, 1008, 2363, 6157, 2269, 10257, 1623, 4696, 1482, 8848, 8521, 4435, 2418, 3333, 8302, 5280, 2661, 1276, 8309, 4314, 510, 3456, 6192, 8404, 2470, 1435, 2473, 4464, 1652, 4748, 2499, 3125, 8363, 2662, 5127, 2591, 9230, 4326, 4487, 3346, 8968, 979, 2283, 2460, 9256, 4409, 1492, 4546, 12296, 953, 2391, 2420, 1928, 4638, 1829, 5634, 3233, 8522, 4430, 2823, 1389, 5172, 2365, 1738, 9345, 4329, 763, 4651, 6158, 10250, 1872, 4870, 974, 4271, 1453, 4219, 8418, 3587, 8741, 5251, 2270, 1643, 9235, 4754, 1713, 8730, 3147, 8579, 2474, 1818, 6216, 1215, 4708, 1402, 4437, 8500, 8408, 2501, 6401, 2285, 1629, 4873, 1520, 8608, 3172, 8463, 4316, 2607, 3218, 8471, 1830, 1691, 8350, 4410, 954, 3340, 6165, 8529, 2881, 10258, 1459, 5201, 2852, 8742, 1734, 4520, 2760, 3130, 8864, 2882, 5164, 2709, 9284, 4491, 879, 3101, 8310, 981, 2856, 2827, 4769, 1505, 4679, 3265, 8524, 8771, 2665, 2652, 1706, 4451, 5392, 3589, 8732, 982, 2481, 6276, 9264, 5190, 2768, 1924, 4383, 927, 4279, 2864, 3149, 10368, 1833, 4330, 5147, 8581, 4221, 4653, 3224, 8365, 5312, 2884, 1639, 9229, 4756, 1447, 4712, 8313, 2395, 1746, 2945, 1343, 4438, 1679, 4412, 8745, 3184, 8391, 6179, 5253, 2291, 1820, 4337, 1761, 8976, 3345, 8371, 4874, 2710, 6402, 1479, 4659, 1275, 8420, 12304, 995, 3648, 6170, 8530, 2502, 1740, 5170, 2366, 1401, 8504, 9728, 4441, 2723, 3158, 8896, 2666, 1888, 9346, 4548, 765, 4493, 3129, 6657, 8582, 8366, 2946, 2829, 956, 1496, 4499, 3362, 8746, 3268, 8773, 2424, 5208, 2476, 9238, 4303, 1861, 3594, 8585, 887, 2713, 6224, 2784, 5636, 10252, 1437, 4770, 8475, 985, 4654, 2615, 3155, 10273, 1720, 4881, 5196, 3240, 8314, 4528, 997, 3126, 8640, 5135, 2888, 1630, 4453, 1813, 4283, 8545, 2673, 10305, 1462, 5258, 2286, 1398, 4332, 4760, 3207, 8753, 2407, 5408, 2505, 9288, 4720, 1645, 8395, 4683, 2447, 2835, 1848, 4876, 1687, 5176, 8255, 12320, 8532, 6181, 2639, 1247, 5218, 2726, 1716, 8586, 9241, 4801, 2482, 6169, 2725, 1936, 9473, 4222, 986, 4338, 3338, 6166, 8719, 3590, 8774, 5159, 2397, 8748, 4661, 1483, 4494, 3348, 8373, 3150, 8487, 2293, 1651, 6280, 9251, 4442, 1745, 4552, 3236, 8477, 943, 2506, 6404, 2714, 1859, 1508, 4454, 3161, 8424, 8316, 4501, 2668, 3601, 10260, 1834, 4399, 1454, 3211, 8397, 4665, 891, 3361, 6408, 8374, 5640, 2411, 1841, 998, 1595, 4340, 8835, 2175, 3115, 10496, 1278, 5254, 2239, 5193, 9348, 4691, 766, 3173, 8754, 2830, 5379, 2455, 4285, 1465, 4662, 8478, 8777, 2484, 2674, 1709, 4772, 5265, 12291, 3266, 8491, 2619, 5150, 2513, 1764, 5204, 2729, 1646, 8546, 4457, 2294, 6182, 2755, 10274, 1737, 4802, 9237, 12293, 511, 4685, 6658, 3394, 8403, 5440, 2398, 1485, 8593, 4311, 9296, 4882, 3132, 8377, 2647, 1404, 2716, 9253, 4743, 1693, 4444, 3596, 6240, 8588, 8536, 6211, 2838, 1866, 4515, 1952, 4502, 3213, 8778, 3368, 8837, 4560, 2508, 9474, 4776, 1491, 3171, 8785, 4897, 988, 3248, 6185, 8727, 2297, 1657, 1752, 5165, 8432, 1807, 4458, 2730, 3712, 10264, 1399, 5260, 2621, 1844, 9242, 4686, 1001, 4505, 3219, 8398, 2459, 5382, 2851, 951, 1654, 4666, 8287, 3164, 8519, 10276, 5217, 2837, 1926, 4884, 1707, 8756, 3352, 8992, 2757, 5648, 2413, 6288, 5202, 2488, 1391, 8594, 1002, 2676, 6172, 2737, 10247, 1468, 4693, 5171, 12352, 8548, 4668, 2422, 3272, 8499, 5282, 2471, 1836, 8493, 4315, 4407, 3604, 6213, 8609, 2514, 1494, 2841, 9352, 4804, 1873, 4694, 6186, 3178, 8405, 2298, 5385, 2419, 9258, 4697, 1271, 4747, 3222, 8760, 4517, 2529, 2622, 9312, 4888, 1694, 4898, 3396, 9024, 12297, 893, 6660, 2461, 1923, 4707, 1461, 5143, 3157, 8780, 9227, 4698, 2651, 1748, 5268, 2414, 1715, 9729, 4506, 975, 4327, 3593, 6193, 8378, 10369, 1862, 894, 4784, 1815, 4749, 8838, 3335, 8596, 3103, 10306, 5224, 2516, 1497, 9283, 4344, 1653, 8419, 3618, 9088, 2703, 5166, 2948, 6218, 1510, 1762, 4465, 8786, 8610, 2853, 6416, 2663, 10752, 1842, 4286, 1375, 8494, 3214, 8841, 4460, 2732, 3457, 8963, 5664, 2758, 1703, 8552, 4750, 1009, 3235, 6304, 8731, 2477, 10251, 1466, 5191, 2842, 12294, 1874, 4755, 2300, 3162, 8303, 2421, 5257, 2653, 9244, 4431, 4576, 3280, 8523, 955, 2896, 2738, 9360, 4411, 1739, 4317, 7170, 12305, 8406, 2761, 2680, 1486, 4466, 1930, 5381, 3364, 8501, 4709, 2530, 6664, 9254, 5504, 2854, 1889, 9476, 4518, 1004, 4521, 6432, 3180, 10280, 1658, 4547, 5173, 8380, 4710, 1821, 4639, 3131, 8641, 5394, 2475, 1718, 9265, 4331, 1929, 4508, 8409, 3225, 8600, 2952, 1599, 6672, 1507, 4439, 1776, 4468, 8801, 3617, 8788, 10308, 6336, 5281, 2462, 1405, 4871, 1735, 8743, 3339, 8842, 4413, 2271, 3174, 6688, 8421, 1831, 1493, 8351, 12298, 1010, 3602, 6214, 8612, 2711, 10370, 1984, 5635, 2740, 1455, 8502, 9285, 4318, 2883, 3376, 8733, 2667, 5195, 2520, 9480, 4522, 957, 3185, 6188, 8965, 8802, 2503, 2844, 4549, 1865, 4333, 3237, 8849, 3649, 8525, 2857, 5220, 2762, 9257, 4655, 5266, 3296, 8311, 983, 2769, 6275, 2885, 9290, 5388, 10259, 1710, 4929, 12306, 958, 4900, 2764, 3134, 10253, 1514, 4808, 5178, 3350, 8792, 4930, 4757, 3400, 8531, 5149, 2912, 1876, 9376, 4904, 1768, 4875, 8410, 6225, 10288, 1721, 5313, 2858, 1938, 4713, 1660, 4700, 8560, 3221, 8844, 6194, 5637, 2654, 9223, 4529, 1500, 8422, 3242, 8583, 4816, 2960, 6217, 1403, 4912, 1892, 5197, 8505, 12416, 8642, 3151, 6159, 2770, 1819, 5272, 2744, 1741, 8734, 9730, 4932, 2425, 6464, 3472, 8526, 2483, 1516, 9268, 4443, 987, 4993, 3341, 6277, 8425, 3608, 8747, 10254, 5232, 2865, 8966, 1932, 4339, 3177, 8367, 3840, 8315, 2367, 5393, 2669, 6196, 9347, 4758, 1463, 3228, 8850, 1012, 2860, 6167, 2532, 5696, 10312, 1843, 4550, 3393, 8804, 8533, 4414, 2478, 3620, 10497, 1749, 4771, 5206, 3186, 8969, 4714, 999, 3347, 6278, 8412, 5177, 2886, 1838, 4994, 1277, 4877, 8506, 2715, 3267, 10261, 1647, 5410, 2536, 5316, 9297, 4472, 4524, 3159, 8616, 2287, 5642, 2426, 9260, 4761, 1925, 4832, 8587, 12300, 2507, 2670, 1498, 4663, 1742, 5203, 8865, 12321, 3458, 8775, 6528, 5288, 2675, 1513, 5174, 2485, 1880, 8547, 9488, 4936, 2428, 6220, 6281, 10372, 1717, 4721, 9286, 12353, 1016, 4334, 3249, 6226, 8479, 3656, 8375, 5255, 2866, 1953, 8426, 4455, 9243, 4553, 3226, 8317, 3342, 8749, 2509, 1837, 6200, 9408, 4495, 1867, 4883, 3591, 6171, 8852, 8808, 2544, 6241, 2717, 1631, 1469, 4687, 3238, 8534, 3365, 8508, 4774, 2727, 3188, 10275, 9349, 4530, 1747, 3127, 8433, 4773, 767, 3269, 6183, 8970, 2772, 5386, 10498, 1904, 5638, 8755, 1724, 4445, 2889, 3353, 10266, 1524, 5396, 2677, 5198, 9266, 4341, 989, 3632, 8537, 2399, 5284, 2515, 4554, 1406, 4762, 8644, 3408, 8589, 10753, 5209, 2486, 1754, 4716, 5649, 12308, 3163, 8595, 2785, 5259, 2299, 6403, 9304, 5409, 2510, 1822, 8399, 4459, 2490, 6228, 2489, 10320, 1835, 4223, 5163, 9732, 12544, 8866, 4287, 6282, 3714, 8750, 5221, 2517, 1499, 8977, 4878, 9292, 4503, 3597, 6289, 8624, 2295, 1944, 2731, 9231, 4532, 1863, 4722, 3244, 6405, 8549, 3274, 8379, 6173, 5314, 2890, 9354, 4667, 1890, 4561, 3460, 8428, 3175, 8856, 4777, 2786, 6187, 9504, 4342, 1467, 4803, 3192, 8816, 12322, 1003, 3356, 6242, 8779, 2947, 1522, 1763, 5442, 3650, 8972, 9272, 4446, 2718, 3366, 10277, 1695, 5180, 2831, 1850, 9314, 4695, 990, 4764, 3133, 6659, 8897, 10265, 5644, 2897, 1005, 1937, 4886, 8318, 3603, 8434, 3241, 10262, 5261, 2868, 5416, 9255, 4556, 1722, 8757, 3624, 8590, 2776, 5219, 2976, 6232, 5296, 10376, 1845, 4345, 8538, 8648, 2839, 6284, 2415, 10500, 1495, 4778, 5760, 12312, 3424, 8550, 4669, 2949, 3281, 8597, 5267, 2678, 1655, 8495, 4507, 4899, 3369, 6174, 8761, 2733, 10504, 1765, 5212, 2892, 9736, 12324, 1956, 4885, 6290, 3252, 8436, 2681, 5400, 2759, 9350, 4805, 9289, 4461, 3166, 8787, 4536, 2301, 2739, 9475, 4724, 1487, 4785, 3349, 7172, 8381, 12295, 8758, 6215, 2872, 1750, 4470, 1869, 5320, 3223, 8868, 9361, 4519, 2950, 6406, 9246, 5652, 2734, 1521, 9300, 4562, 959, 4889, 3716, 6409, 8553, 3270, 10278, 1896, 5226, 8898, 4346, 1263, 4467, 3464, 8781, 3181, 10754, 5270, 2788, 1940, 9536, 4577, 1770, 4670, 8407, 3395, 8978, 2898, 5444, 2423, 6305, 1877, 1509, 4509, 8839, 3606, 8540, 10336, 6720, 5205, 2492, 10307, 1711, 4699, 1756, 8611, 3354, 8598, 4462, 2518, 3215, 6189, 8656, 5641, 2531, 1846, 8872, 12417, 1011, 3595, 6244, 8993, 2463, 10281, 1960, 5383, 2533, 5151, 12354, 9261, 4564, 2953, 3250, 8554, 2843, 5666, 2521, 9356, 4751, 4996, 3288, 6784, 8782, 8601, 2682, 2792, 9478, 4901, 1784, 4711, 7169, 12800, 3664, 8762, 2900, 5262, 3008, 9313, 4780, 1870, 5505, 3370, 8980, 4806, 2913, 6195, 2741, 9744, 5283, 10384, 1662, 4525, 9298, 12299, 1013, 4890, 6292, 3179, 10268, 1985, 4348, 5210, 3842, 8789, 4469, 9267, 4701, 3398, 8764, 5328, 2845, 1753, 9378, 4944, 1927, 4786, 8411, 3273, 6190, 8503, 10309, 1528, 6219, 1849, 4809, 1882, 4728, 8900, 3652, 8790, 3619, 10282, 6410, 5412, 2954, 9481, 4578, 1766, 8793, 3300, 8843, 4902, 2763, 3189, 6417, 8613, 1511, 1954, 5228, 8984, 12328, 8994, 3378, 6661, 2855, 10756, 1719, 5179, 2522, 1777, 8803, 9239, 4523, 2684, 6248, 3227, 8794, 2742, 5273, 2302, 9364, 5000, 895, 3598, 6306, 8602, 3713, 8423, 10289, 5665, 2765, 12356, 1439, 4510, 3119, 8880, 3363, 8845, 2623, 5387, 2961, 6197, 9320, 4319, 5222, 3488, 8440, 1006, 2846, 6337, 2859, 9262, 5650, 10314, 1878, 4759, 7176, 12418, 8561, 4788, 2427, 3256, 10512, 1891, 4931, 5424, 3401, 8382, 4715, 4568, 3239, 6296, 8556, 5233, 2745, 1939, 9760, 4551, 1661, 4892, 8846, 6221, 3612, 10400, 1502, 5285, 2479, 5697, 9287, 4905, 1986, 4810, 3190, 8851, 6308, 5344, 2655, 9353, 4817, 1852, 4933, 8527, 3276, 8672, 12307, 2537, 6912, 1934, 4812, 1723, 5182, 8507, 12301, 3372, 8413, 11266, 6412, 5398, 2914, 1772, 5448, 2771, 1515, 8562, 9477, 4960, 2534, 6418, 3621, 6662, 8805, 10760, 1897, 9600, 12336, 1014, 4906, 3229, 6198, 8614, 3282, 8617, 10528, 5269, 2956, 1470, 8643, 9269, 4702, 3841, 8806, 3609, 8735, 2766, 5290, 2861, 6227, 9490, 5008, 1743, 3412, 6201, 8427, 8604, 2524, 6665, 2904, 5199, 10768, 1931, 4818, 3165, 8535, 3459, 8564, 4792, 2887, 3377, 10432, 9377, 4473, 5520, 3343, 8967, 4531, 1017, 3194, 6256, 8509, 2773, 5389, 10784, 1968, 5656, 12302, 1881, 4913, 2746, 3520, 10310, 1894, 5225, 2962, 5888, 9731, 4415, 4717, 3297, 8414, 2800, 5276, 2916, 9291, 4908, 1769, 4580, 8618, 7168, 12360, 10284, 5441, 2867, 1517, 4526, 1778, 5668, 8645, 12545, 3397, 8429, 6279, 5234, 2862, 6222, 9316, 5395, 2487, 1941, 8751, 9362, 4934, 2977, 6433, 6338, 10371, 1823, 4763, 5315, 9484, 12309, 9025, 4584, 3245, 6229, 3626, 8996, 5207, 2538, 1659, 8904, 4335, 9274, 4474, 3187, 6420, 9026, 3728, 8853, 2671, 1992, 6666, 9245, 4555, 1875, 4718, 3680, 6202, 9000, 3384, 8971, 10321, 6312, 5506, 2719, 9409, 1755, 4723, 3246, 8809, 3410, 8796, 4533, 2787, 3651, 6283, 10290, 9733, 4476, 1501, 3605, 8625, 12420, 1018, 3461, 6243, 8912, 2964, 5297, 10313, 1900, 5704, 3351, 9008, 9293, 4914, 2511, 3284, 10255, 1725, 5274, 2891, 5390, 9368, 4557, 991, 3183, 6230, 9028, 10560, 5639, 2429, 4592, 1933, 4765, 8539, 3720, 9089, 3402, 10373, 5286, 2545, 5413, 9328, 4775, 5236, 12323, 3634, 8435, 2978, 5175, 2869, 6204, 9489, 5317, 10292, 1839, 4820, 8854, 12546, 2774, 6424, 3009, 10263, 1525, 4937, 5401, 9792, 12314, 3251, 8646, 4725, 6233, 3230, 8510, 5680, 2920, 1955, 8867, 4447, 9302, 4563, 3466, 6434, 8810, 6673, 10374, 1988, 5456, 2540, 9273, 12801, 1884, 4534, 3298, 6668, 9090, 3380, 8973, 6340, 5211, 2679, 9506, 4833, 9412, 4347, 3622, 8568, 3271, 8620, 4558, 2777, 6285, 9738, 4538, 1726, 4537, 3193, 7184, 8857, 12368, 8928, 3653, 6245, 2748, 1948, 1780, 5762, 3844, 8759, 9299, 4565, 2491, 6291, 3355, 10624, 9384, 5645, 2789, 1518, 9270, 4343, 1020, 4779, 3426, 6320, 9032, 3610, 10316, 5292, 10377, 5322, 8817, 1767, 4938, 3404, 8430, 3253, 10322, 5508, 2893, 5223, 9351, 4834, 1905, 8551, 3367, 8649, 2968, 5240, 2430, 6286, 5404, 10296, 1851, 4995, 8591, 3633, 8979, 10267, 6674, 5698, 2870, 10337, 1893, 4766, 5414, 12325, 3473, 8783, 4879, 2899, 3277, 6465, 8870, 5181, 2778, 1945, 8626, 12313, 4945, 3657, 6175, 8869, 2546, 10279, 1757, 5651, 2928, 5289, 9482, 12310, 9734, 4916, 6344, 3304, 8541, 2790, 5672, 2493, 9492, 4824, 9294, 5024, 3440, 6234, 8437, 12424, 2519, 2683, 9380, 4887, 1530, 4463, 3196, 7200, 8650, 12548, 3744, 8858, 6689, 5472, 2980, 9305, 4997, 1958, 5329, 3628, 8812, 9745, 4726, 2735, 6436, 6466, 9355, 5417, 10499, 1471, 4781, 9505, 12552, 1007, 4940, 3258, 6676, 8555, 3468, 10324, 2000, 5300, 3660, 8319, 4729, 9259, 4807, 3373, 8383, 3848, 10378, 5214, 2951, 1847, 9317, 4349, 1898, 4787, 8974, 3182, 6407, 8599, 10385, 5397, 2873, 6293, 1523, 1942, 4920, 8628, 3283, 8818, 3409, 10501, 6246, 5271, 2548, 10269, 9410, 4998, 1961, 8763, 3625, 8657, 4782, 2894, 3718, 6249, 8873, 5764, 10283, 1871, 5318, 8438, 12326, 8899, 3243, 6448, 2793, 10338, 1771, 5512, 2874, 5229, 12802, 9538, 4836, 2780, 3312, 8542, 2494, 5443, 3010, 9276, 4946, 4471, 3474, 6440, 8791, 3668, 8860, 10755, 5654, 2984, 9740, 12384, 1529, 4540, 7174, 12355, 3425, 8982, 2523, 5402, 2901, 6307, 9357, 4566, 9512, 5263, 3358, 8652, 4579, 2915, 6236, 2685, 9315, 5643, 10328, 1912, 4511, 7177, 9392, 12329, 8441, 4581, 6191, 3599, 10380, 1758, 5001, 5298, 3278, 8874, 4891, 9856, 4569, 3462, 6411, 8765, 5336, 2955, 1989, 9363, 4730, 1946, 4840, 8603, 3254, 6529, 8995, 3715, 10270, 1526, 6690, 5712, 9308, 4948, 1906, 5056, 3636, 8981, 3381, 10386, 6468, 5418, 2535, 9496, 4961, 1883, 4789, 8901, 3856, 8557, 12432, 2743, 3489, 6352, 8632, 1773, 1957, 5227, 8820, 12316, 3135, 8881, 11268, 6530, 5890, 2794, 10311, 1853, 5446, 2876, 1976, 8566, 9416, 4893, 2801, 6294, 3658, 6297, 8615, 10502, 5321, 2902, 9748, 12357, 1015, 3285, 6309, 8658, 3374, 8985, 10505, 5700, 2905, 5667, 12330, 9322, 5002, 3416, 8442, 3257, 8563, 2552, 5348, 2847, 6250, 9366, 4811, 5237, 3403, 6199, 8673, 8766, 2303, 6472, 3012, 9540, 5426, 10401, 1751, 4903, 7232, 12804, 3290, 8605, 4570, 2957, 3721, 10816, 9301, 4732, 5275, 3607, 8795, 4790, 4350, 3357, 6680, 8558, 2767, 5646, 10285, 1993, 5761, 9737, 12337, 1503, 4813, 6721, 3191, 10340, 1962, 5167, 2525, 5411, 9479, 4671, 9247, 5009, 3665, 8660, 6692, 5536, 2963, 9762, 4894, 1781, 4907, 8847, 3496, 7178, 9092, 12362, 10880, 6257, 1885, 4475, 1908, 5304, 8997, 12560, 3428, 8807, 11265, 6298, 5449, 2686, 6223, 9358, 5287, 2796, 2016, 8876, 9601, 4793, 2992, 6413, 3776, 6252, 8902, 10291, 1854, 5660, 9379, 12448, 8621, 4527, 3379, 6722, 3275, 8986, 10388, 5238, 2917, 1532, 8444, 9306, 4703, 3640, 6368, 8565, 3476, 8797, 2539, 5324, 2747, 6310, 9424, 4585, 1972, 3301, 6663, 9040, 3399, 8882, 10286, 6696, 5420, 2802, 13314, 10315, 1774, 4962, 3231, 8905, 3613, 8824, 4819, 2906, 3666, 6339, 10506, 9508, 4582, 5669, 3465, 8674, 12808, 1019, 3524, 6414, 8998, 2526, 5277, 10513, 1895, 5330, 7185, 12576, 9324, 5004, 3016, 3308, 10757, 1987, 5889, 2431, 5657, 9275, 4814, 4909, 3260, 6785, 8619, 10344, 5460, 2958, 9369, 4572, 1969, 4952, 9096, 7180, 12816, 3849, 10402, 5213, 2863, 5507, 9761, 4935, 1782, 5425, 12480, 3627, 8606, 6667, 5391, 3024, 6419, 9483, 5242, 10293, 1279, 4821, 8415, 9318, 12832, 2918, 6724, 6435, 10433, 1943, 4794, 5568, 9746, 12358, 3732, 8855, 5010, 11272, 6203, 3681, 8884, 5345, 2965, 1899, 9027, 4848, 9520, 4964, 3385, 6313, 8811, 3289, 6704, 8664, 10392, 1994, 6258, 9329, 12332, 1663, 4915, 3654, 6421, 8647, 3872, 8988, 10317, 6300, 5445, 2775, 9381, 9793, 4910, 3198, 9001, 3490, 8906, 4535, 2541, 3405, 6231, 10404, 9440, 5025, 1964, 3299, 7296, 8913, 12419, 9029, 3724, 6341, 2921, 5293, 11008, 1785, 5674, 3432, 8908, 9278, 4586, 2749, 6260, 3614, 10508, 9494, 5235, 2979, 5776, 9544, 4719, 1021, 3371, 6314, 9056, 3846, 10514, 5728, 10758, 5432, 12369, 1935, 4767, 3413, 9002, 3521, 10294, 5294, 2804, 5458, 9365, 4835, 5699, 12338, 3382, 8798, 2908, 5653, 2547, 6205, 9386, 5509, 10323, 1886, 5012, 9104, 7186, 12361, 10297, 6675, 5399, 2779, 10761, 2001, 4559, 5332, 9295, 12303, 3696, 8914, 4939, 6669, 3286, 6786, 8888, 5231, 2871, 1407, 8569, 12608, 9616, 4477, 3623, 6425, 8627, 6422, 10352, 1779, 5768, 2970, 5450, 9485, 12421, 9752, 4593, 3247, 6670, 3722, 9009, 6321, 5682, 2922, 9321, 5026, 9984, 4917, 3480, 6437, 8511, 3469, 8813, 12340, 2966, 6532, 9372, 4822, 1990, 5057, 3684, 7201, 9004, 12311, 3302, 8676, 11264, 6235, 5299, 2550, 9537, 1970, 5278, 3843, 8622, 9764, 4968, 2981, 6728, 3414, 6913, 10375, 9330, 5514, 10318, 1879, 9491, 12422, 1022, 4588, 3386, 6342, 9030, 3730, 10529, 5346, 10434, 5428, 3635, 8859, 9411, 4727, 3259, 8680, 3536, 10325, 5670, 2791, 5319, 9303, 4825, 1902, 8431, 3406, 6316, 8570, 10516, 5241, 2808, 6264, 5701, 10762, 1947, 4796, 8651, 3292, 8814, 3629, 10298, 6345, 5892, 2929, 10408, 9602, 4539, 5403, 12672, 3195, 8819, 4837, 2542, 3427, 6480, 8629, 5474, 10379, 1759, 5658, 8572, 12364, 12425, 3320, 6206, 2750, 10339, 1907, 5452, 2969, 5301, 9393, 12370, 9800, 4941, 6426, 3672, 9010, 2549, 5415, 2924, 9370, 5016, 9486, 4478, 3463, 6287, 8653, 7173, 12344, 10326, 5681, 2895, 9735, 12315, 1527, 4918, 3904, 7188, 8688, 12385, 3492, 8861, 6247, 5521, 3040, 6322, 9382, 4947, 9509, 5325, 3745, 8871, 9332, 4826, 2495, 6438, 6237, 9271, 5705, 10300, 1996, 4594, 7202, 9413, 12327, 8916, 4976, 3655, 6788, 3484, 10520, 1786, 5352, 3417, 9033, 4838, 9497, 4541, 3305, 6346, 8821, 3752, 10329, 5488, 2781, 1959, 9776, 4567, 2002, 4731, 8543, 3845, 6736, 8659, 3717, 10530, 5244, 10769, 6467, 5792, 9552, 1913, 5028, 3388, 8630, 3279, 10764, 6536, 5676, 2875, 10436, 9307, 4783, 1949, 8929, 3638, 8443, 12547, 2982, 3682, 6441, 8654, 5306, 10381, 2017, 5516, 8634, 12372, 3522, 8633, 11280, 6914, 5708, 2930, 10341, 1534, 5421, 2985, 5896, 12426, 9858, 4999, 3011, 3467, 6251, 8661, 10387, 5230, 2795, 9741, 12433, 4921, 3313, 6324, 8439, 3167, 8875, 10416, 5331, 2553, 5457, 9388, 12549, 9418, 4596, 7424, 12317, 3429, 9034, 2903, 5673, 2972, 6295, 9604, 4942, 9319, 5766, 3858, 6353, 8930, 12331, 2782, 6428, 2877, 9336, 5291, 10382, 1788, 4841, 7171, 9500, 12386, 3611, 9091, 4922, 6792, 3261, 10770, 9794, 4828, 5360, 3659, 8862, 4542, 9510, 5058, 3411, 6238, 8975, 6348, 5522, 10561, 1910, 5716, 9277, 12803, 1965, 5032, 3478, 6442, 9041, 3306, 10271, 2004, 6544, 5473, 9747, 4571, 9385, 4949, 3736, 9012, 3434, 10440, 6752, 5406, 3013, 9768, 4963, 1901, 4733, 8920, 3662, 7233, 9120, 12376, 10330, 3778, 6496, 1966, 1775, 5647, 8983, 12428, 3287, 8559, 11296, 6469, 5326, 2986, 6677, 10785, 9568, 5510, 2932, 2008, 9093, 9425, 5003, 2554, 6299, 3375, 6354, 8822, 10532, 5302, 10562, 5763, 9513, 12318, 8877, 3637, 6449, 3852, 9036, 10772, 5684, 2797, 5429, 12434, 9396, 4583, 3418, 8825, 3688, 8903, 2993, 5904, 3014, 6691, 9310, 4791, 5537, 3504, 6444, 8445, 3729, 8883, 10503, 6253, 5183, 2803, 9493, 13316, 10389, 1531, 4842, 7192, 12359, 3314, 9016, 4924, 2907, 3475, 6328, 10342, 9367, 4849, 5706, 3641, 9094, 12550, 4950, 3436, 6678, 8878, 2988, 5333, 10345, 1971, 5422, 7204, 9860, 12553, 9414, 4953, 6681, 3262, 10544, 1950, 5464, 2878, 5305, 9608, 4600, 9325, 4895, 3857, 6259, 8932, 14336, 5451, 2959, 9539, 4351, 1909, 5060, 9042, 3669, 7234, 8567, 12449, 3630, 10536, 6311, 5338, 9750, 5005, 1991, 5769, 12864, 3880, 8636, 11270, 6369, 5655, 2919, 6470, 9498, 5405, 10403, 2018, 4815, 8662, 9359, 12333, 2687, 6450, 3528, 6916, 8675, 10332, 1727, 5239, 9739, 12388, 3746, 8607, 4573, 11273, 6301, 3383, 8677, 10287, 5713, 2936, 1916, 9097, 9394, 5011, 3420, 6800, 8987, 3293, 6473, 8665, 10507, 5544, 2527, 6254, 9432, 12928, 1855, 3470, 6261, 8826, 3316, 8936, 10625, 6356, 5476, 2994, 13313, 10786, 9808, 4734, 3780, 9044, 3725, 9152, 4844, 2798, 3850, 6315, 10564, 9514, 5040, 5824, 3674, 7182, 9057, 12339, 8885, 3441, 6920, 3017, 5427, 10448, 1974, 5323, 7208, 12436, 9323, 4965, 2556, 3661, 10626, 9986, 5688, 2909, 5524, 9542, 4587, 4795, 3494, 6474, 8989, 3905, 10390, 5349, 10393, 5447, 9417, 12334, 1995, 4850, 7297, 12363, 3387, 10405, 5279, 2805, 5661, 9796, 4954, 9763, 5714, 12554, 3430, 9098, 6370, 5513, 3018, 6693, 9444, 5572, 10346, 2020, 4574, 8907, 7187, 9333, 12561, 10295, 6682, 6531, 10568, 1977, 5064, 5356, 9522, 12805, 3748, 8999, 4479, 11328, 6452, 3291, 6360, 8666, 5308, 2967, 1787, 8828, 12392, 9371, 5006, 3642, 6560, 8886, 3481, 6415, 8446, 10776, 1914, 6423, 5897, 9742, 12450, 9857, 4911, 3874, 6302, 3552, 8909, 10817, 6481, 5675, 2923, 9263, 9507, 5072, 3683, 6694, 8767, 3307, 9105, 12341, 2910, 3968, 6816, 10788, 9632, 4966, 2005, 3723, 7236, 8990, 12481, 3493, 9003, 11274, 6262, 5780, 2806, 13320, 10353, 1887, 5729, 3197, 8571, 9400, 5013, 2996, 6476, 3407, 6723, 10394, 9545, 5433, 10319, 5337, 9383, 12440, 1023, 3864, 6684, 8889, 3644, 10509, 5702, 10348, 5920, 7216, 12365, 9756, 4823, 3719, 8623, 3760, 10818, 5246, 3025, 5538, 9334, 4589, 5453, 12452, 3433, 6533, 8799, 10464, 5347, 2971, 6317, 9420, 5772, 10406, 1963, 4969, 8681, 7181, 13056, 3670, 10759, 6265, 5480, 3020, 10792, 9516, 4797, 5662, 12556, 3482, 9058, 5027, 6697, 3359, 6343, 8915, 5419, 10435, 1998, 5894, 8678, 12562, 9765, 12806, 3777, 6928, 6323, 10510, 1783, 5461, 2809, 5569, 9373, 12342, 9426, 4852, 11281, 6372, 3444, 9100, 6482, 5430, 2925, 9985, 4956, 9753, 4595, 3255, 6456, 8910, 3523, 7680, 9005, 12371, 10881, 6848, 9556, 12345, 2024, 4827, 3497, 7298, 8668, 12809, 3860, 9048, 11276, 6534, 5744, 3000, 6318, 9309, 9603, 5334, 3734, 9031, 9521, 4919, 2543, 6698, 3310, 6725, 10763, 9487, 5671, 10515, 1980, 7190, 9338, 12400, 8917, 5018, 3692, 6537, 3667, 10820, 5295, 10531, 5770, 3389, 8890, 9664, 4970, 3477, 6427, 9106, 3873, 10299, 5528, 2751, 5517, 9441, 5014, 1903, 8944, 3419, 6266, 9060, 3686, 10409, 5732, 10800, 6592, 5350, 13312, 10354, 1973, 4598, 3615, 9011, 3784, 10517, 6497, 5891, 2983, 10396, 9541, 5029, 5462, 12423, 3733, 9006, 12366, 3026, 3673, 6705, 8631, 5434, 10327, 2003, 5778, 9121, 12577, 7240, 12482, 11392, 6347, 5683, 2931, 10437, 1789, 5307, 2810, 5584, 9389, 12373, 9770, 4839, 6207, 3294, 6484, 8682, 10356, 5454, 2551, 9331, 12564, 9872, 4856, 3506, 6538, 8815, 7193, 12810, 10410, 5340, 2973, 5677, 9824, 12346, 9528, 4977, 3442, 7425, 12456, 3317, 8863, 6671, 5243, 2926, 6726, 9390, 4590, 9554, 5475, 3526, 6700, 8931, 9795, 12427, 2783, 6325, 6439, 9749, 5368, 10301, 1997, 4798, 7203, 9605, 12387, 3847, 9108, 5017, 11282, 6429, 3726, 10771, 9495, 5720, 3908, 8655, 4597, 9428, 4972, 3491, 6376, 9035, 3685, 6268, 10765, 5511, 10882, 2032, 9327, 12374, 1978, 4943, 3529, 6349, 8573, 3421, 10521, 5952, 10518, 6326, 5540, 9864, 9546, 5088, 3747, 8689, 3303, 10766, 6787, 5793, 3041, 10417, 9778, 4543, 1917, 9122, 3639, 7300, 9013, 12348, 10533, 3876, 6706, 5703, 10628, 2010, 5532, 8918, 12568, 3500, 9153, 11297, 6430, 5465, 2933, 6729, 10331, 9395, 5353, 2987, 5800, 12377, 9374, 4829, 3042, 3448, 6443, 9064, 10824, 5893, 11009, 5765, 9610, 12578, 12817, 3792, 6498, 3704, 8684, 10438, 5436, 3028, 5327, 9442, 12812, 9524, 4923, 7189, 12484, 3737, 8823, 2974, 5686, 2812, 6355, 9766, 5030, 9415, 5730, 3318, 6545, 8921, 7248, 12429, 10412, 6329, 5570, 2989, 9337, 13328, 10360, 1519, 4978, 7205, 9797, 12389, 3676, 8892, 5033, 6540, 3415, 6488, 10441, 9988, 5059, 5515, 3853, 8635, 12435, 9499, 4843, 3505, 6730, 8933, 6789, 5361, 10576, 2019, 5215, 7426, 9570, 12464, 9754, 4601, 3969, 6737, 3631, 10302, 2006, 6679, 5477, 9548, 4951, 9397, 5020, 3435, 6384, 9037, 3690, 10522, 14337, 5906, 3015, 9511, 4830, 1951, 4925, 9112, 3315, 7194, 8574, 12430, 3532, 10383, 11269, 6350, 5659, 9777, 1911, 5309, 12818, 3498, 9014, 11284, 6239, 5707, 2934, 6471, 10343, 9617, 5459, 10418, 2021, 9043, 9421, 12609, 2879, 6708, 3731, 6944, 8922, 10534, 5526, 10333, 5354, 9801, 12319, 3390, 8690, 11298, 6546, 3859, 9072, 10884, 5784, 2995, 5482, 12488, 9448, 5061, 3753, 8934, 3479, 6500, 8637, 10442, 5710, 2555, 6451, 9584, 12378, 5826, 3309, 6445, 8663, 3888, 8827, 10832, 6561, 5335, 2937, 9340, 13344, 10563, 9888, 5034, 7304, 12833, 3698, 9124, 4980, 3032, 3808, 6357, 10632, 9772, 4602, 5423, 3538, 7210, 8879, 12580, 12610, 3663, 6712, 2799, 5685, 10537, 2009, 5900, 7264, 9402, 12820, 9612, 4845, 6976, 3750, 11010, 9804, 5466, 2990, 5736, 9517, 5041, 9992, 5062, 3906, 6732, 9095, 7179, 14338, 5552, 10347, 5777, 9326, 12551, 1790, 4851, 3471, 7681, 9017, 12437, 3508, 10420, 6330, 5362, 9427, 4955, 9553, 5523, 12390, 3431, 8692, 11520, 6790, 5689, 3044, 6548, 9769, 5484, 10391, 2026, 5036, 9038, 7235, 9862, 12393, 10449, 6371, 3740, 7040, 10524, 1975, 5310, 9387, 12592, 3689, 8937, 4926, 11267, 6738, 3862, 6562, 9018, 10888, 5905, 3019, 2012, 8924, 9456, 5007, 3525, 6446, 8638, 3321, 6793, 9154, 10334, 5717, 10444, 6915, 5678, 9618, 12584, 9812, 3560, 6504, 3781, 9128, 10538, 6683, 5928, 2938, 13318, 10640, 9569, 4967, 3646, 8667, 3422, 9045, 12451, 2557, 3854, 6255, 10848, 9502, 4735, 5576, 3970, 7196, 9059, 12380, 3697, 8829, 11329, 6475, 5794, 2997, 13321, 10592, 1967, 5431, 7312, 12335, 9743, 4984, 3021, 3445, 6358, 10565, 9422, 5468, 10773, 5341, 9606, 12555, 4575, 3537, 6453, 9099, 3756, 10395, 5518, 10450, 5364, 7206, 9398, 12673, 9859, 5042, 7428, 12834, 3675, 10545, 5828, 3048, 5773, 9780, 4846, 9525, 5898, 12612, 3738, 6332, 8679, 14340, 5722, 2940, 6593, 10000, 5489, 10787, 1915, 5065, 8887, 7217, 9633, 12496, 3322, 10540, 6361, 6552, 10349, 9279, 4604, 5709, 12674, 3486, 8938, 4957, 11288, 6753, 3865, 6740, 9020, 5542, 10424, 2025, 5953, 8945, 12438, 9802, 12441, 3438, 6695, 3512, 6794, 9046, 10774, 2022, 6373, 5435, 9429, 12453, 9518, 4853, 11300, 6303, 3916, 9049, 10777, 6564, 5478, 2998, 9560, 9401, 5066, 3199, 6454, 8696, 3779, 7237, 8991, 12394, 10355, 3554, 6685, 9547, 12343, 1981, 3875, 7432, 8447, 12616, 3645, 9156, 11330, 6917, 5796, 2911, 6754, 13376, 10407, 9434, 5339, 3499, 9101, 9865, 5015, 2807, 6801, 3912, 6477, 10465, 9751, 5690, 10566, 5529, 7209, 9501, 12824, 8911, 3762, 6263, 3749, 10546, 5922, 11012, 5600, 7242, 12865, 9335, 4971, 3443, 8669, 3851, 10397, 5731, 3056, 5355, 9809, 4958, 6016, 12836, 3671, 6744, 9107, 3530, 10896, 5771, 10569, 6483, 5541, 9640, 13322, 10350, 1918, 4854, 7328, 12401, 3324, 10357, 6362, 5245, 2558, 10452, 9572, 5044, 5455, 12442, 3483, 8830, 12367, 6512, 3700, 6796, 8940, 5912, 10411, 2033, 5692, 9136, 12557, 7175, 9920, 12396, 11278, 6374, 6535, 11016, 1999, 5767, 3027, 5808, 9523, 12866, 9419, 5073, 11304, 6457, 3540, 6594, 9061, 14344, 5481, 3001, 9784, 12512, 9620, 5019, 3976, 6686, 8683, 3877, 7682, 8891, 12454, 10570, 6478, 5718, 9445, 12807, 9543, 5068, 3437, 7220, 12840, 3786, 8946, 11393, 6377, 5530, 2811, 6699, 9375, 9757, 5407, 3920, 6918, 9050, 9810, 12483, 3022, 6319, 3501, 6267, 10466, 9609, 5825, 10789, 2028, 7299, 9668, 12558, 3691, 8670, 4857, 11283, 6802, 3761, 10778, 13329, 10627, 5492, 3866, 9160, 9452, 4973, 3263, 6756, 8575, 3450, 6485, 10548, 5303, 10456, 5571, 9404, 12929, 1533, 3677, 6921, 9102, 3568, 10656, 5545, 10511, 6364, 5908, 13324, 10519, 9993, 5048, 3878, 9007, 3739, 10398, 6458, 5782, 3002, 10577, 9771, 4591, 5358, 12811, 3507, 7249, 9168, 12563, 10790, 3782, 6568, 5740, 10912, 2011, 5715, 9062, 12868, 7212, 12579, 11332, 6539, 5437, 2927, 10358, 9876, 5525, 3029, 5921, 12347, 9825, 4799, 6817, 3553, 6727, 9109, 10572, 5467, 10819, 5734, 9529, 12457, 9433, 12848, 3754, 6499, 7440, 12402, 10780, 5663, 3030, 5832, 9798, 12565, 10016, 5031, 11312, 7238, 12444, 3972, 8919, 6431, 5781, 2975, 6327, 9342, 5074, 9634, 5721, 3881, 6378, 8685, 7195, 9549, 12375, 10629, 6269, 6701, 9443, 13440, 10413, 1982, 4979, 7360, 9868, 12485, 3687, 9065, 4858, 11277, 6804, 3495, 6760, 10361, 9576, 5342, 3794, 8893, 12404, 9758, 4599, 3391, 6486, 9123, 3727, 6460, 10793, 5554, 10439, 2034, 7301, 9515, 12458, 9990, 5021, 3868, 6385, 3809, 11024, 5490, 10419, 6922, 5365, 9557, 9665, 4974, 3527, 6707, 8948, 3323, 10468, 14352, 5574, 3043, 10578, 9526, 4831, 1979, 9052, 3788, 7218, 8691, 12349, 3449, 10552, 11776, 6489, 5895, 13330, 10944, 2023, 5774, 12819, 3936, 8923, 11394, 6596, 5956, 2813, 6541, 10630, 9840, 5539, 10414, 5733, 12813, 9430, 12930, 3004, 3544, 6547, 9015, 10794, 5577, 10821, 5469, 9767, 12569, 7256, 12566, 11286, 6351, 3909, 9114, 10633, 5795, 2935, 5351, 9391, 12814, 9866, 5089, 7684, 12465, 3485, 6818, 9066, 10523, 5687, 3033, 6702, 9624, 12581, 9613, 5924, 3768, 6929, 9110, 7244, 12676, 10362, 6576, 5548, 3045, 9828, 13345, 10688, 9446, 4981, 7183, 12379, 3678, 8694, 5035, 6501, 3861, 6331, 10593, 9987, 5090, 5496, 3510, 7306, 9125, 12872, 9558, 13057, 3446, 6380, 6808, 5840, 10801, 2013, 5752, 7456, 9530, 12486, 9874, 5076, 11336, 6768, 3693, 10443, 9779, 6731, 5785, 9403, 5022, 9680, 4860, 3896, 6924, 8935, 3735, 7224, 10303, 14368, 5366, 10580, 9550, 12460, 2036, 5037, 3295, 7266, 8952, 12408, 3764, 10634, 11289, 6849, 5724, 9436, 9773, 5463, 12489, 3984, 9073, 11521, 6270, 5901, 3034, 6386, 10767, 9339, 5553, 10822, 2007, 8686, 7207, 9571, 12624, 10796, 6709, 3531, 6542, 10421, 6017, 10535, 5679, 9464, 12350, 3699, 8894, 11299, 6490, 3793, 6600, 9113, 10525, 5483, 2991, 5738, 12570, 9816, 5063, 3907, 8693, 3556, 6502, 9068, 10472, 5363, 10364, 6549, 5580, 9607, 12431, 13317, 3882, 6447, 3502, 9039, 10445, 6713, 5546, 2939, 10048, 13332, 10422, 9636, 4982, 7688, 12391, 3889, 9184, 12466, 3046, 3643, 6388, 10883, 9889, 4927, 5779, 3326, 7302, 8639, 12582, 7241, 12381, 11396, 6739, 5438, 2814, 13346, 10802, 2030, 5907, 7427, 9799, 12932, 9628, 5043, 6333, 3513, 6710, 10526, 9561, 5801, 10825, 5527, 9449, 12490, 9896, 4603, 3757, 6820, 8925, 7313, 14339, 5357, 10539, 5936, 7198, 9989, 12880, 9861, 4985, 3812, 7252, 12611, 3694, 10594, 6505, 5746, 9532, 5080, 9423, 5856, 12680, 3785, 6850, 9019, 11285, 14341, 5586, 2559, 6733, 9782, 5711, 10451, 2014, 4847, 9126, 7488, 9826, 12585, 3533, 10641, 6359, 11344, 6930, 10425, 9666, 5798, 13058, 3452, 9074, 5038, 11301, 6791, 3741, 6492, 9129, 10636, 5954, 10584, 2040, 9155, 9611, 12395, 3914, 6563, 4000, 6550, 8939, 10826, 5519, 10885, 6608, 5556, 9457, 12468, 9311, 11522, 6824, 3539, 8697, 10833, 6945, 5479, 3036, 13568, 10775, 9573, 5092, 3705, 9047, 3800, 7213, 9116, 12439, 10480, 3855, 6506, 10002, 12497, 5788, 3447, 7308, 8926, 12572, 3892, 9021, 11290, 6734, 5737, 3049, 6553, 13315, 10446, 9755, 5910, 7430, 12936, 9405, 5067, 2999, 3702, 6714, 10335, 9803, 5573, 10567, 5369, 7265, 9555, 12382, 12492, 3974, 6932, 3755, 10804, 5608, 11040, 5829, 7696, 9622, 12586, 9450, 4986, 7250, 12688, 3439, 10642, 5694, 3050, 5470, 9880, 4605, 9578, 5902, 12896, 3516, 6741, 9157, 7219, 14400, 6018, 10596, 6716, 5745, 9806, 13377, 10547, 1535, 5045, 7330, 9922, 12640, 3884, 10541, 6363, 6455, 10657, 9431, 5069, 5493, 12613, 3542, 9130, 12821, 11400, 6852, 3921, 6742, 9076, 5585, 10453, 2027, 5804, 8698, 12443, 7433, 9519, 12498, 11306, 6745, 3319, 6795, 10808, 2029, 6565, 5723, 9781, 12593, 9996, 5096, 11360, 6936, 3742, 6946, 8941, 11072, 14345, 5786, 2941, 9562, 9832, 4988, 3971, 6755, 9137, 3509, 7191, 9158, 12835, 10828, 11275, 6746, 5370, 9648, 12588, 9873, 3796, 7316, 12397, 3763, 8947, 11777, 6554, 5534, 3023, 6375, 13336, 10426, 9458, 5913, 3910, 9051, 9619, 12472, 2942, 6832, 3863, 6797, 10886, 9785, 5486, 10644, 5560, 7272, 9580, 12822, 3545, 9132, 11331, 6392, 3701, 10467, 13348, 11136, 5964, 7214, 12825, 9406, 5046, 3558, 9022, 3810, 6513, 10834, 5247, 10658, 5827, 10001, 12403, 5602, 3890, 6334, 9103, 3423, 10542, 5923, 10889, 6508, 5693, 9813, 13378, 11011, 9774, 4959, 7712, 12455, 3751, 10600, 6798, 5547, 3057, 10779, 10024, 4855, 5960, 12513, 3514, 7239, 9063, 12614, 14342, 3922, 6803, 5810, 10351, 2035, 5797, 8831, 12594, 7305, 9672, 13060, 11292, 6479, 6624, 10571, 9890, 5491, 3003, 5899, 12445, 9527, 5104, 11408, 6459, 3787, 6365, 9080, 14353, 5719, 10454, 5578, 9564, 12944, 9437, 12617, 3534, 6514, 3978, 7429, 8671, 12398, 10549, 6757, 5372, 9614, 12405, 9460, 4606, 11302, 7552, 12500, 3937, 9138, 11524, 6566, 5531, 3052, 6569, 9924, 9869, 5748, 3706, 6595, 8942, 7221, 9994, 12459, 10428, 6758, 3869, 6687, 9818, 13326, 10689, 2037, 7442, 9585, 13064, 3766, 9161, 5075, 11313, 6379, 3977, 6556, 10457, 13352, 10648, 5588, 3647, 8700, 9805, 5049, 3555, 6487, 9053, 3824, 6516, 10849, 6024, 10836, 5925, 7329, 9638, 12618, 10049, 3453, 6919, 3783, 10791, 5485, 10890, 6461, 5834, 13441, 10469, 9531, 4859, 3879, 8949, 3541, 10399, 14346, 5968, 3058, 10660, 9574, 5070, 5549, 12514, 4032, 7683, 9162, 12837, 3503, 10550, 11333, 6366, 5739, 13331, 10781, 1791, 5809, 12826, 7243, 12675, 11528, 6570, 5914, 3005, 11013, 9892, 5311, 10850, 5498, 12596, 9435, 12504, 6597, 3913, 6381, 9111, 10897, 5725, 10573, 5616, 9786, 12704, 7268, 9625, 12559, 11305, 6703, 7314, 12567, 10359, 5926, 3031, 5787, 10018, 12446, 9696, 5050, 11338, 7436, 12625, 3758, 6977, 9067, 14354, 5555, 3006, 6948, 9827, 12838, 9451, 5830, 3562, 6856, 9054, 7226, 10112, 12960, 10840, 6978, 6805, 9867, 13380, 10579, 9637, 4975, 7197, 12406, 3924, 8950, 5077, 11424, 6952, 3816, 6923, 10458, 9341, 5601, 3769, 7361, 9140, 12620, 9551, 12867, 3986, 6761, 3708, 6748, 10608, 5802, 10892, 2038, 7685, 10008, 12828, 9788, 5078, 11271, 6577, 3548, 10470, 13360, 10631, 6864, 6020, 9863, 9904, 5023, 3451, 6960, 9169, 3940, 7245, 10553, 14464, 5929, 10690, 9577, 12677, 2041, 3867, 7320, 9115, 12461, 3789, 10782, 11778, 6980, 5735, 13325, 10574, 9814, 5543, 12409, 3564, 9164, 11316, 6491, 5842, 3035, 7041, 10473, 9626, 5439, 10795, 5775, 12841, 7280, 9503, 12487, 11014, 3980, 6387, 10415, 5916, 10363, 5857, 9921, 13072, 7441, 12467, 11395, 6806, 3511, 8953, 10898, 5575, 3060, 5371, 12516, 9588, 5091, 7744, 12626, 3891, 6598, 9069, 10852, 5836, 10581, 6462, 5497, 9399, 12600, 9667, 13824, 3797, 6819, 7254, 12992, 11017, 6762, 5984, 3047, 9641, 13442, 10460, 10004, 4861, 7225, 12678, 3886, 9144, 12462, 7042, 3325, 6925, 10554, 9878, 5052, 5592, 3695, 7458, 8687, 12842, 7364, 9454, 12869, 11345, 6520, 6572, 13334, 10664, 1919, 5957, 7690, 9836, 12681, 9811, 4983, 11308, 6809, 3973, 6880, 10635, 9533, 14348, 5533, 9621, 12571, 10017, 5081, 3546, 6711, 8895, 3790, 7251, 10913, 14369, 5816, 10823, 7336, 9563, 12410, 9830, 5093, 3561, 7222, 12736, 3928, 10595, 11536, 6984, 5726, 9759, 9928, 5909, 12641, 3765, 6769, 9127, 11334, 14401, 5558, 3064, 6382, 10527, 9877, 5494, 10423, 2042, 9170, 7303, 9817, 12849, 4001, 10474, 6503, 11291, 6601, 10365, 13384, 10797, 5741, 12491, 3885, 9075, 11456, 6543, 3915, 6931, 8954, 10900, 5944, 10856, 5783, 12351, 9438, 12628, 3679, 3517, 6735, 8695, 10582, 5343, 10556, 6822, 5812, 9650, 12682, 13337, 11397, 6578, 3795, 9117, 10481, 6821, 6032, 2815, 9586, 13569, 11018, 9461, 5082, 7434, 12815, 3952, 7686, 9070, 12870, 10803, 3772, 6493, 9670, 12844, 5579, 3572, 7444, 8927, 12469, 7246, 12583, 11314, 6389, 5747, 3037, 13347, 10585, 9991, 5841, 7332, 12573, 9870, 5039, 6602, 3454, 6810, 10692, 10052, 5955, 10637, 5604, 7257, 9635, 12520, 9829, 12412, 3802, 6764, 7697, 14356, 5930, 10643, 5550, 7307, 9673, 12493, 9565, 4987, 11352, 7457, 12470, 3870, 10447, 6507, 5937, 9891, 5094, 9447, 5691, 12931, 3883, 6271, 9185, 7211, 11780, 14592, 5374, 10914, 6335, 9783, 13444, 10798, 2039, 4862, 7269, 10020, 12850, 3547, 11025, 6926, 11340, 6551, 10672, 9644, 5561, 12574, 3992, 9077, 12873, 11279, 6580, 3911, 6770, 9131, 10597, 5805, 10427, 2044, 9186, 7362, 9592, 12587, 11402, 6715, 3938, 6609, 10476, 5860, 10904, 6825, 5742, 9936, 12642, 9848, 11552, 6390, 3515, 6851, 9172, 10864, 14370, 5833, 3051, 13333, 10827, 9881, 4607, 3570, 9118, 3811, 7490, 8956, 12499, 11020, 11320, 6494, 5581, 9462, 12689, 13392, 3743, 7228, 12473, 3898, 9133, 11362, 6743, 5500, 3038, 6812, 13349, 10945, 9820, 5789, 7692, 12684, 9559, 12632, 3053, 3985, 6934, 10366, 9997, 5962, 10482, 6048, 7309, 9649, 12874, 7464, 12933, 11303, 6604, 3770, 10805, 13570, 10638, 5587, 7267, 10113, 12881, 9775, 5084, 7344, 12823, 3893, 6393, 10586, 5753, 10696, 5848, 9579, 12528, 9834, 5903, 3543, 6826, 9159, 7808, 14360, 5495, 10598, 6717, 5940, 9459, 13338, 10645, 9676, 5097, 7315, 12494, 3703, 10543, 6555, 6947, 10809, 9642, 5047, 5750, 12383, 3813, 7260, 9078, 12615, 11784, 14372, 4004, 6933, 6022, 10484, 2043, 5803, 9023, 12852, 7448, 9875, 13088, 11398, 6853, 11337, 6509, 10835, 9534, 6584, 5487, 12690, 10003, 5098, 11523, 6772, 3535, 6833, 9139, 10429, 14343, 5564, 10806, 9897, 9623, 12644, 3798, 6518, 3917, 7368, 8699, 12595, 10916, 11409, 6567, 5932, 9453, 12589, 10032, 11294, 7700, 12705, 3569, 9081, 11348, 6610, 5590, 3007, 6937, 13448, 10601, 9842, 5969, 3944, 9176, 7274, 9952, 12501, 10946, 6394, 3311, 6515, 9682, 13354, 10829, 5367, 7318, 9807, 12856, 3988, 8943, 11584, 6625, 3818, 6718, 10455, 13408, 11026, 5790, 7492, 13120, 9894, 4989, 3925, 9134, 3557, 6557, 10887, 6019, 10588, 5557, 7253, 10050, 12876, 13323, 3759, 6747, 3804, 10659, 5844, 10646, 6510, 5811, 9615, 13825, 10704, 9652, 5071, 7689, 12474, 3894, 10920, 14465, 5958, 3059, 11041, 9575, 4990, 5911, 12934, 4008, 7431, 9188, 12692, 7199, 14402, 11309, 6612, 5593, 13379, 10602, 2031, 5749, 12515, 7714, 9884, 13184, 11404, 6799, 7044, 10830, 9833, 5606, 10649, 5858, 12882, 10006, 12706, 11526, 6949, 3832, 6759, 9163, 14848, 5938, 10810, 5471, 9669, 12590, 7310, 9465, 12937, 11361, 6828, 3918, 7553, 13059, 11028, 6854, 5799, 9704, 12648, 9925, 5105, 11792, 7331, 12827, 3710, 6573, 9082, 11346, 14347, 5562, 3061, 6938, 9790, 9566, 5970, 4033, 6396, 8701, 7258, 9998, 12399, 10837, 6517, 11315, 6749, 10114, 13340, 10812, 9841, 7376, 12619, 3801, 9141, 5051, 11426, 6992, 3975, 6834, 10459, 13456, 10551, 5835, 3576, 9165, 9589, 12502, 3897, 6857, 3930, 6776, 10948, 5582, 10838, 6026, 7460, 9681, 12597, 9900, 11529, 6626, 3814, 10841, 13350, 10891, 6950, 5985, 13572, 10661, 9819, 5100, 3559, 9192, 4002, 7276, 11032, 14376, 5754, 11042, 9882, 12476, 5917, 3767, 7227, 9084, 12737, 3825, 10851, 11287, 6571, 5814, 13361, 10842, 9466, 6025, 12505, 7321, 12696, 11412, 7048, 5695, 2943, 10650, 9630, 5603, 10471, 5872, 12897, 7713, 10009, 12884, 14404, 3487, 6558, 10928, 5501, 10893, 5831, 9582, 12839, 7435, 9656, 12938, 11368, 6367, 7270, 12517, 10488, 5927, 3054, 5589, 12447, 10060, 5106, 11310, 7698, 12708, 3926, 6807, 9142, 14466, 6080, 10609, 6836, 5551, 9343, 12598, 9923, 13381, 3939, 6979, 7472, 9698, 12829, 10430, 6763, 6616, 10019, 13576, 10604, 9789, 5053, 7281, 13061, 3987, 9055, 12898, 11808, 6599, 3709, 6940, 10894, 9643, 5961, 3550, 7333, 8951, 12945, 7745, 10056, 12621, 11335, 6953, 4034, 6858, 13353, 10899, 1983, 7392, 9906, 12407, 9893, 5079, 11401, 6865, 3900, 6981, 10575, 13386, 10720, 14355, 5806, 9587, 9995, 5054, 3982, 6860, 9200, 3771, 7230, 10555, 14349, 5610, 10461, 7446, 9815, 12888, 9674, 3820, 7496, 12627, 3563, 10610, 11525, 7008, 5972, 13472, 10853, 9468, 5864, 12506, 3945, 8702, 11648, 14384, 5817, 3062, 6954, 10662, 9627, 6034, 10665, 5756, 12656, 7317, 9844, 12940, 3518, 10691, 11317, 6750, 10854, 13319, 10783, 5596, 12518, 7338, 12679, 11538, 7056, 3791, 9171, 10475, 5499, 10652, 5988, 12601, 9684, 12738, 7247, 3979, 6866, 9145, 10583, 5915, 10612, 6840, 5837, 10120, 12830, 10021, 13826, 11425, 6521, 7568, 12622, 11015, 6579, 5612, 3065, 9581, 13364, 10557, 9930, 5083, 7437, 12521, 4016, 7704, 8955, 12843, 14350, 3929, 6961, 10064, 13062, 6028, 3942, 7273, 9166, 12463, 7936, 9645, 12411, 11779, 6463, 6765, 13443, 10462, 9835, 5559, 7324, 12946, 9905, 5108, 11339, 6956, 3817, 6628, 10666, 10010, 14408, 5939, 7489, 9407, 12900, 9594, 12629, 3565, 6574, 3826, 7716, 10693, 14593, 5845, 10477, 7282, 9821, 13065, 9712, 5095, 11364, 7443, 12508, 3989, 10799, 11410, 6982, 5934, 10022, 9883, 5373, 12602, 3871, 6811, 9146, 7363, 11532, 14357, 5743, 11073, 6632, 9651, 13393, 11044, 2046, 7255, 9926, 12712, 3707, 10952, 6383, 11322, 6522, 11074, 13356, 10901, 6021, 12683, 4040, 9071, 11293, 6603, 3923, 6766, 9173, 11048, 5594, 11019, 5838, 12961, 7554, 9697, 12871, 11457, 3803, 6771, 10857, 5609, 10844, 6581, 5976, 9898, 12643, 13584, 11781, 6524, 3549, 9174, 10673, 14468, 5813, 3066, 13382, 10960, 10116, 5112, 7345, 12575, 3948, 7752, 9119, 12471, 11056, 11341, 6962, 6049, 10025, 12522, 13339, 3773, 7322, 12413, 7438, 12845, 11416, 6605, 5933, 3039, 13504, 11076, 9831, 5963, 7687, 12948, 9639, 12904, 6640, 3981, 6813, 10587, 9938, 5727, 11137, 5565, 7334, 9535, 12630, 7461, 9871, 12604, 11376, 6823, 7284, 14371, 13445, 10483, 5843, 7223, 10012, 12529, 9953, 4863, 11537, 7365, 13066, 3887, 6868, 10902, 14594, 6000, 9671, 12851, 9467, 5820, 3573, 6985, 9187, 7449, 11840, 14362, 5620, 10694, 6773, 9932, 13362, 10558, 9593, 5085, 7728, 12633, 4003, 10915, 6495, 11350, 6611, 10858, 10080, 5502, 12740, 4036, 7504, 8957, 12685, 11321, 14849, 3932, 6582, 11138, 5850, 11021, 2047, 9148, 7259, 9688, 12691, 11554, 6881, 11460, 6395, 10616, 13400, 10668, 6606, 5918, 12495, 10053, 11786, 6586, 3774, 6585, 9079, 10905, 14416, 5931, 10976, 13828, 9629, 12962, 3996, 3828, 7810, 9177, 12846, 10807, 11347, 6613, 5595, 9912, 13073, 13388, 11432, 7693, 12720, 3566, 9189, 11318, 6391, 6040, 3068, 6827, 13327, 11080, 9822, 5959, 7340, 12645, 7370, 10005, 12475, 10865, 3815, 6986, 9654, 13450, 10478, 5986, 7556, 9590, 12524, 7271, 12952, 11399, 6882, 3953, 10599, 13600, 10697, 5563, 7288, 12912, 9837, 5099, 7452, 12875, 3899, 7043, 10639, 5618, 11027, 5859, 7746, 10040, 13068, 9879, 13368, 3941, 6814, 7462, 14373, 5791, 10831, 6927, 5946, 9439, 13410, 10918, 9908, 5086, 7229, 12993, 3993, 10674, 14361, 6993, 10917, 10128, 5101, 6033, 12414, 3805, 7699, 9178, 12530, 7337, 11530, 14358, 11782, 6964, 13351, 10589, 2015, 5818, 12853, 7720, 9675, 12686, 11540, 6872, 11342, 7072, 10485, 9843, 14472, 5941, 12634, 9937, 12744, 11428, 6935, 3578, 6511, 9135, 10698, 14596, 5591, 10906, 10051, 7520, 9700, 12646, 11353, 7045, 4006, 7377, 12693, 10860, 11793, 6774, 5751, 10026, 12591, 9646, 11403, 7465, 12857, 3519, 6829, 9083, 11553, 14600, 5861, 3055, 6988, 13832, 10603, 10033, 6052, 4048, 9190, 7348, 9787, 12532, 10367, 6777, 11307, 6855, 9470, 13446, 10431, 13385, 7262, 12883, 3895, 8958, 11365, 6397, 3946, 6835, 11022, 13571, 10647, 5583, 7445, 12477, 9657, 12854, 3571, 3990, 6968, 10676, 5846, 10866, 5965, 7319, 9901, 12964, 13457, 11458, 7046, 4009, 10811, 13342, 10705, 6830, 5617, 9956, 13396, 10921, 9838, 5055, 7812, 12649, 3919, 7366, 10486, 14374, 5992, 10947, 9929, 12994, 5359, 3819, 7560, 8703, 12877, 7277, 14850, 11586, 6884, 6036, 13632, 10590, 9677, 5866, 12503, 7491, 13074, 11324, 6994, 6519, 10839, 9596, 5973, 10908, 5605, 12935, 7702, 9885, 12636, 11788, 14432, 3577, 6588, 14403, 5807, 11030, 5852, 10058, 12707, 7450, 10144, 12694, 11405, 6614, 11560, 7311, 12752, 10700, 6627, 5942, 12968, 9683, 5107, 11363, 7691, 13089, 3960, 6559, 9180, 11440, 14377, 6056, 10489, 6629, 9849, 9944, 13357, 3806, 7049, 7346, 9999, 12650, 10922, 6939, 11904, 6617, 9591, 13452, 10813, 10036, 7384, 12878, 4037, 9193, 12697, 11411, 6778, 3994, 6888, 10651, 13574, 11043, 5880, 3574, 9143, 7760, 9846, 12858, 11356, 6996, 3954, 7104, 13409, 11029, 5966, 7466, 10118, 13076, 9899, 11544, 7009, 3931, 6837, 10949, 13840, 10605, 14480, 5758, 13394, 10680, 9583, 5109, 3821, 9194, 4005, 7275, 10868, 14364, 6081, 10929, 7938, 9660, 12885, 13363, 3901, 7494, 12860, 4024, 10614, 11464, 6941, 5849, 13474, 10663, 10028, 6023, 12507, 7369, 12599, 11796, 14405, 5624, 3063, 10706, 9686, 5945, 11033, 5978, 12996, 7748, 10065, 12886, 7715, 14378, 11370, 7050, 10490, 13577, 10611, 5862, 12889, 7396, 9463, 12939, 11414, 6859, 7285, 12709, 10721, 5607, 10814, 6050, 13080, 9886, 13090, 11588, 7474, 3799, 6951, 9085, 14852, 5815, 10653, 6618, 5873, 10115, 12899, 9653, 13335, 11349, 6780, 7323, 12890, 10843, 6838, 6398, 9940, 13460, 10606, 9907, 4991, 7694, 12698, 4041, 7809, 9167, 12519, 11785, 14385, 3551, 6861, 10054, 5535, 4010, 7215, 9086, 12976, 7459, 10007, 12941, 11527, 6719, 11295, 7057, 13416, 10708, 9689, 7584, 12536, 9845, 5102, 11810, 6942, 3829, 6955, 10895, 13358, 11140, 14410, 5974, 9702, 9954, 12657, 3933, 6523, 3956, 7352, 11045, 14608, 5987, 10855, 7497, 10034, 12478, 9567, 11406, 7335, 12652, 4064, 10924, 11649, 6841, 6035, 13856, 10950, 9895, 5757, 12942, 3902, 9201, 7708, 11427, 14496, 5598, 10669, 6575, 9658, 13383, 11034, 6082, 7286, 10066, 12947, 3580, 10492, 11354, 6751, 10613, 13449, 10845, 5948, 12623, 7372, 12768, 11472, 6633, 4020, 9147, 11088, 6030, 10930, 5819, 12603, 7468, 9931, 12509, 15362, 3822, 7010, 10953, 5868, 10872, 6867, 5611, 9678, 12658, 10122, 13573, 11556, 6630, 7717, 12901, 10722, 14856, 5993, 3067, 13696, 11046, 10081, 5110, 7325, 12710, 3943, 7378, 9196, 12713, 14624, 11372, 7052, 5566, 9850, 12739, 13365, 4035, 7937, 12902, 7705, 10013, 12831, 11323, 6862, 6957, 13586, 10667, 9910, 5839, 7508, 12523, 10121, 12700, 11417, 6620, 4017, 7000, 11144, 9791, 14864, 6027, 7261, 9699, 12631, 7555, 9968, 12660, 11809, 6983, 3830, 7473, 14528, 13473, 10654, 7439, 9597, 13063, 9927, 5113, 11531, 7290, 12605, 3327, 6869, 10463, 11366, 14880, 6064, 10023, 9685, 5977, 3991, 6842, 9202, 7616, 11794, 14406, 5990, 10903, 7058, 10176, 13827, 10932, 9647, 7393, 12510, 3947, 11075, 6896, 11568, 7012, 10859, 13387, 10712, 5865, 12714, 4042, 9149, 11377, 14380, 3711, 6963, 10695, 5613, 11036, 5874, 12741, 7493, 10057, 12525, 11429, 11841, 6958, 11049, 13412, 10954, 6583, 6037, 12847, 13458, 11488, 7073, 4012, 9175, 10961, 14467, 5919, 11077, 13580, 9902, 13121, 7341, 3833, 7722, 9150, 13092, 10956, 11326, 6634, 5755, 9706, 13000, 13370, 11542, 7283, 13122, 7824, 12949, 11592, 6767, 6088, 3069, 13341, 11104, 10068, 5971, 7776, 13096, 7480, 9960, 13067, 14417, 3983, 6815, 9913, 13505, 11050, 5851, 7342, 10130, 12905, 7506, 9852, 12892, 11413, 6883, 7747, 14386, 13829, 10846, 5597, 7701, 12721, 9692, 5114, 11434, 7557, 13008, 3934, 7060, 11152, 14409, 5996, 7447, 9595, 13104, 10084, 13389, 4049, 6607, 7380, 11343, 14351, 5821, 10962, 6987, 10011, 13464, 10936, 9933, 5087, 7279, 13124, 3455, 10617, 14656, 11664, 6525, 10675, 9708, 6029, 12635, 3827, 7816, 9179, 13185, 7498, 11533, 14469, 11800, 6641, 13424, 11057, 2045, 7730, 10124, 12531, 11369, 7074, 12032, 6965, 10559, 13585, 10861, 14388, 5935, 12950, 9655, 11420, 6870, 4038, 7105, 9204, 11052, 14359, 5621, 10724, 13888, 7347, 10035, 12742, 11585, 4018, 7326, 12606, 10670, 11812, 7016, 6051, 9941, 12963, 13398, 11378, 7562, 12906, 3927, 9191, 11539, 14470, 6084, 3070, 6636, 13369, 11078, 10030, 5980, 7394, 13186, 7476, 9469, 13069, 10907, 11459, 6775, 9839, 13602, 10728, 13508, 7718, 12664, 7367, 12716, 11351, 6873, 3950, 10479, 13834, 10618, 5822, 7289, 12953, 10117, 13024, 7749, 3995, 6844, 10699, 6044, 10862, 5876, 7940, 9690, 12855, 9934, 13395, 11650, 6587, 7451, 14720, 13480, 10867, 6885, 5614, 9705, 13366, 10677, 10072, 5116, 7522, 13128, 3807, 7706, 10620, 14412, 14473, 9909, 12913, 5863, 3955, 7500, 9208, 12526, 7349, 11441, 14418, 11848, 6989, 13447, 11058, 10145, 6001, 12647, 7463, 12745, 11418, 7064, 11534, 6526, 10701, 10029, 14392, 5947, 12687, 7729, 10059, 13075, 11783, 14363, 3575, 6966, 10736, 14433, 5989, 10909, 9823, 7569, 9661, 12879, 11430, 6995, 11557, 7373, 12966, 10919, 11380, 6874, 6041, 12722, 9939, 11319, 7753, 12965, 4044, 6642, 8959, 11461, 14375, 5853, 10964, 7024, 13578, 10096, 13830, 3834, 7400, 9916, 12637, 11081, 6886, 11545, 6589, 9716, 13588, 10869, 13390, 7536, 12533, 4007, 9181, 11824, 6615, 4050, 6779, 10591, 13476, 10707, 5626, 7292, 12746, 7840, 9598, 12954, 11600, 3961, 7076, 13401, 10678, 6054, 7724, 9946, 12908, 13841, 11355, 6831, 3997, 10977, 13451, 10491, 14595, 5567, 13601, 10702, 10014, 5103, 7354, 12651, 4065, 7564, 10682, 14420, 6096, 10681, 7756, 10027, 12415, 13355, 3582, 7469, 12479, 7944, 14474, 11906, 7047, 5943, 13413, 10709, 9691, 5994, 13070, 7278, 12695, 11789, 14481, 6969, 10487, 10136, 5619, 10923, 6038, 12724, 7379, 10055, 12914, 7505, 11436, 14597, 11466, 6644, 14365, 13506, 11082, 6057, 12859, 7721, 10082, 12753, 11652, 6990, 11367, 7814, 12969, 10978, 14379, 5967, 12534, 9659, 12995, 11384, 7339, 3836, 6889, 9195, 11548, 14434, 5867, 11139, 6970, 9714, 9955, 13634, 11842, 6876, 7408, 12638, 10910, 6590, 11558, 7106, 9887, 13372, 11023, 10042, 7570, 12887, 3958, 7764, 9182, 12956, 11325, 14851, 4013, 7080, 13836, 11089, 5625, 4052, 9197, 7521, 10129, 13078, 11795, 6619, 11433, 6997, 13453, 11060, 13608, 7454, 12748, 9914, 11816, 7011, 3949, 6781, 10968, 13411, 11168, 14424, 6008, 13488, 10037, 12537, 4014, 3823, 7695, 11031, 14476, 5854, 10607, 7374, 9687, 12970, 13952, 11616, 7558, 12861, 4056, 11141, 11473, 7051, 6085, 13459, 10870, 9847, 6042, 12699, 7350, 13091, 7811, 11561, 14366, 5622, 10925, 9957, 13404, 11084, 6002, 7732, 10148, 13077, 7477, 14482, 11444, 6631, 10873, 13592, 10951, 5979, 12997, 7952, 12653, 11358, 6839, 7585, 12728, 10493, 5869, 10931, 6053, 12916, 7231, 9679, 12977, 11541, 15364, 3579, 6890, 14407, 5949, 11064, 6972, 6072, 9942, 12662, 10061, 13512, 11415, 6897, 7754, 12711, 11142, 14598, 6998, 13844, 10926, 9713, 5111, 7381, 12754, 4019, 7470, 9151, 13081, 11908, 14601, 11462, 7001, 10088, 13418, 3998, 7512, 12538, 7353, 9455, 12659, 11656, 6648, 11373, 6943, 13462, 10980, 10132, 7499, 12769, 9962, 12862, 11587, 6399, 3957, 7108, 11090, 13636, 10615, 14497, 5847, 10069, 7386, 9701, 12701, 11798, 7053, 4039, 7817, 14912, 13397, 10684, 7703, 9903, 12891, 9948, 11546, 7453, 12654, 4066, 6863, 10710, 11407, 14381, 6089, 13833, 10723, 10038, 5599, 3775, 9203, 7287, 11787, 14436, 6058, 10655, 6621, 10152, 13575, 10725, 13343, 7761, 12756, 3964, 11145, 11442, 7059, 11035, 13858, 10713, 5877, 12943, 7592, 13188, 11480, 14976, 3903, 10874, 5981, 10984, 6004, 13093, 7524, 9976, 12903, 15361, 11856, 6782, 11092, 13454, 11200, 6892, 6112, 12972, 10062, 13697, 11562, 7088, 7872, 12998, 11105, 14387, 5950, 10933, 13475, 9854, 12717, 7475, 4022, 7371, 9205, 13082, 14484, 11371, 7013, 5628, 10177, 12540, 13402, 12034, 7736, 12661, 7572, 12893, 11590, 6635, 6843, 13520, 11037, 9945, 6068, 7397, 13136, 7495, 10119, 12978, 11465, 14382, 4043, 6898, 9720, 14411, 5870, 7327, 10041, 13001, 7709, 10074, 12920, 11844, 7002, 11811, 7762, 14602, 13604, 11146, 7561, 12770, 9958, 5115, 11492, 7620, 13094, 4068, 6622, 10955, 11381, 14609, 5991, 9703, 10146, 13420, 4025, 7112, 7404, 11570, 14853, 6083, 11047, 6527, 9911, 13371, 10714, 9969, 7356, 12715, 3835, 10876, 14440, 11419, 7054, 10934, 13465, 10494, 6065, 13192, 3962, 9087, 7945, 11790, 14498, 11905, 6959, 13857, 10957, 5878, 7723, 9631, 12702, 11311, 11555, 7120, 10815, 13579, 11153, 14389, 5375, 12511, 13414, 11680, 7014, 4053, 9198, 11038, 14529, 6039, 11051, 13842, 7828, 10070, 12951, 15368, 3935, 7777, 12980, 10619, 11448, 7061, 5995, 10083, 13123, 13616, 11593, 7481, 12907, 7385, 12760, 11431, 14488, 6090, 3071, 13425, 10937, 10131, 5759, 7750, 12743, 7968, 9853, 13084, 14413, 11804, 6871, 9694, 13477, 10671, 13889, 7294, 13097, 7586, 10178, 13002, 11382, 6637, 7501, 14500, 13536, 10847, 6060, 7395, 13009, 10044, 13125, 11468, 7820, 4011, 7017, 10729, 15104, 5881, 7528, 10126, 13004, 9915, 13374, 11564, 6845, 7710, 14604, 13590, 11106, 7075, 9964, 13640, 10963, 9707, 5117, 7467, 13152, 4046, 7942, 10726, 14610, 11813, 14854, 10089, 6031, 3831, 7509, 9206, 13098, 7617, 11421, 14390, 11474, 6900, 13461, 11148, 9662, 7478, 12894, 12033, 7004, 11801, 6643, 10958, 13482, 11053, 14419, 5982, 13200, 9935, 11604, 14393, 4072, 6875, 10716, 14857, 6097, 11096, 13391, 7792, 10123, 13010, 11357, 11651, 7382, 12984, 11079, 11569, 6967, 5503, 12665, 13712, 11535, 7719, 12723, 4028, 9209, 11386, 14448, 5875, 10965, 7066, 13581, 10160, 13848, 7343, 7818, 10073, 13105, 10938, 11712, 7018, 10086, 13417, 11154, 14080, 7576, 12607, 7565, 12909, 11489, 7062, 3951, 10992, 13468, 11108, 6086, 7780, 13100, 7398, 9961, 12772, 15360, 4021, 6646, 13633, 11059, 6066, 7939, 9709, 12718, 9970, 13860, 11589, 7077, 7510, 14471, 13426, 11054, 14414, 5975, 13587, 10679, 10133, 5118, 7482, 13126, 4051, 7826, 11169, 14625, 14530, 7731, 10015, 12955, 13507, 3837, 7355, 12776, 7632, 11437, 14421, 11818, 6887, 13399, 10730, 9851, 5998, 12527, 7502, 12666, 11379, 14612, 11920, 6904, 10863, 10184, 14858, 6043, 12747, 7388, 10067, 12910, 7725, 11872, 14394, 11576, 7025, 14504, 13698, 10911, 7291, 9947, 12915, 11438, 6638, 11602, 7523, 12725, 10979, 11843, 14475, 5855, 12668, 9693, 11797, 7416, 4045, 6846, 9210, 11653, 14435, 6003, 11156, 7065, 13489, 10092, 13896, 11543, 7768, 13106, 10703, 6645, 11476, 7020, 9917, 13466, 11083, 13582, 7559, 12749, 4080, 9183, 11375, 14422, 4026, 6991, 13831, 10621, 5623, 8000, 12784, 7588, 10125, 12957, 11912, 11594, 7136, 13478, 10737, 13605, 7841, 12967, 13428, 11826, 6591, 3965, 11170, 13367, 11061, 14396, 6092, 13509, 10031, 13012, 7751, 4058, 7580, 10966, 14616, 5882, 11201, 7513, 9717, 13129, 13593, 11443, 7401, 12917, 7848, 14425, 11422, 6877, 6055, 13872, 11112, 10147, 6098, 12639, 7941, 12755, 7813, 11658, 14626, 14865, 10180, 13648, 10732, 6009, 7484, 10076, 12726, 7375, 11490, 14860, 11572, 6971, 14532, 13403, 10871, 6045, 13025, 7734, 12539, 11814, 7078, 11463, 7778, 12750, 10969, 14477, 6113, 12730, 7618, 9918, 12729, 11385, 15376, 3567, 7026, 11845, 14437, 5630, 10940, 7081, 10140, 9972, 13954, 12036, 7107, 7563, 12757, 10683, 14483, 11547, 6891, 13837, 10981, 9710, 7409, 12535, 4067, 7263, 9212, 12971, 11618, 14512, 11802, 6649, 13484, 13514, 4054, 7525, 9959, 13130, 11596, 6999, 11445, 7068, 13700, 11085, 13415, 7954, 13026, 10097, 11559, 6878, 3999, 6973, 11160, 13432, 10622, 14478, 5884, 13596, 7707, 10043, 13187, 11825, 3959, 7357, 14866, 13890, 11062, 7755, 10085, 12958, 13606, 11665, 7507, 13071, 4069, 11091, 11469, 14657, 6006, 13373, 10970, 10137, 6061, 7574, 13137, 7402, 11849, 14367, 6100, 10738, 9949, 13843, 11120, 13481, 7832, 13108, 7530, 14536, 11496, 7109, 10982, 13864, 10685, 5997, 13016, 7758, 13216, 11632, 14426, 7874, 10711, 6062, 10875, 5871, 13079, 7383, 9722, 12655, 11388, 15392, 11936, 7082, 14881, 13664, 11172, 7028, 6104, 13189, 10150, 13521, 11820, 6650, 7471, 12918, 10927, 14628, 14658, 13609, 9663, 12973, 7733, 4057, 7948, 9199, 13132, 11450, 14868, 11660, 6893, 10192, 13492, 11852, 7514, 12921, 7784, 12999, 11565, 7089, 12040, 7110, 13406, 11143, 10039, 7600, 12541, 7825, 10090, 12979, 11374, 14599, 3838, 6899, 13589, 11065, 14485, 5627, 9715, 7410, 10134, 13112, 11475, 7003, 11601, 7571, 14438, 13463, 10740, 7737, 13190, 10153, 11817, 7532, 12974, 4074, 7084, 11086, 11910, 14441, 6067, 13956, 10063, 13510, 4023, 7358, 11435, 14640, 6046, 10985, 6974, 9963, 13704, 11066, 13421, 7953, 13028, 4060, 10972, 11504, 7055, 10686, 13635, 11202, 6005, 13138, 7765, 12663, 7726, 11666, 14632, 11860, 13846, 11176, 6087, 7976, 9721, 12732, 15366, 11617, 7015, 10715, 13594, 11093, 14499, 6114, 12758, 13455, 11550, 6783, 7624, 12771, 11107, 14428, 5823, 10877, 13835, 7842, 10104, 12703, 15369, 4015, 7479, 12773, 14383, 11791, 7032, 6012, 9950, 13193, 13490, 11470, 7516, 13083, 7389, 12761, 11654, 14603, 6623, 13528, 11147, 10181, 5951, 7566, 12922, 7412, 10138, 13032, 11446, 14721, 11907, 7090, 9718, 14882, 13904, 7876, 13140, 7821, 10098, 13248, 11828, 6894, 11573, 7946, 14660, 13610, 10727, 7770, 13153, 10075, 12981, 12048, 7537, 3963, 7113, 10935, 11681, 14544, 6070, 9965, 10149, 13419, 11327, 6652, 7757, 14722, 14082, 10986, 7005, 10045, 13638, 11068, 10168, 7590, 13085, 4073, 8001, 10993, 14486, 11850, 14489, 13513, 11094, 6091, 4070, 9207, 7483, 11477, 14501, 11566, 6901, 13892, 11097, 13859, 7526, 13194, 11608, 11449, 7114, 10744, 13540, 11039, 14442, 6116, 13003, 13429, 11595, 14391, 4029, 10495, 14664, 6073, 11204, 13618, 7844, 9943, 13095, 15424, 11482, 7387, 12762, 11149, 11913, 7063, 5883, 12924, 13467, 11799, 7738, 12982, 7577, 12542, 11549, 14872, 6010, 10959, 13838, 10185, 13953, 7970, 7648, 9695, 13005, 14913, 11383, 7019, 10154, 13359, 10717, 13603, 7779, 12863, 7403, 13201, 11857, 7006, 8064, 14884, 13728, 11155, 6101, 7819, 13086, 7589, 9973, 13099, 11688, 15370, 3966, 6902, 14449, 5983, 7293, 10077, 12667, 10100, 13496, 11620, 7092, 7503, 14490, 13641, 10878, 14415, 13479, 10988, 10208, 5119, 7960, 12985, 4081, 7740, 11184, 14605, 11968, 14444, 10046, 13852, 4047, 7815, 12719, 7856, 11571, 14914, 11467, 7121, 13430, 11109, 9724, 7529, 12895, 11832, 14560, 11668, 7067, 10731, 13516, 10939, 14502, 6059, 12777, 10164, 7766, 11493, 14855, 11591, 7116, 14888, 13612, 10994, 7578, 9966, 13154, 11423, 11805, 7455, 13011, 11098, 11858, 14531, 6094, 12774, 13861, 11657, 7873, 4076, 9211, 11716, 14606, 5879, 10718, 6905, 13469, 10087, 13522, 15377, 7540, 13196, 11208, 11500, 7021, 10179, 14081, 10623, 13849, 7351, 13006, 7619, 13101, 11452, 14977, 3581, 13652, 11150, 6120, 7593, 12764, 7956, 10161, 13144, 15372, 12041, 7096, 13405, 11055, 13699, 7830, 13127, 9974, 13617, 11819, 6639, 7406, 14859, 13583, 11216, 14611, 6076, 13434, 9471, 13013, 7788, 4059, 7763, 11110, 14916, 14627, 7485, 10135, 12986, 13760, 11924, 7573, 13202, 7969, 14395, 11873, 6847, 13537, 11157, 10091, 5999, 13040, 7515, 13156, 7782, 11577, 14505, 11481, 14896, 10186, 14450, 6069, 7711, 9855, 13107, 7880, 11846, 14613, 12064, 7079, 14492, 13637, 10967, 7829, 13102, 11390, 7122, 11682, 7769, 12727, 10733, 11597, 14423, 6099, 13217, 10156, 11491, 15488, 4030, 7027, 11916, 14533, 5885, 11113, 6906, 13485, 9977, 13866, 11624, 7390, 12778, 10941, 14452, 11806, 6647, 13427, 11171, 13968, 7602, 12911, 4082, 9213, 11563, 14506, 12038, 7069, 13920, 13624, 7538, 7413, 10127, 12959, 11605, 11713, 7022, 13486, 10996, 13650, 7622, 13027, 13891, 11574, 6879, 4027, 11100, 13845, 10739, 14397, 6093, 13701, 7943, 10078, 13204, 15378, 4071, 7822, 14867, 13591, 10971, 8004, 10193, 12751, 13524, 11888, 7587, 13131, 7781, 14861, 11478, 14978, 6128, 13423, 11063, 9599, 6074, 7625, 12669, 7517, 11815, 14617, 14614, 9971, 13960, 11162, 13642, 7843, 12785, 7399, 11439, 14862, 11914, 7137, 14513, 13874, 11114, 6013, 13218, 7735, 13109, 11672, 14629, 11661, 7972, 11158, 14724, 6106, 13014, 7596, 10182, 13249, 11876, 15393, 11494, 7029, 14427, 13491, 10742, 7083, 10162, 13470, 12035, 7138, 7544, 13160, 11173, 14920, 11606, 15105, 13706, 10071, 7888, 4061, 7800, 9214, 12780, 11578, 14534, 11922, 7124, 13538, 13620, 11827, 7833, 12919, 11451, 7070, 11728, 6908, 13862, 10983, 13511, 7414, 13017, 10094, 11598, 14508, 4084, 7085, 13433, 11000, 14456, 5615, 13893, 7772, 10139, 12988, 11484, 11821, 7511, 14537, 14084, 11121, 7949, 12731, 13595, 11387, 7601, 13029, 4055, 10734, 11619, 14672, 6115, 13666, 9951, 13850, 8065, 7727, 11512, 14398, 6102, 10942, 10099, 13644, 11161, 13493, 7531, 13133, 7786, 14618, 11864, 7111, 10741, 13607, 11116, 6047, 13208, 7411, 12670, 7628, 11655, 14479, 15365, 13873, 11087, 6007, 7594, 9719, 13110, 12096, 15380, 11684, 7030, 14439, 13713, 11232, 14514, 6117, 13139, 13517, 11937, 6975, 7827, 13018, 10687, 14630, 14429, 13897, 7486, 10188, 12786, 15394, 4078, 7955, 13168, 11847, 14980, 11676, 7091, 9978, 13544, 11609, 7849, 13030, 7575, 12733, 11497, 14538, 11944, 6651, 13680, 10973, 10151, 7405, 12759, 7984, 10194, 12923, 12037, 14928, 11909, 7033, 13436, 14659, 13984, 7794, 10105, 13220, 11580, 7128, 11471, 7904, 14728, 13868, 11067, 7634, 12975, 10141, 11830, 7759, 4062, 6895, 11174, 11874, 14633, 6105, 13498, 10209, 13708, 11714, 7846, 15106, 13900, 11122, 7086, 9726, 13613, 11177, 14088, 8002, 13191, 4088, 11203, 11659, 14443, 13422, 10987, 5886, 7567, 13113, 7604, 11505, 14516, 11359, 13523, 10745, 13649, 7527, 12788, 15616, 11621, 7140, 11095, 13865, 11164, 14487, 6122, 13134, 13958, 12050, 14545, 7836, 10974, 14620, 6071, 11069, 13483, 7785, 9980, 13033, 15363, 11803, 7958, 13114, 14984, 11453, 7115, 6108, 13020, 13552, 11851, 7621, 12734, 7417, 13250, 11603, 14430, 14540, 13714, 10102, 13908, 7656, 7877, 10157, 13224, 11670, 14634, 11498, 7034, 10196, 14736, 13665, 7742, 12763, 7518, 13141, 11928, 6653, 11626, 7950, 14944, 13598, 11205, 8066, 13155, 7793, 10093, 12925, 11854, 15425, 3583, 7093, 11970, 14688, 6063, 10158, 9967, 13839, 11479, 7117, 7541, 14661, 13518, 11178, 14869, 13702, 11124, 10200, 7633, 13195, 4075, 7852, 10746, 14491, 11567, 14546, 13494, 13955, 4077, 7771, 11829, 14641, 12044, 7144, 13876, 10989, 13621, 7834, 12775, 11610, 11880, 7036, 11185, 14096, 11206, 14883, 6011, 12983, 13729, 7418, 11696, 14636, 11921, 14445, 13375, 10995, 7582, 9723, 13034, 15384, 11506, 7961, 13116, 11099, 11667, 14520, 6121, 13041, 13898, 11833, 7534, 7608, 13142, 11628, 14870, 6118, 11180, 13525, 10163, 13614, 15396, 8012, 13145, 14873, 11454, 7094, 10142, 13656, 11070, 13497, 7295, 12792, 7875, 13087, 12049, 14451, 7650, 13643, 11151, 6077, 7971, 12543, 7741, 10101, 13252, 11861, 15426, 11822, 7007, 14503, 13530, 7595, 13197, 10183, 13961, 12072, 6903, 8008, 14561, 13847, 11111, 14662, 13597, 10210, 13007, 7858, 4083, 7845, 10879, 14642, 11720, 15108, 9919, 13431, 11938, 7539, 12765, 7947, 14493, 11575, 7152, 13905, 11128, 10108, 7767, 13203, 7626, 11612, 14992, 11485, 14665, 13736, 10719, 14446, 6014, 10047, 7420, 11662, 14453, 11508, 6654, 14548, 13668, 11186, 7579, 12926, 11972, 11917, 7796, 13036, 10990, 12042, 14507, 6129, 13232, 14016, 11866, 15374, 4085, 11633, 15112, 6095, 11209, 7123, 13619, 10166, 13515, 15400, 7636, 13157, 10748, 11853, 7097, 13880, 11101, 13716, 8072, 12779, 7973, 12987, 11686, 14666, 12097, 13541, 13639, 7533, 7882, 10187, 13042, 15489, 11579, 6907, 13471, 10997, 13853, 8016, 13146, 13906, 11622, 7118, 7597, 14562, 13705, 11210, 14885, 6124, 13764, 7787, 10212, 12766, 15379, 3839, 7857, 14874, 14723, 7962, 10169, 13256, 13548, 11940, 7359, 12671, 7546, 14644, 11483, 14552, 13500, 11159, 9979, 5629, 7773, 13198, 7664, 11834, 14752, 11673, 14607, 10106, 14615, 14089, 7974, 13103, 7835, 12066, 14494, 11744, 7098, 14673, 13867, 11115, 7603, 13264, 11875, 14886, 11499, 7878, 11102, 12160, 15008, 6107, 13158, 10197, 11915, 15428, 11685, 7023, 14454, 13972, 10998, 7125, 10079, 13921, 11389, 7649, 13205, 11188, 14668, 11599, 14915, 13625, 13529, 7850, 4086, 9215, 12056, 14876, 11836, 7126, 13894, 14112, 15408, 8068, 13015, 11911, 11952, 7071, 13438, 11217, 13730, 7977, 12781, 13645, 11625, 14725, 4089, 13539, 11163, 14509, 6078, 13964, 7783, 10155, 13161, 15373, 11862, 7591, 14457, 13672, 11212, 7890, 12989, 13854, 11674, 7487, 13219, 7823, 14889, 11551, 14535, 6130, 13611, 10190, 14086, 7964, 7905, 11969, 15120, 14515, 9975, 13653, 11001, 13761, 7623, 13044, 7419, 14564, 11636, 7139, 14674, 13622, 11117, 6075, 13148, 7884, 12787, 7545, 11447, 14648, 11715, 15872, 15040, 6119, 8032, 10216, 13019, 11689, 15490, 12052, 6909, 14726, 13936, 11192, 14510, 13526, 11926, 7100, 7640, 13111, 10735, 14890, 11502, 14917, 13863, 10172, 15382, 3967, 8005, 13210, 11884, 14729, 11859, 7031, 13487, 13962, 11581, 7581, 13162, 11669, 14619, 12065, 7129, 13720, 10943, 13709, 7864, 13206, 10095, 11611, 14458, 11878, 7141, 13924, 14784, 13542, 7774, 10165, 12790, 11807, 11976, 7957, 14689, 14083, 11175, 7606, 13221, 13654, 11925, 7542, 4090, 11218, 11865, 14897, 6109, 13626, 10195, 13970, 15432, 7789, 14539, 13875, 11123, 9981, 13499, 11002, 13776, 7992, 13031, 7831, 14399, 11486, 14676, 13646, 10743, 6132, 7391, 13048, 7860, 11698, 14730, 15385, 13532, 11165, 13869, 8080, 13169, 11634, 15617, 11509, 7130, 14863, 13435, 11118, 14918, 6103, 12782, 13667, 11718, 14892, 7627, 10975, 14517, 14631, 13560, 7795, 10189, 12990, 15395, 12039, 7889, 13209, 14621, 11918, 7087, 13912, 12100, 8003, 12789, 7652, 13164, 11683, 14568, 11877, 14460, 13703, 10224, 7978, 7598, 10170, 13135, 11721, 14541, 11613, 7035, 14144, 14518, 13732, 7985, 13280, 11939, 7142, 11495, 7739, 14979, 13985, 11233, 7422, 12735, 10109, 11831, 15492, 4087, 6910, 12068, 14898, 6126, 13895, 10202, 13724, 11692, 7609, 14622, 13657, 11125, 14921, 13545, 11179, 13992, 7853, 13021, 4092, 11234, 11640, 14635, 14085, 13957, 7908, 7790, 11984, 14690, 11896, 13628, 11220, 13519, 7881, 13115, 15381, 11929, 6655, 11166, 13878, 11004, 14547, 6110, 13222, 13922, 7629, 11510, 14737, 15440, 14521, 13762, 11181, 7548, 9711, 13170, 15397, 11868, 7837, 13225, 14732, 11607, 14680, 6136, 13251, 13707, 12045, 8010, 8096, 13035, 11697, 14922, 14981, 13553, 10211, 13407, 15618, 7635, 12793, 12161, 14929, 11823, 7132, 10198, 14871, 13669, 7801, 13143, 7896, 13212, 11627, 14576, 11882, 7951, 14098, 11207, 7543, 13022, 7988, 10143, 13117, 11507, 15386, 11724, 7145, 14542, 13851, 10103, 13501, 11690, 7095, 7798, 14431, 13899, 11126, 14663, 13651, 10213, 8070, 4091, 7851, 11071, 14900, 11923, 15136, 13718, 13546, 11582, 7535, 14738, 12051, 7146, 13976, 11187, 13674, 7612, 13253, 11945, 11671, 14692, 13902, 10747, 14643, 5631, 14018, 7980, 11501, 14637, 12080, 14753, 13527, 11129, 7638, 13226, 15496, 11890, 8017, 13172, 11224, 12000, 14549, 6123, 12794, 13615, 11730, 15402, 7415, 11855, 14904, 6125, 10991, 13877, 10201, 14092, 15456, 7838, 13037, 15168, 11942, 7037, 13658, 11182, 13928, 8067, 13233, 7605, 13254, 12098, 14924, 15371, 13744, 13969, 7892, 7859, 9982, 13043, 11663, 15873, 11700, 7119, 14522, 13554, 8006, 13147, 13715, 11623, 7038, 7959, 14982, 13881, 11236, 14740, 13676, 7641, 10218, 13228, 15427, 4079, 7797, 14563, 11932, 15232, 10167, 13502, 11881, 7654, 13118, 7906, 14930, 12054, 14754, 14097, 11211, 10204, 7986, 13199, 7519, 11717, 14638, 11513, 14985, 13909, 15107, 13870, 7847, 11752, 14696, 11973, 7153, 14875, 14120, 11130, 7610, 13159, 11838, 11614, 8018, 10749, 12046, 14447, 6131, 12927, 13768, 12162, 15388, 11889, 14667, 13986, 11189, 7099, 10159, 13623, 15504, 7883, 13176, 11213, 11637, 14550, 13660, 13533, 7630, 8074, 12767, 11729, 14645, 11948, 13710, 13556, 15398, 8033, 13234, 15620, 11867, 7148, 14020, 11240, 13965, 7802, 13038, 14090, 11930, 14524, 7965, 13914, 11132, 14785, 6133, 13681, 7862, 10107, 13257, 15409, 11514, 8073, 14553, 14744, 7743, 12796, 13901, 11678, 7651, 13149, 7920, 14945, 12057, 14932, 13734, 10217, 14145, 7549, 7879, 11630, 14887, 11704, 14986, 10214, 14565, 13627, 7975, 13045, 7637, 14495, 12108, 7154, 14756, 13670, 11190, 8128, 13258, 7599, 11391, 14646, 11971, 15429, 11746, 14877, 5887, 10173, 12067, 15624, 11837, 7101, 15109, 13988, 11103, 14946, 13531, 11691, 8009, 13207, 10999, 14993, 12104, 14669, 13882, 13721, 15401, 4031, 11954, 14455, 11941, 7127, 14114, 13792, 15434, 7854, 13163, 11635, 12043, 7102, 13923, 11248, 13547, 7658, 13150, 14208, 11863, 14936, 11722, 13963, 14675, 13733, 8020, 10110, 13046, 15520, 11516, 7912, 14554, 13437, 10750, 7865, 13236, 13647, 11675, 8082, 7804, 14704, 11892, 14988, 6134, 14104, 10225, 13884, 15367, 7644, 14566, 14727, 10191, 13959, 11219, 14000, 7547, 13265, 8036, 14649, 11732, 14786, 13673, 11193, 6137, 7963, 13211, 7885, 12168, 14878, 12069, 15874, 14670, 13910, 7660, 13260, 11629, 15412, 11978, 7131, 14569, 13722, 11003, 14891, 13599, 12112, 15110, 8076, 11214, 14511, 11693, 14459, 14017, 10220, 15491, 11883, 7607, 13049, 14994, 11953, 7156, 13684, 12058, 7987, 13165, 11455, 14948, 11642, 14677, 13495, 13763, 7893, 9725, 11869, 15113, 11760, 7143, 13737, 14556, 14100, 7982, 13240, 12070, 11931, 7421, 14650, 13974, 11194, 7791, 12783, 13550, 11699, 15441, 4094, 11974, 14760, 6015, 13932, 10203, 13907, 15404, 8069, 14731, 13629, 11119, 13717, 11221, 14113, 7642, 12991, 7886, 15009, 11745, 14919, 13659, 13926, 7657, 8024, 11946, 14691, 15632, 13855, 11222, 14024, 7861, 13223, 15430, 12164, 7160, 14623, 13973, 11167, 14519, 6138, 13266, 13913, 8097, 12073, 14570, 15387, 14461, 14893, 7981, 10174, 13171, 15552, 11879, 8011, 13050, 14996, 11687, 14952, 13534, 11986, 7775, 7613, 12791, 11583, 14678, 11919, 14652, 13746, 10226, 15493, 7891, 13213, 12060, 14577, 12001, 6911, 13682, 15114, 13557, 8048, 13166, 11719, 14899, 11515, 7868, 13766, 11235, 7668, 13023, 10171, 11980, 15410, 11641, 7133, 14681, 14087, 10215, 13966, 12128, 7550, 14788, 14148, 11005, 14733, 13731, 13925, 7898, 4095, 11196, 11736, 14739, 13769, 13661, 15448, 7966, 14543, 12101, 13987, 11127, 13543, 7979, 13281, 15876, 11677, 15010, 13879, 11225, 14894, 6135, 14116, 7643, 11960, 15121, 15436, 14768, 13740, 11237, 8088, 13173, 15375, 11870, 8007, 13227, 14693, 12053, 14523, 6140, 13282, 13688, 11702, 15498, 8034, 11638, 14572, 15000, 14032, 10205, 13944, 15648, 7611, 13268, 14960, 11885, 7147, 14923, 13977, 7666, 13214, 7907, 13052, 12088, 15116, 11927, 15416, 13558, 7839, 7994, 10228, 13229, 11487, 15458, 11956, 7134, 15041, 13916, 13655, 12176, 7149, 8081, 14462, 14093, 11226, 14578, 13745, 10199, 15399, 4063, 7866, 14901, 11723, 14734, 14209, 13871, 11891, 7989, 14682, 11985, 14792, 13675, 11183, 13930, 7639, 13255, 12099, 11748, 14694, 13555, 14741, 13772, 7799, 12074, 14639, 11694, 14905, 13738, 11131, 7909, 13174, 15880, 12081, 8100, 11238, 11835, 14580, 6139, 13119, 13971, 11518, 15494, 15433, 14931, 13630, 11006, 10222, 14099, 15619, 7631, 13235, 14525, 11705, 14902, 13993, 13719, 7894, 8013, 12795, 11949, 15012, 15505, 13549, 14128, 15390, 7665, 13177, 12004, 15444, 11886, 7103, 14697, 13938, 8040, 13272, 14048, 11977, 15042, 7407, 13778, 10751, 14925, 13903, 8084, 10206, 13039, 15680, 11725, 7914, 14551, 15122, 13990, 11644, 8021, 13230, 7653, 14983, 11933, 14684, 14146, 10232, 7855, 7900, 12106, 14755, 12192, 14742, 13711, 14800, 13748, 7990, 15016, 11731, 7155, 15137, 13671, 11228, 8104, 13284, 11897, 11992, 15405, 12047, 14698, 6127, 13980, 11639, 15500, 12084, 14926, 13929, 11241, 14745, 14102, 15622, 7928, 13259, 11191, 11894, 14906, 13765, 13561, 15457, 8014, 12166, 15124, 11947, 13800, 14021, 15888, 7806, 13178, 15442, 11631, 7157, 13886, 11242, 13662, 8129, 12797, 14094, 11708, 14933, 15411, 14210, 14908, 13937, 7897, 9727, 13237, 15522, 12076, 8071, 14555, 14647, 7672, 13261, 13685, 11734, 7993, 8026, 15044, 12113, 14934, 13777, 10219, 13996, 15625, 7910, 14937, 11511, 14987, 10221, 14757, 13915, 7655, 13288, 8098, 15128, 11934, 15138, 13978, 11133, 7863, 13180, 7921, 12163, 14947, 11701, 15383, 14938, 13562, 11988, 15508, 11955, 7039, 14746, 13726, 11215, 14567, 14105, 12102, 7583, 11134, 15024, 12055, 14989, 13678, 13752, 15464, 11737, 14584, 11893, 7150, 14156, 15406, 8022, 13238, 11750, 12002, 14705, 13439, 14019, 8035, 13794, 12082, 14526, 11615, 14115, 14700, 13885, 8083, 13151, 15904, 11943, 7805, 14990, 13739, 11249, 7646, 13047, 14152, 11706, 15431, 8130, 12114, 14995, 6079, 14002, 10227, 13989, 15497, 7996, 14671, 14816, 13683, 11195, 14091, 8078, 13296, 7867, 14651, 11979, 14557, 13911, 13770, 7916, 7659, 11726, 14706, 12170, 15621, 14949, 13564, 8041, 12798, 15744, 12129, 7158, 14758, 13723, 11244, 14761, 13940, 7614, 11898, 14787, 15413, 14950, 12061, 14879, 10229, 15634, 11958, 7887, 13267, 14571, 12169, 14748, 13780, 11839, 8075, 13241, 11747, 14679, 12016, 14708, 14216, 14117, 15521, 11645, 15111, 11975, 7161, 13677, 14653, 14026, 8112, 13051, 12071, 11733, 8025, 14160, 11250, 8038, 13262, 13741, 12224, 15875, 11695, 14558, 13931, 9983, 14001, 15435, 7913, 14762, 14106, 11197, 13503, 13690, 7661, 7922, 14789, 12105, 14573, 13917, 13808, 15460, 8085, 14895, 15506, 14118, 11223, 13979, 7967, 13242, 15628, 11950, 15169, 13747, 11198, 15140, 6142, 14022, 7803, 11754, 15048, 15418, 15170, 14997, 8136, 13167, 15389, 12116, 8019, 13269, 15144, 12008, 15115, 13793, 11961, 15553, 7899, 12178, 14953, 11900, 14940, 13994, 10230, 15877, 7645, 13270, 14769, 11740, 7162, 15056, 14212, 8044, 13215, 11643, 15152, 12132, 15437, 14121, 7869, 10233, 12059, 15512, 11981, 7135, 15172, 13927, 13735, 11756, 8077, 14683, 14034, 11227, 15233, 13631, 13967, 15472, 4093, 12172, 14579, 14108, 14049, 15633, 7983, 14998, 11703, 13767, 11252, 13563, 7669, 13283, 15936, 12083, 14790, 14028, 14654, 13689, 8099, 11989, 15011, 15446, 14954, 14176, 11239, 8132, 13053, 15417, 12078, 8028, 15234, 11517, 15117, 6143, 13244, 13784, 11887, 15650, 15556, 14712, 14764, 10111, 14149, 15882, 7870, 13175, 15001, 12165, 15072, 13725, 8092, 7924, 13273, 11738, 14903, 11982, 15443, 14008, 15528, 7662, 13285, 11753, 15414, 12120, 7164, 15176, 13918, 14101, 11957, 14961, 7911, 13750, 11256, 14574, 13686, 10234, 15495, 12193, 8049, 14695, 14793, 13933, 12077, 7995, 14735, 12107, 15123, 14136, 13975, 8037, 11871, 11709, 14927, 13535, 15014, 14004, 8089, 14770, 11987, 15013, 14224, 11007, 7901, 13274, 15626, 12144, 15878, 11964, 14685, 6111, 13771, 11764, 15636, 15438, 14581, 13939, 11229, 14033, 15524, 7674, 13231, 14794, 11646, 15002, 14147, 13796, 15449, 8102, 11994, 14956, 15889, 14122, 13742, 15499, 7615, 13179, 15649, 12062, 7151, 14699, 14129, 8144, 13286, 13883, 12075, 14463, 15403, 13566, 14527, 7991, 10231, 13054, 15461, 11739, 8042, 15118, 14743, 13753, 12184, 7667, 8086, 14772, 12103, 14962, 13997, 10236, 15554, 8105, 14907, 12130, 14801, 14052, 15017, 13934, 8015, 14582, 11707, 15043, 14025, 11243, 7915, 12799, 11762, 12003, 15682, 14686, 13773, 11935, 15420, 12090, 14935, 13692, 11230, 15004, 13981, 15884, 7673, 11245, 12177, 15126, 14154, 14240, 15501, 15656, 14796, 11962, 13779, 15459, 8056, 13276, 15536, 12085, 14585, 13945, 14040, 7902, 14095, 11735, 15018, 16000, 13687, 14909, 14132, 8133, 13289, 15507, 11895, 8090, 14747, 15139, 7670, 13239, 13942, 12005, 15452, 8050, 12196, 15125, 14214, 10235, 13995, 15640, 8027, 15045, 14701, 14776, 13679, 7917, 13290, 8101, 14964, 11727, 15025, 13756, 7997, 8120, 11990, 14710, 12109, 15560, 14759, 14124, 15892, 11761, 7159, 14802, 13782, 11199, 15129, 14161, 12136, 15466, 14586, 11503, 14707, 13559, 15510, 12180, 14817, 12010, 14910, 13982, 15684, 7895, 13181, 12117, 11749, 14749, 14211, 13749, 15445, 11951, 14939, 11996, 14036, 14702, 14003, 8137, 13263, 15881, 12086, 7647, 14150, 11251, 8106, 13182, 14103, 12200, 15623, 15391, 14804, 13785, 10223, 13941, 15906, 7925, 14991, 15236, 13798, 14050, 8029, 8052, 15141, 12024, 14951, 14130, 13663, 15502, 8160, 15020, 12110, 15745, 15046, 13991, 7998, 13297, 15523, 11902, 14765, 13754, 11253, 15130, 14162, 7676, 12225, 14588, 15450, 14709, 14941, 15568, 11993, 8116, 13243, 15184, 12167, 15026, 14027, 11768, 7918, 12089, 15049, 12122, 14968, 13774, 14218, 15652, 14818, 12006, 7163, 15142, 14177, 8039, 13292, 11751, 12194, 15468, 13946, 8131, 14109, 11959, 15419, 12017, 14763, 14006, 14217, 15513, 8113, 15240, 13887, 11135, 13795, 14064, 15905, 7926, 11679, 14750, 13693, 14023, 15627, 7423, 14559, 15462, 14119, 11246, 13781, 8087, 13298, 15890, 12118, 14999, 14272, 15028, 13743, 8043, 12131, 15171, 15664, 14955, 14808, 8138, 13245, 15473, 12179, 7807, 14791, 11901, 15132, 14153, 11742, 15525, 15937, 15145, 12226, 15050, 10175, 15584, 8108, 13271, 15057, 12092, 15173, 13998, 7929, 13246, 12174, 15052, 11963, 15422, 13802, 15638, 12012, 15688, 11755, 7165, 15200, 14164, 14056, 12137, 8079, 14009, 11254, 15146, 14226, 13948, 15509, 11710, 14942, 13788, 15530, 8030, 15248, 11983, 13691, 14180, 8145, 15439, 12171, 15058, 14107, 15032, 14029, 7551, 14713, 15760, 14771, 13804, 11257, 7923, 13275, 15629, 12208, 15896, 12121, 15153, 6141, 14220, 12134, 15465, 16128, 14655, 14957, 13751, 15516, 8134, 13300, 15148, 12009, 14820, 14131, 15681, 8114, 11757, 14766, 12018, 15908, 14037, 15474, 8023, 13287, 15635, 12181, 7166, 15174, 14126, 13565, 12063, 15003, 15555, 13935, 14824, 10238, 15447, 11899, 8046, 14575, 14714, 14213, 12232, 8091, 14795, 12115, 14958, 13786, 14030, 15746, 11995, 14963, 13801, 14773, 14168, 7903, 14716, 11741, 14005, 11258, 8051, 13304, 15537, 12140, 15944, 15154, 14241, 11965, 15514, 15630, 14797, 14125, 11231, 14155, 15879, 7671, 14832, 12173, 15005, 13919, 13757, 15526, 15653, 15015, 15476, 14035, 15415, 8140, 13055, 15557, 12079, 15060, 14192, 7930, 14012, 11765, 15177, 15641, 13812, 14965, 8103, 13277, 15920, 12195, 8146, 14687, 14803, 13694, 12228, 15696, 8057, 12124, 14774, 14042, 10239, 15451, 8093, 15073, 14587, 14798, 14110, 8161, 14778, 11966, 14777, 14123, 7678, 12188, 12020, 16002, 14805, 13787, 15885, 11758, 14583, 14232, 11260, 15019, 14151, 15532, 15562, 12007, 15178, 14178, 15748, 15463, 15074, 12145, 13755, 15480, 7932, 13291, 15644, 12091, 15235, 13810, 14051, 15938, 12133, 15006, 15654, 13983, 15119, 14138, 8054, 13278, 15421, 12185, 8109, 15185, 8148, 13293, 14225, 11997, 15891, 15529, 15156, 10207, 14010, 15912, 8045, 15064, 15264, 14133, 8110, 7919, 15127, 11770, 14703, 13783, 15712, 8152, 15237, 12198, 15569, 14966, 13943, 15657, 11711, 15021, 14053, 11247, 15180, 14244, 12240, 15540, 14969, 15047, 15454, 12087, 14589, 12138, 15027, 13775, 15637, 7675, 11763, 12182, 15160, 14038, 14157, 15511, 15238, 12201, 15022, 13809, 8115, 13247, 16004, 12111, 15558, 14184, 8094, 13551, 12011, 15752, 15469, 15076, 14228, 14058, 15683, 8053, 15186, 14711, 14165, 13797, 15894, 8135, 11769, 14780, 13999, 14044, 15642, 8162, 14806, 15503, 14819, 14134, 7871, 13299, 15883, 12152, 14751, 14248, 14821, 8060, 11998, 15241, 15538, 15131, 14809, 15576, 12229, 7999, 14970, 12186, 15080, 14072, 11766, 15952, 15188, 12146, 15296, 14158, 15658, 15201, 12123, 15029, 13950, 8118, 13301, 12013, 12197, 15467, 14273, 16130, 12093, 15686, 12216, 15133, 14041, 14215, 15561, 8139, 13816, 11255, 14137, 14170, 15940, 15907, 15242, 14054, 15588, 8164, 15051, 15477, 13799, 14242, 8121, 15666, 11991, 15143, 14007, 14810, 14065, 7931, 14972, 15515, 15030, 14590, 8058, 13183, 15886, 12233, 16001, 11743, 15053, 13727, 12202, 15407, 15651, 14911, 15249, 15776, 8149, 13294, 15134, 12021, 15147, 14166, 8031, 12125, 14715, 12148, 15544, 14179, 15689, 15527, 12256, 7167, 15033, 14227, 13949, 12094, 15900, 13790, 14767, 14274, 15478, 11772, 14943, 14140, 15564, 8107, 14825, 12212, 14222, 14011, 15660, 12014, 15202, 14060, 15059, 13803, 8142, 14822, 15909, 14185, 11259, 7927, 13302, 15517, 12135, 15570, 15244, 13758, 12227, 16129, 15897, 15054, 15149, 14031, 15700, 8168, 14812, 12209, 15192, 14219, 15453, 15747, 15175, 12022, 15665, 15631, 8124, 13305, 15482, 11519, 15061, 14256, 14169, 12183, 15034, 15808, 14182, 15250, 15585, 12139, 8047, 15088, 15204, 14057, 12234, 8117, 11903, 15155, 13805, 14066, 15685, 15150, 14775, 14229, 8147, 15265, 12204, 14111, 7933, 15533, 12025, 15914, 14826, 13947, 15475, 16016, 14959, 14280, 11261, 14163, 15968, 15672, 12175, 15007, 14043, 15534, 15698, 15075, 15939, 13789, 15893, 8141, 13306, 15749, 12126, 15252, 14188, 15639, 12241, 14799, 15572, 14013, 15179, 8176, 13279, 15471, 11647, 8122, 14717, 14221, 12019, 16008, 15690, 14833, 10237, 15922, 8061, 15266, 15157, 14127, 8154, 15062, 12230, 15297, 13813, 15539, 12210, 15518, 15208, 14243, 15754, 12119, 14276, 11262, 14828, 14172, 15586, 15668, 14967, 15910, 15559, 15065, 12142, 14014, 15481, 7663, 15941, 12187, 15036, 14236, 14068, 16132, 14779, 15643, 15077, 13806, 8163, 13308, 15714, 11999, 15898, 8150, 14055, 12147, 15692, 15541, 15181, 14193, 15655, 8095, 15256, 14718, 14139, 15921, 8055, 11767, 15158, 14181, 15761, 8165, 15187, 15565, 15066, 14233, 15945, 12236, 14834, 14045, 15216, 12026, 15592, 15078, 14781, 15728, 12199, 14807, 12242, 14971, 13818, 15484, 16032, 12153, 15268, 14246, 15916, 15023, 12189, 13759, 8153, 13295, 15546, 12257, 15756, 14288, 15948, 11774, 15661, 16136, 15239, 14135, 14186, 15470, 7934, 15161, 13811, 14230, 15571, 15697, 14836, 14249, 15913, 8170, 15182, 16006, 14159, 8119, 15531, 12028, 15081, 14059, 15162, 8156, 15068, 15600, 14782, 15298, 15762, 12150, 15956, 12205, 15272, 13817, 12244, 15713, 14811, 15189, 15646, 15203, 12141, 14973, 14200, 8111, 12206, 12015, 15887, 14046, 15566, 15750, 12248, 15243, 14277, 14234, 15542, 16003, 13814, 14194, 15924, 15669, 14823, 14171, 16144, 8059, 15031, 15777, 14061, 14245, 15423, 11771, 15082, 14141, 15164, 14264, 8169, 15089, 15946, 15190, 8166, 13303, 15573, 12211, 15662, 15193, 12190, 15704, 15545, 14840, 15135, 15691, 8125, 14591, 12149, 15300, 14039, 15578, 15245, 12231, 16009, 15895, 15645, 12258, 15055, 14281, 13791, 11967, 15479, 14250, 14813, 15953, 12156, 15251, 14069, 15784, 8062, 12095, 14173, 14196, 15716, 14974, 15084, 14304, 8177, 15280, 16064, 14142, 8143, 15667, 12214, 15563, 15205, 13820, 15928, 15764, 14827, 15035, 14260, 15589, 15687, 12235, 15090, 14062, 15519, 15901, 15194, 15954, 15753, 8172, 13307, 15812, 12260, 14814, 14183, 12217, 15304, 15596, 14275, 14719, 15548, 12027, 7677, 15246, 14257, 12154, 16137, 15151, 14070, 15915, 15312, 13567, 8155, 15206, 12245, 14231, 16020, 12127, 15969, 15253, 14187, 15673, 15577, 14282, 11263, 13951, 15942, 16160, 15063, 15486, 15778, 14829, 15693, 14252, 15587, 8126, 16012, 12203, 15209, 14073, 15720, 15037, 15902, 15267, 8178, 13309, 15659, 12238, 16134, 14223, 12023, 15701, 15809, 15092, 15670, 8123, 15196, 14835, 14174, 8167, 12264, 15067, 14289, 15984, 15574, 15159, 13695, 15911, 12220, 14067, 15258, 15535, 16010, 15210, 15768, 15757, 15254, 12143, 14278, 15972, 15590, 12213, 14838, 14258, 16131, 15269, 15702, 14167, 8157, 13310, 15674, 12243, 16018, 15923, 12029, 15547, 15824, 15079, 14190, 15694, 8180, 15096, 14235, 15580, 15917, 15217, 15483, 8151, 14830, 15715, 14047, 15608, 12237, 15038, 14195, 15257, 15960, 14837, 15212, 15751, 12272, 12218, 15183, 13815, 16192, 15780, 15328, 16033, 14783, 12157, 14284, 8174, 15943, 12250, 15772, 14074, 15705, 15593, 16040, 15069, 14247, 14290, 16133, 16005, 14201, 15676, 15567, 15163, 14237, 15926, 8158, 15270, 15970, 14305, 15810, 11759, 15218, 13822, 15273, 8184, 15299, 15755, 15083, 15601, 12259, 15455, 14841, 12246, 15717, 15191, 15260, 16146, 15070, 12191, 15165, 14076, 15899, 12151, 15549, 15947, 15699, 12261, 14198, 14253, 15766, 15594, 14292, 16024, 15722, 15301, 14189, 15950, 7679, 16066, 14254, 14063, 15575, 15274, 15220, 14296, 8171, 14842, 15663, 8173, 15925, 12249, 16140, 15085, 15706, 15976, 15281, 15302, 15792, 16017, 12030, 15091, 13819, 15602, 15195, 15763, 15929, 15724, 12266, 15276, 14259, 12215, 15550, 14238, 15166, 16145, 12252, 15247, 14197, 15957, 15918, 14279, 16168, 15207, 14306, 8179, 14975, 15816, 14015, 16034, 12207, 15671, 15224, 14204, 15708, 15581, 14815, 14143, 15758, 15604, 15282, 16068, 16013, 15086, 16138, 15962, 8181, 15729, 12155, 15305, 14262, 14844, 15949, 15197, 15782, 12265, 16193, 14283, 12262, 15675, 15093, 15718, 15306, 14308, 7935, 12221, 14265, 16036, 15579, 15255, 14075, 15930, 15769, 14202, 16162, 15840, 15211, 15971, 15595, 15198, 16256, 14293, 16011, 15781, 12158, 15094, 14175, 15485, 15284, 15695, 8182, 13311, 16152, 12273, 15932, 12239, 16007, 16048, 15313, 15721, 8185, 15259, 14251, 15958, 15308, 15770, 15647, 14286, 16065, 12268, 14071, 15097, 15732, 15213, 15543, 15811, 11773, 14312, 15785, 16148, 15288, 16022, 14831, 15598, 14268, 8063, 15980, 12251, 15955, 15677, 15765, 16161, 15039, 14191, 15707, 15974, 14261, 15903, 16072, 15271, 16021, 8186, 15314, 15961, 14291, 12222, 15219, 14077, 15098, 15582, 14839, 15794, 12274, 15261, 15730, 15605, 15214, 15814, 15071, 12219, 14285, 16135, 12263, 16014, 16196, 15779, 15973, 14320, 14266, 15817, 15709, 16035, 15591, 15329, 14205, 15927, 8183, 16164, 14298, 15788, 15221, 15275, 8188, 15330, 15736, 16080, 12253, 15992, 15316, 16025, 15262, 15100, 15606, 12276, 15277, 13807, 15964, 15703, 16141, 15793, 12247, 14307, 16257, 15919, 14294, 15723, 15978, 15303, 14239, 15603, 15820, 14199, 15786, 15222, 14309, 8187, 15167, 16019, 15678, 12270, 16147, 15283, 16041, 15767, 14843, 15597, 16176, 15225, 15986, 15320, 16096, 15826, 15951, 12254, 15087, 14297, 16038, 15278, 16194, 12280, 14078, 15759, 15796, 15719, 15332, 14314, 8175, 16028, 14263, 15977, 16150, 15307, 14300, 15813, 15609, 15848, 16069, 15226, 15934, 15710, 14845, 16142, 16258, 15985, 11775, 15285, 14255, 15309, 15733, 15825, 12267, 16044, 12269, 15963, 15336, 16026, 15228, 14203, 15610, 15774, 16153, 14313, 15726, 15800, 14310, 16204, 15286, 15487, 16067, 15842, 14269, 16163, 15933, 15199, 15787, 15095, 16200, 8127, 16050, 12275, 16037, 15731, 16139, 15344, 15959, 15818, 14206, 15612, 14846, 15771, 15988, 14321, 12277, 14287, 15315, 15828, 15289, 16264, 16165, 15725, 16074, 15099, 16208, 15310, 15789, 14316, 15979, 12031, 16049, 16154, 15551, 15738, 13821, 15965, 15856, 16166, 16027, 15290, 15795, 8190, 16070, 14299, 15215, 15317, 15841, 16042, 12278, 15318, 16260, 15263, 16169, 12281, 14270, 15975, 15783, 16082, 15679, 16015, 14322, 16156, 16097, 15815, 15611, 15331, 14267, 16076, 15737, 14311, 16224, 15101, 8191, 15292, 15832, 12159, 16197, 15223, 15773, 15321, 16056, 15333, 15966, 16149, 15798, 15734, 12282, 14301, 15981, 16184, 16023, 14324, 15583, 16052, 16272, 15322, 14295, 8159, 15819, 15987, 16081, 15279, 16195, 15844, 16170, 15790, 15227, 16177, 15334, 15931, 15614, 12279, 15102, 14318, 15801, 16045, 12284, 16100, 15982, 16073, 14847, 14302, 15821, 15740, 16029, 14328, 16202, 16288, 15827, 15324, 15993, 16088, 16143, 15735, 16180, 15337, 15287, 15990, 16262, 12283, 16043, 15727, 15338, 15804, 13823, 16172, 15830, 16209, 14315, 15607, 14317, 16030, 15229, 16259, 15797, 16084, 16051, 15311, 16198, 15230, 16151, 15833, 12271, 15989, 15846, 16098, 16178, 15711, 16039, 15345, 15802, 16210, 14323, 15291, 16075, 15822, 16266, 16225, 15340, 15994, 16157, 14325, 16054, 16265, 15935, 15843, 16112, 15741, 16071, 16167, 15829, 15346, 16320, 15791, 14079, 15293, 16201, 12223, 15319, 16046, 15294, 15850, 16212, 16104, 16057, 16274, 15996, 14326, 15836, 15739, 16228, 14329, 16155, 16077, 15852, 15323, 8189, 16268, 15799, 15348, 16179, 16085, 15335, 16174, 15613, 15983, 12286, 14207, 16261, 15834, 16078, 15849, 16216, 16053, 15352, 14330, 16289, 16173, 16203, 15967, 15805, 16083, 15103, 16240, 16060, 15860, 15325, 15742, 16090, 12287, 16158, 16171, 14327, 15835, 16280, 16199, 14332, 16226, 15803, 15339, 15858, 16099, 16031, 16186, 15326, 15341, 16273, 12255, 16058, 16181, 15831, 15991, 16101, 16292, 14331, 15823, 16086, 16205, 15857, 15295, 16232, 15599, 16276, 16106, 16213, 15845, 16047, 16092, 16182, 15347, 16296, 14319, 16120, 16206, 15998, 15349, 16321, 16089, 16263, 15864, 16185, 16218, 16102, 15847, 16290, 16055, 16113, 15231, 15775, 15342, 16214, 16227, 16275, 15997, 15838, 16322, 14271, 16188, 16270, 16059, 16108, 15851, 16233, 15350, 15806, 16079, 16267, 15353, 16304, 16217, 16230, 16105, 15853, 16114, 16277, 16159, 14334, 15995, 16328, 16211, 16091, 15837, 15354, 16236, 16061, 15327, 16269, 12285, 16175, 15861, 16291, 16324, 16220, 14335, 16062, 16284, 16116, 15854, 15356, 16103, 16241, 16187, 16229, 16281, 16093, 14303, 15866, 16294, 15807, 15343, 16336, 16183, 16234, 15859, 16278, 16297, 16207, 16107, 15865, 16248, 16094, 16325, 16282, 15862, 16242, 16219, 16109, 16293, 16189, 16312, 15351, 16087, 16329, 15839, 16298, 16117, 16221, 16244, 16352, 16190, 15868, 16308, 16110, 15355, 16231, 16323, 16305, 16118, 15615, 16279, 16235, 16330, 15999, 16300, 16121, 15357, 16271, 16222, 16337, 15743, 16115, 14333, 16326, 16306, 16215, 15358, 16238, 16283, 16095, 16243, 15863, 16332, 16122, 16295, 16338, 16249, 16285, 16353, 15870, 16124, 16246, 16301, 16340, 16237, 16302, 16111, 16344, 15867, 16307, 16286, 16245, 16327, 16354, 16063, 16252, 16191, 16310, 16331, 16356, 16313, 16123, 16250, 16341, 16223, 15359, 16299, 16334, 16119, 16360, 16316, 16239, 16309, 16339, 16125, 16333, 16368, 16314, 16253, 16346, 15855, 16355, 16342, 16287, 16247, 16357, 16345, 16126, 16362, 16311, 16348, 16303, 16251, 16361, 16358, 16317, 16254, 16369, 16335, 16364, 15869, 16347, 16318, 16370, 16315, 16359, 16349, 16372, 16343, 16366, 16350, 16376, 15871, 16363, 16365, 16371, 16373, 16127, 16374, 16377, 16255, 16378, 16375, 16380, 16379, 16367, 16319, 16382, 16383, 16351, 16381]

### Sequence Group 6: Q6_4096

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 67, 41, 144, 28, 69, 42, 516, 49, 74, 272, 160, 1026, 520, 288, 528, 192, 544, 70, 44, 131, 81, 50, 73, 15, 320, 133, 52, 23, 134, 384, 76, 137, 82, 56, 27, 97, 39, 259, 84, 138, 145, 261, 29, 43, 98, 515, 88, 140, 30, 146, 1028, 71, 262, 265, 161, 576, 45, 100, 640, 1025, 51, 148, 46, 75, 266, 273, 517, 104, 162, 53, 193, 1032, 152, 77, 164, 768, 2048, 2049, 268, 274, 518, 54, 83, 57, 521, 112, 1024, 135, 78, 289, 194, 85, 276, 522, 58, 168, 139, 99, 86, 60, 280, 89, 290, 529, 524, 196, 141, 1040, 101, 147, 176, 142, 530, 321, 31, 200, 90, 1056, 545, 292, 322, 532, 263, 149, 102, 105, 304, 296, 1030, 163, 92, 1033, 47, 267, 385, 546, 324, 208, 386, 150, 153, 165, 106, 55, 328, 1088, 536, 577, 548, 1034, 113, 154, 79, 269, 2050, 2052, 108, 578, 224, 166, 519, 552, 195, 270, 1041, 641, 1036, 523, 275, 580, 291, 59, 2056, 2064, 169, 560, 114, 277, 156, 87, 1152, 197, 116, 170, 61, 1042, 531, 525, 642, 281, 278, 526, 177, 293, 388, 1057, 2080, 2051, 91, 584, 769, 198, 172, 120, 201, 336, 62, 282, 143, 1029, 1044, 103, 178, 294, 93, 1058, 644, 202, 592, 323, 392, 297, 2053, 2112, 770, 107, 180, 1280, 151, 209, 284, 1027, 648, 94, 204, 298, 400, 608, 1089, 352, 325, 533, 155, 210, 305, 547, 300, 109, 1048, 184, 534, 1060, 537, 115, 1090, 167, 225, 326, 306, 772, 157, 656, 329, 110, 2057, 2054, 117, 212, 171, 1038, 776, 1064, 330, 1153, 226, 549, 1043, 538, 387, 308, 216, 416, 271, 279, 2065, 2058, 158, 337, 550, 672, 1092, 118, 332, 579, 540, 1072, 389, 173, 1037, 121, 553, 199, 784, 179, 228, 338, 2066, 2176, 312, 1536, 704, 1154, 2060, 2081, 390, 174, 554, 581, 1046, 393, 283, 122, 448, 353, 561, 1096, 203, 63, 340, 394, 1049, 1281, 527, 582, 556, 181, 295, 1059, 285, 232, 2113, 2068, 124, 205, 182, 643, 1156, 562, 2304, 2082, 286, 585, 299, 354, 1045, 211, 401, 1104, 185, 1061, 396, 344, 586, 645, 1282, 593, 535, 240, 1050, 206, 95, 327, 564, 800, 2072, 2084, 402, 356, 2055, 2177, 307, 301, 417, 1160, 213, 1066, 568, 1120, 832, 588, 1035, 1537, 186, 646, 404, 1091, 227, 896, 594, 418, 302, 649, 2114, 2560, 771, 360, 539, 111, 1052, 331, 1168, 214, 2059, 2088, 309, 1062, 1284, 188, 449, 1073, 217, 408, 609, 596, 551, 650, 229, 159, 420, 310, 1093, 541, 2116, 2178, 1288, 773, 610, 657, 333, 1065, 119, 1098, 600, 339, 1184, 218, 368, 652, 1031, 230, 391, 313, 450, 542, 1538, 334, 2067, 2061, 2096, 2062, 1076, 233, 555, 774, 175, 123, 1155, 658, 2120, 2305, 612, 341, 777, 220, 314, 1105, 424, 1068, 395, 673, 583, 355, 1296, 1094, 287, 183, 234, 1051, 2069, 2180, 125, 557, 1216, 660, 616, 342, 2083, 2306, 316, 1157, 241, 778, 563, 1074, 345, 452, 397, 403, 1112, 207, 2074, 2561, 1540, 674, 558, 785, 1100, 432, 1039, 357, 187, 1162, 236, 664, 1312, 624, 587, 780, 1080, 1122, 2128, 2085, 705, 126, 242, 1063, 2073, 2070, 565, 398, 346, 456, 2184, 2308, 358, 405, 303, 569, 1544, 244, 1158, 1097, 595, 1283, 189, 566, 676, 1169, 1054, 1108, 361, 706, 589, 1344, 215, 786, 647, 348, 2312, 2086, 419, 406, 2562, 2144, 464, 680, 2115, 2089, 801, 1069, 362, 1164, 2192, 2076, 590, 409, 1286, 570, 1121, 788, 1552, 1106, 597, 1075, 572, 1186, 219, 311, 708, 598, 1289, 601, 651, 421, 792, 802, 2117, 2090, 611, 1047, 602, 1172, 410, 231, 688, 653, 2564, 2097, 1128, 248, 1070, 369, 2122, 2320, 190, 364, 1568, 654, 1095, 659, 1161, 335, 480, 315, 221, 370, 1285, 613, 1408, 422, 2208, 3074, 425, 451, 2568, 2336, 1077, 614, 543, 1298, 235, 412, 343, 372, 2576, 2240, 1185, 775, 317, 1539, 222, 1099, 426, 453, 237, 1124, 559, 1170, 2592, 2118, 1292, 833, 804, 712, 1082, 834, 661, 1053, 2092, 2179, 2129, 2098, 808, 779, 1217, 617, 604, 1541, 433, 720, 816, 1101, 2121, 2063, 1176, 836, 347, 897, 1136, 243, 1297, 662, 1600, 454, 318, 675, 2368, 2181, 1110, 618, 1081, 898, 781, 1314, 1220, 376, 428, 1546, 2100, 2071, 665, 736, 567, 1107, 2182, 2432, 1192, 1078, 2124, 2185, 840, 625, 238, 1159, 359, 457, 399, 787, 2130, 2104, 591, 678, 434, 677, 1290, 1542, 2075, 2145, 349, 1300, 1102, 245, 1188, 458, 666, 1113, 620, 1553, 1163, 1313, 363, 127, 1067, 191, 1125, 782, 407, 436, 2087, 2307, 626, 1218, 2132, 2186, 571, 465, 2193, 2309, 681, 246, 707, 1346, 2077, 2091, 2146, 2563, 350, 1084, 599, 668, 1548, 790, 2136, 2188, 1165, 1320, 460, 1123, 1200, 249, 682, 1664, 573, 1171, 411, 803, 1116, 789, 1304, 709, 365, 440, 628, 689, 2078, 2194, 374, 1224, 3076, 2119, 423, 1556, 466, 793, 2310, 2313, 2209, 2624, 1130, 250, 371, 1174, 2093, 2148, 481, 574, 1348, 413, 1109, 603, 366, 1545, 1287, 1055, 468, 1570, 655, 900, 805, 615, 1166, 684, 1409, 710, 2688, 3073, 1187, 429, 2099, 2196, 794, 252, 1114, 373, 605, 1232, 848, 690, 2094, 2123, 713, 632, 2314, 2321, 1316, 482, 806, 1132, 2565, 2152, 1083, 427, 1177, 904, 1569, 414, 2210, 2101, 1291, 223, 1126, 1554, 663, 692, 835, 1328, 619, 472, 2241, 3080, 1137, 455, 2200, 2125, 796, 1189, 1601, 809, 714, 1248, 721, 837, 716, 1086, 2212, 2816, 1302, 1352, 864, 810, 1173, 606, 1194, 912, 1103, 722, 696, 377, 2316, 2322, 1424, 435, 2566, 2102, 1293, 1560, 817, 1129, 1792, 319, 621, 1180, 2131, 2105, 2569, 2160, 812, 484, 1345, 430, 1572, 1138, 3072, 2183, 1299, 838, 667, 1219, 2126, 2337, 488, 1111, 239, 378, 459, 622, 1410, 627, 2242, 2133, 437, 380, 1201, 1608, 818, 1178, 2324, 2570, 1294, 461, 1543, 496, 669, 1190, 1317, 679, 2106, 2216, 1140, 1079, 2187, 2147, 1221, 724, 841, 1305, 629, 1584, 2134, 2108, 351, 467, 2328, 2137, 1360, 438, 1115, 737, 2338, 2577, 251, 462, 442, 441, 2572, 2244, 1666, 469, 1549, 247, 683, 1196, 2189, 3088, 2149, 2195, 1226, 842, 1412, 1127, 738, 1144, 2224, 2190, 1308, 899, 1602, 670, 1318, 783, 1085, 849, 1555, 1193, 820, 1576, 728, 928, 791, 367, 2578, 2369, 1376, 901, 2079, 2248, 2138, 3104, 1233, 630, 2593, 2340, 1321, 685, 844, 1204, 633, 711, 2370, 2580, 2311, 2197, 2150, 2153, 1118, 253, 691, 1301, 824, 1175, 2352, 2344, 902, 686, 1668, 1222, 1416, 1133, 740, 1347, 850, 375, 1558, 444, 1306, 470, 1167, 483, 1547, 415, 3078, 2211, 485, 905, 2140, 3081, 1202, 795, 473, 1240, 2095, 2315, 634, 744, 2433, 2594, 1616, 852, 2372, 2256, 2434, 2198, 960, 1322, 2201, 2213, 865, 693, 2154, 2103, 1131, 1794, 1350, 797, 1225, 1604, 1571, 906, 2376, 3136, 1252, 715, 1141, 1330, 807, 474, 636, 1179, 694, 254, 1550, 1665, 2584, 2625, 717, 1071, 2596, 3082, 1315, 575, 913, 1440, 798, 811, 379, 1208, 2161, 2202, 1353, 1191, 2127, 2317, 697, 1564, 431, 1142, 607, 1228, 2156, 2626, 489, 1324, 2272, 2214, 866, 723, 2567, 2600, 486, 1573, 1181, 1234, 908, 1793, 1561, 718, 813, 1364, 2243, 2318, 476, 856, 3089, 2689, 1117, 1411, 839, 1329, 1295, 1146, 3084, 2571, 725, 698, 1472, 914, 2323, 2628, 1249, 752, 868, 819, 1349, 814, 439, 929, 2339, 2107, 1197, 1578, 490, 1139, 2217, 2608, 1680, 623, 2162, 2325, 1632, 1336, 671, 1198, 1362, 739, 2204, 2135, 1603, 1557, 3200, 2245, 2164, 2218, 1413, 916, 1303, 463, 1236, 843, 2109, 3090, 1135, 381, 1672, 1354, 2579, 2573, 497, 1586, 930, 821, 2690, 2329, 726, 961, 1203, 1182, 2326, 2574, 872, 1418, 492, 1250, 1332, 631, 2225, 2341, 2436, 3105, 1574, 1223, 729, 1145, 1605, 700, 2139, 2632, 1796, 443, 2817, 2246, 1307, 741, 2220, 2168, 1378, 1562, 1356, 1205, 845, 1319, 2249, 2384, 920, 382, 2110, 2330, 1585, 822, 1425, 851, 2191, 3077, 3092, 2151, 1229, 730, 1609, 498, 2226, 2342, 880, 1256, 742, 445, 1392, 471, 2141, 3106, 2692, 2250, 2640, 2371, 635, 1148, 1696, 932, 1580, 687, 2440, 2345, 1210, 1420, 1612, 1325, 1800, 903, 1134, 825, 1235, 1361, 500, 1577, 846, 1670, 1195, 745, 2818, 2155, 2228, 3328, 826, 732, 2199, 2257, 2332, 3075, 1264, 446, 2696, 2142, 962, 1426, 1620, 936, 2252, 2346, 1377, 475, 2448, 2656, 3137, 2400, 2373, 2581, 853, 1310, 867, 637, 2203, 2258, 1551, 1230, 2353, 2595, 1414, 907, 1206, 1667, 1588, 1333, 487, 1808, 2348, 2157, 695, 1441, 1087, 746, 828, 753, 1610, 854, 1237, 1326, 3096, 2232, 857, 1368, 2582, 3108, 1209, 504, 799, 1355, 2585, 2163, 255, 964, 3138, 2215, 2273, 2374, 1242, 909, 2354, 2820, 2205, 2704, 1673, 1559, 1309, 719, 2377, 2158, 1143, 477, 2165, 2260, 1617, 915, 1448, 1380, 2219, 3086, 638, 748, 2824, 3112, 944, 1728, 1331, 1227, 869, 1592, 1428, 491, 699, 1253, 1351, 754, 2378, 3201, 1183, 1565, 2274, 2597, 858, 1618, 1417, 1476, 3091, 2586, 478, 968, 1260, 383, 2435, 2356, 1212, 910, 1801, 815, 2264, 2464, 1579, 976, 2319, 2327, 870, 1684, 1633, 917, 2206, 2385, 2598, 2720, 3140, 2166, 1337, 1241, 2380, 2627, 1606, 1824, 727, 1150, 1442, 493, 1357, 1251, 2588, 3120, 1676, 873, 2437, 2221, 1384, 701, 3085, 2169, 1566, 931, 1323, 1798, 1365, 1473, 2601, 2247, 756, 1334, 860, 499, 2832, 2227, 731, 1648, 1238, 823, 1575, 922, 1199, 1674, 2276, 2386, 874, 1432, 1421, 918, 2360, 3584, 2752, 3202, 1636, 1254, 2438, 2222, 502, 1795, 2602, 2629, 933, 1366, 3094, 2441, 1338, 1682, 2331, 2170, 2496, 2401, 1587, 1211, 1488, 743, 1358, 760, 2609, 3144, 1244, 1581, 881, 1147, 2251, 2111, 494, 1379, 1272, 702, 2388, 2442, 3097, 3329, 921, 1624, 501, 876, 2575, 2630, 1415, 847, 1856, 1444, 992, 1697, 2604, 2229, 2343, 3107, 2333, 2280, 447, 1607, 1436, 1369, 2172, 2253, 1257, 1704, 2230, 2691, 733, 1797, 3204, 2610, 1669, 1340, 1231, 827, 1590, 934, 2334, 2633, 1634, 1474, 2347, 2402, 3093, 2259, 882, 937, 2449, 3152, 2233, 3109, 963, 1419, 747, 1265, 2444, 2392, 1119, 505, 1381, 855, 2634, 2693, 924, 1810, 3330, 2641, 2583, 2288, 3098, 2254, 734, 829, 1563, 1213, 2143, 2375, 1611, 1363, 2612, 2848, 1430, 1258, 1688, 1386, 965, 1614, 1730, 1239, 2450, 2404, 938, 884, 506, 1327, 1589, 1804, 2355, 2349, 2465, 3208, 749, 1370, 2261, 3114, 2616, 3168, 1640, 945, 2880, 2636, 966, 1456, 1681, 755, 3083, 3585, 2234, 2694, 1266, 859, 2452, 3139, 2275, 2944, 2642, 2466, 1427, 1593, 1388, 940, 2350, 2697, 1214, 830, 2819, 2408, 1809, 911, 1621, 1582, 2587, 2159, 1832, 871, 3100, 2379, 639, 1480, 1698, 1335, 888, 1372, 1245, 479, 1422, 1268, 3216, 2262, 946, 1732, 2357, 3110, 1677, 750, 1802, 1626, 3332, 2236, 2497, 3121, 1393, 969, 2265, 2456, 2657, 2644, 508, 1613, 2599, 2698, 2277, 2207, 861, 1446, 2468, 2358, 1857, 1339, 3141, 2589, 757, 1382, 3336, 2821, 970, 1700, 2658, 2705, 2381, 3113, 1243, 919, 2167, 3146, 1594, 1433, 1826, 1504, 875, 1635, 1259, 862, 2648, 2387, 1920, 1675, 3232, 2266, 1445, 758, 2416, 2700, 1149, 948, 1359, 1816, 3079, 2278, 1596, 1671, 1712, 977, 2439, 2361, 1385, 923, 1622, 972, 2498, 2590, 1434, 1311, 3586, 2382, 1729, 761, 1396, 877, 3124, 2281, 2603, 2822, 2223, 2171, 3203, 2706, 1207, 1475, 2660, 2389, 1449, 1812, 952, 1686, 2825, 2268, 495, 1262, 2362, 3153, 1644, 1619, 2472, 3116, 1341, 1429, 2443, 2721, 1825, 703, 1371, 1638, 1567, 1736, 2631, 2403, 935, 1685, 978, 1625, 3344, 3142, 883, 762, 1246, 503, 2335, 2231, 1458, 925, 1394, 1269, 2282, 3099, 878, 1478, 735, 1799, 2173, 2605, 3264, 2708, 2664, 2390, 1678, 1860, 2364, 3205, 2289, 2826, 2611, 3122, 1443, 1637, 2393, 2500, 1481, 1373, 2445, 2451, 3160, 2255, 1699, 1255, 993, 1591, 1828, 1452, 3588, 2722, 885, 939, 994, 1400, 2606, 2833, 3148, 2480, 1744, 1656, 3087, 2405, 2235, 3210, 980, 1689, 926, 764, 2284, 2712, 1270, 941, 1628, 1367, 1805, 1457, 3360, 2672, 2635, 2828, 3128, 3170, 1921, 1583, 2753, 2174, 1387, 1642, 2290, 3111, 967, 1267, 2613, 2446, 1484, 1450, 2394, 2504, 886, 831, 1683, 1342, 1811, 947, 2406, 2453, 2351, 2617, 3592, 2292, 1705, 1431, 3206, 3145, 2643, 3331, 507, 1261, 1840, 889, 2237, 2614, 1650, 984, 1760, 1490, 2724, 3217, 3102, 3156, 1615, 751, 2409, 2754, 2637, 3392, 2263, 2834, 1702, 942, 1858, 1423, 2695, 2396, 1460, 1383, 2467, 2454, 996, 1692, 1641, 1814, 971, 1477, 2512, 2728, 1273, 1512, 1733, 890, 1598, 1374, 2849, 3117, 2410, 3212, 509, 1806, 2638, 2457, 3334, 2618, 1922, 1649, 3169, 2836, 3600, 3154, 949, 973, 2645, 3123, 2620, 3234, 1397, 1489, 2267, 2359, 2756, 2646, 3337, 2649, 1708, 1627, 2699, 2469, 1000, 1690, 2840, 2850, 892, 1274, 2659, 3095, 1438, 1817, 2650, 3220, 2458, 2279, 1390, 1464, 2736, 2701, 1868, 950, 1151, 1731, 1506, 1827, 1597, 863, 3176, 2296, 3118, 2417, 1451, 759, 2238, 2412, 1864, 1714, 3616, 2702, 3143, 2707, 1701, 1395, 3209, 2383, 2528, 2363, 1803, 1008, 2269, 2418, 3333, 2661, 1623, 1482, 3456, 2470, 1276, 510, 2473, 2499, 1435, 1652, 3125, 2662, 2591, 3346, 2283, 2460, 2391, 2420, 979, 1492, 3233, 2823, 953, 1928, 1829, 1389, 2365, 3587, 1738, 763, 2270, 3147, 1872, 974, 2474, 2501, 1453, 1643, 2285, 3172, 1713, 1818, 1215, 1402, 2607, 3218, 1629, 1520, 1830, 1691, 3340, 2881, 954, 1459, 1734, 879, 2852, 2760, 3130, 2882, 981, 1505, 2709, 3101, 1706, 982, 2856, 2827, 3265, 2665, 2652, 3589, 2481, 2768, 2864, 3149, 1924, 927, 3224, 2884, 1833, 1639, 2395, 2945, 3184, 2291, 1447, 1746, 3345, 2710, 1343, 1679, 3648, 2502, 2366, 2723, 1820, 1761, 1479, 1275, 995, 1740, 3158, 2666, 1401, 1888, 765, 956, 3129, 2946, 2829, 3362, 1496, 1861, 3268, 2424, 887, 1437, 985, 1720, 2476, 3594, 997, 1630, 1813, 1462, 2713, 2784, 2615, 3155, 3240, 3126, 1398, 1645, 2888, 2673, 2286, 3207, 2407, 2505, 2447, 2835, 1848, 1687, 2639, 2726, 1247, 1716, 2482, 2725, 3338, 3590, 1936, 986, 1483, 1651, 1745, 943, 2397, 3348, 1859, 1508, 3150, 2293, 3236, 2506, 1834, 1454, 2714, 3161, 2668, 3601, 891, 1841, 998, 1595, 3211, 3361, 1278, 766, 1465, 1709, 2411, 2175, 1764, 1646, 3115, 2239, 3173, 2830, 2455, 2484, 1737, 511, 2674, 3266, 1485, 1404, 2619, 2513, 1693, 1866, 2729, 2294, 2755, 3394, 1952, 1491, 988, 1657, 1752, 1807, 2398, 3132, 2647, 2716, 3596, 2838, 1399, 1844, 3213, 3368, 2508, 3171, 1001, 951, 1654, 1926, 3248, 2297, 2730, 3712, 1707, 1391, 2621, 3219, 2459, 2851, 1002, 1468, 3164, 2837, 3352, 2757, 2413, 2488, 1836, 1494, 1873, 1271, 2676, 2737, 1694, 893, 2422, 3272, 1923, 1461, 2471, 3604, 1748, 1715, 2514, 2841, 975, 1862, 894, 1815, 3178, 2298, 2419, 3222, 1497, 1653, 2529, 2622, 3396, 2461, 3157, 2651, 2414, 3593, 1510, 1762, 3335, 3103, 2516, 3618, 1842, 1375, 2703, 2948, 2853, 2663, 3214, 2732, 1703, 1009, 3457, 2758, 1466, 1874, 3235, 2477, 955, 1739, 2842, 2300, 3162, 2421, 2653, 3280, 2896, 2738, 1486, 1930, 2761, 2680, 1889, 1004, 1658, 1821, 1718, 1929, 3364, 2530, 2854, 3180, 1599, 1507, 3131, 2475, 1776, 1405, 3225, 2952, 3617, 2462, 1735, 1831, 3339, 2271, 3174, 3602, 1493, 1010, 2711, 2740, 2883, 3376, 1984, 1455, 2667, 2520, 957, 1865, 3185, 2503, 2844, 3237, 3649, 2857, 2762, 3296, 2769, 2885, 2764, 3134, 983, 1710, 3350, 3400, 958, 1514, 2912, 2858, 3221, 2654, 1876, 1768, 3242, 2960, 1721, 1938, 3151, 2770, 2744, 2425, 1660, 1500, 1403, 1892, 3472, 2483, 1819, 1741, 1516, 987, 3341, 3608, 1932, 1463, 2865, 3177, 3840, 2367, 1012, 1843, 2669, 3228, 1749, 999, 2860, 2532, 3393, 2478, 3620, 3186, 3347, 2886, 2715, 3267, 1838, 1277, 2536, 3159, 2287, 2426, 2507, 2670, 3458, 2675, 1647, 1925, 2485, 2428, 1498, 1742, 3249, 3656, 2866, 3226, 1513, 1880, 1717, 1016, 1953, 1837, 3342, 2509, 1867, 1631, 3591, 2544, 2717, 3238, 1469, 1747, 3365, 2727, 767, 1904, 1724, 1524, 3188, 3127, 989, 1406, 1754, 1822, 3269, 2772, 2889, 3353, 2677, 3632, 2399, 2515, 3408, 2486, 3163, 2785, 2299, 2510, 2490, 2489, 1835, 1499, 3714, 2517, 3597, 2295, 2731, 3244, 1944, 1863, 1890, 1467, 1003, 1522, 3274, 2890, 3460, 3175, 2786, 3192, 1763, 1695, 3356, 2947, 3650, 2718, 1850, 990, 1005, 1937, 3366, 2831, 3133, 2897, 1722, 1845, 3603, 3241, 1495, 1655, 2868, 3624, 2776, 2976, 2839, 2415, 1765, 1956, 3424, 2949, 1487, 1750, 3281, 2678, 1869, 1521, 3369, 2733, 2892, 3252, 2681, 2759, 959, 1896, 1263, 1940, 3166, 2301, 2739, 3349, 2872, 3223, 1770, 1877, 2950, 2734, 3716, 3270, 1509, 1711, 3464, 3181, 2788, 3395, 1756, 1846, 2898, 2423, 3606, 2492, 1011, 1960, 3354, 2518, 3215, 2531, 3595, 2463, 1784, 1870, 1662, 1013, 2533, 2953, 1985, 1753, 3250, 2843, 2521, 3288, 2682, 2792, 1927, 1528, 3664, 2900, 1849, 1882, 3008, 3370, 2913, 2741, 1766, 1511, 3179, 3842, 3398, 2845, 3273, 3652, 3619, 2954, 1954, 1719, 3300, 2763, 3189, 3378, 1777, 895, 2855, 2522, 2684, 3227, 2742, 2302, 1439, 1006, 3598, 3713, 1878, 1891, 2765, 3119, 3363, 2623, 2961, 3488, 2846, 2859, 2427, 3256, 1939, 1661, 3401, 3239, 1502, 1986, 2745, 3612, 1852, 1934, 2479, 3190, 2655, 3276, 2537, 3372, 1723, 1772, 2914, 2771, 1515, 1897, 2534, 3621, 3229, 3282, 2956, 3841, 3609, 2766, 1014, 1470, 2861, 3412, 1743, 1931, 2524, 2904, 3165, 3459, 2887, 3377, 3343, 3194, 2773, 2746, 3520, 2962, 1017, 1968, 3297, 2800, 2916, 2867, 3397, 2862, 2487, 2977, 1881, 1894, 3245, 3626, 1769, 1517, 2538, 3187, 1778, 1941, 1823, 1659, 3728, 2671, 1992, 1875, 3680, 3384, 1755, 1501, 2719, 3246, 3410, 2787, 1018, 1900, 3651, 3605, 1725, 991, 3461, 2964, 3351, 2511, 3284, 2891, 3183, 2429, 3720, 3402, 2545, 3634, 2978, 2869, 2774, 3009, 3251, 3230, 1933, 1839, 2920, 3466, 2540, 3298, 3380, 2679, 1525, 1955, 1988, 1884, 1726, 1948, 3622, 3271, 2777, 3193, 3653, 2748, 1780, 1518, 3844, 2491, 1020, 1767, 1905, 1851, 3355, 2789, 1893, 1945, 3426, 3610, 3404, 3253, 2893, 3367, 2968, 2430, 3633, 2870, 3473, 2899, 3277, 2778, 3657, 2546, 1757, 1530, 2928, 3304, 2790, 2493, 3440, 2519, 1958, 1471, 1007, 2000, 2683, 3196, 3744, 2980, 3628, 2735, 1847, 1898, 3258, 3468, 3660, 3373, 1523, 1942, 3848, 2951, 3182, 2873, 1961, 1871, 3283, 3409, 1771, 1529, 2548, 3625, 2894, 3718, 3243, 2793, 1912, 1758, 2874, 2780, 1989, 1946, 3312, 2494, 3010, 3474, 3668, 2984, 3425, 2523, 1526, 1906, 2901, 3358, 2915, 2685, 3599, 3278, 1883, 1773, 3462, 2955, 3254, 3715, 3636, 3381, 2535, 3856, 1957, 1853, 2743, 3489, 3135, 2794, 1976, 1015, 2876, 2801, 3658, 2902, 3285, 3374, 1751, 1993, 1503, 1962, 2905, 3416, 3257, 2552, 2847, 3403, 2303, 3012, 1781, 1885, 3290, 2957, 1908, 2016, 3721, 3607, 3357, 2767, 3191, 2525, 3665, 2963, 3496, 3428, 2686, 2796, 1854, 1532, 2992, 3776, 3379, 3275, 2917, 3640, 3476, 2539, 2747, 3301, 1972, 1774, 3399, 2802, 1019, 1895, 3231, 3613, 2906, 3666, 3465, 3524, 2526, 3016, 3308, 2431, 1987, 1969, 3260, 2958, 3849, 2863, 3627, 3024, 1782, 1279, 2918, 3732, 3681, 2965, 1943, 1899, 3385, 3289, 1994, 1663, 3654, 3872, 2775, 3198, 3490, 2541, 3405, 3299, 1964, 1785, 3724, 2921, 1021, 1935, 3432, 2749, 3614, 2979, 3371, 3846, 3413, 3521, 2804, 3382, 2908, 2547, 2779, 3696, 3286, 2871, 3623, 2970, 3247, 3722, 1886, 2001, 2922, 3480, 3469, 2966, 1407, 1779, 1990, 1970, 3684, 3302, 2550, 3843, 1879, 1022, 2981, 3414, 1902, 1947, 3386, 3730, 3635, 3259, 3536, 2791, 3406, 2808, 3292, 3629, 2929, 3195, 2542, 3427, 3320, 2750, 2969, 3672, 2549, 2924, 1759, 1907, 3463, 2895, 3904, 3492, 3040, 3745, 1527, 1996, 1786, 1959, 2495, 3655, 3484, 3417, 2002, 1913, 3305, 3752, 1949, 2017, 2781, 3845, 1534, 1788, 3717, 3388, 3279, 2875, 3638, 2982, 3682, 3522, 2930, 2985, 3011, 3467, 2795, 3313, 3167, 2553, 3429, 2903, 2972, 3858, 1910, 1965, 2782, 2877, 3611, 3261, 3659, 3411, 2004, 1901, 3478, 3306, 3736, 3434, 3013, 3662, 3778, 3287, 1966, 1775, 2986, 2932, 2008, 1531, 2554, 3375, 3637, 3852, 1971, 1950, 2797, 3418, 3688, 2993, 3014, 3504, 3729, 2803, 3314, 2907, 1909, 1991, 3475, 3641, 3436, 2988, 3262, 2878, 3857, 2959, 3669, 3630, 3880, 2919, 2018, 1727, 2687, 3528, 3746, 3383, 2936, 3420, 3293, 2527, 3470, 3316, 1916, 1855, 1974, 1995, 2994, 3780, 3725, 2798, 3850, 3674, 3441, 3017, 2020, 1977, 2556, 3661, 2909, 3494, 3905, 3387, 2805, 3430, 3018, 3748, 3291, 2967, 1787, 1914, 3642, 3481, 3874, 3552, 2923, 3683, 3307, 2910, 2005, 1887, 3968, 3723, 1023, 1963, 3493, 2806, 3197, 2996, 3407, 3864, 3644, 3719, 3760, 3025, 3433, 2971, 3670, 3020, 3482, 3359, 1998, 1783, 3777, 2809, 3444, 2925, 2024, 1980, 3255, 3523, 3497, 3860, 3000, 3734, 2543, 3310, 1903, 1973, 3692, 3667, 3389, 3477, 3873, 2751, 3419, 3686, 3615, 3784, 2983, 3733, 3026, 3673, 2931, 2810, 3294, 2551, 3506, 2973, 3442, 3317, 2003, 1789, 2926, 3526, 2783, 3847, 1997, 2032, 3726, 3908, 1978, 1917, 3491, 3685, 2010, 1519, 3529, 3421, 3747, 3303, 3041, 3639, 3876, 3500, 2933, 2987, 3042, 3448, 3792, 3704, 3028, 3737, 2974, 2812, 3318, 2989, 3676, 3415, 3853, 3505, 2019, 2006, 3969, 3631, 3435, 3690, 1951, 1911, 3015, 3315, 3532, 3498, 2021, 2009, 2934, 2879, 3731, 3390, 3859, 2995, 3753, 3479, 2555, 3309, 3888, 2937, 3698, 3032, 3808, 3538, 3663, 2799, 1790, 2026, 3750, 2990, 3906, 3471, 3508, 3431, 3044, 3740, 3689, 3862, 3019, 3525, 1975, 2012, 3321, 3560, 3781, 2938, 3646, 3422, 1967, 1915, 2557, 3854, 3970, 3697, 2997, 3021, 3445, 3537, 3756, 3675, 3048, 3738, 2940, 3322, 3486, 3865, 3438, 3512, 2025, 2022, 3916, 2998, 3199, 3779, 3554, 3875, 3645, 2911, 1981, 1918, 2033, 1999, 3499, 2807, 3912, 3762, 3749, 3443, 3851, 3056, 3671, 3530, 3324, 2558, 3483, 3700, 3027, 3540, 3001, 3976, 3877, 3437, 3786, 2811, 2028, 1533, 3920, 3022, 3501, 3691, 3761, 3866, 3263, 3450, 3677, 3568, 3878, 3739, 3002, 3507, 3782, 2927, 3029, 3553, 2011, 1982, 3754, 3030, 3972, 2975, 3881, 3687, 3495, 3794, 2034, 1979, 3391, 3727, 3868, 3809, 3527, 3323, 3043, 3788, 3449, 3936, 2813, 3004, 3544, 3909, 2935, 3485, 3033, 3768, 3045, 3678, 3861, 3510, 2023, 2013, 3446, 3693, 2036, 2007, 3896, 3735, 3295, 3764, 3984, 3034, 3531, 3699, 3793, 2991, 3907, 3556, 3882, 3502, 2939, 3889, 3046, 3643, 3326, 2814, 3513, 3757, 3812, 3694, 2030, 2014, 3785, 2559, 3533, 3452, 3741, 3914, 2040, 1535, 4000, 3539, 3036, 3705, 3800, 3855, 3447, 3892, 3049, 2999, 3702, 3974, 3755, 3439, 3050, 3516, 3884, 3542, 3921, 3319, 3742, 2941, 3971, 3509, 3796, 3763, 2027, 2029, 3023, 3910, 2942, 3863, 2035, 2037, 3545, 3701, 3558, 3810, 3890, 3423, 3751, 3057, 3514, 3922, 3003, 3787, 3534, 3978, 3937, 3052, 3706, 3869, 3766, 3977, 1791, 2038, 3647, 3555, 3824, 3453, 3783, 3879, 3541, 3058, 4032, 3503, 3005, 3913, 3031, 3758, 3006, 3562, 3924, 3816, 2041, 1919, 3769, 3986, 3708, 3548, 3451, 3940, 3867, 3789, 3564, 3035, 3980, 3511, 3060, 3891, 3797, 3047, 3886, 3325, 3695, 3973, 3546, 3790, 3561, 3928, 3765, 3064, 4001, 3885, 3915, 3679, 3517, 3795, 2815, 3952, 3772, 3572, 3037, 3454, 3802, 3870, 2042, 2039, 3883, 3547, 3992, 3911, 3938, 3515, 3051, 3570, 3811, 3743, 3898, 3038, 3053, 3985, 3770, 3893, 3543, 3703, 3813, 4004, 3535, 3798, 3917, 3569, 2044, 2043, 3007, 3944, 3311, 3988, 3818, 3925, 3557, 3759, 3804, 3894, 3059, 4008, 3832, 3918, 3710, 3061, 4033, 3801, 3975, 3576, 3897, 3930, 2031, 1983, 3814, 3559, 4002, 3767, 3825, 2943, 3487, 3054, 3926, 3939, 3987, 3709, 3550, 4034, 3900, 3982, 2046, 2047, 3771, 3820, 3563, 3945, 3062, 3518, 3791, 3979, 3065, 4016, 3929, 3942, 3817, 3565, 3826, 3989, 3871, 3707, 4040, 3923, 3803, 3549, 3066, 3948, 3773, 3039, 3981, 3887, 3573, 4003, 4036, 3932, 3774, 3996, 3828, 3566, 3068, 3815, 3953, 3899, 3941, 3993, 3805, 3578, 4006, 3519, 3055, 4048, 3895, 3946, 3571, 3990, 4009, 3919, 3819, 3577, 3960, 3806, 4037, 3994, 3574, 3954, 3931, 3821, 4005, 3901, 4024, 3063, 3799, 4041, 3551, 4010, 3829, 3933, 3956, 4064, 2015, 2045, 3902, 3580, 4020, 3822, 3067, 3943, 4035, 4017, 3830, 3327, 3991, 3947, 4042, 3711, 4012, 3833, 3069, 3983, 3934, 4049, 3455, 3827, 4038, 4018, 3927, 3070, 3950, 3995, 3807, 3955, 3575, 4044, 3834, 4007, 4050, 3961, 3997, 4065, 3582, 3836, 3958, 4013, 4052, 3949, 4014, 3823, 4056, 3579, 4019, 3998, 3957, 4039, 4066, 3775, 3964, 3903, 4022, 4043, 4068, 4025, 3835, 3962, 4053, 3935, 3071, 4011, 4046, 3831, 4072, 4028, 3951, 4021, 4051, 3837, 4045, 4080, 4026, 3965, 4058, 3567, 4067, 4054, 3999, 3959, 4069, 4057, 3838, 4074, 4023, 4060, 4015, 3963, 4073, 4070, 4029, 3966, 4081, 4047, 4076, 3581, 4059, 4030, 4082, 4027, 4071, 4061, 4084, 4055, 4078, 4062, 4088, 3583, 4075, 4077, 4083, 4085, 3839, 4086, 4089, 3967, 4090, 4087, 4092, 4091, 4079, 4031, 4094, 4095, 4063, 4093]

### Sequence Group 7: Q7_4096

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 67, 41, 144, 28, 69, 42, 516, 49, 74, 272, 160, 1026, 520, 288, 528, 192, 544, 70, 44, 131, 81, 50, 73, 15, 320, 133, 52, 23, 134, 384, 76, 137, 82, 56, 27, 97, 39, 259, 84, 138, 145, 261, 29, 43, 98, 515, 88, 140, 30, 146, 1028, 71, 262, 265, 161, 576, 45, 100, 640, 1025, 51, 148, 46, 75, 266, 273, 517, 104, 162, 53, 193, 1032, 152, 77, 164, 768, 2048, 2049, 268, 274, 518, 54, 83, 57, 521, 112, 1024, 135, 78, 289, 194, 85, 276, 522, 58, 168, 139, 99, 86, 60, 280, 89, 290, 529, 524, 196, 141, 1040, 101, 147, 176, 142, 530, 321, 31, 200, 90, 1056, 545, 292, 322, 532, 263, 149, 102, 105, 304, 296, 1030, 163, 92, 1033, 47, 267, 385, 546, 324, 208, 386, 150, 153, 165, 106, 55, 328, 1088, 536, 577, 548, 1034, 113, 154, 79, 269, 2050, 2052, 108, 578, 224, 166, 519, 552, 195, 270, 1041, 641, 1036, 523, 275, 580, 291, 59, 2056, 2064, 169, 560, 114, 277, 156, 87, 1152, 197, 116, 170, 61, 1042, 531, 525, 642, 281, 278, 526, 177, 293, 388, 1057, 2080, 2051, 91, 584, 769, 198, 172, 120, 201, 336, 62, 282, 143, 1029, 1044, 103, 178, 294, 93, 1058, 644, 202, 592, 323, 392, 297, 2053, 2112, 770, 107, 180, 1280, 151, 209, 284, 1027, 648, 94, 204, 298, 400, 608, 1089, 352, 325, 533, 155, 210, 305, 547, 300, 109, 1048, 184, 534, 1060, 537, 115, 1090, 167, 225, 326, 306, 772, 157, 656, 329, 110, 2057, 2054, 117, 212, 171, 1038, 776, 1064, 330, 1153, 226, 549, 1043, 538, 387, 308, 216, 416, 271, 279, 2065, 2058, 158, 337, 550, 672, 1092, 118, 332, 579, 540, 1072, 389, 173, 1037, 121, 553, 199, 784, 179, 228, 338, 2066, 2176, 312, 1536, 704, 1154, 2060, 2081, 390, 174, 554, 581, 1046, 393, 283, 122, 448, 353, 561, 1096, 203, 63, 340, 394, 1049, 1281, 527, 582, 556, 181, 295, 1059, 285, 232, 2113, 2068, 124, 205, 182, 643, 1156, 562, 2304, 2082, 286, 585, 299, 354, 1045, 211, 401, 1104, 185, 1061, 396, 344, 586, 645, 1282, 593, 535, 240, 1050, 206, 95, 327, 564, 800, 2072, 2084, 402, 356, 2055, 2177, 307, 301, 417, 1160, 213, 1066, 568, 1120, 832, 588, 1035, 1537, 186, 646, 404, 1091, 227, 896, 594, 418, 302, 649, 2114, 2560, 771, 360, 539, 111, 1052, 331, 1168, 214, 2059, 2088, 309, 1062, 1284, 188, 449, 1073, 217, 408, 609, 596, 551, 650, 229, 159, 420, 310, 1093, 541, 2116, 2178, 1288, 773, 610, 657, 333, 1065, 119, 1098, 600, 339, 1184, 218, 368, 652, 1031, 230, 391, 313, 450, 542, 1538, 334, 2067, 2061, 2096, 2062, 1076, 233, 555, 774, 175, 123, 1155, 658, 2120, 2305, 612, 341, 777, 220, 314, 1105, 424, 1068, 395, 673, 583, 355, 1296, 1094, 287, 183, 234, 1051, 2069, 2180, 125, 557, 1216, 660, 616, 342, 2083, 2306, 316, 1157, 241, 778, 563, 1074, 345, 452, 397, 403, 1112, 207, 2074, 2561, 1540, 674, 558, 785, 1100, 432, 1039, 357, 187, 1162, 236, 664, 1312, 624, 587, 780, 1080, 1122, 2128, 2085, 705, 126, 242, 1063, 2073, 2070, 565, 398, 346, 456, 2184, 2308, 358, 405, 303, 569, 1544, 244, 1158, 1097, 595, 1283, 189, 566, 676, 1169, 1054, 1108, 361, 706, 589, 1344, 215, 786, 647, 348, 2312, 2086, 419, 406, 2562, 2144, 464, 680, 2115, 2089, 801, 1069, 362, 1164, 2192, 2076, 590, 409, 1286, 570, 1121, 788, 1552, 1106, 597, 1075, 572, 1186, 219, 311, 708, 598, 1289, 601, 651, 421, 792, 802, 2117, 2090, 611, 1047, 602, 1172, 410, 231, 688, 653, 2564, 2097, 1128, 248, 1070, 369, 2122, 2320, 190, 364, 1568, 654, 1095, 659, 1161, 335, 480, 315, 221, 370, 1285, 613, 1408, 422, 2208, 3074, 425, 451, 2568, 2336, 1077, 614, 543, 1298, 235, 412, 343, 372, 2576, 2240, 1185, 775, 317, 1539, 222, 1099, 426, 453, 237, 1124, 559, 1170, 2592, 2118, 1292, 833, 804, 712, 1082, 834, 661, 1053, 2092, 2179, 2129, 2098, 808, 779, 1217, 617, 604, 1541, 433, 720, 816, 1101, 2121, 2063, 1176, 836, 347, 897, 1136, 243, 1297, 662, 1600, 454, 318, 675, 2368, 2181, 1110, 618, 1081, 898, 781, 1314, 1220, 376, 428, 1546, 2100, 2071, 665, 736, 567, 1107, 2182, 2432, 1192, 1078, 2124, 2185, 840, 625, 238, 1159, 359, 457, 399, 787, 2130, 2104, 591, 678, 434, 677, 1290, 1542, 2075, 2145, 349, 1300, 1102, 245, 1188, 458, 666, 1113, 620, 1553, 1163, 1313, 363, 127, 1067, 191, 1125, 782, 407, 436, 2087, 2307, 626, 1218, 2132, 2186, 571, 465, 2193, 2309, 681, 246, 707, 1346, 2077, 2091, 2146, 2563, 350, 1084, 599, 668, 1548, 790, 2136, 2188, 1165, 1320, 460, 1123, 1200, 249, 682, 1664, 573, 1171, 411, 803, 1116, 789, 1304, 709, 365, 440, 628, 689, 2078, 2194, 374, 1224, 3076, 2119, 423, 1556, 466, 793, 2310, 2313, 2209, 2624, 1130, 250, 371, 1174, 2093, 2148, 481, 574, 1348, 413, 1109, 603, 366, 1545, 1287, 1055, 468, 1570, 655, 900, 805, 615, 1166, 684, 1409, 710, 2688, 3073, 1187, 429, 2099, 2196, 794, 252, 1114, 373, 605, 1232, 848, 690, 2094, 2123, 713, 632, 2314, 2321, 1316, 482, 806, 1132, 2565, 2152, 1083, 427, 1177, 904, 1569, 414, 2210, 2101, 1291, 223, 1126, 1554, 663, 692, 835, 1328, 619, 472, 2241, 3080, 1137, 455, 2200, 2125, 796, 1189, 1601, 809, 714, 1248, 721, 837, 716, 1086, 2212, 2816, 1302, 1352, 864, 810, 1173, 606, 1194, 912, 1103, 722, 696, 377, 2316, 2322, 1424, 435, 2566, 2102, 1293, 1560, 817, 1129, 1792, 319, 621, 1180, 2131, 2105, 2569, 2160, 812, 484, 1345, 430, 1572, 1138, 3072, 2183, 1299, 838, 667, 1219, 2126, 2337, 488, 1111, 239, 378, 459, 622, 1410, 627, 2242, 2133, 437, 380, 1201, 1608, 818, 1178, 2324, 2570, 1294, 461, 1543, 496, 669, 1190, 1317, 679, 2106, 2216, 1140, 1079, 2187, 2147, 1221, 724, 841, 1305, 629, 1584, 2134, 2108, 351, 467, 2328, 2137, 1360, 438, 1115, 737, 2338, 2577, 251, 462, 442, 441, 2572, 2244, 1666, 469, 1549, 247, 683, 1196, 2189, 3088, 2149, 2195, 1226, 842, 1412, 1127, 738, 1144, 2224, 2190, 1308, 899, 1602, 670, 1318, 783, 1085, 849, 1555, 1193, 820, 1576, 728, 928, 791, 367, 2578, 2369, 1376, 901, 2079, 2248, 2138, 3104, 1233, 630, 2593, 2340, 1321, 685, 844, 1204, 633, 711, 2370, 2580, 2311, 2197, 2150, 2153, 1118, 253, 691, 1301, 824, 1175, 2352, 2344, 902, 686, 1668, 1222, 1416, 1133, 740, 1347, 850, 375, 1558, 444, 1306, 470, 1167, 483, 1547, 415, 3078, 2211, 485, 905, 2140, 3081, 1202, 795, 473, 1240, 2095, 2315, 634, 744, 2433, 2594, 1616, 852, 2372, 2256, 2434, 2198, 960, 1322, 2201, 2213, 865, 693, 2154, 2103, 1131, 1794, 1350, 797, 1225, 1604, 1571, 906, 2376, 3136, 1252, 715, 1141, 1330, 807, 474, 636, 1179, 694, 254, 1550, 1665, 2584, 2625, 717, 1071, 2596, 3082, 1315, 575, 913, 1440, 798, 811, 379, 1208, 2161, 2202, 1353, 1191, 2127, 2317, 697, 1564, 431, 1142, 607, 1228, 2156, 2626, 489, 1324, 2272, 2214, 866, 723, 2567, 2600, 486, 1573, 1181, 1234, 908, 1793, 1561, 718, 813, 1364, 2243, 2318, 476, 856, 3089, 2689, 1117, 1411, 839, 1329, 1295, 1146, 3084, 2571, 725, 698, 1472, 914, 2323, 2628, 1249, 752, 868, 819, 1349, 814, 439, 929, 2339, 2107, 1197, 1578, 490, 1139, 2217, 2608, 1680, 623, 2162, 2325, 1632, 1336, 671, 1198, 1362, 739, 2204, 2135, 1603, 1557, 3200, 2245, 2164, 2218, 1413, 916, 1303, 463, 1236, 843, 2109, 3090, 1135, 381, 1672, 1354, 2579, 2573, 497, 1586, 930, 821, 2690, 2329, 726, 961, 1203, 1182, 2326, 2574, 872, 1418, 492, 1250, 1332, 631, 2225, 2341, 2436, 3105, 1574, 1223, 729, 1145, 1605, 700, 2139, 2632, 1796, 443, 2817, 2246, 1307, 741, 2220, 2168, 1378, 1562, 1356, 1205, 845, 1319, 2249, 2384, 920, 382, 2110, 2330, 1585, 822, 1425, 851, 2191, 3077, 3092, 2151, 1229, 730, 1609, 498, 2226, 2342, 880, 1256, 742, 445, 1392, 471, 2141, 3106, 2692, 2250, 2640, 2371, 635, 1148, 1696, 932, 1580, 687, 2440, 2345, 1210, 1420, 1612, 1325, 1800, 903, 1134, 825, 1235, 1361, 500, 1577, 846, 1670, 1195, 745, 2818, 2155, 2228, 3328, 826, 732, 2199, 2257, 2332, 3075, 1264, 446, 2696, 2142, 962, 1426, 1620, 936, 2252, 2346, 1377, 475, 2448, 2656, 3137, 2400, 2373, 2581, 853, 1310, 867, 637, 2203, 2258, 1551, 1230, 2353, 2595, 1414, 907, 1206, 1667, 1588, 1333, 487, 1808, 2348, 2157, 695, 1441, 1087, 746, 828, 753, 1610, 854, 1237, 1326, 3096, 2232, 857, 1368, 2582, 3108, 1209, 504, 799, 1355, 2585, 2163, 255, 964, 3138, 2215, 2273, 2374, 1242, 909, 2354, 2820, 2205, 2704, 1673, 1559, 1309, 719, 2377, 2158, 1143, 477, 2165, 2260, 1617, 915, 1448, 1380, 2219, 3086, 638, 748, 2824, 3112, 944, 1728, 1331, 1227, 869, 1592, 1428, 491, 699, 1253, 1351, 754, 2378, 3201, 1183, 1565, 2274, 2597, 858, 1618, 1417, 1476, 3091, 2586, 478, 968, 1260, 383, 2435, 2356, 1212, 910, 1801, 815, 2264, 2464, 1579, 976, 2319, 2327, 870, 1684, 1633, 917, 2206, 2385, 2598, 2720, 3140, 2166, 1337, 1241, 2380, 2627, 1606, 1824, 727, 1150, 1442, 493, 1357, 1251, 2588, 3120, 1676, 873, 2437, 2221, 1384, 701, 3085, 2169, 1566, 931, 1323, 1798, 1365, 1473, 2601, 2247, 756, 1334, 860, 499, 2832, 2227, 731, 1648, 1238, 823, 1575, 922, 1199, 1674, 2276, 2386, 874, 1432, 1421, 918, 2360, 3584, 2752, 3202, 1636, 1254, 2438, 2222, 502, 1795, 2602, 2629, 933, 1366, 3094, 2441, 1338, 1682, 2331, 2170, 2496, 2401, 1587, 1211, 1488, 743, 1358, 760, 2609, 3144, 1244, 1581, 881, 1147, 2251, 2111, 494, 1379, 1272, 702, 2388, 2442, 3097, 3329, 921, 1624, 501, 876, 2575, 2630, 1415, 847, 1856, 1444, 992, 1697, 2604, 2229, 2343, 3107, 2333, 2280, 447, 1607, 1436, 1369, 2172, 2253, 1257, 1704, 2230, 2691, 733, 1797, 3204, 2610, 1669, 1340, 1231, 827, 1590, 934, 2334, 2633, 1634, 1474, 2347, 2402, 3093, 2259, 882, 937, 2449, 3152, 2233, 3109, 963, 1419, 747, 1265, 2444, 2392, 1119, 505, 1381, 855, 2634, 2693, 924, 1810, 3330, 2641, 2583, 2288, 3098, 2254, 734, 829, 1563, 1213, 2143, 2375, 1611, 1363, 2612, 2848, 1430, 1258, 1688, 1386, 965, 1614, 1730, 1239, 2450, 2404, 938, 884, 506, 1327, 1589, 1804, 2355, 2349, 2465, 3208, 749, 1370, 2261, 3114, 2616, 3168, 1640, 945, 2880, 2636, 966, 1456, 1681, 755, 3083, 3585, 2234, 2694, 1266, 859, 2452, 3139, 2275, 2944, 2642, 2466, 1427, 1593, 1388, 940, 2350, 2697, 1214, 830, 2819, 2408, 1809, 911, 1621, 1582, 2587, 2159, 1832, 871, 3100, 2379, 639, 1480, 1698, 1335, 888, 1372, 1245, 479, 1422, 1268, 3216, 2262, 946, 1732, 2357, 3110, 1677, 750, 1802, 1626, 3332, 2236, 2497, 3121, 1393, 969, 2265, 2456, 2657, 2644, 508, 1613, 2599, 2698, 2277, 2207, 861, 1446, 2468, 2358, 1857, 1339, 3141, 2589, 757, 1382, 3336, 2821, 970, 1700, 2658, 2705, 2381, 3113, 1243, 919, 2167, 3146, 1594, 1433, 1826, 1504, 875, 1635, 1259, 862, 2648, 2387, 1920, 1675, 3232, 2266, 1445, 758, 2416, 2700, 1149, 948, 1359, 1816, 3079, 2278, 1596, 1671, 1712, 977, 2439, 2361, 1385, 923, 1622, 972, 2498, 2590, 1434, 1311, 3586, 2382, 1729, 761, 1396, 877, 3124, 2281, 2603, 2822, 2223, 2171, 3203, 2706, 1207, 1475, 2660, 2389, 1449, 1812, 952, 1686, 2825, 2268, 495, 1262, 2362, 3153, 1644, 1619, 2472, 3116, 1341, 1429, 2443, 2721, 1825, 703, 1371, 1638, 1567, 1736, 2631, 2403, 935, 1685, 978, 1625, 3344, 3142, 883, 762, 1246, 503, 2335, 2231, 1458, 925, 1394, 1269, 2282, 3099, 878, 1478, 735, 1799, 2173, 2605, 3264, 2708, 2664, 2390, 1678, 1860, 2364, 3205, 2289, 2826, 2611, 3122, 1443, 1637, 2393, 2500, 1481, 1373, 2445, 2451, 3160, 2255, 1699, 1255, 993, 1591, 1828, 1452, 3588, 2722, 885, 939, 994, 1400, 2606, 2833, 3148, 2480, 1744, 1656, 3087, 2405, 2235, 3210, 980, 1689, 926, 764, 2284, 2712, 1270, 941, 1628, 1367, 1805, 1457, 3360, 2672, 2635, 2828, 3128, 3170, 1921, 1583, 2753, 2174, 1387, 1642, 2290, 3111, 967, 1267, 2613, 2446, 1484, 1450, 2394, 2504, 886, 831, 1683, 1342, 1811, 947, 2406, 2453, 2351, 2617, 3592, 2292, 1705, 1431, 3206, 3145, 2643, 3331, 507, 1261, 1840, 889, 2237, 2614, 1650, 984, 1760, 1490, 2724, 3217, 3102, 3156, 1615, 751, 2409, 2754, 2637, 3392, 2263, 2834, 1702, 942, 1858, 1423, 2695, 2396, 1460, 1383, 2467, 2454, 996, 1692, 1641, 1814, 971, 1477, 2512, 2728, 1273, 1512, 1733, 890, 1598, 1374, 2849, 3117, 2410, 3212, 509, 1806, 2638, 2457, 3334, 2618, 1922, 1649, 3169, 2836, 3600, 3154, 949, 973, 2645, 3123, 2620, 3234, 1397, 1489, 2267, 2359, 2756, 2646, 3337, 2649, 1708, 1627, 2699, 2469, 1000, 1690, 2840, 2850, 892, 1274, 2659, 3095, 1438, 1817, 2650, 3220, 2458, 2279, 1390, 1464, 2736, 2701, 1868, 950, 1151, 1731, 1506, 1827, 1597, 863, 3176, 2296, 3118, 2417, 1451, 759, 2238, 2412, 1864, 1714, 3616, 2702, 3143, 2707, 1701, 1395, 3209, 2383, 2528, 2363, 1803, 1008, 2269, 2418, 3333, 2661, 1623, 1482, 3456, 2470, 1276, 510, 2473, 2499, 1435, 1652, 3125, 2662, 2591, 3346, 2283, 2460, 2391, 2420, 979, 1492, 3233, 2823, 953, 1928, 1829, 1389, 2365, 3587, 1738, 763, 2270, 3147, 1872, 974, 2474, 2501, 1453, 1643, 2285, 3172, 1713, 1818, 1215, 1402, 2607, 3218, 1629, 1520, 1830, 1691, 3340, 2881, 954, 1459, 1734, 879, 2852, 2760, 3130, 2882, 981, 1505, 2709, 3101, 1706, 982, 2856, 2827, 3265, 2665, 2652, 3589, 2481, 2768, 2864, 3149, 1924, 927, 3224, 2884, 1833, 1639, 2395, 2945, 3184, 2291, 1447, 1746, 3345, 2710, 1343, 1679, 3648, 2502, 2366, 2723, 1820, 1761, 1479, 1275, 995, 1740, 3158, 2666, 1401, 1888, 765, 956, 3129, 2946, 2829, 3362, 1496, 1861, 3268, 2424, 887, 1437, 985, 1720, 2476, 3594, 997, 1630, 1813, 1462, 2713, 2784, 2615, 3155, 3240, 3126, 1398, 1645, 2888, 2673, 2286, 3207, 2407, 2505, 2447, 2835, 1848, 1687, 2639, 2726, 1247, 1716, 2482, 2725, 3338, 3590, 1936, 986, 1483, 1651, 1745, 943, 2397, 3348, 1859, 1508, 3150, 2293, 3236, 2506, 1834, 1454, 2714, 3161, 2668, 3601, 891, 1841, 998, 1595, 3211, 3361, 1278, 766, 1465, 1709, 2411, 2175, 1764, 1646, 3115, 2239, 3173, 2830, 2455, 2484, 1737, 511, 2674, 3266, 1485, 1404, 2619, 2513, 1693, 1866, 2729, 2294, 2755, 3394, 1952, 1491, 988, 1657, 1752, 1807, 2398, 3132, 2647, 2716, 3596, 2838, 1399, 1844, 3213, 3368, 2508, 3171, 1001, 951, 1654, 1926, 3248, 2297, 2730, 3712, 1707, 1391, 2621, 3219, 2459, 2851, 1002, 1468, 3164, 2837, 3352, 2757, 2413, 2488, 1836, 1494, 1873, 1271, 2676, 2737, 1694, 893, 2422, 3272, 1923, 1461, 2471, 3604, 1748, 1715, 2514, 2841, 975, 1862, 894, 1815, 3178, 2298, 2419, 3222, 1497, 1653, 2529, 2622, 3396, 2461, 3157, 2651, 2414, 3593, 1510, 1762, 3335, 3103, 2516, 3618, 1842, 1375, 2703, 2948, 2853, 2663, 3214, 2732, 1703, 1009, 3457, 2758, 1466, 1874, 3235, 2477, 955, 1739, 2842, 2300, 3162, 2421, 2653, 3280, 2896, 2738, 1486, 1930, 2761, 2680, 1889, 1004, 1658, 1821, 1718, 1929, 3364, 2530, 2854, 3180, 1599, 1507, 3131, 2475, 1776, 1405, 3225, 2952, 3617, 2462, 1735, 1831, 3339, 2271, 3174, 3602, 1493, 1010, 2711, 2740, 2883, 3376, 1984, 1455, 2667, 2520, 957, 1865, 3185, 2503, 2844, 3237, 3649, 2857, 2762, 3296, 2769, 2885, 2764, 3134, 983, 1710, 3350, 3400, 958, 1514, 2912, 2858, 3221, 2654, 1876, 1768, 3242, 2960, 1721, 1938, 3151, 2770, 2744, 2425, 1660, 1500, 1403, 1892, 3472, 2483, 1819, 1741, 1516, 987, 3341, 3608, 1932, 1463, 2865, 3177, 3840, 2367, 1012, 1843, 2669, 3228, 1749, 999, 2860, 2532, 3393, 2478, 3620, 3186, 3347, 2886, 2715, 3267, 1838, 1277, 2536, 3159, 2287, 2426, 2507, 2670, 3458, 2675, 1647, 1925, 2485, 2428, 1498, 1742, 3249, 3656, 2866, 3226, 1513, 1880, 1717, 1016, 1953, 1837, 3342, 2509, 1867, 1631, 3591, 2544, 2717, 3238, 1469, 1747, 3365, 2727, 767, 1904, 1724, 1524, 3188, 3127, 989, 1406, 1754, 1822, 3269, 2772, 2889, 3353, 2677, 3632, 2399, 2515, 3408, 2486, 3163, 2785, 2299, 2510, 2490, 2489, 1835, 1499, 3714, 2517, 3597, 2295, 2731, 3244, 1944, 1863, 1890, 1467, 1003, 1522, 3274, 2890, 3460, 3175, 2786, 3192, 1763, 1695, 3356, 2947, 3650, 2718, 1850, 990, 1005, 1937, 3366, 2831, 3133, 2897, 1722, 1845, 3603, 3241, 1495, 1655, 2868, 3624, 2776, 2976, 2839, 2415, 1765, 1956, 3424, 2949, 1487, 1750, 3281, 2678, 1869, 1521, 3369, 2733, 2892, 3252, 2681, 2759, 959, 1896, 1263, 1940, 3166, 2301, 2739, 3349, 2872, 3223, 1770, 1877, 2950, 2734, 3716, 3270, 1509, 1711, 3464, 3181, 2788, 3395, 1756, 1846, 2898, 2423, 3606, 2492, 1011, 1960, 3354, 2518, 3215, 2531, 3595, 2463, 1784, 1870, 1662, 1013, 2533, 2953, 1985, 1753, 3250, 2843, 2521, 3288, 2682, 2792, 1927, 1528, 3664, 2900, 1849, 1882, 3008, 3370, 2913, 2741, 1766, 1511, 3179, 3842, 3398, 2845, 3273, 3652, 3619, 2954, 1954, 1719, 3300, 2763, 3189, 3378, 1777, 895, 2855, 2522, 2684, 3227, 2742, 2302, 1439, 1006, 3598, 3713, 1878, 1891, 2765, 3119, 3363, 2623, 2961, 3488, 2846, 2859, 2427, 3256, 1939, 1661, 3401, 3239, 1502, 1986, 2745, 3612, 1852, 1934, 2479, 3190, 2655, 3276, 2537, 3372, 1723, 1772, 2914, 2771, 1515, 1897, 2534, 3621, 3229, 3282, 2956, 3841, 3609, 2766, 1014, 1470, 2861, 3412, 1743, 1931, 2524, 2904, 3165, 3459, 2887, 3377, 3343, 3194, 2773, 2746, 3520, 2962, 1017, 1968, 3297, 2800, 2916, 2867, 3397, 2862, 2487, 2977, 1881, 1894, 3245, 3626, 1769, 1517, 2538, 3187, 1778, 1941, 1823, 1659, 3728, 2671, 1992, 1875, 3680, 3384, 1755, 1501, 2719, 3246, 3410, 2787, 1018, 1900, 3651, 3605, 1725, 991, 3461, 2964, 3351, 2511, 3284, 2891, 3183, 2429, 3720, 3402, 2545, 3634, 2978, 2869, 2774, 3009, 3251, 3230, 1933, 1839, 2920, 3466, 2540, 3298, 3380, 2679, 1525, 1955, 1988, 1884, 1726, 1948, 3622, 3271, 2777, 3193, 3653, 2748, 1780, 1518, 3844, 2491, 1020, 1767, 1905, 1851, 3355, 2789, 1893, 1945, 3426, 3610, 3404, 3253, 2893, 3367, 2968, 2430, 3633, 2870, 3473, 2899, 3277, 2778, 3657, 2546, 1757, 1530, 2928, 3304, 2790, 2493, 3440, 2519, 1958, 1471, 1007, 2000, 2683, 3196, 3744, 2980, 3628, 2735, 1847, 1898, 3258, 3468, 3660, 3373, 1523, 1942, 3848, 2951, 3182, 2873, 1961, 1871, 3283, 3409, 1771, 1529, 2548, 3625, 2894, 3718, 3243, 2793, 1912, 1758, 2874, 2780, 1989, 1946, 3312, 2494, 3010, 3474, 3668, 2984, 3425, 2523, 1526, 1906, 2901, 3358, 2915, 2685, 3599, 3278, 1883, 1773, 3462, 2955, 3254, 3715, 3636, 3381, 2535, 3856, 1957, 1853, 2743, 3489, 3135, 2794, 1976, 1015, 2876, 2801, 3658, 2902, 3285, 3374, 1751, 1993, 1503, 1962, 2905, 3416, 3257, 2552, 2847, 3403, 2303, 3012, 1781, 1885, 3290, 2957, 1908, 2016, 3721, 3607, 3357, 2767, 3191, 2525, 3665, 2963, 3496, 3428, 2686, 2796, 1854, 1532, 2992, 3776, 3379, 3275, 2917, 3640, 3476, 2539, 2747, 3301, 1972, 1774, 3399, 2802, 1019, 1895, 3231, 3613, 2906, 3666, 3465, 3524, 2526, 3016, 3308, 2431, 1987, 1969, 3260, 2958, 3849, 2863, 3627, 3024, 1782, 1279, 2918, 3732, 3681, 2965, 1943, 1899, 3385, 3289, 1994, 1663, 3654, 3872, 2775, 3198, 3490, 2541, 3405, 3299, 1964, 1785, 3724, 2921, 1021, 1935, 3432, 2749, 3614, 2979, 3371, 3846, 3413, 3521, 2804, 3382, 2908, 2547, 2779, 3696, 3286, 2871, 3623, 2970, 3247, 3722, 1886, 2001, 2922, 3480, 3469, 2966, 1407, 1779, 1990, 1970, 3684, 3302, 2550, 3843, 1879, 1022, 2981, 3414, 1902, 1947, 3386, 3730, 3635, 3259, 3536, 2791, 3406, 2808, 3292, 3629, 2929, 3195, 2542, 3427, 3320, 2750, 2969, 3672, 2549, 2924, 1759, 1907, 3463, 2895, 3904, 3492, 3040, 3745, 1527, 1996, 1786, 1959, 2495, 3655, 3484, 3417, 2002, 1913, 3305, 3752, 1949, 2017, 2781, 3845, 1534, 1788, 3717, 3388, 3279, 2875, 3638, 2982, 3682, 3522, 2930, 2985, 3011, 3467, 2795, 3313, 3167, 2553, 3429, 2903, 2972, 3858, 1910, 1965, 2782, 2877, 3611, 3261, 3659, 3411, 2004, 1901, 3478, 3306, 3736, 3434, 3013, 3662, 3778, 3287, 1966, 1775, 2986, 2932, 2008, 1531, 2554, 3375, 3637, 3852, 1971, 1950, 2797, 3418, 3688, 2993, 3014, 3504, 3729, 2803, 3314, 2907, 1909, 1991, 3475, 3641, 3436, 2988, 3262, 2878, 3857, 2959, 3669, 3630, 3880, 2919, 2018, 1727, 2687, 3528, 3746, 3383, 2936, 3420, 3293, 2527, 3470, 3316, 1916, 1855, 1974, 1995, 2994, 3780, 3725, 2798, 3850, 3674, 3441, 3017, 2020, 1977, 2556, 3661, 2909, 3494, 3905, 3387, 2805, 3430, 3018, 3748, 3291, 2967, 1787, 1914, 3642, 3481, 3874, 3552, 2923, 3683, 3307, 2910, 2005, 1887, 3968, 3723, 1023, 1963, 3493, 2806, 3197, 2996, 3407, 3864, 3644, 3719, 3760, 3025, 3433, 2971, 3670, 3020, 3482, 3359, 1998, 1783, 3777, 2809, 3444, 2925, 2024, 1980, 3255, 3523, 3497, 3860, 3000, 3734, 2543, 3310, 1903, 1973, 3692, 3667, 3389, 3477, 3873, 2751, 3419, 3686, 3615, 3784, 2983, 3733, 3026, 3673, 2931, 2810, 3294, 2551, 3506, 2973, 3442, 3317, 2003, 1789, 2926, 3526, 2783, 3847, 1997, 2032, 3726, 3908, 1978, 1917, 3491, 3685, 2010, 1519, 3529, 3421, 3747, 3303, 3041, 3639, 3876, 3500, 2933, 2987, 3042, 3448, 3792, 3704, 3028, 3737, 2974, 2812, 3318, 2989, 3676, 3415, 3853, 3505, 2019, 2006, 3969, 3631, 3435, 3690, 1951, 1911, 3015, 3315, 3532, 3498, 2021, 2009, 2934, 2879, 3731, 3390, 3859, 2995, 3753, 3479, 2555, 3309, 3888, 2937, 3698, 3032, 3808, 3538, 3663, 2799, 1790, 2026, 3750, 2990, 3906, 3471, 3508, 3431, 3044, 3740, 3689, 3862, 3019, 3525, 1975, 2012, 3321, 3560, 3781, 2938, 3646, 3422, 1967, 1915, 2557, 3854, 3970, 3697, 2997, 3021, 3445, 3537, 3756, 3675, 3048, 3738, 2940, 3322, 3486, 3865, 3438, 3512, 2025, 2022, 3916, 2998, 3199, 3779, 3554, 3875, 3645, 2911, 1981, 1918, 2033, 1999, 3499, 2807, 3912, 3762, 3749, 3443, 3851, 3056, 3671, 3530, 3324, 2558, 3483, 3700, 3027, 3540, 3001, 3976, 3877, 3437, 3786, 2811, 2028, 1533, 3920, 3022, 3501, 3691, 3761, 3866, 3263, 3450, 3677, 3568, 3878, 3739, 3002, 3507, 3782, 2927, 3029, 3553, 2011, 1982, 3754, 3030, 3972, 2975, 3881, 3687, 3495, 3794, 2034, 1979, 3391, 3727, 3868, 3809, 3527, 3323, 3043, 3788, 3449, 3936, 2813, 3004, 3544, 3909, 2935, 3485, 3033, 3768, 3045, 3678, 3861, 3510, 2023, 2013, 3446, 3693, 2036, 2007, 3896, 3735, 3295, 3764, 3984, 3034, 3531, 3699, 3793, 2991, 3907, 3556, 3882, 3502, 2939, 3889, 3046, 3643, 3326, 2814, 3513, 3757, 3812, 3694, 2030, 2014, 3785, 2559, 3533, 3452, 3741, 3914, 2040, 1535, 4000, 3539, 3036, 3705, 3800, 3855, 3447, 3892, 3049, 2999, 3702, 3974, 3755, 3439, 3050, 3516, 3884, 3542, 3921, 3319, 3742, 2941, 3971, 3509, 3796, 3763, 2027, 2029, 3023, 3910, 2942, 3863, 2035, 2037, 3545, 3701, 3558, 3810, 3890, 3423, 3751, 3057, 3514, 3922, 3003, 3787, 3534, 3978, 3937, 3052, 3706, 3869, 3766, 3977, 1791, 2038, 3647, 3555, 3824, 3453, 3783, 3879, 3541, 3058, 4032, 3503, 3005, 3913, 3031, 3758, 3006, 3562, 3924, 3816, 2041, 1919, 3769, 3986, 3708, 3548, 3451, 3940, 3867, 3789, 3564, 3035, 3980, 3511, 3060, 3891, 3797, 3047, 3886, 3325, 3695, 3973, 3546, 3790, 3561, 3928, 3765, 3064, 4001, 3885, 3915, 3679, 3517, 3795, 2815, 3952, 3772, 3572, 3037, 3454, 3802, 3870, 2042, 2039, 3883, 3547, 3992, 3911, 3938, 3515, 3051, 3570, 3811, 3743, 3898, 3038, 3053, 3985, 3770, 3893, 3543, 3703, 3813, 4004, 3535, 3798, 3917, 3569, 2044, 2043, 3007, 3944, 3311, 3988, 3818, 3925, 3557, 3759, 3804, 3894, 3059, 4008, 3832, 3918, 3710, 3061, 4033, 3801, 3975, 3576, 3897, 3930, 2031, 1983, 3814, 3559, 4002, 3767, 3825, 2943, 3487, 3054, 3926, 3939, 3987, 3709, 3550, 4034, 3900, 3982, 2046, 2047, 3771, 3820, 3563, 3945, 3062, 3518, 3791, 3979, 3065, 4016, 3929, 3942, 3817, 3565, 3826, 3989, 3871, 3707, 4040, 3923, 3803, 3549, 3066, 3948, 3773, 3039, 3981, 3887, 3573, 4003, 4036, 3932, 3774, 3996, 3828, 3566, 3068, 3815, 3953, 3899, 3941, 3993, 3805, 3578, 4006, 3519, 3055, 4048, 3895, 3946, 3571, 3990, 4009, 3919, 3819, 3577, 3960, 3806, 4037, 3994, 3574, 3954, 3931, 3821, 4005, 3901, 4024, 3063, 3799, 4041, 3551, 4010, 3829, 3933, 3956, 4064, 2015, 2045, 3902, 3580, 4020, 3822, 3067, 3943, 4035, 4017, 3830, 3327, 3991, 3947, 4042, 3711, 4012, 3833, 3069, 3983, 3934, 4049, 3455, 3827, 4038, 4018, 3927, 3070, 3950, 3995, 3807, 3955, 3575, 4044, 3834, 4007, 4050, 3961, 3997, 4065, 3582, 3836, 3958, 4013, 4052, 3949, 4014, 3823, 4056, 3579, 4019, 3998, 3957, 4039, 4066, 3775, 3964, 3903, 4022, 4043, 4068, 4025, 3835, 3962, 4053, 3935, 3071, 4011, 4046, 3831, 4072, 4028, 3951, 4021, 4051, 3837, 4045, 4080, 4026, 3965, 4058, 3567, 4067, 4054, 3999, 3959, 4069, 4057, 3838, 4074, 4023, 4060, 4015, 3963, 4073, 4070, 4029, 3966, 4081, 4047, 4076, 3581, 4059, 4030, 4082, 4027, 4071, 4061, 4084, 4055, 4078, 4062, 4088, 3583, 4075, 4077, 4083, 4085, 3839, 4086, 4089, 3967, 4090, 4087, 4092, 4091, 4079, 4031, 4094, 4095, 4063, 4093]

### Sequence Group 8: Q8_4096

[0, 1, 2, 4, 8, 16, 32, 3, 5, 64, 9, 6, 17, 10, 18, 128, 12, 33, 65, 20, 256, 34, 24, 36, 7, 129, 66, 512, 11, 40, 68, 130, 19, 13, 48, 14, 72, 257, 21, 132, 35, 258, 26, 513, 80, 37, 25, 22, 136, 260, 264, 38, 514, 96, 67, 41, 144, 28, 69, 42, 516, 49, 74, 272, 160, 1026, 520, 288, 528, 192, 544, 70, 44, 131, 81, 50, 73, 15, 320, 133, 52, 23, 134, 384, 76, 137, 82, 56, 27, 97, 39, 259, 84, 138, 145, 261, 29, 43, 98, 515, 88, 140, 30, 146, 1028, 71, 262, 265, 161, 576, 45, 100, 640, 1025, 51, 148, 46, 75, 266, 273, 517, 104, 162, 53, 193, 1032, 152, 77, 164, 768, 2048, 2049, 268, 274, 518, 54, 83, 57, 521, 112, 1024, 135, 78, 289, 194, 85, 276, 522, 58, 168, 139, 99, 86, 60, 280, 89, 290, 529, 524, 196, 141, 1040, 101, 147, 176, 142, 530, 321, 31, 200, 90, 1056, 545, 292, 322, 532, 263, 149, 102, 105, 304, 296, 1030, 163, 92, 1033, 47, 267, 385, 546, 324, 208, 386, 150, 153, 165, 106, 55, 328, 1088, 536, 577, 548, 1034, 113, 154, 79, 269, 2050, 2052, 108, 578, 224, 166, 519, 552, 195, 270, 1041, 641, 1036, 523, 275, 580, 291, 59, 2056, 2064, 169, 560, 114, 277, 156, 87, 1152, 197, 116, 170, 61, 1042, 531, 525, 642, 281, 278, 526, 177, 293, 388, 1057, 2080, 2051, 91, 584, 769, 198, 172, 120, 201, 336, 62, 282, 143, 1029, 1044, 103, 178, 294, 93, 1058, 644, 202, 592, 323, 392, 297, 2053, 2112, 770, 107, 180, 1280, 151, 209, 284, 1027, 648, 94, 204, 298, 400, 608, 1089, 352, 325, 533, 155, 210, 305, 547, 300, 109, 1048, 184, 534, 1060, 537, 115, 1090, 167, 225, 326, 306, 772, 157, 656, 329, 110, 2057, 2054, 117, 212, 171, 1038, 776, 1064, 330, 1153, 226, 549, 1043, 538, 387, 308, 216, 416, 271, 279, 2065, 2058, 158, 337, 550, 672, 1092, 118, 332, 579, 540, 1072, 389, 173, 1037, 121, 553, 199, 784, 179, 228, 338, 2066, 2176, 312, 1536, 704, 1154, 2060, 2081, 390, 174, 554, 581, 1046, 393, 283, 122, 448, 353, 561, 1096, 203, 63, 340, 394, 1049, 1281, 527, 582, 556, 181, 295, 1059, 285, 232, 2113, 2068, 124, 205, 182, 643, 1156, 562, 2304, 2082, 286, 585, 299, 354, 1045, 211, 401, 1104, 185, 1061, 396, 344, 586, 645, 1282, 593, 535, 240, 1050, 206, 95, 327, 564, 800, 2072, 2084, 402, 356, 2055, 2177, 307, 301, 417, 1160, 213, 1066, 568, 1120, 832, 588, 1035, 1537, 186, 646, 404, 1091, 227, 896, 594, 418, 302, 649, 2114, 2560, 771, 360, 539, 111, 1052, 331, 1168, 214, 2059, 2088, 309, 1062, 1284, 188, 449, 1073, 217, 408, 609, 596, 551, 650, 229, 159, 420, 310, 1093, 541, 2116, 2178, 1288, 773, 610, 657, 333, 1065, 119, 1098, 600, 339, 1184, 218, 368, 652, 1031, 230, 391, 313, 450, 542, 1538, 334, 2067, 2061, 2096, 2062, 1076, 233, 555, 774, 175, 123, 1155, 658, 2120, 2305, 612, 341, 777, 220, 314, 1105, 424, 1068, 395, 673, 583, 355, 1296, 1094, 287, 183, 234, 1051, 2069, 2180, 125, 557, 1216, 660, 616, 342, 2083, 2306, 316, 1157, 241, 778, 563, 1074, 345, 452, 397, 403, 1112, 207, 2074, 2561, 1540, 674, 558, 785, 1100, 432, 1039, 357, 187, 1162, 236, 664, 1312, 624, 587, 780, 1080, 1122, 2128, 2085, 705, 126, 242, 1063, 2073, 2070, 565, 398, 346, 456, 2184, 2308, 358, 405, 303, 569, 1544, 244, 1158, 1097, 595, 1283, 189, 566, 676, 1169, 1054, 1108, 361, 706, 589, 1344, 215, 786, 647, 348, 2312, 2086, 419, 406, 2562, 2144, 464, 680, 2115, 2089, 801, 1069, 362, 1164, 2192, 2076, 590, 409, 1286, 570, 1121, 788, 1552, 1106, 597, 1075, 572, 1186, 219, 311, 708, 598, 1289, 601, 651, 421, 792, 802, 2117, 2090, 611, 1047, 602, 1172, 410, 231, 688, 653, 2564, 2097, 1128, 248, 1070, 369, 2122, 2320, 190, 364, 1568, 654, 1095, 659, 1161, 335, 480, 315, 221, 370, 1285, 613, 1408, 422, 2208, 3074, 425, 451, 2568, 2336, 1077, 614, 543, 1298, 235, 412, 343, 372, 2576, 2240, 1185, 775, 317, 1539, 222, 1099, 426, 453, 237, 1124, 559, 1170, 2592, 2118, 1292, 833, 804, 712, 1082, 834, 661, 1053, 2092, 2179, 2129, 2098, 808, 779, 1217, 617, 604, 1541, 433, 720, 816, 1101, 2121, 2063, 1176, 836, 347, 897, 1136, 243, 1297, 662, 1600, 454, 318, 675, 2368, 2181, 1110, 618, 1081, 898, 781, 1314, 1220, 376, 428, 1546, 2100, 2071, 665, 736, 567, 1107, 2182, 2432, 1192, 1078, 2124, 2185, 840, 625, 238, 1159, 359, 457, 399, 787, 2130, 2104, 591, 678, 434, 677, 1290, 1542, 2075, 2145, 349, 1300, 1102, 245, 1188, 458, 666, 1113, 620, 1553, 1163, 1313, 363, 127, 1067, 191, 1125, 782, 407, 436, 2087, 2307, 626, 1218, 2132, 2186, 571, 465, 2193, 2309, 681, 246, 707, 1346, 2077, 2091, 2146, 2563, 350, 1084, 599, 668, 1548, 790, 2136, 2188, 1165, 1320, 460, 1123, 1200, 249, 682, 1664, 573, 1171, 411, 803, 1116, 789, 1304, 709, 365, 440, 628, 689, 2078, 2194, 374, 1224, 3076, 2119, 423, 1556, 466, 793, 2310, 2313, 2209, 2624, 1130, 250, 371, 1174, 2093, 2148, 481, 574, 1348, 413, 1109, 603, 366, 1545, 1287, 1055, 468, 1570, 655, 900, 805, 615, 1166, 684, 1409, 710, 2688, 3073, 1187, 429, 2099, 2196, 794, 252, 1114, 373, 605, 1232, 848, 690, 2094, 2123, 713, 632, 2314, 2321, 1316, 482, 806, 1132, 2565, 2152, 1083, 427, 1177, 904, 1569, 414, 2210, 2101, 1291, 223, 1126, 1554, 663, 692, 835, 1328, 619, 472, 2241, 3080, 1137, 455, 2200, 2125, 796, 1189, 1601, 809, 714, 1248, 721, 837, 716, 1086, 2212, 2816, 1302, 1352, 864, 810, 1173, 606, 1194, 912, 1103, 722, 696, 377, 2316, 2322, 1424, 435, 2566, 2102, 1293, 1560, 817, 1129, 1792, 319, 621, 1180, 2131, 2105, 2569, 2160, 812, 484, 1345, 430, 1572, 1138, 3072, 2183, 1299, 838, 667, 1219, 2126, 2337, 488, 1111, 239, 378, 459, 622, 1410, 627, 2242, 2133, 437, 380, 1201, 1608, 818, 1178, 2324, 2570, 1294, 461, 1543, 496, 669, 1190, 1317, 679, 2106, 2216, 1140, 1079, 2187, 2147, 1221, 724, 841, 1305, 629, 1584, 2134, 2108, 351, 467, 2328, 2137, 1360, 438, 1115, 737, 2338, 2577, 251, 462, 442, 441, 2572, 2244, 1666, 469, 1549, 247, 683, 1196, 2189, 3088, 2149, 2195, 1226, 842, 1412, 1127, 738, 1144, 2224, 2190, 1308, 899, 1602, 670, 1318, 783, 1085, 849, 1555, 1193, 820, 1576, 728, 928, 791, 367, 2578, 2369, 1376, 901, 2079, 2248, 2138, 3104, 1233, 630, 2593, 2340, 1321, 685, 844, 1204, 633, 711, 2370, 2580, 2311, 2197, 2150, 2153, 1118, 253, 691, 1301, 824, 1175, 2352, 2344, 902, 686, 1668, 1222, 1416, 1133, 740, 1347, 850, 375, 1558, 444, 1306, 470, 1167, 483, 1547, 415, 3078, 2211, 485, 905, 2140, 3081, 1202, 795, 473, 1240, 2095, 2315, 634, 744, 2433, 2594, 1616, 852, 2372, 2256, 2434, 2198, 960, 1322, 2201, 2213, 865, 693, 2154, 2103, 1131, 1794, 1350, 797, 1225, 1604, 1571, 906, 2376, 3136, 1252, 715, 1141, 1330, 807, 474, 636, 1179, 694, 254, 1550, 1665, 2584, 2625, 717, 1071, 2596, 3082, 1315, 575, 913, 1440, 798, 811, 379, 1208, 2161, 2202, 1353, 1191, 2127, 2317, 697, 1564, 431, 1142, 607, 1228, 2156, 2626, 489, 1324, 2272, 2214, 866, 723, 2567, 2600, 486, 1573, 1181, 1234, 908, 1793, 1561, 718, 813, 1364, 2243, 2318, 476, 856, 3089, 2689, 1117, 1411, 839, 1329, 1295, 1146, 3084, 2571, 725, 698, 1472, 914, 2323, 2628, 1249, 752, 868, 819, 1349, 814, 439, 929, 2339, 2107, 1197, 1578, 490, 1139, 2217, 2608, 1680, 623, 2162, 2325, 1632, 1336, 671, 1198, 1362, 739, 2204, 2135, 1603, 1557, 3200, 2245, 2164, 2218, 1413, 916, 1303, 463, 1236, 843, 2109, 3090, 1135, 381, 1672, 1354, 2579, 2573, 497, 1586, 930, 821, 2690, 2329, 726, 961, 1203, 1182, 2326, 2574, 872, 1418, 492, 1250, 1332, 631, 2225, 2341, 2436, 3105, 1574, 1223, 729, 1145, 1605, 700, 2139, 2632, 1796, 443, 2817, 2246, 1307, 741, 2220, 2168, 1378, 1562, 1356, 1205, 845, 1319, 2249, 2384, 920, 382, 2110, 2330, 1585, 822, 1425, 851, 2191, 3077, 3092, 2151, 1229, 730, 1609, 498, 2226, 2342, 880, 1256, 742, 445, 1392, 471, 2141, 3106, 2692, 2250, 2640, 2371, 635, 1148, 1696, 932, 1580, 687, 2440, 2345, 1210, 1420, 1612, 1325, 1800, 903, 1134, 825, 1235, 1361, 500, 1577, 846, 1670, 1195, 745, 2818, 2155, 2228, 3328, 826, 732, 2199, 2257, 2332, 3075, 1264, 446, 2696, 2142, 962, 1426, 1620, 936, 2252, 2346, 1377, 475, 2448, 2656, 3137, 2400, 2373, 2581, 853, 1310, 867, 637, 2203, 2258, 1551, 1230, 2353, 2595, 1414, 907, 1206, 1667, 1588, 1333, 487, 1808, 2348, 2157, 695, 1441, 1087, 746, 828, 753, 1610, 854, 1237, 1326, 3096, 2232, 857, 1368, 2582, 3108, 1209, 504, 799, 1355, 2585, 2163, 255, 964, 3138, 2215, 2273, 2374, 1242, 909, 2354, 2820, 2205, 2704, 1673, 1559, 1309, 719, 2377, 2158, 1143, 477, 2165, 2260, 1617, 915, 1448, 1380, 2219, 3086, 638, 748, 2824, 3112, 944, 1728, 1331, 1227, 869, 1592, 1428, 491, 699, 1253, 1351, 754, 2378, 3201, 1183, 1565, 2274, 2597, 858, 1618, 1417, 1476, 3091, 2586, 478, 968, 1260, 383, 2435, 2356, 1212, 910, 1801, 815, 2264, 2464, 1579, 976, 2319, 2327, 870, 1684, 1633, 917, 2206, 2385, 2598, 2720, 3140, 2166, 1337, 1241, 2380, 2627, 1606, 1824, 727, 1150, 1442, 493, 1357, 1251, 2588, 3120, 1676, 873, 2437, 2221, 1384, 701, 3085, 2169, 1566, 931, 1323, 1798, 1365, 1473, 2601, 2247, 756, 1334, 860, 499, 2832, 2227, 731, 1648, 1238, 823, 1575, 922, 1199, 1674, 2276, 2386, 874, 1432, 1421, 918, 2360, 3584, 2752, 3202, 1636, 1254, 2438, 2222, 502, 1795, 2602, 2629, 933, 1366, 3094, 2441, 1338, 1682, 2331, 2170, 2496, 2401, 1587, 1211, 1488, 743, 1358, 760, 2609, 3144, 1244, 1581, 881, 1147, 2251, 2111, 494, 1379, 1272, 702, 2388, 2442, 3097, 3329, 921, 1624, 501, 876, 2575, 2630, 1415, 847, 1856, 1444, 992, 1697, 2604, 2229, 2343, 3107, 2333, 2280, 447, 1607, 1436, 1369, 2172, 2253, 1257, 1704, 2230, 2691, 733, 1797, 3204, 2610, 1669, 1340, 1231, 827, 1590, 934, 2334, 2633, 1634, 1474, 2347, 2402, 3093, 2259, 882, 937, 2449, 3152, 2233, 3109, 963, 1419, 747, 1265, 2444, 2392, 1119, 505, 1381, 855, 2634, 2693, 924, 1810, 3330, 2641, 2583, 2288, 3098, 2254, 734, 829, 1563, 1213, 2143, 2375, 1611, 1363, 2612, 2848, 1430, 1258, 1688, 1386, 965, 1614, 1730, 1239, 2450, 2404, 938, 884, 506, 1327, 1589, 1804, 2355, 2349, 2465, 3208, 749, 1370, 2261, 3114, 2616, 3168, 1640, 945, 2880, 2636, 966, 1456, 1681, 755, 3083, 3585, 2234, 2694, 1266, 859, 2452, 3139, 2275, 2944, 2642, 2466, 1427, 1593, 1388, 940, 2350, 2697, 1214, 830, 2819, 2408, 1809, 911, 1621, 1582, 2587, 2159, 1832, 871, 3100, 2379, 639, 1480, 1698, 1335, 888, 1372, 1245, 479, 1422, 1268, 3216, 2262, 946, 1732, 2357, 3110, 1677, 750, 1802, 1626, 3332, 2236, 2497, 3121, 1393, 969, 2265, 2456, 2657, 2644, 508, 1613, 2599, 2698, 2277, 2207, 861, 1446, 2468, 2358, 1857, 1339, 3141, 2589, 757, 1382, 3336, 2821, 970, 1700, 2658, 2705, 2381, 3113, 1243, 919, 2167, 3146, 1594, 1433, 1826, 1504, 875, 1635, 1259, 862, 2648, 2387, 1920, 1675, 3232, 2266, 1445, 758, 2416, 2700, 1149, 948, 1359, 1816, 3079, 2278, 1596, 1671, 1712, 977, 2439, 2361, 1385, 923, 1622, 972, 2498, 2590, 1434, 1311, 3586, 2382, 1729, 761, 1396, 877, 3124, 2281, 2603, 2822, 2223, 2171, 3203, 2706, 1207, 1475, 2660, 2389, 1449, 1812, 952, 1686, 2825, 2268, 495, 1262, 2362, 3153, 1644, 1619, 2472, 3116, 1341, 1429, 2443, 2721, 1825, 703, 1371, 1638, 1567, 1736, 2631, 2403, 935, 1685, 978, 1625, 3344, 3142, 883, 762, 1246, 503, 2335, 2231, 1458, 925, 1394, 1269, 2282, 3099, 878, 1478, 735, 1799, 2173, 2605, 3264, 2708, 2664, 2390, 1678, 1860, 2364, 3205, 2289, 2826, 2611, 3122, 1443, 1637, 2393, 2500, 1481, 1373, 2445, 2451, 3160, 2255, 1699, 1255, 993, 1591, 1828, 1452, 3588, 2722, 885, 939, 994, 1400, 2606, 2833, 3148, 2480, 1744, 1656, 3087, 2405, 2235, 3210, 980, 1689, 926, 764, 2284, 2712, 1270, 941, 1628, 1367, 1805, 1457, 3360, 2672, 2635, 2828, 3128, 3170, 1921, 1583, 2753, 2174, 1387, 1642, 2290, 3111, 967, 1267, 2613, 2446, 1484, 1450, 2394, 2504, 886, 831, 1683, 1342, 1811, 947, 2406, 2453, 2351, 2617, 3592, 2292, 1705, 1431, 3206, 3145, 2643, 3331, 507, 1261, 1840, 889, 2237, 2614, 1650, 984, 1760, 1490, 2724, 3217, 3102, 3156, 1615, 751, 2409, 2754, 2637, 3392, 2263, 2834, 1702, 942, 1858, 1423, 2695, 2396, 1460, 1383, 2467, 2454, 996, 1692, 1641, 1814, 971, 1477, 2512, 2728, 1273, 1512, 1733, 890, 1598, 1374, 2849, 3117, 2410, 3212, 509, 1806, 2638, 2457, 3334, 2618, 1922, 1649, 3169, 2836, 3600, 3154, 949, 973, 2645, 3123, 2620, 3234, 1397, 1489, 2267, 2359, 2756, 2646, 3337, 2649, 1708, 1627, 2699, 2469, 1000, 1690, 2840, 2850, 892, 1274, 2659, 3095, 1438, 1817, 2650, 3220, 2458, 2279, 1390, 1464, 2736, 2701, 1868, 950, 1151, 1731, 1506, 1827, 1597, 863, 3176, 2296, 3118, 2417, 1451, 759, 2238, 2412, 1864, 1714, 3616, 2702, 3143, 2707, 1701, 1395, 3209, 2383, 2528, 2363, 1803, 1008, 2269, 2418, 3333, 2661, 1623, 1482, 3456, 2470, 1276, 510, 2473, 2499, 1435, 1652, 3125, 2662, 2591, 3346, 2283, 2460, 2391, 2420, 979, 1492, 3233, 2823, 953, 1928, 1829, 1389, 2365, 3587, 1738, 763, 2270, 3147, 1872, 974, 2474, 2501, 1453, 1643, 2285, 3172, 1713, 1818, 1215, 1402, 2607, 3218, 1629, 1520, 1830, 1691, 3340, 2881, 954, 1459, 1734, 879, 2852, 2760, 3130, 2882, 981, 1505, 2709, 3101, 1706, 982, 2856, 2827, 3265, 2665, 2652, 3589, 2481, 2768, 2864, 3149, 1924, 927, 3224, 2884, 1833, 1639, 2395, 2945, 3184, 2291, 1447, 1746, 3345, 2710, 1343, 1679, 3648, 2502, 2366, 2723, 1820, 1761, 1479, 1275, 995, 1740, 3158, 2666, 1401, 1888, 765, 956, 3129, 2946, 2829, 3362, 1496, 1861, 3268, 2424, 887, 1437, 985, 1720, 2476, 3594, 997, 1630, 1813, 1462, 2713, 2784, 2615, 3155, 3240, 3126, 1398, 1645, 2888, 2673, 2286, 3207, 2407, 2505, 2447, 2835, 1848, 1687, 2639, 2726, 1247, 1716, 2482, 2725, 3338, 3590, 1936, 986, 1483, 1651, 1745, 943, 2397, 3348, 1859, 1508, 3150, 2293, 3236, 2506, 1834, 1454, 2714, 3161, 2668, 3601, 891, 1841, 998, 1595, 3211, 3361, 1278, 766, 1465, 1709, 2411, 2175, 1764, 1646, 3115, 2239, 3173, 2830, 2455, 2484, 1737, 511, 2674, 3266, 1485, 1404, 2619, 2513, 1693, 1866, 2729, 2294, 2755, 3394, 1952, 1491, 988, 1657, 1752, 1807, 2398, 3132, 2647, 2716, 3596, 2838, 1399, 1844, 3213, 3368, 2508, 3171, 1001, 951, 1654, 1926, 3248, 2297, 2730, 3712, 1707, 1391, 2621, 3219, 2459, 2851, 1002, 1468, 3164, 2837, 3352, 2757, 2413, 2488, 1836, 1494, 1873, 1271, 2676, 2737, 1694, 893, 2422, 3272, 1923, 1461, 2471, 3604, 1748, 1715, 2514, 2841, 975, 1862, 894, 1815, 3178, 2298, 2419, 3222, 1497, 1653, 2529, 2622, 3396, 2461, 3157, 2651, 2414, 3593, 1510, 1762, 3335, 3103, 2516, 3618, 1842, 1375, 2703, 2948, 2853, 2663, 3214, 2732, 1703, 1009, 3457, 2758, 1466, 1874, 3235, 2477, 955, 1739, 2842, 2300, 3162, 2421, 2653, 3280, 2896, 2738, 1486, 1930, 2761, 2680, 1889, 1004, 1658, 1821, 1718, 1929, 3364, 2530, 2854, 3180, 1599, 1507, 3131, 2475, 1776, 1405, 3225, 2952, 3617, 2462, 1735, 1831, 3339, 2271, 3174, 3602, 1493, 1010, 2711, 2740, 2883, 3376, 1984, 1455, 2667, 2520, 957, 1865, 3185, 2503, 2844, 3237, 3649, 2857, 2762, 3296, 2769, 2885, 2764, 3134, 983, 1710, 3350, 3400, 958, 1514, 2912, 2858, 3221, 2654, 1876, 1768, 3242, 2960, 1721, 1938, 3151, 2770, 2744, 2425, 1660, 1500, 1403, 1892, 3472, 2483, 1819, 1741, 1516, 987, 3341, 3608, 1932, 1463, 2865, 3177, 3840, 2367, 1012, 1843, 2669, 3228, 1749, 999, 2860, 2532, 3393, 2478, 3620, 3186, 3347, 2886, 2715, 3267, 1838, 1277, 2536, 3159, 2287, 2426, 2507, 2670, 3458, 2675, 1647, 1925, 2485, 2428, 1498, 1742, 3249, 3656, 2866, 3226, 1513, 1880, 1717, 1016, 1953, 1837, 3342, 2509, 1867, 1631, 3591, 2544, 2717, 3238, 1469, 1747, 3365, 2727, 767, 1904, 1724, 1524, 3188, 3127, 989, 1406, 1754, 1822, 3269, 2772, 2889, 3353, 2677, 3632, 2399, 2515, 3408, 2486, 3163, 2785, 2299, 2510, 2490, 2489, 1835, 1499, 3714, 2517, 3597, 2295, 2731, 3244, 1944, 1863, 1890, 1467, 1003, 1522, 3274, 2890, 3460, 3175, 2786, 3192, 1763, 1695, 3356, 2947, 3650, 2718, 1850, 990, 1005, 1937, 3366, 2831, 3133, 2897, 1722, 1845, 3603, 3241, 1495, 1655, 2868, 3624, 2776, 2976, 2839, 2415, 1765, 1956, 3424, 2949, 1487, 1750, 3281, 2678, 1869, 1521, 3369, 2733, 2892, 3252, 2681, 2759, 959, 1896, 1263, 1940, 3166, 2301, 2739, 3349, 2872, 3223, 1770, 1877, 2950, 2734, 3716, 3270, 1509, 1711, 3464, 3181, 2788, 3395, 1756, 1846, 2898, 2423, 3606, 2492, 1011, 1960, 3354, 2518, 3215, 2531, 3595, 2463, 1784, 1870, 1662, 1013, 2533, 2953, 1985, 1753, 3250, 2843, 2521, 3288, 2682, 2792, 1927, 1528, 3664, 2900, 1849, 1882, 3008, 3370, 2913, 2741, 1766, 1511, 3179, 3842, 3398, 2845, 3273, 3652, 3619, 2954, 1954, 1719, 3300, 2763, 3189, 3378, 1777, 895, 2855, 2522, 2684, 3227, 2742, 2302, 1439, 1006, 3598, 3713, 1878, 1891, 2765, 3119, 3363, 2623, 2961, 3488, 2846, 2859, 2427, 3256, 1939, 1661, 3401, 3239, 1502, 1986, 2745, 3612, 1852, 1934, 2479, 3190, 2655, 3276, 2537, 3372, 1723, 1772, 2914, 2771, 1515, 1897, 2534, 3621, 3229, 3282, 2956, 3841, 3609, 2766, 1014, 1470, 2861, 3412, 1743, 1931, 2524, 2904, 3165, 3459, 2887, 3377, 3343, 3194, 2773, 2746, 3520, 2962, 1017, 1968, 3297, 2800, 2916, 2867, 3397, 2862, 2487, 2977, 1881, 1894, 3245, 3626, 1769, 1517, 2538, 3187, 1778, 1941, 1823, 1659, 3728, 2671, 1992, 1875, 3680, 3384, 1755, 1501, 2719, 3246, 3410, 2787, 1018, 1900, 3651, 3605, 1725, 991, 3461, 2964, 3351, 2511, 3284, 2891, 3183, 2429, 3720, 3402, 2545, 3634, 2978, 2869, 2774, 3009, 3251, 3230, 1933, 1839, 2920, 3466, 2540, 3298, 3380, 2679, 1525, 1955, 1988, 1884, 1726, 1948, 3622, 3271, 2777, 3193, 3653, 2748, 1780, 1518, 3844, 2491, 1020, 1767, 1905, 1851, 3355, 2789, 1893, 1945, 3426, 3610, 3404, 3253, 2893, 3367, 2968, 2430, 3633, 2870, 3473, 2899, 3277, 2778, 3657, 2546, 1757, 1530, 2928, 3304, 2790, 2493, 3440, 2519, 1958, 1471, 1007, 2000, 2683, 3196, 3744, 2980, 3628, 2735, 1847, 1898, 3258, 3468, 3660, 3373, 1523, 1942, 3848, 2951, 3182, 2873, 1961, 1871, 3283, 3409, 1771, 1529, 2548, 3625, 2894, 3718, 3243, 2793, 1912, 1758, 2874, 2780, 1989, 1946, 3312, 2494, 3010, 3474, 3668, 2984, 3425, 2523, 1526, 1906, 2901, 3358, 2915, 2685, 3599, 3278, 1883, 1773, 3462, 2955, 3254, 3715, 3636, 3381, 2535, 3856, 1957, 1853, 2743, 3489, 3135, 2794, 1976, 1015, 2876, 2801, 3658, 2902, 3285, 3374, 1751, 1993, 1503, 1962, 2905, 3416, 3257, 2552, 2847, 3403, 2303, 3012, 1781, 1885, 3290, 2957, 1908, 2016, 3721, 3607, 3357, 2767, 3191, 2525, 3665, 2963, 3496, 3428, 2686, 2796, 1854, 1532, 2992, 3776, 3379, 3275, 2917, 3640, 3476, 2539, 2747, 3301, 1972, 1774, 3399, 2802, 1019, 1895, 3231, 3613, 2906, 3666, 3465, 3524, 2526, 3016, 3308, 2431, 1987, 1969, 3260, 2958, 3849, 2863, 3627, 3024, 1782, 1279, 2918, 3732, 3681, 2965, 1943, 1899, 3385, 3289, 1994, 1663, 3654, 3872, 2775, 3198, 3490, 2541, 3405, 3299, 1964, 1785, 3724, 2921, 1021, 1935, 3432, 2749, 3614, 2979, 3371, 3846, 3413, 3521, 2804, 3382, 2908, 2547, 2779, 3696, 3286, 2871, 3623, 2970, 3247, 3722, 1886, 2001, 2922, 3480, 3469, 2966, 1407, 1779, 1990, 1970, 3684, 3302, 2550, 3843, 1879, 1022, 2981, 3414, 1902, 1947, 3386, 3730, 3635, 3259, 3536, 2791, 3406, 2808, 3292, 3629, 2929, 3195, 2542, 3427, 3320, 2750, 2969, 3672, 2549, 2924, 1759, 1907, 3463, 2895, 3904, 3492, 3040, 3745, 1527, 1996, 1786, 1959, 2495, 3655, 3484, 3417, 2002, 1913, 3305, 3752, 1949, 2017, 2781, 3845, 1534, 1788, 3717, 3388, 3279, 2875, 3638, 2982, 3682, 3522, 2930, 2985, 3011, 3467, 2795, 3313, 3167, 2553, 3429, 2903, 2972, 3858, 1910, 1965, 2782, 2877, 3611, 3261, 3659, 3411, 2004, 1901, 3478, 3306, 3736, 3434, 3013, 3662, 3778, 3287, 1966, 1775, 2986, 2932, 2008, 1531, 2554, 3375, 3637, 3852, 1971, 1950, 2797, 3418, 3688, 2993, 3014, 3504, 3729, 2803, 3314, 2907, 1909, 1991, 3475, 3641, 3436, 2988, 3262, 2878, 3857, 2959, 3669, 3630, 3880, 2919, 2018, 1727, 2687, 3528, 3746, 3383, 2936, 3420, 3293, 2527, 3470, 3316, 1916, 1855, 1974, 1995, 2994, 3780, 3725, 2798, 3850, 3674, 3441, 3017, 2020, 1977, 2556, 3661, 2909, 3494, 3905, 3387, 2805, 3430, 3018, 3748, 3291, 2967, 1787, 1914, 3642, 3481, 3874, 3552, 2923, 3683, 3307, 2910, 2005, 1887, 3968, 3723, 1023, 1963, 3493, 2806, 3197, 2996, 3407, 3864, 3644, 3719, 3760, 3025, 3433, 2971, 3670, 3020, 3482, 3359, 1998, 1783, 3777, 2809, 3444, 2925, 2024, 1980, 3255, 3523, 3497, 3860, 3000, 3734, 2543, 3310, 1903, 1973, 3692, 3667, 3389, 3477, 3873, 2751, 3419, 3686, 3615, 3784, 2983, 3733, 3026, 3673, 2931, 2810, 3294, 2551, 3506, 2973, 3442, 3317, 2003, 1789, 2926, 3526, 2783, 3847, 1997, 2032, 3726, 3908, 1978, 1917, 3491, 3685, 2010, 1519, 3529, 3421, 3747, 3303, 3041, 3639, 3876, 3500, 2933, 2987, 3042, 3448, 3792, 3704, 3028, 3737, 2974, 2812, 3318, 2989, 3676, 3415, 3853, 3505, 2019, 2006, 3969, 3631, 3435, 3690, 1951, 1911, 3015, 3315, 3532, 3498, 2021, 2009, 2934, 2879, 3731, 3390, 3859, 2995, 3753, 3479, 2555, 3309, 3888, 2937, 3698, 3032, 3808, 3538, 3663, 2799, 1790, 2026, 3750, 2990, 3906, 3471, 3508, 3431, 3044, 3740, 3689, 3862, 3019, 3525, 1975, 2012, 3321, 3560, 3781, 2938, 3646, 3422, 1967, 1915, 2557, 3854, 3970, 3697, 2997, 3021, 3445, 3537, 3756, 3675, 3048, 3738, 2940, 3322, 3486, 3865, 3438, 3512, 2025, 2022, 3916, 2998, 3199, 3779, 3554, 3875, 3645, 2911, 1981, 1918, 2033, 1999, 3499, 2807, 3912, 3762, 3749, 3443, 3851, 3056, 3671, 3530, 3324, 2558, 3483, 3700, 3027, 3540, 3001, 3976, 3877, 3437, 3786, 2811, 2028, 1533, 3920, 3022, 3501, 3691, 3761, 3866, 3263, 3450, 3677, 3568, 3878, 3739, 3002, 3507, 3782, 2927, 3029, 3553, 2011, 1982, 3754, 3030, 3972, 2975, 3881, 3687, 3495, 3794, 2034, 1979, 3391, 3727, 3868, 3809, 3527, 3323, 3043, 3788, 3449, 3936, 2813, 3004, 3544, 3909, 2935, 3485, 3033, 3768, 3045, 3678, 3861, 3510, 2023, 2013, 3446, 3693, 2036, 2007, 3896, 3735, 3295, 3764, 3984, 3034, 3531, 3699, 3793, 2991, 3907, 3556, 3882, 3502, 2939, 3889, 3046, 3643, 3326, 2814, 3513, 3757, 3812, 3694, 2030, 2014, 3785, 2559, 3533, 3452, 3741, 3914, 2040, 1535, 4000, 3539, 3036, 3705, 3800, 3855, 3447, 3892, 3049, 2999, 3702, 3974, 3755, 3439, 3050, 3516, 3884, 3542, 3921, 3319, 3742, 2941, 3971, 3509, 3796, 3763, 2027, 2029, 3023, 3910, 2942, 3863, 2035, 2037, 3545, 3701, 3558, 3810, 3890, 3423, 3751, 3057, 3514, 3922, 3003, 3787, 3534, 3978, 3937, 3052, 3706, 3869, 3766, 3977, 1791, 2038, 3647, 3555, 3824, 3453, 3783, 3879, 3541, 3058, 4032, 3503, 3005, 3913, 3031, 3758, 3006, 3562, 3924, 3816, 2041, 1919, 3769, 3986, 3708, 3548, 3451, 3940, 3867, 3789, 3564, 3035, 3980, 3511, 3060, 3891, 3797, 3047, 3886, 3325, 3695, 3973, 3546, 3790, 3561, 3928, 3765, 3064, 4001, 3885, 3915, 3679, 3517, 3795, 2815, 3952, 3772, 3572, 3037, 3454, 3802, 3870, 2042, 2039, 3883, 3547, 3992, 3911, 3938, 3515, 3051, 3570, 3811, 3743, 3898, 3038, 3053, 3985, 3770, 3893, 3543, 3703, 3813, 4004, 3535, 3798, 3917, 3569, 2044, 2043, 3007, 3944, 3311, 3988, 3818, 3925, 3557, 3759, 3804, 3894, 3059, 4008, 3832, 3918, 3710, 3061, 4033, 3801, 3975, 3576, 3897, 3930, 2031, 1983, 3814, 3559, 4002, 3767, 3825, 2943, 3487, 3054, 3926, 3939, 3987, 3709, 3550, 4034, 3900, 3982, 2046, 2047, 3771, 3820, 3563, 3945, 3062, 3518, 3791, 3979, 3065, 4016, 3929, 3942, 3817, 3565, 3826, 3989, 3871, 3707, 4040, 3923, 3803, 3549, 3066, 3948, 3773, 3039, 3981, 3887, 3573, 4003, 4036, 3932, 3774, 3996, 3828, 3566, 3068, 3815, 3953, 3899, 3941, 3993, 3805, 3578, 4006, 3519, 3055, 4048, 3895, 3946, 3571, 3990, 4009, 3919, 3819, 3577, 3960, 3806, 4037, 3994, 3574, 3954, 3931, 3821, 4005, 3901, 4024, 3063, 3799, 4041, 3551, 4010, 3829, 3933, 3956, 4064, 2015, 2045, 3902, 3580, 4020, 3822, 3067, 3943, 4035, 4017, 3830, 3327, 3991, 3947, 4042, 3711, 4012, 3833, 3069, 3983, 3934, 4049, 3455, 3827, 4038, 4018, 3927, 3070, 3950, 3995, 3807, 3955, 3575, 4044, 3834, 4007, 4050, 3961, 3997, 4065, 3582, 3836, 3958, 4013, 4052, 3949, 4014, 3823, 4056, 3579, 4019, 3998, 3957, 4039, 4066, 3775, 3964, 3903, 4022, 4043, 4068, 4025, 3835, 3962, 4053, 3935, 3071, 4011, 4046, 3831, 4072, 4028, 3951, 4021, 4051, 3837, 4045, 4080, 4026, 3965, 4058, 3567, 4067, 4054, 3999, 3959, 4069, 4057, 3838, 4074, 4023, 4060, 4015, 3963, 4073, 4070, 4029, 3966, 4081, 4047, 4076, 3581, 4059, 4030, 4082, 4027, 4071, 4061, 4084, 4055, 4078, 4062, 4088, 3583, 4075, 4077, 4083, 4085, 3839, 4086, 4089, 3967, 4090, 4087, 4092, 4091, 4079, 4031, 4094, 4095, 4063, 4093].

### Sequence Group 8: Z8_4096

[0, 1, 2, 7, 3, 8, 11, 24, 4, 10, 13, 28, 16, 33, 35, 77, 5, 12, 14, 32, 19, 38, 47, 81, 22, 46, 42, 88, 57, 96, 102, 168, 6, 17, 21, 40, 23, 45, 51, 90, 29, 55, 59, 97, 72, 110, 116, 186, 34, 61, 75, 114, 80, 123, 135, 197, 87, 137, 148, 225, 153, 238, 260, 381, 9, 18, 26, 54, 30, 58, 71, 105, 36, 76, 62, 117, 84, 127, 142, 206, 44, 74, 86, 136, 92, 145, 152, 233, 100, 155, 170, 252, 184, 268, 287, 424, 53, 89, 98, 151, 111, 162, 178, 265, 121, 179, 196, 279, 210, 301, 317, 461, 139, 204, 230, 307, 236, 320, 345, 494, 257, 353, 375, 519, 396, 544, 587, 815, 15, 25, 31, 73, 39, 79, 82, 141, 48, 85, 93, 150, 101, 160, 165, 262, 56, 94, 103, 163, 115, 177, 193, 282, 126, 194, 205, 296, 232, 314, 340, 481, 64, 108, 122, 183, 128, 195, 213, 309, 149, 228, 237, 322, 256, 351, 369, 518, 164, 246, 266, 357, 280, 389, 398, 539, 303, 412, 446, 574, 471, 608, 678, 817, 69, 124, 144, 216, 159, 235, 255, 355, 169, 258, 271, 380, 288, 397, 423, 563, 191, 283, 297, 409, 321, 438, 465, 618, 334, 474, 499, 650, 527, 688, 714, 943, 212, 310, 328, 450, 358, 480, 503, 667, 393, 515, 540, 704, 576, 718, 786, 1016, 421, 554, 588, 753, 603, 805, 833, 1073, 673, 853, 883, 1064, 915, 1129, 1203, 1490, 20, 37, 41, 91, 49, 95, 106, 176, 50, 107, 118, 187, 132, 207, 217, 336, 63, 119, 133, 222, 146, 231, 244, 337, 154, 243, 261, 374, 284, 392, 404, 538, 67, 143, 156, 224, 173, 247, 267, 390, 181, 275, 289, 406, 300, 435, 454, 600, 180, 298, 312, 434, 333, 468, 483, 651, 362, 505, 528, 687, 552, 712, 758, 993, 78, 167, 174, 273, 190, 294, 311, 425, 198, 316, 326, 463, 346, 492, 509, 685, 259, 341, 359, 497, 382, 525, 549, 706, 415, 558, 594, 750, 621, 802, 840, 1054, 293, 377, 407, 535, 431, 573, 598, 788, 459, 614, 634, 814, 679, 864, 894, 1103, 500, 675, 689, 884, 707, 917, 870, 1145, 769, 981, 1017, 1218, 1025, 1315, 1367, 1549, 83, 188, 192, 332, 248, 350, 368, 504, 274, 373, 383, 532, 414, 560, 593, 790, 290, 410, 430, 561, 448, 599, 625, 820, 475, 639, 666, 858, 705, 891, 939, 1153, 335, 436, 453, 624, 482, 657, 693, 874, 530, 696, 716, 935, 770, 911, 1003, 1228, 571, 742, 796, 985, 821, 1024, 1059, 1278, 865, 1067, 1066, 1351, 1147, 1387, 1431, 1684, 376, 472, 506, 697, 559, 717, 757, 955, 595, 789, 807, 1018, 850, 1033, 1065, 1309, 628, 829, 876, 1055, 898, 1071, 1149, 1389, 951, 1162, 1199, 1441, 1254, 1509, 1546, 1821, 686, 888, 929, 1151, 1001, 1156, 1242, 1464, 1014, 1234, 1284, 1529, 1334, 1581, 1658, 1934, 1035, 1320, 1381, 1605, 1414, 1668, 1630, 1963, 1485, 1725, 1760, 2074, 1844, 2124, 2211, 2399, 27, 43, 52, 99, 60, 120, 134, 214, 66, 138, 147, 221, 158, 241, 245, 386, 68, 157, 166, 240, 175, 295, 304, 420, 200, 306, 331, 460, 348, 485, 507, 702, 70, 172, 189, 299, 202, 329, 342, 478, 215, 354, 370, 516, 388, 545, 568, 720, 229, 378, 401, 556, 426, 592, 609, 776, 440, 601, 641, 828, 648, 856, 889, 1213, 109, 201, 211, 347, 223, 371, 387, 534, 253, 405, 416, 580, 443, 616, 638, 794, 272, 419, 452, 606, 477, 646, 653, 842, 496, 655, 664, 893, 740, 918, 975, 1230, 291, 476, 490, 662, 524, 691, 701, 903, 548, 739, 763, 950, 810, 994, 1019, 1289, 579, 785, 824, 1021, 866, 1050, 1113, 1337, 925, 1120, 1166, 1396, 1200, 1451, 1518, 1814, 112, 219, 242, 399, 270, 417, 447, 620, 286, 455, 479, 656, 501, 669, 681, 900, 315, 491, 521, 683, 547, 730, 755, 946, 577, 774, 808, 1010, 843, 1036, 1091, 1294, 343, 533, 567, 759, 610, 797, 795, 1039, 629, 832, 854, 1074, 905, 1117, 1137, 1401, 668, 867, 921, 1130, 947, 1181, 1202, 1468, 980, 1226, 1267, 1530, 1347, 1591, 1661, 1947, 364, 586, 615, 834, 652, 863, 907, 1121, 727, 924, 962, 1195, 966, 1208, 1249, 1505, 743, 964, 979, 1239, 1047, 1266, 1326, 1578, 1100, 1344, 1379, 1608, 1425, 1694, 1738, 1974, 775, 1061, 1084, 1297, 1142, 1355, 1386, 1647, 1167, 1419, 1471, 1720, 1519, 1768, 1831, 2089, 1273, 1473, 1533, 1781, 1602, 1858, 1887, 2185, 1649, 1913, 1961, 2235, 2025, 2312, 2385, 2666, 129, 254, 278, 458, 313, 489, 517, 711, 324, 526, 555, 737, 581, 766, 819, 1093, 356, 569, 619, 791, 643, 861, 845, 1102, 658, 877, 914, 1161, 958, 1187, 1216, 1486, 427, 632, 659, 859, 726, 902, 930, 1198, 736, 961, 973, 1217, 1000, 1250, 1277, 1555, 744, 990, 1028, 1275, 1098, 1323, 1371, 1611, 1132, 1411, 1424, 1701, 1472, 1739, 1801, 2057, 442, 725, 729, 948, 749, 965, 1009, 1260, 784, 1048, 1081, 1311, 1118, 1362, 1416, 1673, 920, 1095, 1144, 1373, 1171, 1448, 1475, 1727, 1255, 1480, 1540, 1787, 1604, 1850, 1879, 2179, 972, 1180, 1238, 1450, 1274, 1526, 1562, 1811, 1332, 1587, 1618, 1876, 1669, 1915, 1972, 2261, 1384, 1654, 1712, 1960, 1759, 2008, 2056, 2322, 1818, 2077, 2117, 2378, 2158, 2459, 2472, 2831, 451, 751, 765, 1089, 901, 1107, 1136, 1409, 937, 1157, 1191, 1459, 1246, 1497, 1553, 1805, 977, 1214, 1269, 1513, 1307, 1565, 1621, 1869, 1366, 1666, 1613, 1903, 1730, 1967, 2024, 2283, 1101, 1279, 1322, 1595, 1399, 1634, 1703, 1954, 1437, 1713, 1758, 2009, 1797, 2029, 2097, 2363, 1522, 1775, 1826, 2061, 1891, 2136, 2173, 2431, 1930, 2228, 2258, 2510, 2313, 2560, 2578, 2754, 1176, 1327, 1434, 1718, 1491, 1752, 1778, 2048, 1547, 1839, 1862, 2110, 1905, 2137, 2239, 2470, 1559, 1899, 1956, 2224, 2022, 2266, 2271, 2574, 2081, 2324, 2359, 2603, 2414, 2672, 2719, 2941, 1676, 2002, 2010, 2306, 2106, 2328, 2380, 2617, 2154, 2430, 2444, 2704, 2525, 2720, 2839, 3018, 2201, 2503, 2551, 2782, 2612, 2793, 2884, 3089, 2651, 2902, 2936, 3142, 2984, 3186, 3223, 3400, 140, 113, 65, 285, 104, 263, 182, 502, 125, 185, 203, 444, 220, 352, 323, 572, 161, 218, 239, 330, 264, 408, 372, 663, 302, 384, 422, 541, 462, 731, 612, 897, 171, 249, 269, 391, 305, 413, 469, 589, 325, 493, 439, 816, 531, 633, 674, 1209, 349, 473, 557, 647, 514, 700, 781, 1043, 582, 764, 728, 934, 841, 1094, 967, 1470, 199, 292, 308, 449, 344, 484, 537, 682, 379, 605, 495, 715, 570, 745, 804, 978, 411, 529, 645, 777, 613, 892, 762, 1015, 562, 809, 916, 1060, 860, 1258, 1128, 1724, 441, 642, 583, 851, 719, 818, 944, 1083, 672, 991, 882, 1184, 931, 1141, 1410, 1314, 752, 954, 1005, 1285, 1042, 1196, 1229, 1508, 1085, 1345, 1263, 1655, 1397, 1890, 1579, 2174, 234, 327, 365, 520, 400, 553, 604, 787, 437, 684, 575, 812, 635, 848, 904, 1150, 464, 611, 721, 857, 665, 974, 885, 1133, 748, 936, 1029, 1201, 995, 1244, 1329, 1536, 498, 710, 649, 910, 806, 959, 1037, 1223, 780, 1097, 976, 1418, 1075, 1282, 1295, 1614, 852, 1026, 1160, 1328, 1119, 1361, 1460, 1924, 1219, 1484, 1404, 1645, 1552, 1741, 1800, 2248, 546, 738, 825, 1011, 768, 1046, 1139, 1343, 871, 1188, 1080, 1525, 1231, 1378, 1455, 1700, 919, 1112, 1245, 1412, 1310, 1476, 1610, 1755, 1163, 1573, 1496, 1868, 1652, 1820, 1962, 2352, 963, 1272, 1335, 1583, 1194, 1531, 1627, 2001, 1385, 1690, 1749, 1878, 1548, 2075, 1935, 2756, 1430, 1721, 1786, 2049, 1823, 1969, 2028, 2455, 1660, 2114, 2159, 2305, 2210, 2629, 2384, 3163, 281, 385, 418, 607, 470, 690, 640, 896, 488, 654, 798, 942, 724, 988, 1032, 1262, 536, 754, 703, 1008, 803, 1131, 970, 1308, 862, 1049, 1148, 1354, 1088, 1504, 1449, 1909, 578, 813, 767, 1212, 928, 1038, 1092, 1363, 849, 1116, 1177, 1596, 1235, 1407, 1477, 1761, 949, 1261, 1197, 1524, 1336, 1463, 1603, 1817, 1293, 1572, 1638, 1855, 1699, 1942, 2059, 2296, 617, 1002, 835, 1143, 890, 1276, 1186, 1532, 971, 1222, 1317, 1487, 1360, 1582, 1648, 1892, 1058, 1413, 1296, 1745, 1251, 1598, 1635, 2031, 1481, 1687, 1769, 1948, 1819, 1995, 2119, 2495, 1106, 1440, 1358, 1659, 1515, 1726, 1859, 2103, 1590, 1902, 1751, 2044, 1796, 2231, 2168, 2439, 1388, 1838, 1968, 2195, 1914, 2142, 2338, 2424, 2011, 2310, 2249, 2596, 2403, 2539, 2673, 3214, 692, 906, 1020, 1259, 1082, 1306, 1458, 1672, 1140, 1542, 1333, 1719, 1405, 1620, 1822, 2099, 984, 1372, 1435, 1794, 1528, 1943, 1748, 2069, 1619, 1873, 1908, 2214, 1686, 2323, 2162, 2838, 1215, 1469, 1580, 1990, 1675, 1886, 1851, 2292, 1514, 1928, 2053, 2184, 2005, 2242, 2373, 2557, 1779, 2033, 1966, 2259, 2102, 2463, 2331, 2607, 2169, 2386, 2506, 2703, 2445, 2662, 2885, 3017, 1268, 1599, 1707, 1925, 1543, 2111, 1973, 2304, 1815, 1994, 2207, 2360, 2052, 2402, 2520, 2742, 1646, 2143, 2083, 2413, 2225, 2550, 2453, 2730, 2318, 2478, 2642, 2693, 2595, 2931, 2858, 3098, 1875, 2267, 2176, 2535, 2367, 2770, 2488, 2815, 2115, 2648, 2579, 2874, 2602, 2917, 2981, 3473, 2253, 2747, 2705, 3032, 2669, 2968, 3064, 3256, 2805, 3043, 3009, 3317, 3127, 3609, 3272, 3701, 363, 445, 508, 713, 566, 741, 799, 1034, 602, 895, 771, 1152, 844, 1072, 1204, 1454, 644, 811, 945, 1096, 875, 1301, 1146, 1503, 989, 1248, 1359, 1740, 1227, 1537, 1594, 1950, 680, 938, 899, 1190, 1004, 1243, 1342, 1612, 1099, 1415, 1283, 1558, 1400, 1653, 1807, 2041, 1051, 1370, 1321, 1644, 1462, 1762, 1702, 2003, 1527, 1795, 1872, 2381, 1896, 2178, 2118, 2534, 756, 960, 1090, 1300, 1189, 1346, 1576, 1685, 1027, 1380, 1474, 1744, 1406, 1845, 1753, 2088, 1170, 1512, 1541, 1939, 1436, 1806, 1904, 2206, 1667, 1957, 1833, 2151, 2030, 2252, 2329, 2657, 1292, 1564, 1706, 1877, 1626, 1991, 1949, 2287, 1774, 2108, 2045, 2243, 1938, 2339, 2391, 2638, 1609, 2131, 2080, 2361, 2215, 2479, 2432, 2731, 2017, 2415, 2526, 2923, 2594, 2855, 2792, 3173, 855, 1205, 1070, 1461, 1138, 1698, 1417, 1897, 1316, 1502, 1615, 1883, 1586, 1830, 1982, 2297, 1288, 1780, 1639, 2058, 1563, 1955, 1931, 2349, 1750, 2023, 2155, 2255, 2107, 2406, 2458, 2713, 1398, 1677, 1816, 2000, 1863, 2194, 2096, 2502, 1691, 2068, 2270, 2438, 2150, 2387, 2575, 2771, 1898, 2246, 2189, 2467, 2353, 2650, 2528, 2825, 2325, 2588, 2726, 2870, 2668, 2940, 2972, 3349, 1523, 1912, 1754, 2175, 1827, 2116, 2260, 2544, 1951, 2398, 2234, 2511, 2307, 2601, 2643, 2888, 2016, 2362, 2293, 2663, 2466, 2616, 2743, 3096, 2416, 2797, 2674, 2930, 2776, 3008, 3051, 3248, 2082, 2303, 2489, 2712, 2390, 2738, 2814, 2985, 2585, 2916, 2764, 3042, 2871, 3073, 3139, 3313, 2538, 2830, 2920, 3215, 2980, 3108, 3162, 3419, 2790, 3183, 3258, 3386, 3273, 3459, 3530, 3756, 992, 1247, 1185, 1631, 1350, 1695, 1597, 1975, 1408, 1554, 1832, 2200, 1763, 2032, 2125, 2417, 1465, 1804, 1731, 2060, 1929, 2330, 2109, 2473, 1893, 2163, 2247, 2600, 2302, 2527, 2675, 2922, 1577, 1946, 1874, 2177, 2004, 2230, 2254, 2545, 1810, 2286, 2372, 2692, 2452, 2653, 2628, 2961, 2076, 2379, 2494, 2613, 2425, 2727, 2777, 3026, 2348, 2808, 2718, 2987, 2862, 3083, 3126, 3361, 1674, 1854, 2098, 2366, 1983, 2319, 2471, 2701, 2188, 2561, 2407, 2656, 2172, 2746, 2791, 3039, 2238, 2454, 2507, 2927, 2584, 2765, 2842, 3222, 2649, 2912, 2809, 3072, 2971, 3109, 3208, 3397, 2311, 2524, 2702, 2843, 2597, 2990, 2913, 3143, 2755, 2875, 3027, 3169, 2937, 3303, 3226, 3434, 2667, 2986, 3065, 3249, 3112, 3334, 3294, 3505, 3050, 3265, 3387, 3553, 3360, 3469, 3583, 3777, 1882, 2040, 2130, 2462, 2282, 2639, 2433, 2804, 2229, 2529, 2521, 2889, 2606, 2960, 2863, 3187, 2358, 2721, 2589, 2854, 2757, 2921, 3033, 3168, 2700, 2991, 3055, 3227, 2973, 3268, 3323, 3504, 2412, 2652, 2824, 2969, 2739, 3082, 3016, 3259, 2783, 3038, 3099, 3401, 3182, 3295, 3312, 3552, 2903, 3155, 3217, 3322, 3138, 3435, 3362, 3544, 3088, 3373, 3468, 3639, 3425, 3582, 3629, 3869, 2556, 2796, 2859, 3154, 2970, 3054, 3216, 3335, 2926, 3097, 3172, 3363, 3257, 3464, 3418, 3585, 3019, 3209, 3264, 3458, 3302, 3396, 3499, 3667, 3316, 3511, 3472, 3628, 3545, 3663, 3693, 3964, 3113, 3269, 3348, 3498, 3372, 3510, 3573, 3662, 3424, 3572, 3531, 3728, 3608, 3729, 3692, 3868, 3465, 3584, 3638, 3734, 3666, 3735, 3757, 3819, 3700, 3776, 3818, 3845, 3844, 3965, 3886, 3887, 130, 131, 208, 251, 209, 276, 319, 432, 226, 318, 339, 466, 366, 511, 513, 747, 227, 338, 360, 510, 395, 542, 591, 773, 428, 590, 564, 800, 637, 836, 868, 1108, 250, 367, 403, 550, 429, 585, 623, 822, 467, 631, 661, 837, 732, 886, 922, 1164, 512, 671, 735, 912, 772, 941, 987, 1183, 793, 997, 1040, 1281, 1053, 1312, 1368, 1657, 277, 394, 456, 630, 486, 660, 723, 873, 522, 746, 676, 923, 782, 957, 1012, 1224, 584, 734, 792, 996, 826, 1023, 1052, 1299, 846, 1057, 1110, 1348, 1158, 1390, 1433, 1742, 627, 801, 838, 1045, 887, 1078, 1126, 1377, 933, 1127, 1182, 1421, 1232, 1467, 1507, 1809, 999, 1220, 1290, 1489, 1304, 1510, 1571, 1870, 1357, 1593, 1641, 1921, 1688, 1976, 2043, 2389, 361, 433, 487, 733, 543, 761, 778, 1007, 596, 783, 827, 1044, 847, 1076, 1087, 1374, 636, 830, 869, 1079, 913, 1125, 1175, 1426, 956, 1178, 1221, 1452, 1298, 1500, 1566, 1849, 694, 880, 940, 1155, 968, 1179, 1237, 1493, 1041, 1286, 1305, 1516, 1356, 1589, 1629, 1920, 1086, 1338, 1382, 1607, 1422, 1679, 1692, 1965, 1479, 1716, 1784, 2020, 1835, 2078, 2186, 2393, 709, 952, 1022, 1252, 1069, 1303, 1353, 1601, 1109, 1364, 1393, 1656, 1438, 1689, 1737, 1999, 1173, 1427, 1453, 1711, 1511, 1770, 1825, 2094, 1556, 1840, 1885, 2144, 1933, 2202, 2236, 2547, 1236, 1494, 1538, 1790, 1616, 1848, 1895, 2167, 1683, 1917, 1970, 2220, 2026, 2244, 2342, 2632, 1735, 1986, 2046, 2291, 2067, 2369, 2409, 2697, 2181, 2435, 2475, 2688, 2513, 2759, 2837, 3106, 402, 523, 551, 823, 597, 831, 878, 1124, 622, 879, 926, 1165, 982, 1225, 1253, 1560, 677, 927, 983, 1270, 1030, 1291, 1330, 1561, 1056, 1325, 1369, 1640, 1428, 1682, 1704, 1964, 699, 1013, 1062, 1280, 1115, 1339, 1383, 1680, 1135, 1403, 1439, 1708, 1466, 1765, 1798, 2064, 1134, 1456, 1498, 1764, 1551, 1828, 1853, 2145, 1622, 1901, 1936, 2199, 1984, 2232, 2300, 2611, 760, 1105, 1122, 1395, 1172, 1446, 1495, 1743, 1192, 1506, 1534, 1813, 1574, 1866, 1911, 2197, 1365, 1567, 1617, 1881, 1662, 1927, 1981, 2222, 1723, 1992, 2054, 2288, 2101, 2364, 2418, 2682, 1445, 1643, 1709, 1953, 1757, 2019, 2062, 2344, 1803, 2090, 2122, 2388, 2187, 2450, 2486, 2737, 1888, 2183, 2203, 2476, 2223, 2515, 2460, 2779, 2321, 2593, 2633, 2852, 2641, 2949, 2999, 3153, 779, 1168, 1174, 1550, 1340, 1588, 1628, 1900, 1402, 1637, 1663, 1944, 1722, 1996, 2051, 2346, 1442, 1714, 1756, 1997, 1788, 2063, 2105, 2396, 1841, 2127, 2166, 2442, 2221, 2483, 2543, 2789, 1557, 1766, 1793, 2104, 1852, 2153, 2209, 2464, 1940, 2212, 2240, 2537, 2326, 2509, 2621, 2864, 2015, 2278, 2354, 2599, 2397, 2640, 2685, 2910, 2451, 2691, 2690, 2983, 2781, 3013, 3057, 3260, 1642, 1836, 1906, 2213, 1993, 2241, 2299, 2563, 2055, 2345, 2371, 2634, 2428, 2655, 2689, 2945, 2112, 2405, 2468, 2683, 2492, 2695, 2785, 3015, 2559, 2800, 2833, 3063, 2890, 3119, 3150, 3357, 2198, 2480, 2531, 2787, 2619, 2794, 2876, 3080, 2630, 2868, 2918, 3135, 2964, 3179, 3240, 3432, 2659, 2952, 3007, 3199, 3044, 3246, 3220, 3453, 3103, 3289, 3318, 3520, 3374, 3554, 3597, 3695, 457, 565, 626, 839, 670, 932, 986, 1240, 698, 998, 1031, 1265, 1068, 1319, 1331, 1670, 708, 1063, 1104, 1318, 1123, 1447, 1482, 1734, 1206, 1488, 1545, 1808, 1584, 1857, 1907, 2218, 722, 1114, 1169, 1457, 1210, 1539, 1568, 1846, 1241, 1600, 1632, 1918, 1678, 1977, 2012, 2250, 1287, 1650, 1697, 1988, 1746, 2050, 2079, 2334, 1772, 2065, 2129, 2404, 2140, 2440, 2481, 2847, 881, 1207, 1233, 1575, 1271, 1633, 1671, 1952, 1349, 1705, 1728, 2036, 1777, 2092, 2126, 2350, 1394, 1733, 1792, 2072, 1843, 2138, 2147, 2420, 1880, 2149, 2164, 2485, 2276, 2516, 2583, 2866, 1443, 1842, 1864, 2160, 1926, 2205, 2217, 2499, 1980, 2275, 2309, 2558, 2376, 2614, 2635, 2925, 2035, 2341, 2400, 2637, 2456, 2680, 2745, 2967, 2523, 2752, 2802, 3020, 2834, 3069, 3124, 3350, 908, 1257, 1324, 1693, 1392, 1729, 1785, 2100, 1432, 1799, 1847, 2152, 1889, 2171, 2191, 2496, 1501, 1865, 1923, 2193, 1979, 2268, 2295, 2552, 2027, 2332, 2374, 2626, 2421, 2660, 2717, 2932, 1569, 1945, 2007, 2301, 2084, 2355, 2351, 2665, 2113, 2408, 2436, 2698, 2501, 2749, 2767, 3025, 2170, 2457, 2519, 2760, 2553, 2813, 2836, 3084, 2592, 2860, 2899, 3136, 2979, 3189, 3243, 3441, 1624, 2042, 2091, 2410, 2146, 2449, 2505, 2753, 2263, 2522, 2568, 2827, 2572, 2844, 2883, 3117, 2279, 2570, 2591, 2873, 2677, 2898, 2956, 3176, 2734, 2976, 3005, 3200, 3053, 3270, 3296, 3462, 2333, 2687, 2710, 2935, 2774, 2989, 3012, 3233, 2803, 3049, 3087, 3286, 3125, 3324, 3367, 3529, 2905, 3091, 3141, 3331, 3196, 3380, 3403, 3587, 3235, 3421, 3451, 3607, 3491, 3650, 3687, 3810, 969, 1352, 1420, 1802, 1499, 1861, 1919, 2227, 1520, 1932, 1987, 2273, 2037, 2316, 2395, 2723, 1606, 2013, 2095, 2347, 2133, 2447, 2423, 2736, 2156, 2469, 2512, 2799, 2564, 2819, 2850, 3104, 1747, 2120, 2157, 2443, 2262, 2498, 2532, 2832, 2272, 2567, 2581, 2851, 2618, 2886, 2909, 3159, 2280, 2608, 2646, 2907, 2732, 2955, 3001, 3203, 2762, 3037, 3052, 3277, 3090, 3297, 3341, 3513, 1776, 2257, 2265, 2554, 2285, 2571, 2625, 2894, 2340, 2678, 2707, 2947, 2750, 2996, 3046, 3251, 2518, 2725, 2778, 3003, 2807, 3066, 3093, 3291, 2891, 3100, 3146, 3333, 3198, 3376, 3395, 3581, 2580, 2812, 2872, 3068, 2906, 3132, 3164, 3347, 2962, 3185, 3210, 3392, 3247, 3423, 3460, 3625, 3010, 3238, 3282, 3450, 3315, 3482, 3512, 3654, 3354, 3523, 3549, 3682, 3566, 3723, 3732, 3875, 1791, 2289, 2315, 2715, 2497, 2741, 2766, 3035, 2541, 2795, 2823, 3075, 2880, 3111, 3157, 3343, 2587, 2848, 2901, 3121, 2943, 3167, 3213, 3385, 2998, 3244, 3205, 3413, 3292, 3455, 3490, 3633, 2735, 2911, 2954, 3191, 3023, 3224, 3279, 3446, 3061, 3283, 3314, 3483, 3339, 3493, 3533, 3677, 3128, 3327, 3364, 3517, 3405, 3558, 3575, 3711, 3430, 3602, 3622, 3746, 3651, 3768, 3772, 3846, 2810, 2957, 3058, 3284, 3107, 3308, 3328, 3506, 3151, 3371, 3382, 3542, 3415, 3559, 3611, 3730, 3161, 3411, 3448, 3600, 3488, 3626, 3631, 3770, 3525, 3656, 3673, 3787, 3704, 3814, 3831, 3913, 3254, 3478, 3484, 3646, 3538, 3658, 3684, 3793, 3564, 3710, 3716, 3826, 3751, 3832, 3877, 3934, 3593, 3743, 3765, 3856, 3790, 3861, 3892, 3955, 3803, 3896, 3910, 3970, 3924, 3982, 3991, 4030, 1006, 909, 695, 1429, 872, 1375, 1154, 1894, 953, 1159, 1211, 1782, 1264, 1592, 1517, 2018, 1077, 1256, 1313, 1544, 1376, 1710, 1636, 2161, 1478, 1664, 1736, 1971, 1812, 2269, 2086, 2491, 1111, 1341, 1391, 1681, 1483, 1717, 1829, 2047, 1521, 1867, 1771, 2392, 1941, 2121, 2182, 2845, 1585, 1837, 1989, 2139, 1916, 2216, 2337, 2671, 2038, 2314, 2264, 2536, 2419, 2724, 2573, 3086, 1193, 1444, 1492, 1789, 1570, 1856, 1959, 2192, 1651, 2071, 1871, 2237, 2014, 2281, 2368, 2590, 1715, 1937, 2135, 2335, 2087, 2484, 2308, 2631, 1998, 2375, 2514, 2686, 2446, 2892, 2758, 3288, 1773, 2132, 2039, 2429, 2245, 2394, 2548, 2709, 2180, 2609, 2474, 2816, 2533, 2773, 3036, 2948, 2290, 2562, 2623, 2919, 2670, 2828, 2865, 3118, 2711, 2977, 2897, 3239, 3021, 3404, 3177, 3576, 1302, 1535, 1625, 1922, 1696, 1985, 2070, 2343, 1767, 2196, 2021, 2382, 2123, 2426, 2500, 2786, 1824, 2085, 2251, 2441, 2165, 2582, 2477, 2763, 2284, 2540, 2647, 2835, 2615, 2878, 2959, 3144, 1884, 2226, 2141, 2508, 2370, 2565, 2661, 2857, 2336, 2729, 2586, 3048, 2699, 2914, 2933, 3206, 2434, 2644, 2798, 2958, 2751, 2995, 3076, 3426, 2853, 3102, 3028, 3231, 3156, 3299, 3340, 3616, 1978, 2274, 2401, 2627, 2320, 2676, 2769, 2975, 2461, 2820, 2706, 3131, 2867, 3004, 3071, 3276, 2517, 2744, 2879, 3040, 2946, 3094, 3202, 3311, 2801, 3171, 3110, 3384, 3236, 3356, 3452, 3670, 2569, 2904, 2965, 3181, 2826, 3137, 3219, 3477, 3011, 3266, 3305, 3394, 3152, 3521, 3433, 3848, 3056, 3287, 3332, 3507, 3359, 3457, 3492, 3721, 3242, 3546, 3567, 3645, 3596, 3795, 3686, 3975, 1423, 1665, 1732, 2073, 1834, 2204, 2128, 2490, 1860, 2148, 2356, 2546, 2256, 2604, 2654, 2896, 1958, 2294, 2219, 2624, 2365, 2761, 2576, 2944, 2448, 2679, 2784, 2988, 2714, 3116, 3067, 3417, 2034, 2383, 2317, 2846, 2530, 2664, 2722, 2997, 2427, 2748, 2811, 3192, 2869, 3031, 3095, 3319, 2555, 2895, 2829, 3130, 2966, 3079, 3197, 3353, 2929, 3170, 3228, 3379, 3275, 3438, 3515, 3640, 2093, 2620, 2411, 2775, 2482, 2908, 2818, 3140, 2577, 2856, 2951, 3105, 2994, 3180, 3234, 3406, 2684, 3041, 2934, 3301, 2887, 3194, 3225, 3495, 3101, 3263, 3325, 3442, 3355, 3475, 3551, 3741, 2740, 3062, 2992, 3241, 3123, 3290, 3381, 3537, 3188, 3412, 3307, 3502, 3338, 3605, 3570, 3715, 3014, 3370, 3456, 3591, 3422, 3560, 3664, 3708, 3485, 3648, 3617, 3782, 3697, 3761, 3815, 3986, 2208, 2504, 2636, 2893, 2708, 2942, 3074, 3250, 2772, 3148, 2963, 3285, 3029, 3212, 3358, 3535, 2598, 3002, 3059, 3336, 3134, 3439, 3304, 3519, 3211, 3389, 3416, 3598, 3262, 3655, 3568, 3876, 2849, 3085, 3178, 3470, 3253, 3402, 3377, 3636, 3122, 3428, 3509, 3586, 3481, 3612, 3681, 3767, 3329, 3497, 3454, 3623, 3536, 3725, 3661, 3789, 3571, 3688, 3744, 3825, 3717, 3808, 3893, 3933, 2900, 3195, 3281, 3427, 3149, 3543, 3461, 3644, 3351, 3474, 3595, 3674, 3508, 3696, 3748, 3840, 3232, 3561, 3527, 3703, 3601, 3764, 3719, 3836, 3652, 3736, 3798, 3821, 3781, 3909, 3882, 3958, 3391, 3627, 3578, 3759, 3679, 3852, 3738, 3871, 3547, 3800, 3773, 3890, 3786, 3901, 3923, 4045, 3619, 3843, 3827, 3938, 3813, 3916, 3948, 3996, 3865, 3943, 3931, 4013, 3967, 4065, 4004, 4077, 1623, 1783, 1910, 2233, 2006, 2277, 2357, 2658, 2066, 2487, 2327, 2788, 2422, 2696, 2840, 3070, 2134, 2377, 2549, 2728, 2465, 2939, 2780, 3115, 2605, 2882, 2993, 3298, 2861, 3145, 3190, 3444, 2190, 2542, 2493, 2822, 2622, 2877, 2974, 3204, 2733, 3045, 2915, 3160, 3024, 3237, 3345, 3501, 2681, 3000, 2953, 3230, 3078, 3320, 3278, 3479, 3133, 3337, 3388, 3685, 3408, 3580, 3550, 3758, 2298, 2566, 2716, 2938, 2821, 2978, 3174, 3261, 2645, 3006, 3092, 3300, 3030, 3375, 3309, 3528, 2806, 3120, 3147, 3437, 3060, 3344, 3414, 3594, 3245, 3449, 3369, 3563, 3494, 3618, 3659, 3807, 2928, 3166, 3280, 3393, 3218, 3471, 3443, 3635, 3326, 3540, 3503, 3613, 3436, 3665, 3691, 3796, 3201, 3557, 3524, 3675, 3599, 3737, 3712, 3837, 3487, 3705, 3752, 3905, 3780, 3881, 3860, 3979, 2437, 2841, 2694, 3077, 2768, 3274, 3047, 3409, 2950, 3114, 3207, 3399, 3184, 3366, 3466, 3641, 2924, 3330, 3229, 3514, 3165, 3447, 3431, 3669, 3306, 3489, 3565, 3621, 3539, 3698, 3722, 3829, 3022, 3255, 3352, 3476, 3383, 3590, 3532, 3742, 3267, 3518, 3630, 3714, 3562, 3689, 3771, 3853, 3410, 3614, 3589, 3727, 3671, 3802, 3754, 3873, 3657, 3778, 3834, 3888, 3812, 3912, 3920, 4019, 3129, 3420, 3310, 3577, 3365, 3548, 3624, 3762, 3445, 3694, 3606, 3747, 3647, 3785, 3799, 3894, 3486, 3676, 3637, 3809, 3726, 3792, 3841, 3956, 3706, 3863, 3816, 3908, 3854, 3930, 3945, 3994, 3526, 3643, 3739, 3828, 3690, 3838, 3870, 3925, 3775, 3900, 3850, 3942, 3889, 3951, 3969, 4011, 3760, 3874, 3902, 3987, 3922, 3960, 3974, 4033, 3858, 3981, 3998, 4026, 4005, 4039, 4052, 4082, 2610, 2881, 2817, 3221, 2982, 3271, 3193, 3463, 3034, 3158, 3368, 3592, 3321, 3496, 3555, 3707, 3081, 3342, 3293, 3516, 3429, 3660, 3541, 3733, 3407, 3569, 3615, 3784, 3642, 3753, 3817, 3904, 3175, 3440, 3390, 3579, 3480, 3604, 3620, 3763, 3346, 3634, 3680, 3820, 3718, 3805, 3794, 3915, 3522, 3683, 3740, 3791, 3709, 3835, 3855, 3936, 3668, 3866, 3830, 3927, 3884, 3953, 3966, 4021, 3252, 3378, 3534, 3678, 3467, 3653, 3731, 3823, 3588, 3769, 3699, 3806, 3574, 3842, 3859, 3941, 3610, 3720, 3745, 3907, 3774, 3851, 3878, 3990, 3801, 3898, 3867, 3950, 3919, 3961, 3984, 4029, 3649, 3750, 3824, 3879, 3783, 3928, 3899, 3971, 3847, 3891, 3937, 3977, 3911, 4009, 3992, 4036, 3811, 3926, 3949, 3995, 3962, 4016, 4006, 4049, 3944, 4001, 4027, 4057, 4020, 4043, 4061, 4085, 3398, 3500, 3556, 3724, 3632, 3797, 3713, 3864, 3603, 3755, 3749, 3895, 3788, 3914, 3885, 3983, 3672, 3833, 3779, 3880, 3849, 3903, 3939, 3976, 3822, 3929, 3947, 3993, 3921, 4002, 4015, 4048, 3702, 3804, 3872, 3917, 3839, 3952, 3932, 3999, 3857, 3940, 3959, 4031, 3980, 4007, 4010, 4056, 3897, 3973, 3989, 4014, 3968, 4037, 4022, 4054, 3954, 4025, 4042, 4069, 4035, 4060, 4067, 4091, 3766, 3862, 3883, 3972, 3918, 3946, 3988, 4017, 3906, 3957, 3978, 4023, 3997, 4040, 4032, 4063, 3935, 3985, 4000, 4038, 4008, 4028, 4047, 4073, 4012, 4051, 4044, 4066, 4055, 4071, 4075, 4094, 3963, 4003, 4018, 4046, 4024, 4050, 4059, 4070, 4034, 4058, 4053, 4078, 4064, 4079, 4074, 4090, 4041, 4062, 4068, 4080, 4072, 4081, 4083, 4087, 4076, 4084, 4086, 4089, 4088, 4095, 4092, 4093].

1. A polar code decoding method, comprising:
obtaining, by a decoding apparatus, a to-be-decoded information sequence, wherein the to-be-decoded information sequence comprises K to-be-decoded bits;
determining a mother code length N and a first sequence, wherein the first sequence comprises sequence numbers of N polarized subchannels, the sequence numbers of the N polarized subchannels are arranged in the first sequence based on reliability of the N polarized subchannels, N=2ⁿ, K≤N, N is greater than or equal to 32, and K, n, and N are positive integers;
determining, based on the first sequence, K polarized subchannels used to contain the K to-be-decoded bits, and decoding the to-be-decoded information sequence to obtain a decoding result; wherein
the first sequence is any one of: Q1_y, Q2_y, Q3_y, Q4_y, Q5_y, Q6_y, Q7_y or Q8_y; or the first sequence is a subsequence of any one of: Q1_y, Q2_y, Q3_y, Q4_y, Q5_y, Q6_y, Q7_y or Q8_y, wherein y is any value in 2048, 4096, 8192.

2. The polar code decoding method according to claim 1, wherein the first sequence is a subsequence of a second sequence, the second sequence comprises sequence numbers of Nₘₐₓ polarized subchannels, the sequence numbers of the Nₘₐₓ polarized subchannels are arranged in the second sequence based on reliability of the Nₘₐₓ polarized subchannels, N is less than or equal to Nₘₐₓ, and Nₘₐₓ=2ⁿ^{ₘₐₓ}, wherein nₘₐₓ is a positive integer, n is less than or equal to nₘₐₓ, and the second sequence is any one of: Q1_y, Q2_y, Q3_y, Q4_y, Q5_y, Q6_y, Q7_y or Q8_y.

3. The polar code decoding according to claim 1, wherein the K to-be-decoded bits comprise a cyclic redundancy check bit.

4. The polar code decoding method according to claim 1, wherein the K to-be-decoded bits comprise a parity check bit.

5. The polar code decoding method according to claim 1, wherein the determining, based on the first sequence, K polarized subchannels used to contain the K to-be-decoded bits comprises, in response to M being less than or equal to N, mapping the K to-be-decoded bits to the K polarized subchannels with high reliability in M−P non-punctured polarized subchannels to enable reliability of the polarized subchannels containing the K to-be-decoded bits to be higher than reliability of remaining M−P−K polarized subchannels, wherein M is a target code length, P is a quantity of pre-frozen polarized subchannels, and P is greater than or equal to 0.

6. The polar code decoding method according to claim 1, wherein the first sequence is prestored.

7. The polar code decoding method according to claim 1, wherein the sequence numbers of the N polarized subchannels are 0 to (N−1) or 1 to N.

8. A polar code decoding apparatus, comprising:
at least one processor, wherein when executing program instructions stored in at least one non-transitory memory, the polar code decoding apparatus is caused to:
obtain a to-be-decoded information sequence, wherein the to-be-decoded information sequence comprises K to-be-decoded bits;
determine a mother code length N and a first sequence, wherein the first sequence comprises sequence numbers of N polarized subchannels, the sequence numbers of the N polarized subchannels are arranged in the first sequence based on reliability of the N polarized subchannels, N=2ⁿ, K≤N, N is greater than or equal to 32, and K, n, and N are positive integers;
determine, based on the first sequence, K polarized subchannels used to contain the K to-be-decoded bits, and decoding the to-be-decoded information sequence to obtain a decoding result; wherein
the first sequence is any one of: Q1_y, Q2_y, Q3_y, Q4_y, Q5_y, Q6_y, Q7_y or Q8_y; or the first sequence is a subsequence of any one of: Q1_y, Q2_y, Q3_y, Q4_y, Q5_y, Q6_y, Q7_y or Q8_y, wherein y is any value in 2048, 4096, 8192.

9. The apparatus according to claim 8, wherein the first sequence is a subsequence of a second sequence, the second sequence comprises sequence numbers of Nₘₐₓ polarized subchannels, the sequence numbers of the Nₘₐₓ polarized subchannels are arranged in the second sequence based on reliability of the Nₘₐₓ polarized subchannels, N is less than or equal to Nₘₐₓ, and Nₘₐₓ=2ⁿ^{ₘₐₓ}, wherein nₘₐₓ is a positive integer, n is less than or equal to nₘₐₓ, and the second sequence is the second sequence is any one of: Q1_y, Q2_y, Q3_y, Q4_y, Q5_y, Q6_y, Q7_y or Q8_y.

10. The apparatus according to claim 8, wherein the K to-be-decoded bits comprise a cyclic redundancy check bit.

11. The apparatus according to claim 8, wherein the K to-be-decoded bits comprise a parity check bit.

12. The apparatus according to claim 8, wherein in response to M being less than or equal to N, the polar code encoding apparatus is caused to map the K to-be-decoded bits to the K polarized subchannels with high reliability in M−P non-punctured polarized subchannels to enable reliability of the polarized subchannels containing the K to-be-decoded bits to be higher than reliability of remaining M−P−K polarized subchannels, wherein M is a target code length, P is a quantity of pre-frozen polarized subchannels, and P is greater than or equal to 0.

13. The apparatus according to claim 8, wherein the first sequence is prestored.

14. The apparatus according to claim 8, wherein the sequence numbers of the N polarized subchannels are 0 to (N−1) or 1 to N.

15. A computer-readable medium, wherein the computer-readable medium is configured to store computer program instructions, and when the computer program instructions are executed by an apparatus, the apparatus is enabled to:
obtain a to-be-decoded information sequence, wherein the to-be-decoded information sequence comprises K to-be-decoded bits;
determine a mother code length N and a first sequence, wherein the first sequence comprises sequence numbers of N polarized subchannels, the sequence numbers of the N polarized subchannels are arranged in the first sequence based on reliability of the N polarized subchannels, N=2ⁿ, K≤N, N is greater than or equal to 32, and K, n, and N are positive integers;
determine, based on the first sequence, K polarized subchannels used to contain the K to-be-decoded bits, and decoding the to-be-decoded information sequence to obtain a decoding result; wherein
the first sequence is any one of: Q1_y, Q2_y, Q3_y, Q4_y, Q5_y, Q6_y, Q7_y or Q8_y; or the first sequence is a subsequence of any one of: Q1_y, Q2_y, Q3_y, Q4_y, Q5_y, Q6_y, Q7_y or Q8_y, wherein y is any value in 2048, 4096, 8192.

16. The computer-readable medium according to claim 15, wherein the first sequence is a subsequence of a second sequence, the second sequence comprises sequence numbers of Nₘₐₓ polarized subchannels, the sequence numbers of the Nₘₐₓ polarized subchannels are arranged in the second sequence based on reliability of the Nₘₐₓ polarized subchannels, N is less than or equal to Nₘₐₓ, and Nₘₐₓ=2ⁿ^{ₘₐₓ}, wherein nₘₐₓ is a positive integer, n is less than or equal to nₘₐₓ, and the second sequence is any one of: Q1_y, Q2_y, Q3_y, Q4_y, Q5_y, Q6_y, Q7_y or Q8_y.

17. The computer-readable medium according to claim 15, wherein the K to-be-decoded bits comprise a cyclic redundancy check bit.

18. The computer-readable medium according to claim 15, wherein the K to-be-decoded bits comprise a parity check bit.

19. The computer-readable medium according to claim 15, wherein in response to M being less than or equal to N, the apparatus is enabled to map the K to-be-decoded bits to the K polarized subchannels with high reliability in M−P non-punctured polarized subchannels to enable reliability of the polarized subchannels containing the K to-be-decoded bits to be higher than reliability of remaining M−P−K polarized subchannels, wherein M is a target code length, P is a quantity of pre-frozen polarized subchannels, and P is greater than or equal to 0.

20. The computer-readable medium according to claim 15, wherein the first sequence is prestored. ((save))
